(19) United States
(12) Patent Application Publication
(10) Pub. No.: US 2023/0270001 A1
(43) Pub. Date: Aug. 24, 2023

(54) LIGHT-EMITTING DEVICE INCLUDING HETEROCYCLIC COMPOUND, ELECTRONIC APPARATUS INCLUDING THE LIGHT-EMITTING DEVICE, AND THE HETEROCYCLIC COMPOUND

(71) Applicant: Samsung Display Co., Ltd., Yongin-si (KR)

(72) Inventors: Hyeongmin Kim, Yongin-si (KR); Heechoon Ahn, Yongin-si (KR); Hyunah Um, Yongin-si (KR); Juhui Yun, Yongin-si (KR); Yeseul Lee, Yongin-si (KR)

(21) Appl. No.: 18/166,409

(22) Filed: Feb. 8, 2023

(30) Foreign Application Priority Data
Feb. 24, 2022 (KR) 10-2022-0024573

(51) Int. Cl. H10K 85/40; C07F 7/08; H10K 85/60; H10K 50/12

(52) U.S. Cl. CPC H10K 85/40; C07F 7/0812; H10K 85/6572; H10K 85/654; H10K 50/12; C07B 2200/05; H10K 2102/301

(57) ABSTRACT

A light-emitting device includes a heterocyclic compound represented by Formula 1, an electronic apparatus includes the light-emitting device, and the heterocyclic compound is represented by Formula 1:

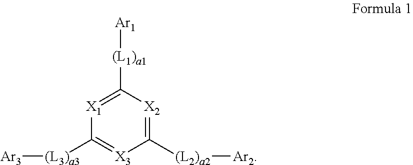

Formula 1 is the same as described in the present specification.

### CROSS-REFERENCE TO RELATED APPLICATION

This application claims priority to and the benefit of Korean Patent Application No. 10-2022-0024573, filed on Feb. 24, 2022, in the Korean Intellectual Property Office, the entire content of which is hereby incorporated by reference.

### BACKGROUND

### 1. Field

One or more embodiments relate to a light-emitting device including a heterocyclic compound, an electronic apparatus including the light-emitting device, and the heterocyclic compound.

### 2. Description of the Related Art

Self-emissive devices from among light-emitting devices have relatively wide viewing angles, high contrast ratios, short response times, and/or excellent or suitable characteristics in terms of luminance, driving voltage, and/or response speed.

In a light-emitting device, a first electrode is arranged on a substrate, and a hole transport region, an emission layer, an electron transport region, and a second electrode are sequentially arranged on the first electrode. Holes provided from the first electrode may move toward the emission layer through the hole transport region, and electrons provided from the second electrode may move toward the emission layer through the electron transport region. Carriers, such as holes and electrons, recombine in the emission layer region to produce excitons. These excitons transition from an excited state to a ground state to thereby generate light.

### SUMMARY

Aspects according to one or more embodiments of the present disclosure are directed toward a light-emitting device including a heterocyclic compound, an electronic apparatus including the light-emitting device, and the heterocyclic compound.

Additional aspects will be set forth in part in the description which follows and, in part, will be apparent from the description, or may be learned by practice of the presented embodiments of the disclosure.

According to one or more embodiments,
a light-emitting device includes a first electrode,
a second electrode facing the first electrode, and
an interlayer between the first electrode and the second electrode and including an emission layer,
wherein the light-emitting device includes a heterocyclic compound represented by Formula 1.

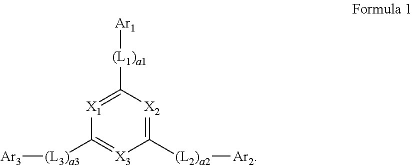

In Formula 1,
X₁ may be C(R₁₀ₐₐ) or N,
X₂ may be C(R_{10ab}) or N,
X₃ may be C(R_{10ac}) or N,
at least one of X₁ to X₃ may be N,
L₁ to L₃ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a1 to a3 may each independently be an integer from 0 to 3,
wherein, when a1 is 0, *-(L₁)ₐ₁-*′ may be a single bond,
when a2 is 0, *-(L₂)ₐ₂-*′ may be a single bond, and
when a3 is 0, *-(L₃)ₐ₃-*′ may be a single bond,
Ar₁ may be a group represented by Formula 1-1, and
Ar₂ to Ar₃ may each independently be a C₃-C₃₀ carbocyclic group that is unsubstituted or substituted with R₁₀ₐ or a π electron-rich C₃-C₆₀ cyclic group that is unsubstituted or substituted with R₁₀ₐ,

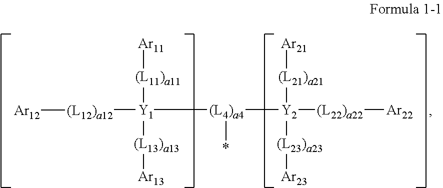

wherein, in Formula 1-1,
Y₁ and Y₂ may each independently be C, Si, or Ge,
Ar₁₁, Ar₁₂, Ar₁₃, Ar₂₁, Ar₂₂, Ar₂₃, L₁₁, L₁₂, L₁₃, L₂₁, L₂₂, L₂₃, and L₄ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a11, a12, a13, a21, a22, and a23 may each independently be an integer from 0 to 3,
wherein a sum of a11, a12, a13, a21, a22, and a23 may be 1 or more,
when a11 is 0, *-(L₁₁)ₐ₁₁-*′ may be a single bond,
when a12 is 0, *-(L₁₂)ₐ₁₂-*′ may be a single bond,
when a13 is 0, *-(L₁₃)ₐ₁₃-*′ may be a single bond,
when a21 is 0, *-(L₂₁)ₐ₂₁-*′ may be a single bond,
when a22 is 0, *-(L₂₂)ₐ₂₂-*′ may be a single bond, and
when a23 is 0, *-(L₂₃)ₐ₂₃-*′ may be a single bond,
a4 may be an integer from 1 to 3,
* may indicate a binding site to a neighboring atom,
R₁₀ₐ, R₁₀ₐₐ, R_{10ab}, and R_{10ac} may each independently be
deuterium, —F, —Cl, —Br, —I, a hydroxyl group, a cyano group, or a nitro group,
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —C₁, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₂, Q₁₁ to Q₁₃, Q₂₁ to Q₂₃, and Q₃₁ to Q₃₃ may each independently be hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

According to one or more embodiments, an electronic apparatus includes the light-emitting device.

According to one or more embodiments, the heterocyclic compound represented by Formula 1 is provided.

### BRIEF DESCRIPTION OF THE DRAWINGS

The above and other aspects, features, and enhancements of certain embodiments of the disclosure will be more apparent from the following description taken in conjunction with the accompanying drawings, in which:

FIG. 1 is a schematic cross-sectional view of a light-emitting device according to an embodiment;

FIG. 2 is a schematic cross-sectional view of an electronic apparatus according to an embodiment; and

FIG. 3 is a cross-sectional schematic view of an electronic apparatus according to another embodiment.

### DETAILED DESCRIPTION

Reference will now be made in more detail to embodiments, examples of which are illustrated in the accompanying drawings, wherein like reference numerals refer to like elements throughout, and duplicative descriptions thereof may not be provided the specification. In this regard, the present embodiments may have different forms and should not be construed as being limited to the descriptions set forth herein. Accordingly, the embodiments are merely described below, by referring to the drawings, to explain aspects of the present description. As utilized herein, the term “and/or” includes any and all combinations of one or more of the associated listed items. Throughout the disclosure, the expression “at least one of a, b or c”, “at least one selected from a, b, and c”, “at least one selected from the group consisting of a, b, and c”, “at least one of a to c”, etc., indicates only a, only b, only c, both (e.g., simultaneously) a and b, both (e.g., simultaneously) a and c, both (e.g., simultaneously) b and c, all of a, b, and c, or variations thereof. Also, as used herein, the singular forms “a”, “an” and “the” are intended to include the plural forms as well, unless the context clearly indicates otherwise.

A light-emitting device according to an embodiment of the disclosure may include: a first electrode; a second electrode facing the first electrode; an interlayer arranged between the first electrode and the second electrode and including an emission layer; and a heterocyclic compound represented by Formula 1.

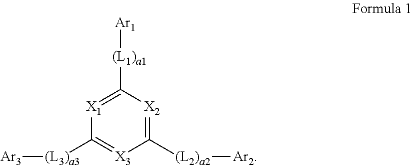

In Formula 1,
X₁ may be C(R₁₀ₐₐ) or N,
X₂ may be C(R_{10ab}) or N,
X₃ may be C(R_{10ac}) or N,
at least one of X₁ to X₃ may be N,
L₁ to L₃ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a1 to a3 may each independently be an integer from 0 to 3,
wherein, when a1 is 0, *-(L₁)ₐ₁-*′ may be a single bond,
when a2 is 0, *-(L₂)ₐ₂-*′ may be a single bond, and
when a3 is 0, *-(L₃)ₐ₃*′ may be a single bond,
Ar₁ may be a group represented by Formula 1-1, and
Ar₂ to Ar₃ may each independently be a C₃-C₃₀ carbocyclic group that is unsubstituted or substituted with R₁₀ₐ or a π electron-rich C₃-C₆₀ cyclic group that is unsubstituted or substituted with R₁₀ₐ,

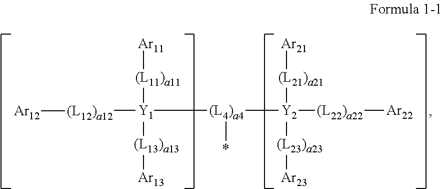

in Formula 1-1,
Y₁ and Y₂ may each independently be C, Si, or Ge,
Ar₁₁, Ar₁₂, Ar₁₃, Ar₂₁, Ar₂₂, Ar₂₃, L₁₁, L₁₂, L₁₃, L₂₁, L₂₂, L₂₃, and L₄ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a11, a12, a13, a21, a22, and a23 may each independently be an integer from 0 to 3,
wherein the sum of a11, a12, a13, a21, a22, and a23 may be 1 or more,
when a11 is 0, *-(L₁₁)ₐ₁₁-*′ may be a single bond,
when a12 is 0, *-(L₁₂)ₐ₁₂-*′ may be a single bond,
when a13 is 0, *-(L₁₃)ₐ₁₃-*′ may be a single bond,
when a21 is 0, *-(L₂₁)ₐ₂₁-*′ may be a single bond,
when a22 is 0, *-(L₂₂)ₐ₂₂-*′ may be a single bond, and
when a23 is 0, *-(L₂₃)ₐ₂₃-*′ may be a single bond,
a4 may be an integer from 1 to 3,
* may indicate a binding site to a neighboring atom,
R₁₀ₐ, R₁₀ₐₐ, R_{10ab}, and R_{10ac} may each independently be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —C₁, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₂, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In the light-emitting device according to an embodiment, the interlayer may include the heterocyclic compound represented by Formula 1.

In the light-emitting device according to an embodiment, the emission layer may include the heterocyclic compound represented by Formula 1, and the emission layer may further include a fluorescent dopant or a phosphorescent dopant.

In the light-emitting device according to an embodiment, the first electrode may be an anode, the second electrode may be a cathode,

the interlayer may further include a hole transport region arranged between the first electrode and the emission layer and an electron transport region arranged between the emission layer and the second electrode,

the hole transport region may include a hole injection layer, a hole transport layer, an emission auxiliary layer, an electron blocking layer, or any combination thereof, and

the electron transport region may include a hole blocking layer, an electron transport layer, an electron injection layer, or any combination thereof.

In the light-emitting device according to an embodiment, the hole transport region may include the heterocyclic compound represented by Formula 1.

In the light-emitting device according to an embodiment, the electron transport region may include the heterocyclic compound represented by Formula 1.

In the light-emitting device according to an embodiment, the emission layer may be to emit blue light.

The light-emitting device according to an embodiment may further include a first capping layer and/or a second capping layer, the first capping layer may be located on one surface of the first electrode, and the second capping layer may be located on one surface of the second electrode.

In the light-emitting device according to an embodiment, at least one of the first capping layer or the second capping layer may include the heterocyclic compound represented by Formula 1.

Also, an electronic apparatus may include the light-emitting device according to any one of embodiments.

The electronic apparatus according to an embodiment may further include
a thin-film transistor,
the thin-film transistor may include a source electrode and a drain electrode, and
the first electrode of the light-emitting device may be electrically connected to the source electrode or the drain electrode of the thin-film transistor.

The electronic apparatus according to an embodiment may further include

a color filter, a color-conversion layer, a touch screen layer, a polarizing layer, or any combination thereof.

Also, according to one or more embodiments, a heterocyclic compound represented by Formula 1 is provided.

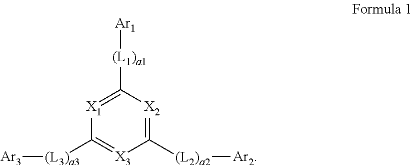

In Formula 1,
X₁ may be C(R₁₀ₐₐ) or N,
X₂ may be C(R_{10ab}) or N,
X₃ may be C(R_{10ac}) or N,
at least one of X₁ to X₃ may be N,
L₁ to L₃ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a1 to a3 may each independently be an integer from 0 to 3,
wherein, when a1 is 0, *-(L₁)ₐ₁-*′ may be a single bond,
when a2 is 0, *-(L₂)ₐ₂-*′ may be a single bond, and
when a3 is 0, *-(L₃)ₐ₃*′ may be a single bond,
Ar₁ may be a group represented by Formula 1-1, and
Ar₂ to Ar₃ may each independently be a C₃-C₃₀ carbocyclic group that is unsubstituted or substituted with R₁₀ₐ or a π electron-rich C₃-C₆₀ cyclic group that is unsubstituted or substituted with R₁₀ₐ,

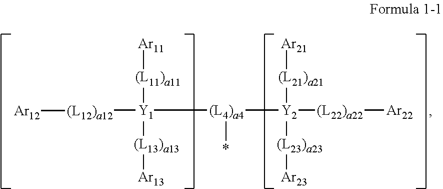

in Formula 1-1,
Y₁ and Y₂ may each independently be C, Si, or Ge,
Ar₁₁, Ar₁₂, Ar₁₃, Ar₂₁, Ar₂₂, Ar₂₃, L₁₁, L₁₂, L₁₃, L₂₁, L₂₂, L₂₃, and L₄ may each independently be a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a11, a12, a13, a21, a22, and a23 may each independently be an integer from 0 to 3,
wherein the sum of a11, a12, a13, a21, a22, and a23 may be 1 or more,
when a11 is 0, *-(L₁₁)ₐ₁₁-*′ may be a single bond,
when a12 is 0, *-(L₁₂)ₐ₁₂-*′ may be a single bond,
when a13 is 0, *-(L₁₃)ₐ₁₃-*′ may be a single bond,
when a21 is 0, *-(L₂₁)ₐ₂₁-*′ may be a single bond,
when a22 is 0, *-(L₂₂)ₐ₂₂-*′ may be a single bond, and
when a23 is 0, *-(L₂₃)ₐ₂₃-*′ may be a single bond,
a4 may be an integer from 1 to 3,
* may indicate a binding site to a neighboring atom,
R₁₀ₐ, R₁₀ₐₐ, R_{10ab}, and R_{10ac} may each independently be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —C₁, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₂, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In the heterocyclic compound according to an embodiment,
i) each of X₁ to X₃ may be N;
ii) X₁ may be C(R₁₀ₐₐ), X₂ may be N, and X₃ may be N;
iii) X₁ may be N, X₂ may be C(R_{10ab}), and X₃ may be N;
iv) X₁ may be N, X₂ may be N, and X₃ may be C(R_{10ac});
v) X₁ may be C(R₁₀ₐₐ), X₂ may be C(R_{10ab}), and X₃ may be N;
vi) X₁ may be C(R₁₀ₐₐ), X₂ may be N, and X₃ may be C(R_{10ac}); or
vii) X₁ may be N, X₂ may be C(R_{10ab}), and X₃ may be C(R_{10ac}).

In the heterocyclic compound according to an embodiment,
L₁ to L₃ may each independently be a divalent linking group of a benzene group or a divalent linking group of a naphthalene group.

In the heterocyclic compound according to an embodiment,
L₄ may be a trivalent linking group of a benzene group or a trivalent linking group of a naphthalene group.

In the heterocyclic compound according to an embodiment,
L₁ to L₃ may each independently be a group represented by one of Formulae 1-5-1 to 1-5-3,

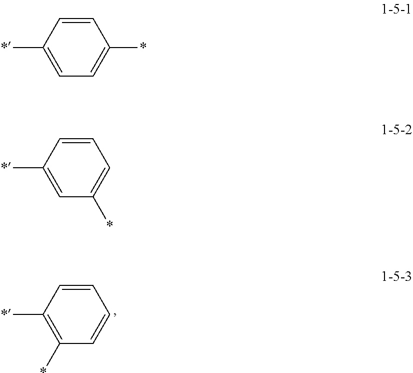

wherein, in Formulae 1-5-1 to 1-5-3,
* and *′ may each indicate a binding site to a neighboring atom.

In the heterocyclic compound according to an embodiment,
L₄ may be a group represented by one of Formulae 1-5-4 to 1-5-6

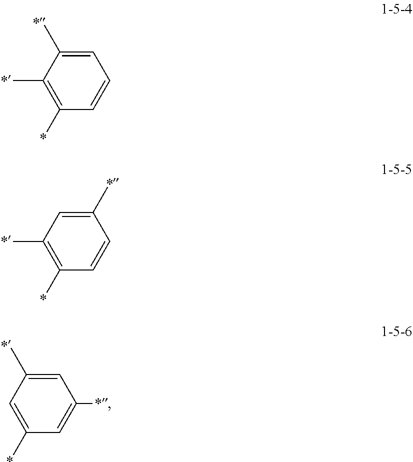

wherein, in Formulae 1-5-4 to 1-5-6,
*, *′, and *″ may each indicate a binding site to a neighboring atom.

In the heterocyclic compound according to an embodiment,
i) each of a1 to a3 may be 1;
ii) a1 may be 0, and each of a2 and a3 may be 1;
iii) a2 may be 0, and each of a1 and a3 may be 1;
iv) a3 may be 0, and each of a1 and a2 may be 1;
v) each of a1 and a2 may be 0, and a3 may be 1;
vi) each of a1 and a3 may be 0, and a2 may be 1; or
vii) each of a2 and a3 may be 0, and a1 may be 1.

In the heterocyclic compound according to an embodiment,
in Formula 1-1,
Ar₁₁ to Ar₁₃ may all be identical to each other, or two of Ar₁₁ to Ar₁₃ may be identical to each other.

In the heterocyclic compound according to an embodiment,
in Formula 1-1,
Ar₁₁ to Ar₁₃ may be different from each other.

In the heterocyclic compound according to an embodiment,
in Formula 1-1,
Ar₂₁ to Ar₂₃ may all be identical to each other, or two of Ar₂₁ to Ar₂₃ may be identical to each other.

In the heterocyclic compound according to an embodiment,
in Formula 1-1,
Ar₂₁ to Ar₂₃ may be different from each other.

In the heterocyclic compound according to an embodiment,
in Formula 1-1,
two or more of Ar₁₁ to Ar₁₃ and Ar₂₁ to Ar₂₃ may be identical to each other. In an embodiment, one of Ar₁₁ to Ar₁₃ and one of Ar₂₁ to Ar₂₃ may be identical to each other. In an embodiment, Ar₁₁ and Ar₂₁ may be identical to each other, Ar₁₂ and Ar₂₂ may be identical to each other, or Ar₁₃ and Ar₂₃ may be identical to each other.

In the heterocyclic compound according to an embodiment,
in Formula 1-1,
Ar₁₁ to Ar₁₃ and Ar₂₁ to Ar₂₃ may each independently be a benzene group, a naphthalene group, or a biphenyl group.

In the heterocyclic compound according to an embodiment,
in Formula 1-1,
i) the sum of a₁₁ to a₁₃ may be 1 or more, and the sum of a₂₁ to a₂₃ may be 0,
ii) the sum of a₁₁ to a₁₃ may be 0, and the sum of a₂₁ to a₂₃ may be 1 or more, or
iii) the sum of a₁₁ to a₁₃ may be 1 or more, and the sum of a₂₁ to a₂₃ may be 1 or more.

In the heterocyclic compound according to an embodiment,
in Formula 1-1
   a moiety represented by

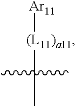

a moiety represented by

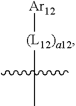

a moiety represented by

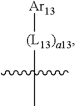

a moiety represented by

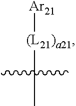

a moiety represented by

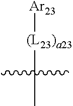

and a moiety represented by

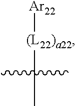

may each independently be a benzene group or a group represented by one of Formulae 1-1-1 to 1-1-19,

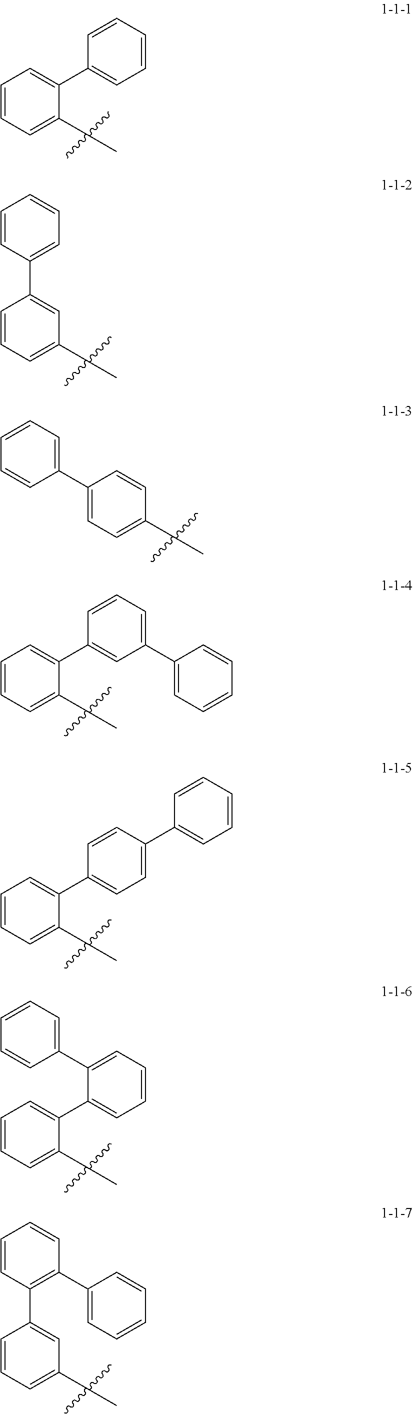

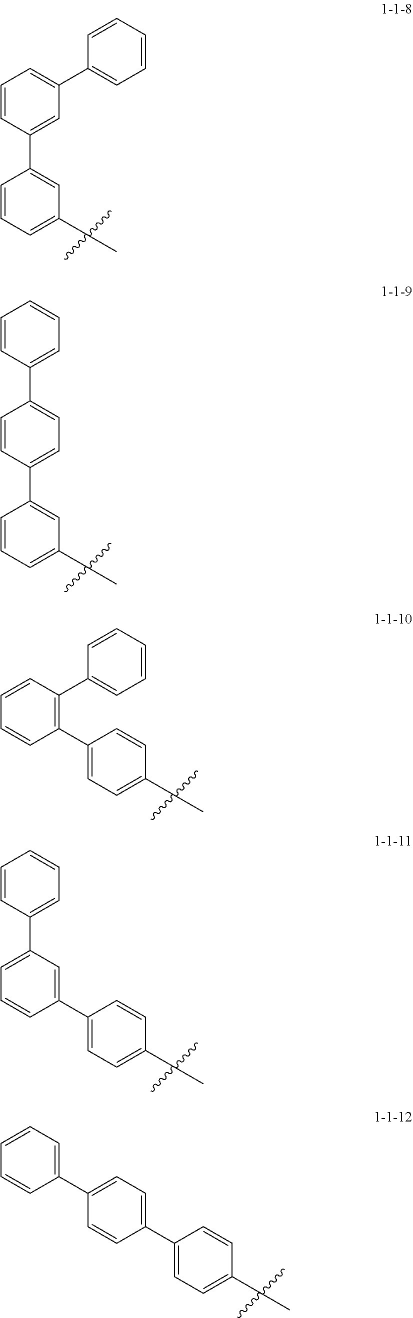

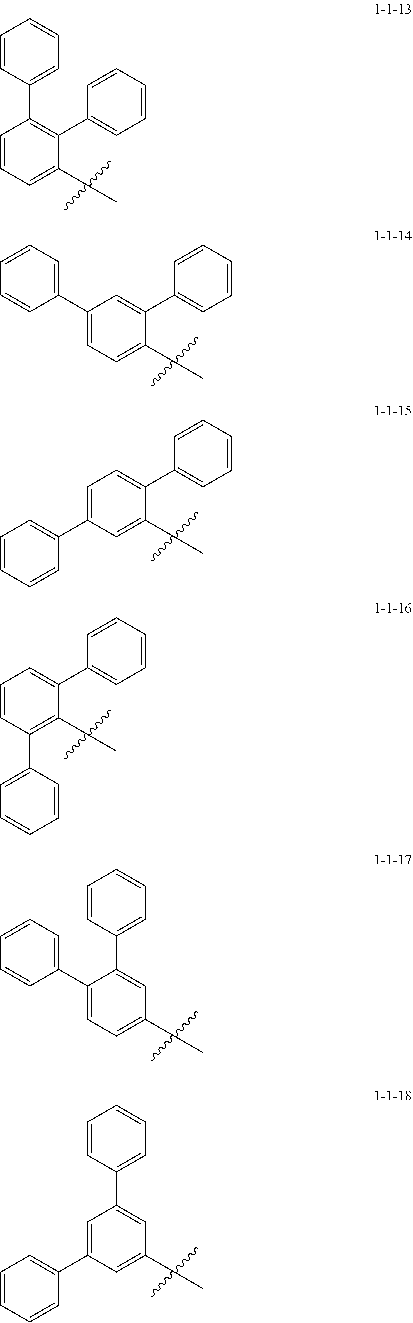

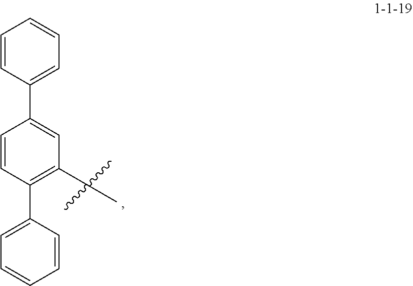

wherein, in Formulae 1-1-1 to 1-1-19,
[symbol] may indicate a binding site to a neighboring atom.

In the heterocyclic compound according to an embodiment,
Ar₂ or Ar₃ may be a carbazole group that is unsubstituted or substituted with at least one R₁₀ₐ.

In the heterocyclic compound according to an embodiment,

the other one of Ar₂ and Ar₃ that is not the carbazole group may be a benzene group or a group represented by one of Formulae 1-6-1 to 1-6-3,

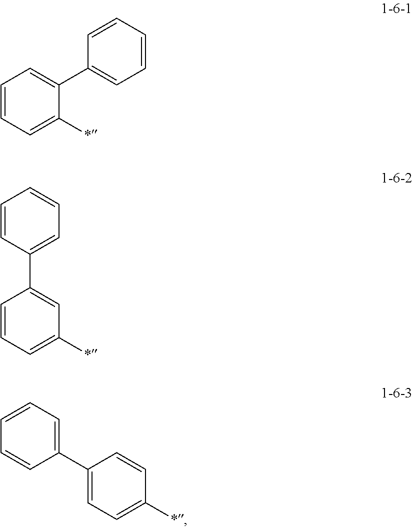

wherein, in Formulae 1-6-1 to 1-6-3,
*″ may indicate a binding site to a neighboring atom.

In the heterocyclic compound according to an embodiment,

Ar₂ and Ar₃ may each independently be a carbazole group that is unsubstituted or substituted with at least one R₁₀ₐ.

In the heterocyclic compound according to an embodiment,
R₁₀ₐ substituted in the carbazole group may be an isopropane group, an isobutane group, a secbutane group, a tertbutane group, an isopentane group, a secpentane group, a tertpentane group, a neopentane group, or a benzene group.

The heterocyclic compound according to an embodiment may have a degree of deuteration of about 1% or more, for example, about 15% or more, or, about 25% or more. By satisfying these ranges, chemical decomposition of the heterocyclic compound may be delayed in the process of hole and/or electron transfer, and lifespan characteristics of a light-emitting device including the heterocyclic compound may be improved.

The degree of deuteration may be calculated by dividing the number of deuterium atoms chemically bonded to the heterocyclic compound by the total number of hydrogen atoms and deuterated atoms, which are bonded to the heterocyclic compound. In an embodiment, a degree of deuteration of a benzene group (CH₅D) in which one deuterium is substituted is about 16.67%.

In the heterocyclic compound according to an embodiment,
a C₃-C₃₀ carbocyclic group may be a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indeno phenanthrene group, an indenoanthracene group, an adamantanyl group, a norbornanyl group, a norbornenyl group, a bicyclo[1.1.1]pentyl group, a bicyclo[2.1.1]hexyl group, a bicyclo[2.2.2]octyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a mono(C₁-C₂₀ alkyl)adamantanyl group, a di(C₁-C₂₀ alkyl)adamantanyl group, a mono(C₁-C₂₀ alkyl)norbornanyl group, a di(C₁-C₂₀ alkyl)norbornanyl group, a mono(C₁-C₂₀ alkyl)norbornenyl group, a di(C₁-C₂₀ alkyl)norbornenyl group, or a biphenyl group, and
a C₁-C₃₀ heterocyclic group may be a pyrrole group, a thiophene group, a furan group, an indole group, a benzoindole group, a naphthoindole group, an isoindole group, a benzoiso-indole group, a naphthoiso-indole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an azacarbazole group, an azafluorene group, an azadibenzosilole group, an azadibenzothiophene group, or an azadibenzofuran group.

In the heterocyclic compound according to an embodiment,

the π electron-rich C₃-C₆₀ cyclic group may be a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoiso-indole group, a naphthoiso-indole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, or a benzothienodibenzothiophene group.

In an embodiment, the heterocyclic compound represented by Formula 1 may be at least one of Compounds 1 to 210.

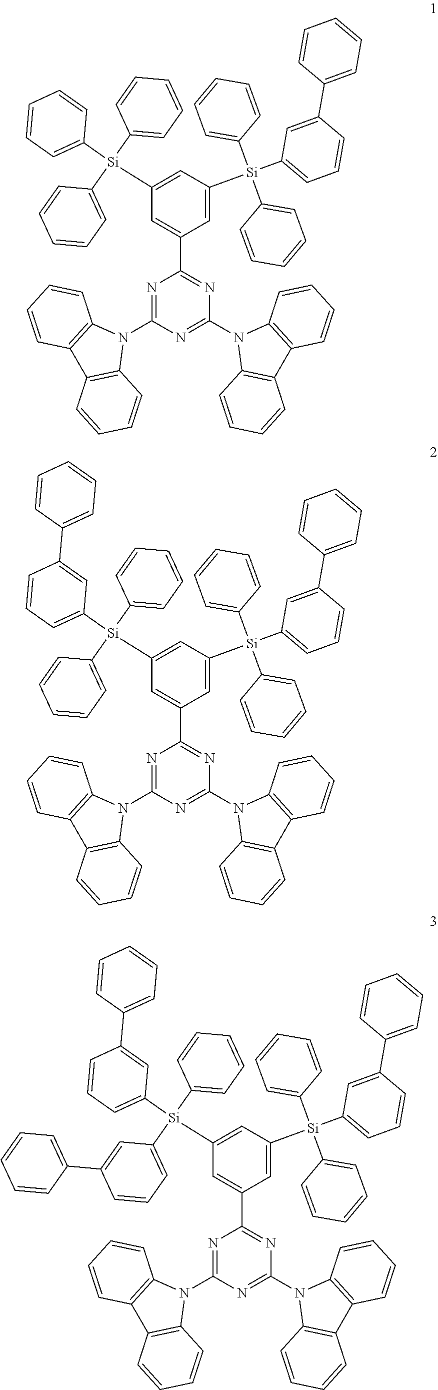

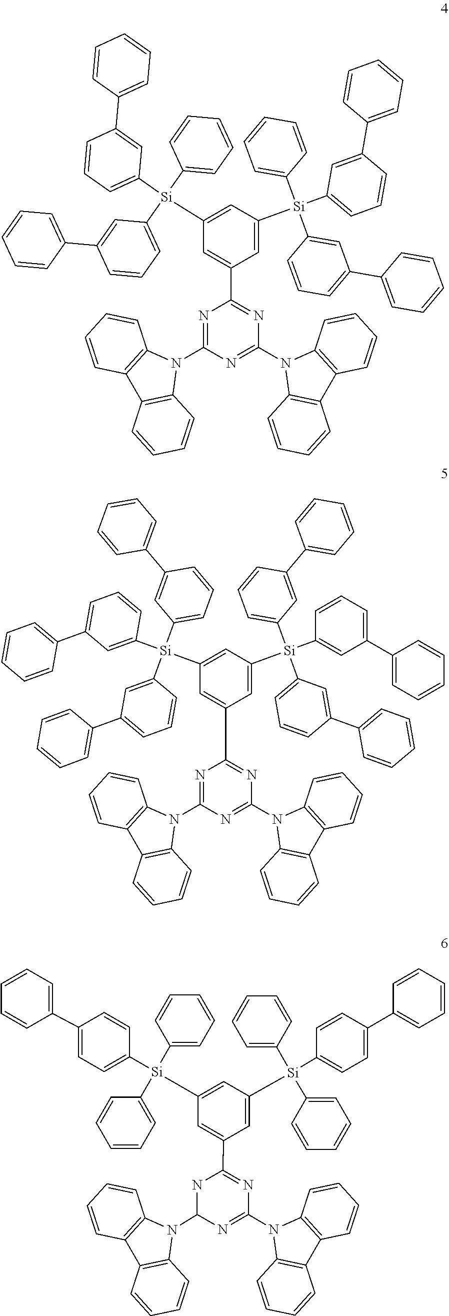

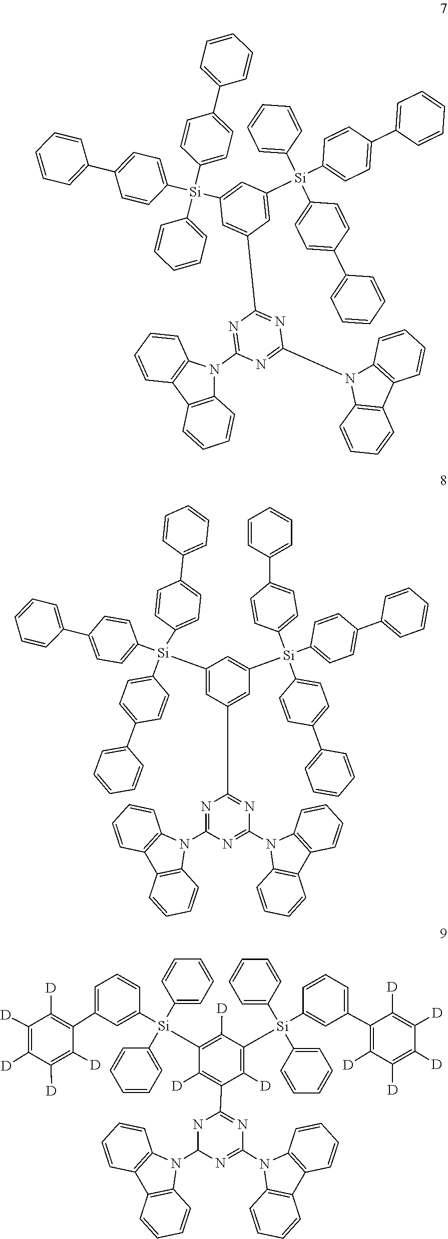

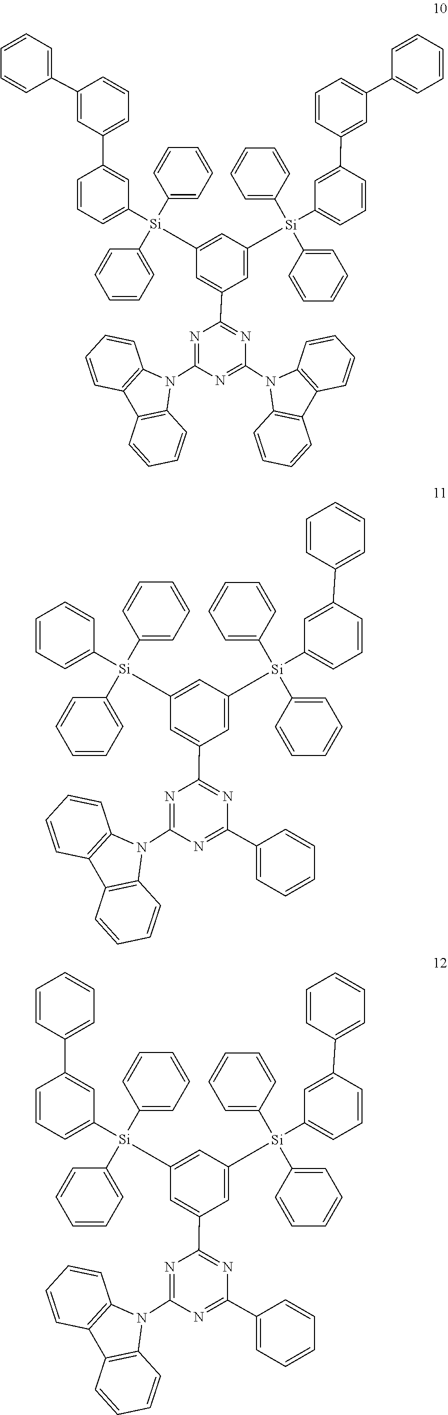 [SMILES: c1ccc(-c2cccc(-c3cccc([Si](c4ccccc4)(c4ccccc4)c4cc(-c5nc(-n6c7ccccc7c7ccccc76)nc(-n6c7ccccc7c7ccccc76)n5)cc([Si](c5ccccc5)(c5ccccc5)c5cccc(-c6cccc(-c7ccccc7)c6)c5)c4)c3)c2)cc1 ; c1ccc(-c2cccc([Si](c3ccccc3)(c3ccccc3)c3cc(-c4nc(-c5ccccc5)nc(-n5c6ccccc6c6ccccc65)n4)cc([Si](c4ccccc4)(c4ccccc4)c4ccccc4)c3)c2)cc1 ; c1ccc(-c2cccc([Si](c3ccccc3)(c3ccccc3)c3cc(-c4nc(-c5ccccc5)nc(-n5c6ccccc6c6ccccc65)n4)cc([Si](c4ccccc4)(c4ccccc4)c4cccc(-c5ccccc5)c4)c3)c2)cc1]

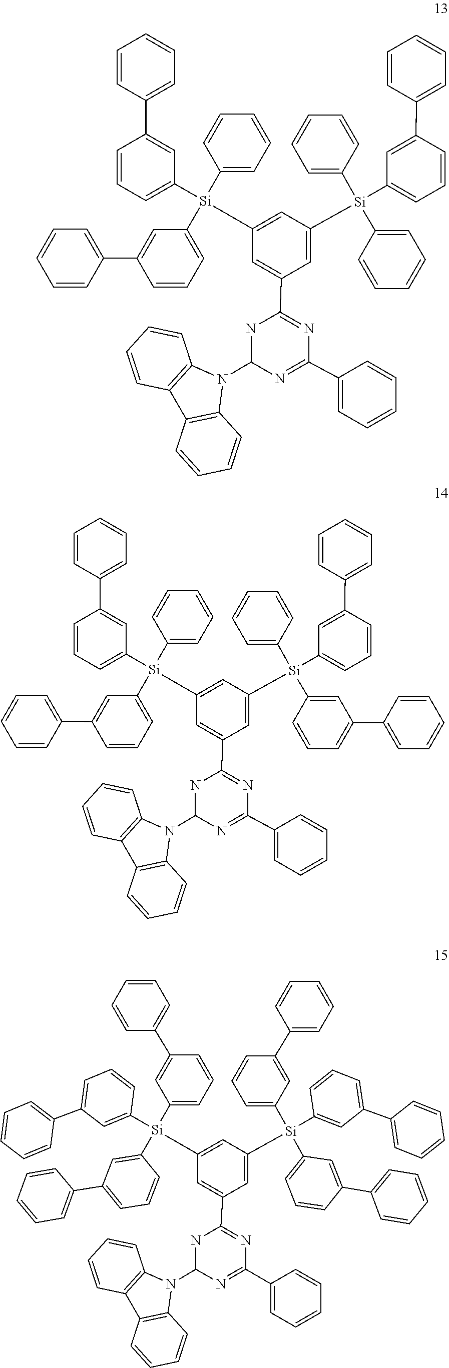

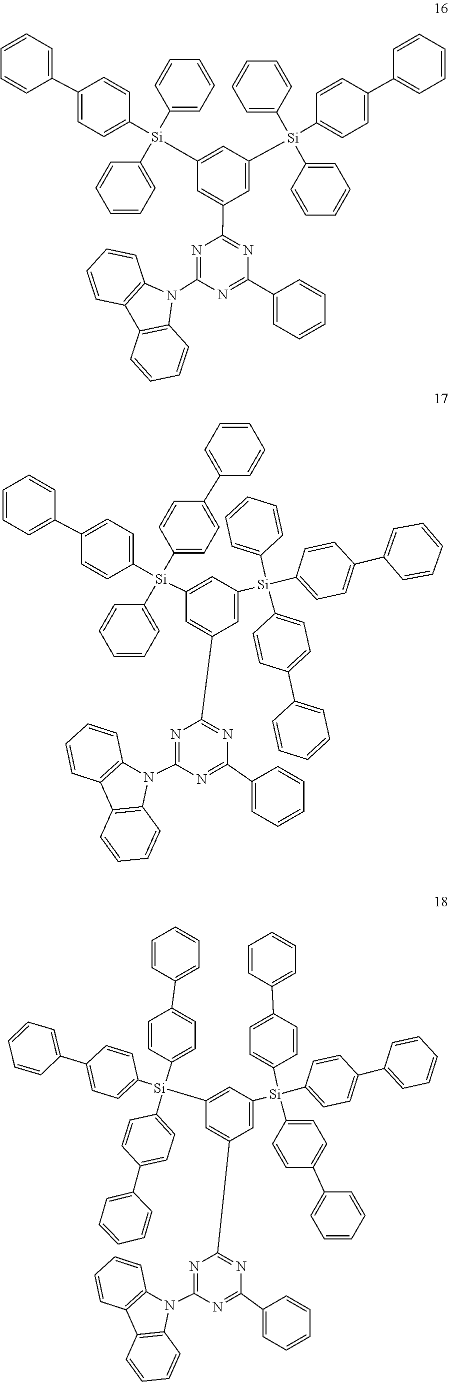 [SMILES: c1ccc(-c2ccc([Si](c3ccccc3)(c3ccccc3)c3cc(-c4nc(-c5ccccc5)nc(-n5c6ccccc6c6ccccc65)n4)cc([Si](c4ccccc4)(c4ccccc4)c4ccc(-c5ccccc5)cc4)c3)cc2)cc1 ; c1ccc(-c2ccc([Si](c3ccccc3)(c3ccc(-c4ccccc4)cc3)c3cc(-c4nc(-c5ccccc5)nc(-n5c6ccccc6c6ccccc65)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4nc(-c5ccccc5)nc(-n5c6ccccc6c6ccccc65)n4)cc([Si](c4ccc(-c5ccccc5)cc4)(c4ccc(-c5ccccc5)cc4)c4ccc(-c5ccccc5)cc4)c3)cc2)cc1]

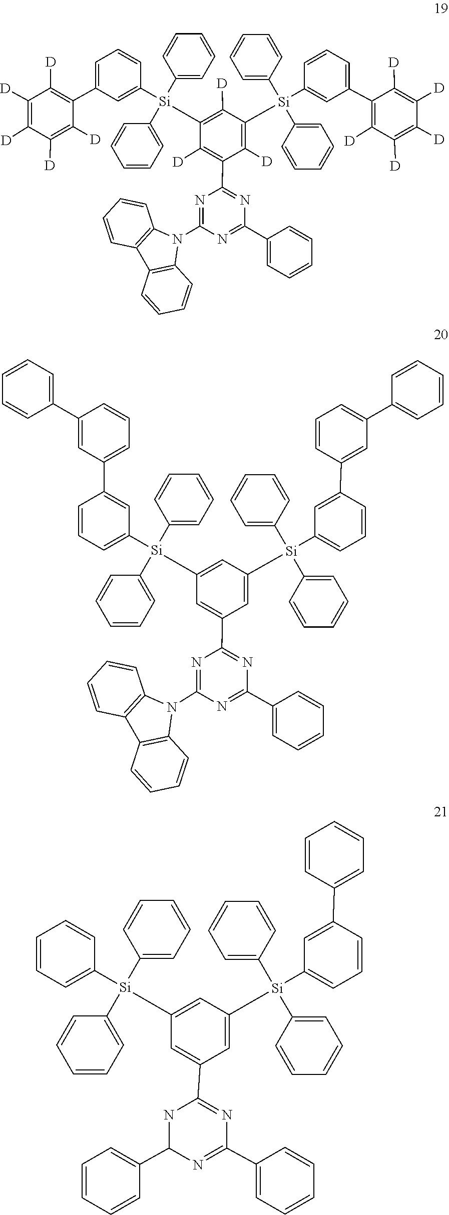

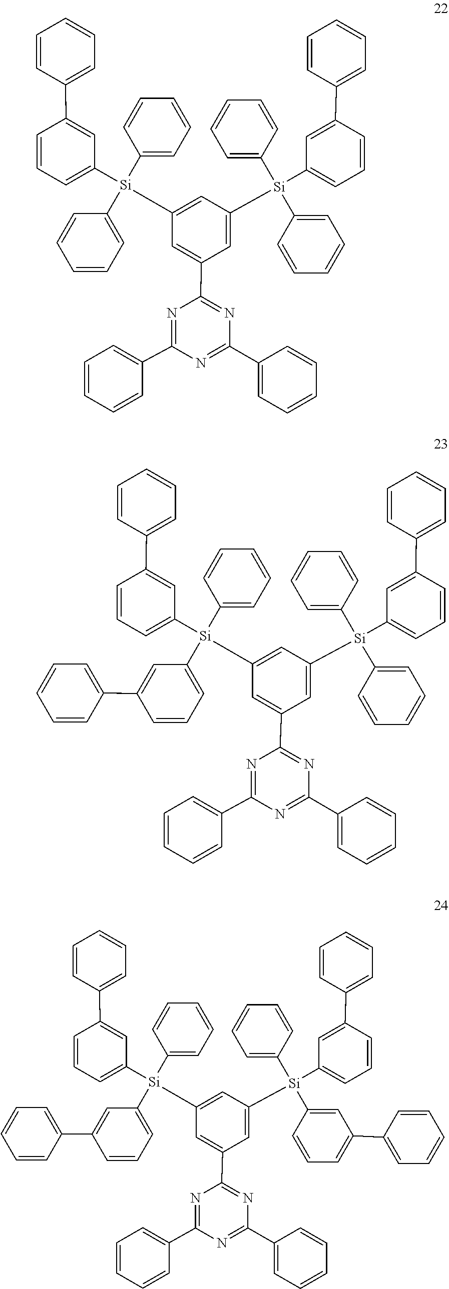 [SMILES: c1ccc(-c2cccc([Si](c3ccccc3)(c3ccccc3)c3cc(-c4nc(-c5ccccc5)nc(-c5ccccc5)n4)cc([Si](c4ccccc4)(c4ccccc4)c4cccc(-c5ccccc5)c4)c3)c2)cc1 ; c1ccc(-c2cccc([Si](c3ccccc3)(c3ccccc3)c3cc(-c4nc(-c5ccccc5)nc(-c5ccccc5)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4nc(-c5ccccc5)nc(-c5ccccc5)n4)cc([Si](c4ccccc4)(c4cccc(-c5ccccc5)c4)c4cccc(-c5ccccc5)c4)c3)c2)cc1]

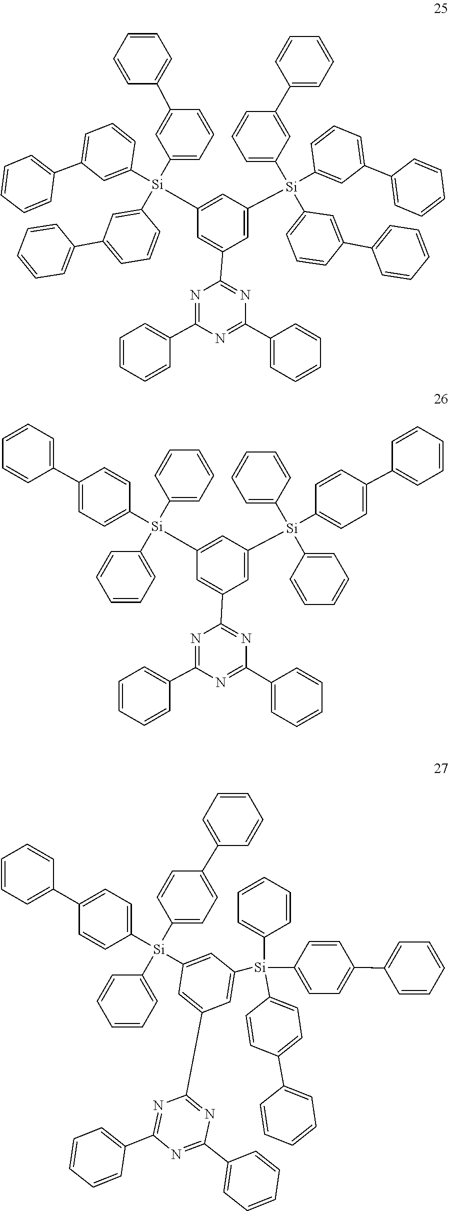 [SMILES: c1ccc(-c2cccc([Si](c3cccc(-c4ccccc4)c3)(c3cccc(-c4ccccc4)c3)c3cc(-c4nc(-c5ccccc5)nc(-c5ccccc5)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4nc(-c5ccccc5)nc(-c5ccccc5)n4)cc([Si](c4ccccc4)(c4ccccc4)c4ccc(-c5ccccc5)cc4)c3)cc2)cc1 ; c1ccc(-c2ccc([Si](c3ccccc3)(c3ccc(-c4ccccc4)cc3)c3cc(-c4nc(-c5ccccc5)nc(-c5ccccc5)n4)cc([Si](c4ccccc4)(c4ccc(-c5ccccc5)cc4)c4ccc(-c5ccccc5)cc4)c3)cc2)cc1]

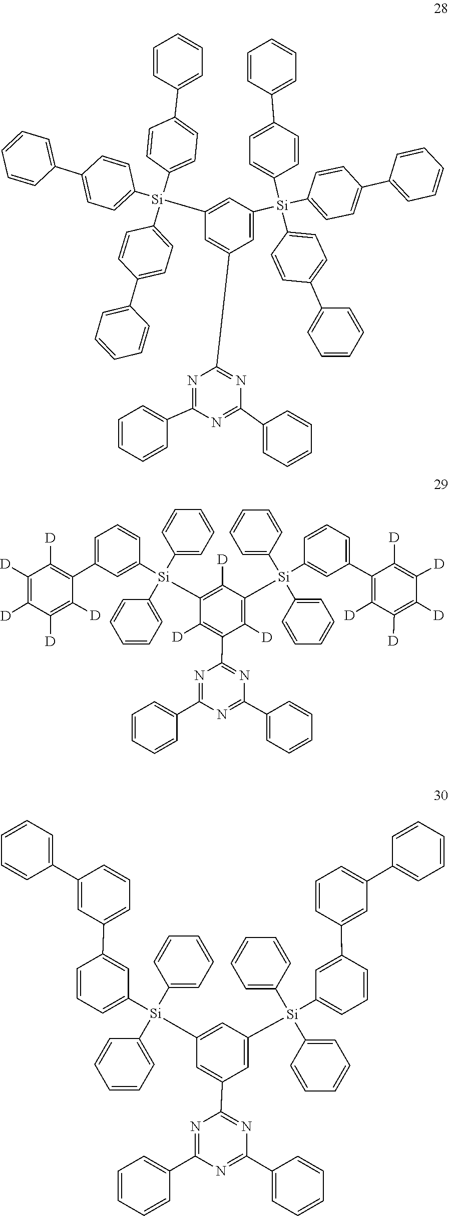

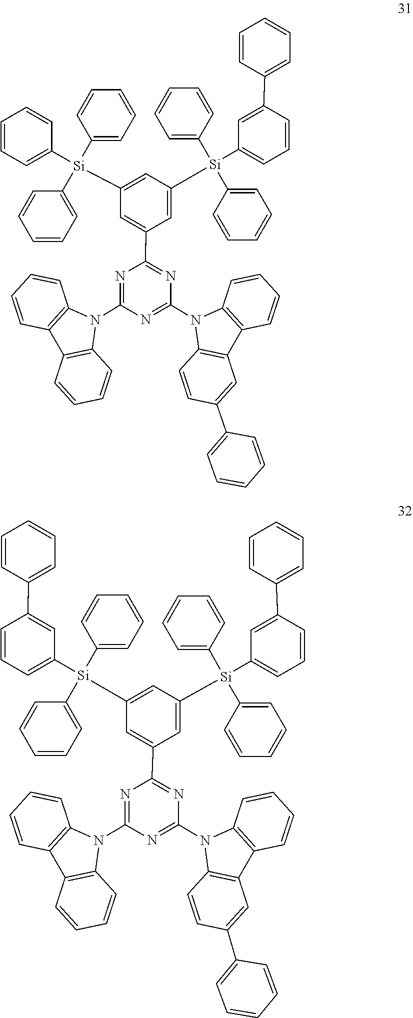 [SMILES: c1ccc(-c2cccc([Si](c3ccccc3)(c3ccccc3)c3cc(-c4nc(-n5c6ccccc6c6ccccc65)nc(-n5c6ccccc6c6cc(-c7ccccc7)ccc65)n4)cc([Si](c4ccccc4)(c4ccccc4)c4ccccc4)c3)c2)cc1 ; c1ccc(-c2cccc([Si](c3ccccc3)(c3ccccc3)c3cc(-c4nc(-n5c6ccccc6c6ccccc65)nc(-n5c6ccccc6c6cc(-c7ccccc7)ccc65)n4)cc([Si](c4ccccc4)(c4ccccc4)c4cccc(-c5ccccc5)c4)c3)c2)cc1]

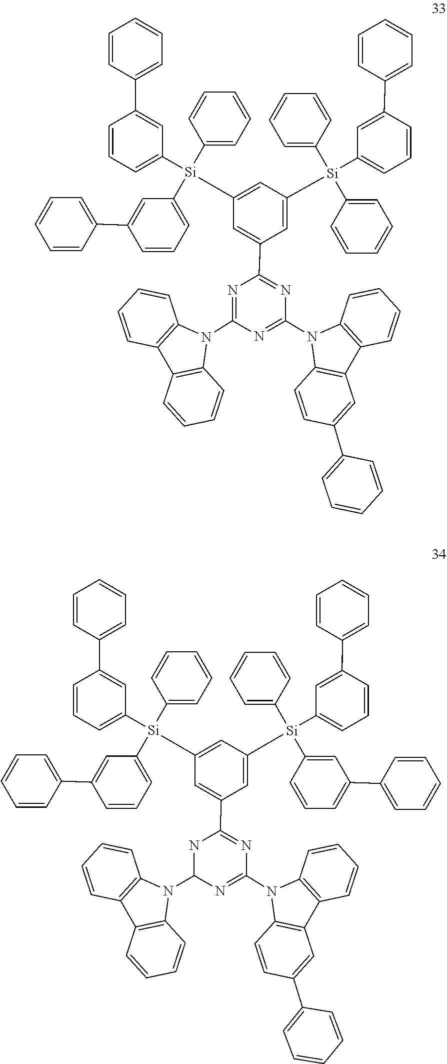

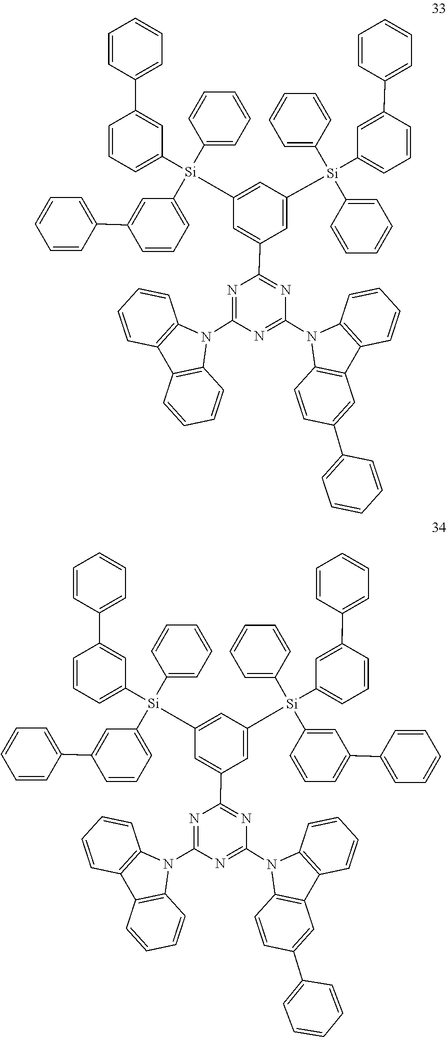 [SMILES: c1ccc(-c2cccc([Si](c3ccccc3)(c3ccccc3)c3cc(-c4nc(-n5c6ccccc6c6ccccc65)nc(-n5c6ccccc6c6cc(-c7ccccc7)ccc65)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4nc(-n5c6ccccc6c6ccccc65)nc(-n5c6ccccc6c6cc(-c7ccccc7)ccc65)n4)cc([Si](c4ccccc4)(c4cccc(-c5ccccc5)c4)c4cccc(-c5ccccc5)c4)c3)c2)cc1]

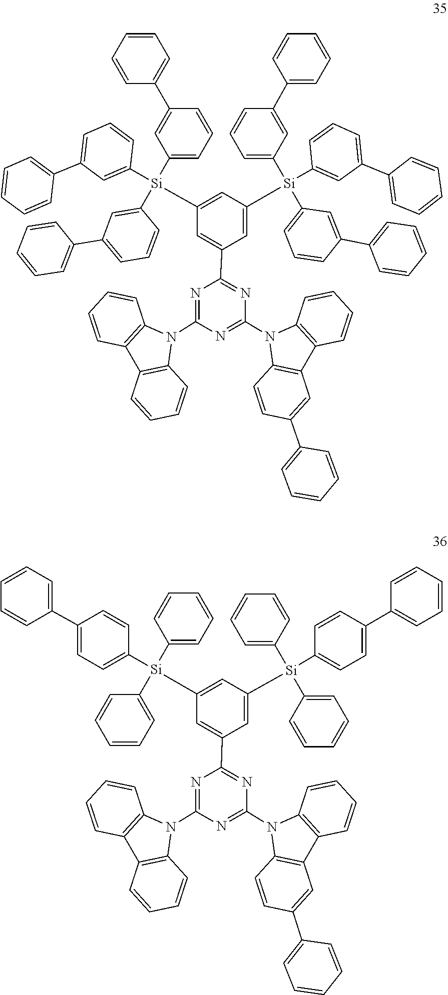 [SMILES: c1ccc(-c2cccc([Si](c3cccc(-c4ccccc4)c3)(c3cccc(-c4ccccc4)c3)c3cc(-c4nc(-n5c6ccccc6c6ccccc65)nc(-n5c6ccccc6c6cc(-c7ccccc7)ccc65)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4nc(-n5c6ccccc6c6ccccc65)nc(-n5c6ccccc6c6cc(-c7ccccc7)ccc65)n4)cc([Si](c4ccccc4)(c4ccccc4)c4ccc(-c5ccccc5)cc4)c3)cc2)cc1]

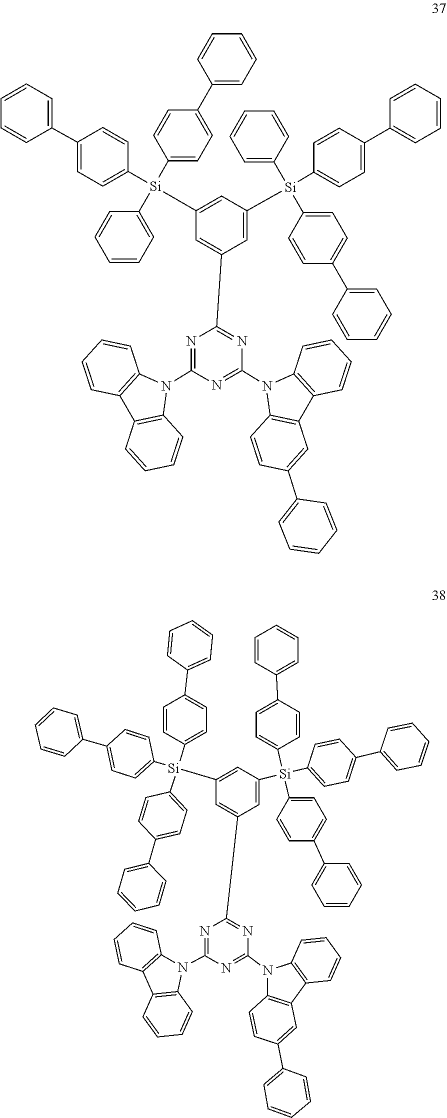 [SMILES: c1ccc(-c2ccc([Si](c3ccccc3)(c3ccc(-c4ccccc4)cc3)c3cc(-c4nc(-n5c6ccccc6c6ccccc65)nc(-n5c6ccccc6c6cc(-c7ccccc7)ccc65)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4nc(-n5c6ccccc6c6ccccc65)nc(-n5c6ccccc6c6cc(-c7ccccc7)ccc65)n4)cc([Si](c4ccc(-c5ccccc5)cc4)(c4ccc(-c5ccccc5)cc4)c4ccc(-c5ccccc5)cc4)c3)cc2)cc1]

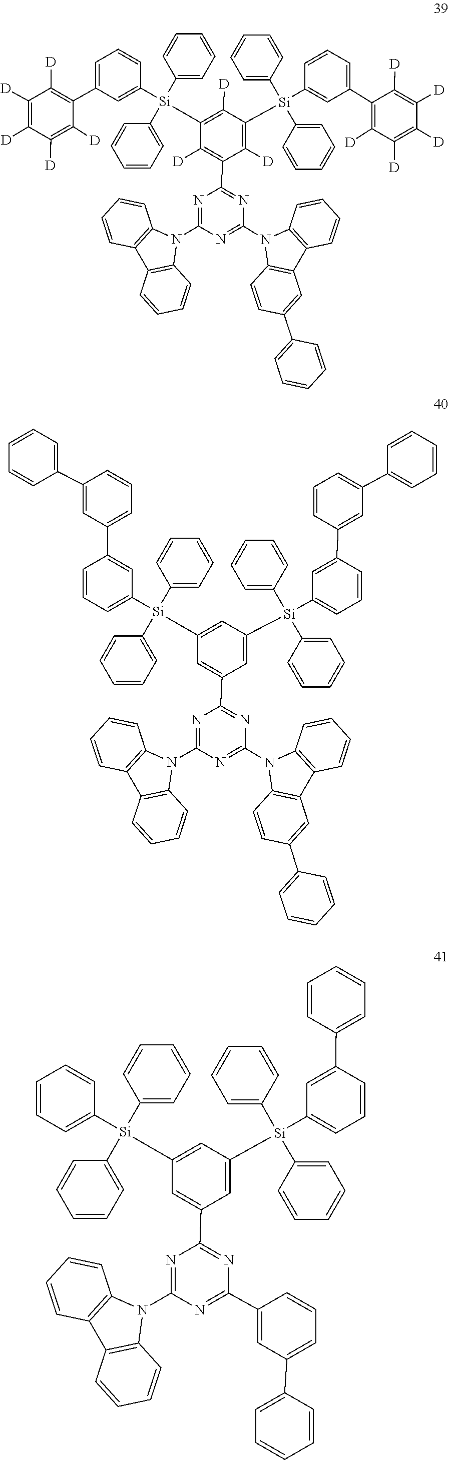

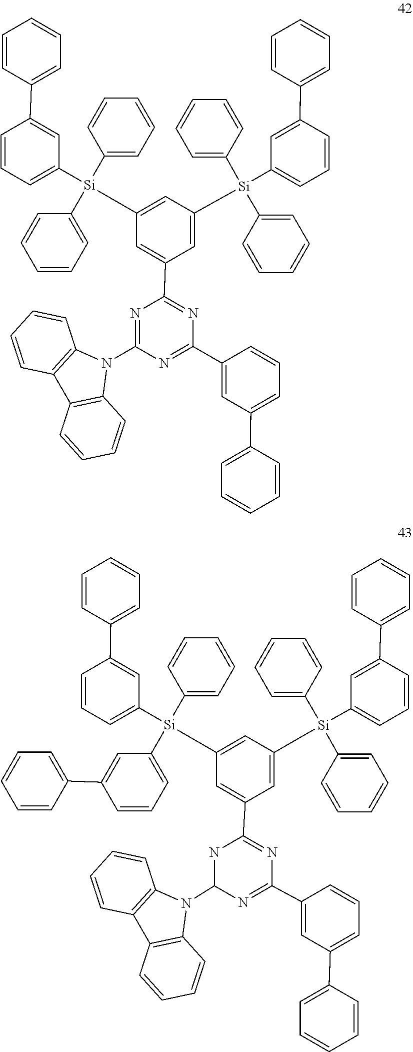

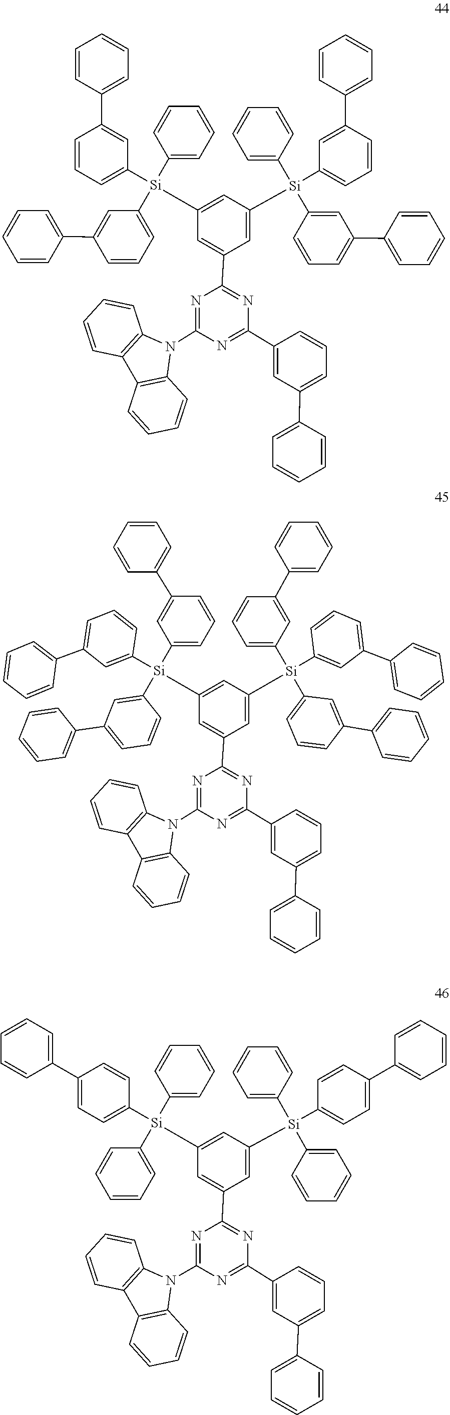

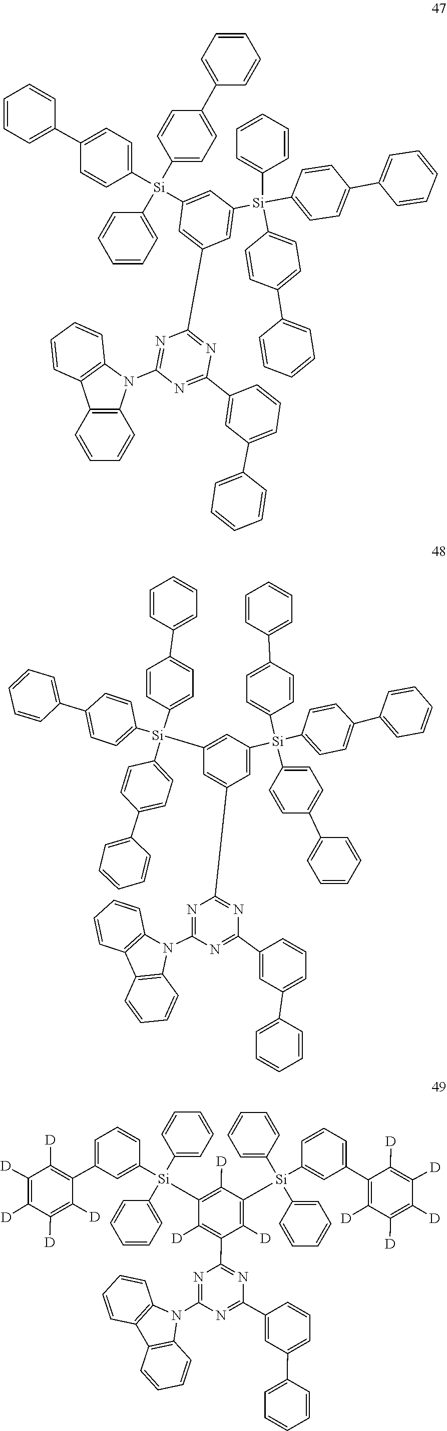

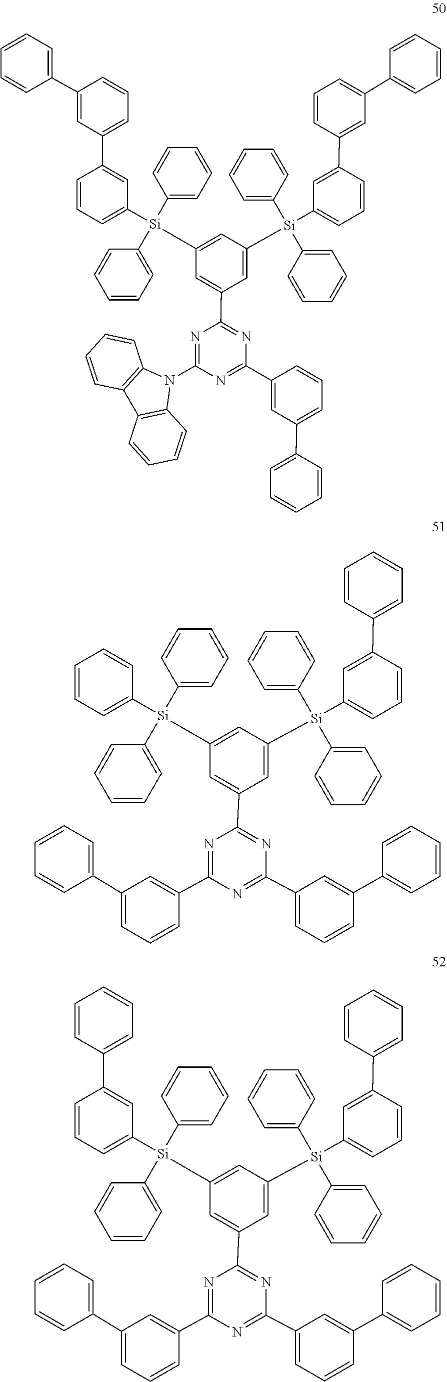 [SMILES: c1ccc(-c2cccc(-c3cccc([Si](c4ccccc4)(c4ccccc4)c4cc(-c5nc(-c6cccc(-c7ccccc7)c6)nc(-n6c7ccccc7c7ccccc76)n5)cc([Si](c5ccccc5)(c5ccccc5)c5cccc(-c6cccc(-c7ccccc7)c6)c5)c4)c3)c2)cc1 ; c1ccc(-c2cccc(-c3nc(-c4cccc(-c5ccccc5)c4)nc(-c4cc([Si](c5ccccc5)(c5ccccc5)c5ccccc5)cc([Si](c5ccccc5)(c5ccccc5)c5cccc(-c6ccccc6)c5)c4)n3)c2)cc1 ; c1ccc(-c2cccc(-c3nc(-c4cccc(-c5ccccc5)c4)nc(-c4cc([Si](c5ccccc5)(c5ccccc5)c5cccc(-c6ccccc6)c5)cc([Si](c5ccccc5)(c5ccccc5)c5cccc(-c6ccccc6)c5)c4)n3)c2)cc1]

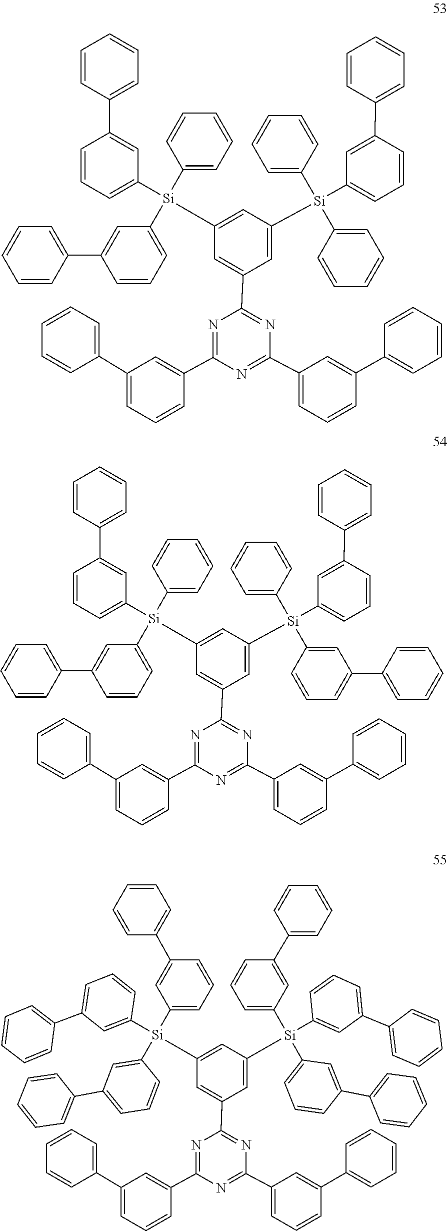

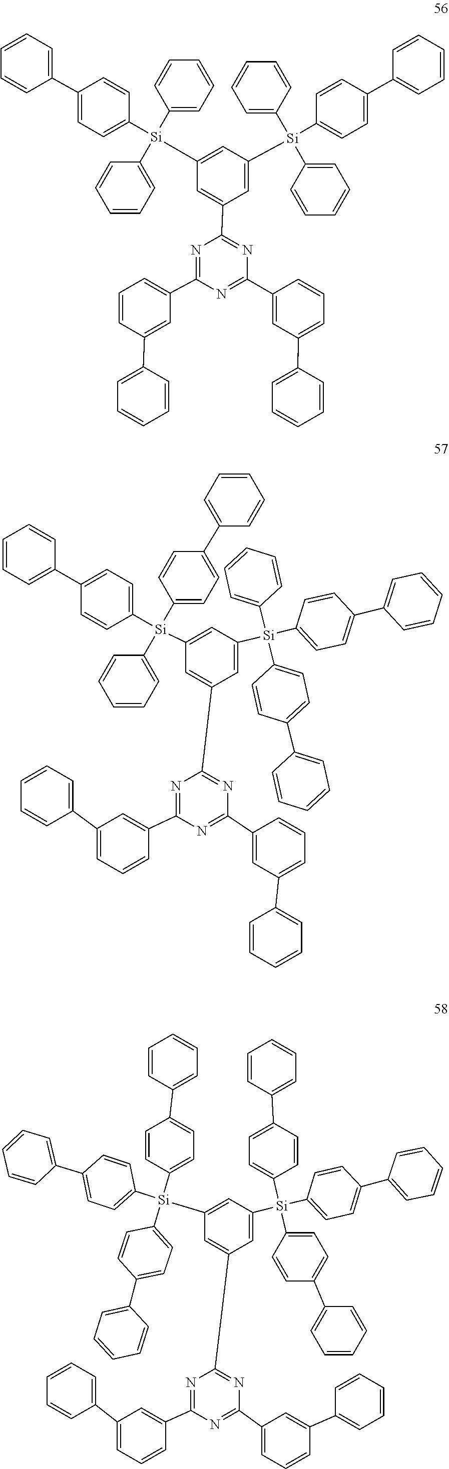

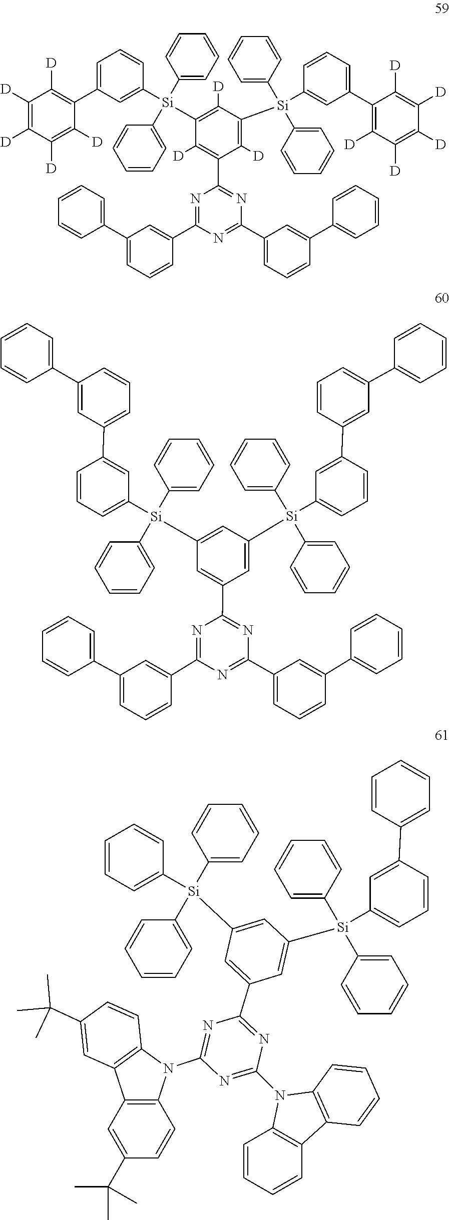

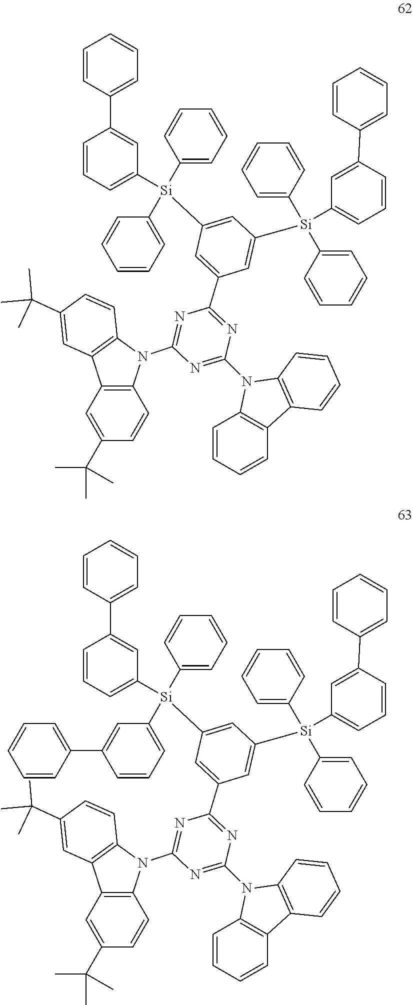

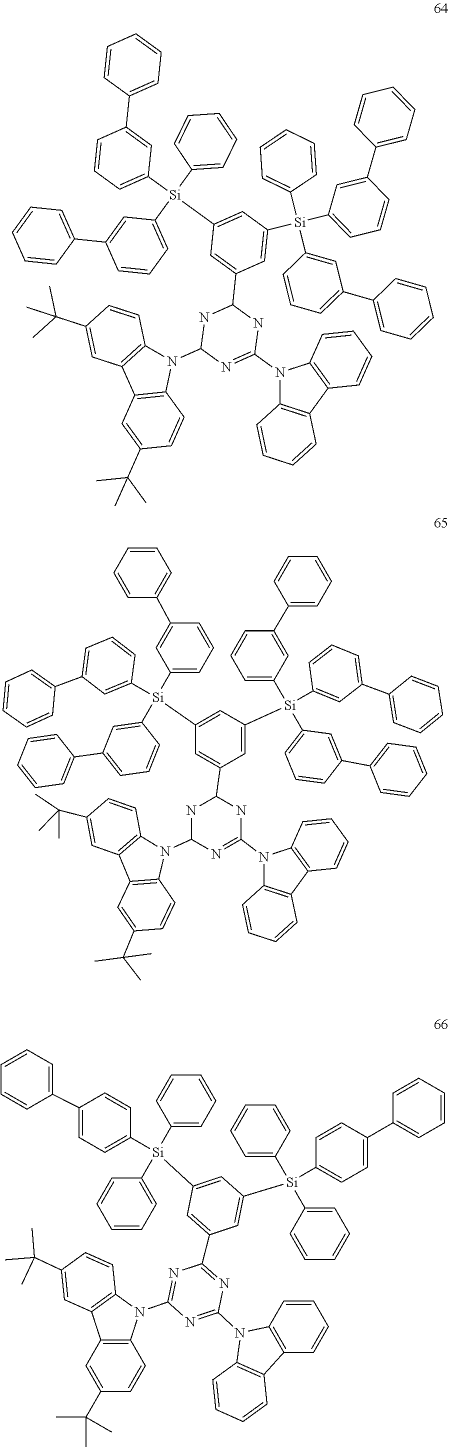

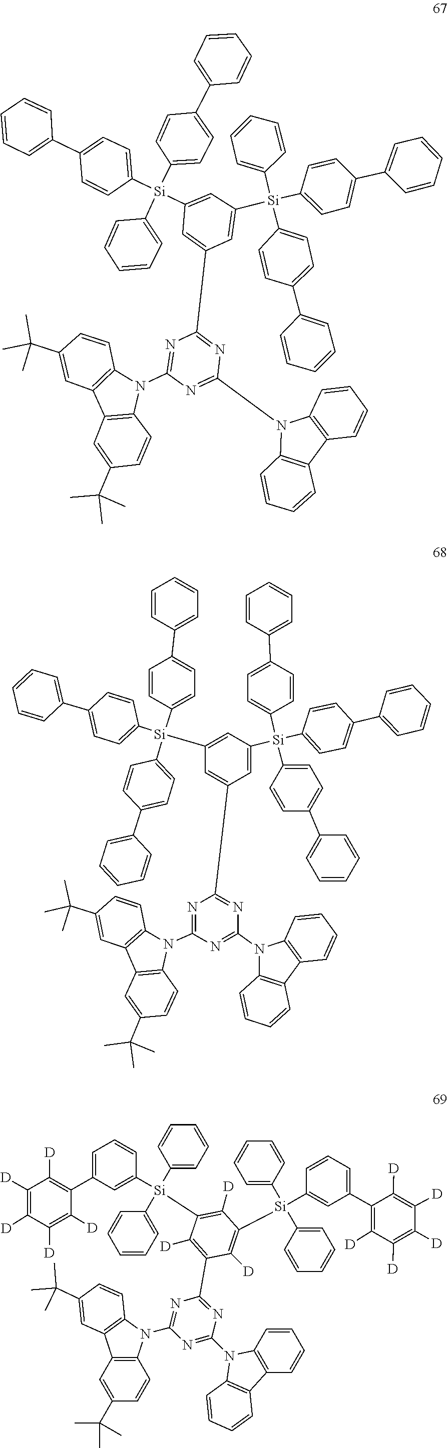

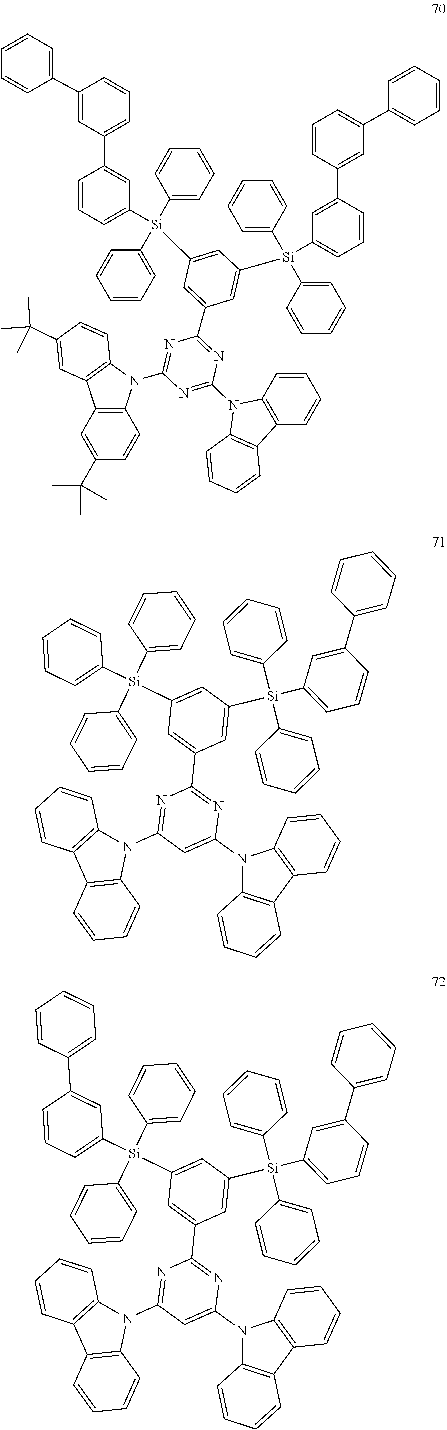 [SMILES: CC(C)(C)c1ccc2c(c1)c1cc(C(C)(C)C)ccc1n2-c1nc(-c2cc([Si](c3ccccc3)(c3ccccc3)c3cccc(-c4cccc(-c5ccccc5)c4)c3)cc([Si](c3ccccc3)(c3ccccc3)c3cccc(-c4cccc(-c5ccccc5)c4)c3)c2)nc(-n2c3ccccc3c3ccccc32)n1 ; c1ccc(-c2cccc([Si](c3ccccc3)(c3ccccc3)c3cc(-c4nc(-n5c6ccccc6c6ccccc65)cc(-n5c6ccccc6c6ccccc65)n4)cc([Si](c4ccccc4)(c4ccccc4)c4ccccc4)c3)c2)cc1 ; c1ccc(-c2cccc([Si](c3ccccc3)(c3ccccc3)c3cc(-c4nc(-n5c6ccccc6c6ccccc65)cc(-n5c6ccccc6c6ccccc65)n4)cc([Si](c4ccccc4)(c4ccccc4)c4cccc(-c5ccccc5)c4)c3)c2)cc1]

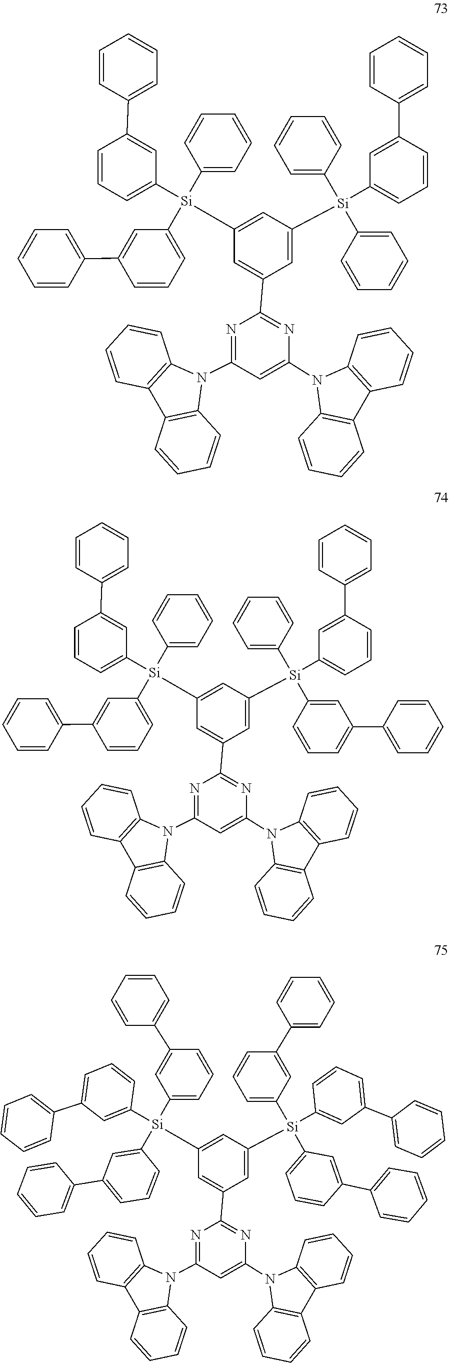

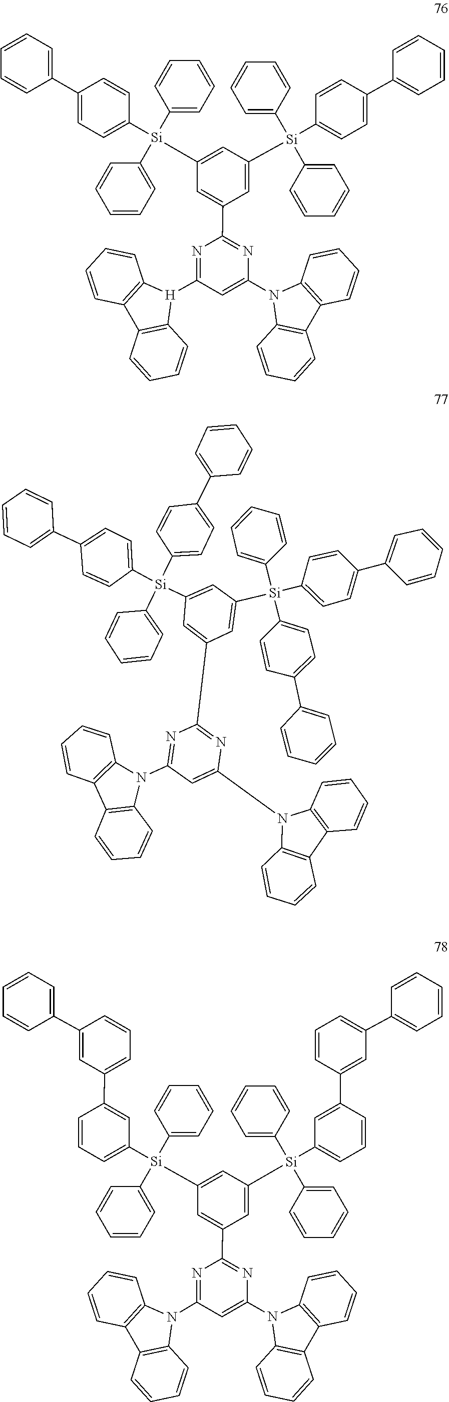

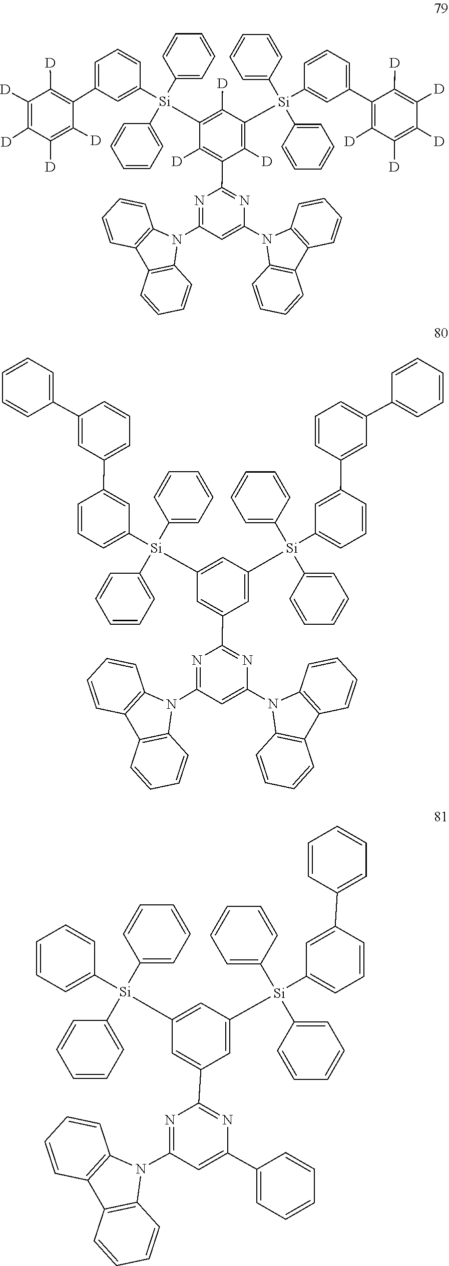

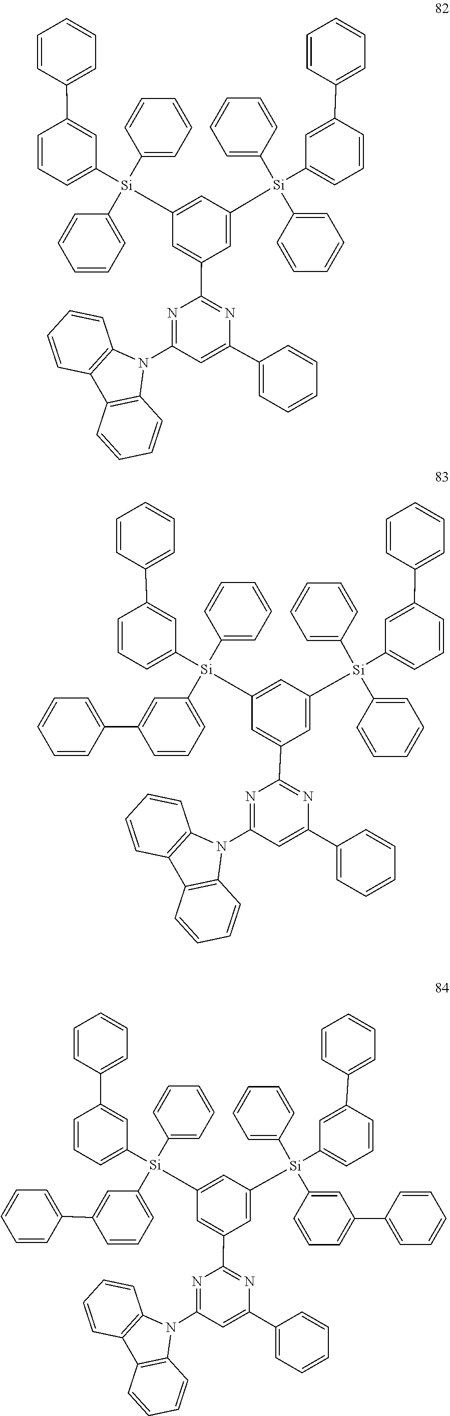 [SMILES: c1ccc(-c2cccc([Si](c3ccccc3)(c3ccccc3)c3cc(-c4nc(-c5ccccc5)cc(-n5c6ccccc6c6ccccc65)n4)cc([Si](c4ccccc4)(c4ccccc4)c4cccc(-c5ccccc5)c4)c3)c2)cc1 ; c1ccc(-c2cccc([Si](c3ccccc3)(c3ccccc3)c3cc(-c4nc(-c5ccccc5)cc(-n5c6ccccc6c6ccccc65)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4nc(-c5ccccc5)cc(-n5c6ccccc6c6ccccc65)n4)cc([Si](c4ccccc4)(c4cccc(-c5ccccc5)c4)c4cccc(-c5ccccc5)c4)c3)c2)cc1]

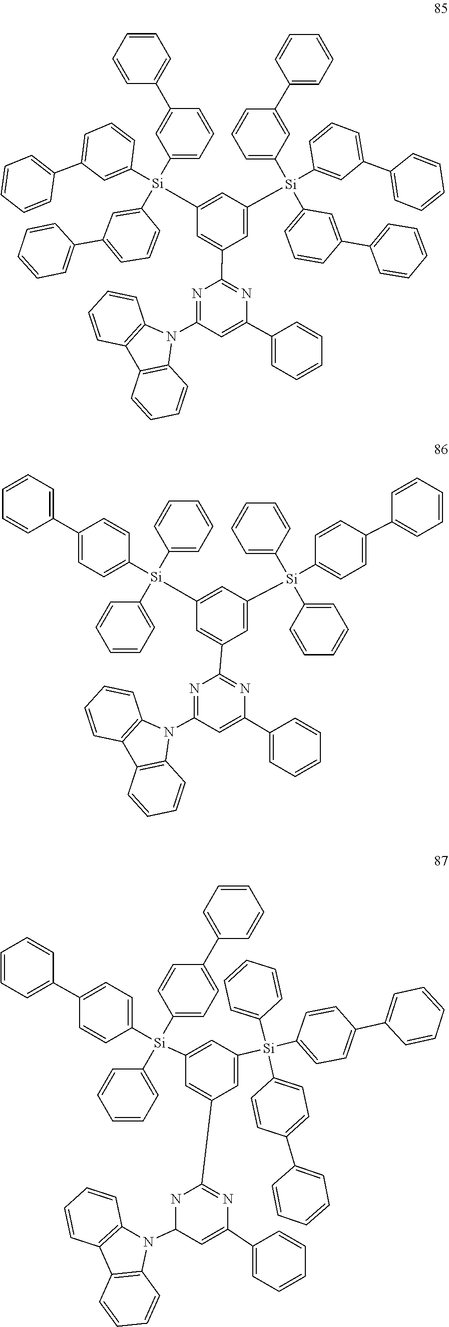

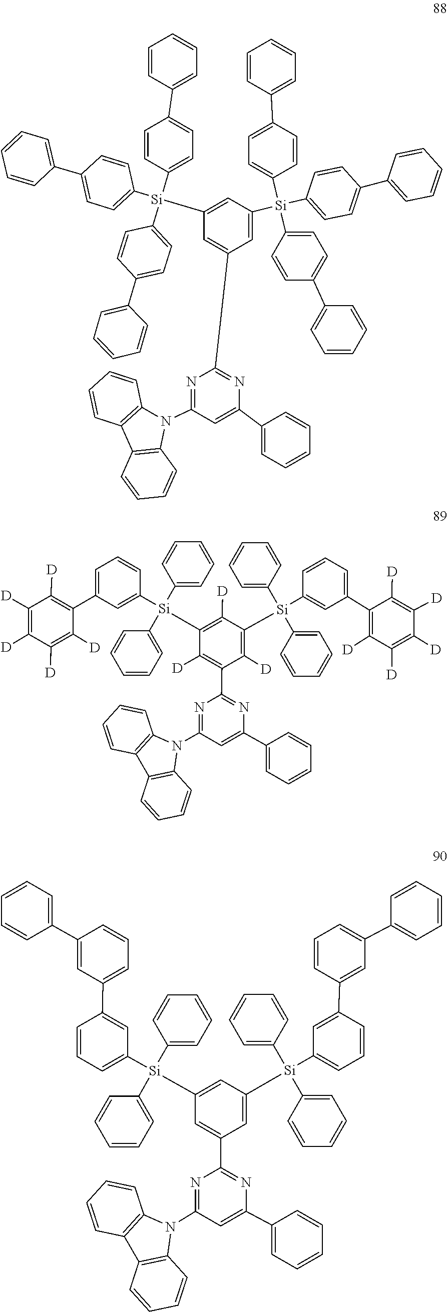

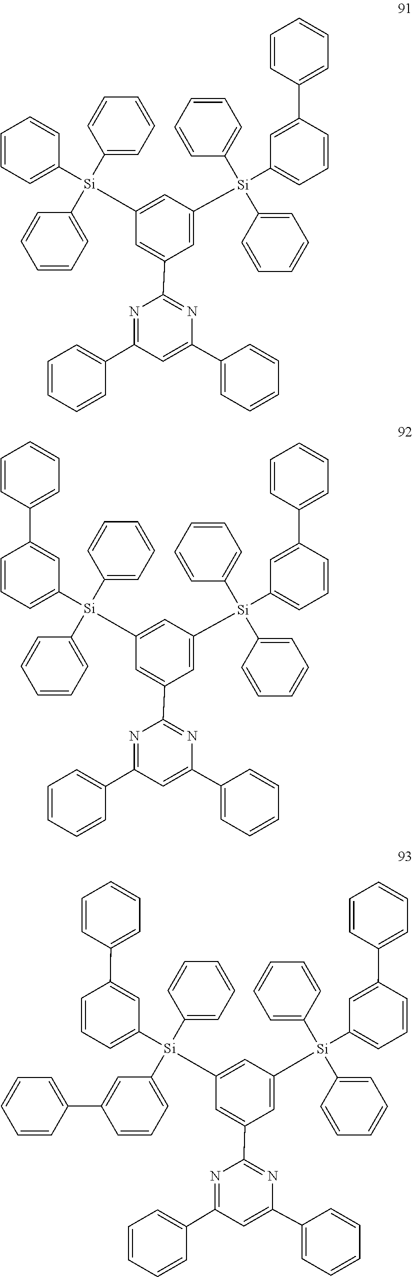 [SMILES: c1ccc(-c2cccc([Si](c3ccccc3)(c3ccccc3)c3cc(-c4nc(-c5ccccc5)cc(-c5ccccc5)n4)cc([Si](c4ccccc4)(c4ccccc4)c4ccccc4)c3)c2)cc1 ; c1ccc(-c2cccc([Si](c3ccccc3)(c3ccccc3)c3cc(-c4nc(-c5ccccc5)cc(-c5ccccc5)n4)cc([Si](c4ccccc4)(c4ccccc4)c4cccc(-c5ccccc5)c4)c3)c2)cc1 ; c1ccc(-c2cccc([Si](c3ccccc3)(c3ccccc3)c3cc(-c4nc(-c5ccccc5)cc(-c5ccccc5)n4)cc([Si](c4ccccc4)(c4cccc(-c5ccccc5)c4)c4cccc(-c5ccccc5)c4)c3)c2)cc1]

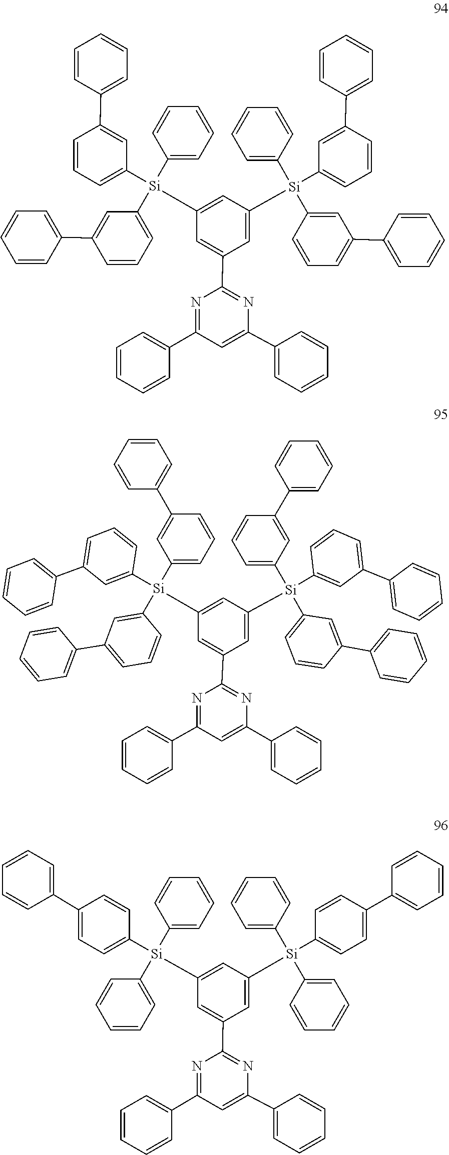 [SMILES: c1ccc(-c2cccc([Si](c3ccccc3)(c3cccc(-c4ccccc4)c3)c3cc(-c4nc(-c5ccccc5)cc(-c5ccccc5)n4)cc([Si](c4ccccc4)(c4cccc(-c5ccccc5)c4)c4cccc(-c5ccccc5)c4)c3)c2)cc1 ; c1ccc(-c2cccc([Si](c3cccc(-c4ccccc4)c3)(c3cccc(-c4ccccc4)c3)c3cc(-c4nc(-c5ccccc5)cc(-c5ccccc5)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4nc(-c5ccccc5)cc(-c5ccccc5)n4)cc([Si](c4ccccc4)(c4ccccc4)c4ccc(-c5ccccc5)cc4)c3)cc2)cc1]

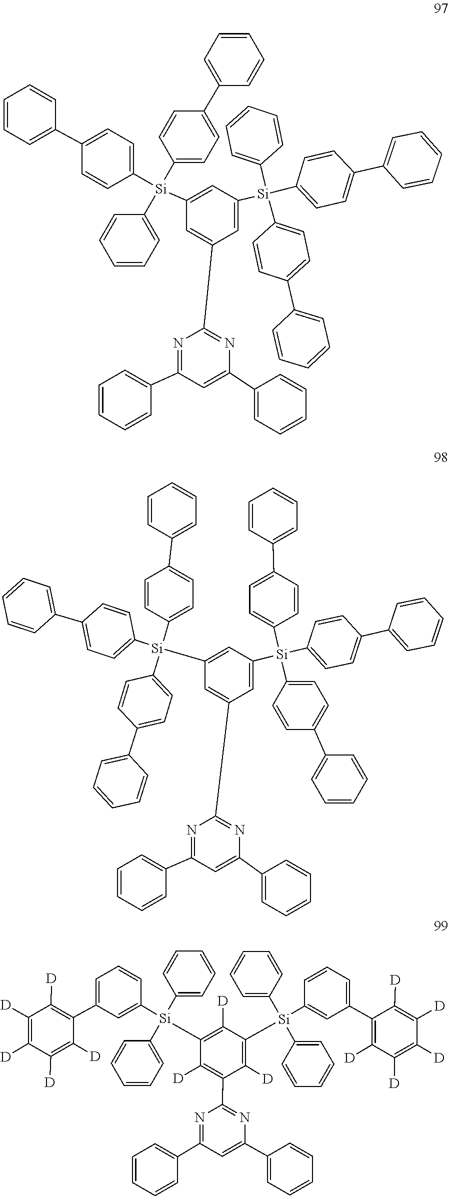

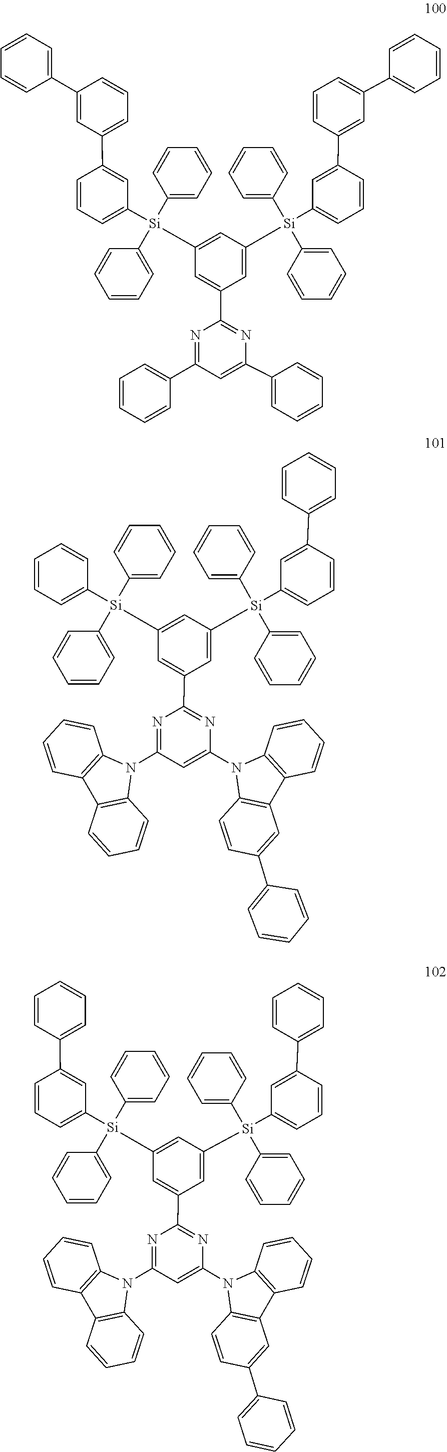

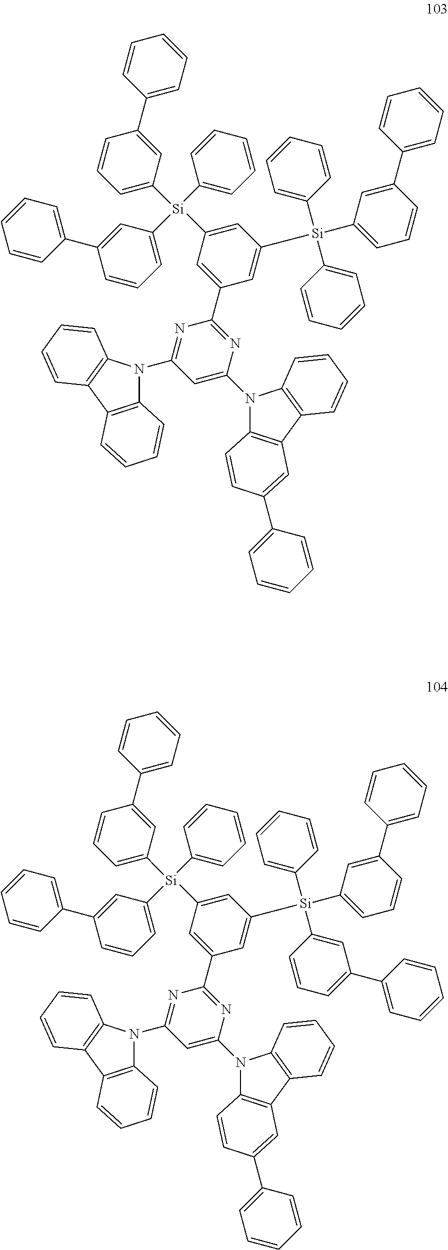 [SMILES: c1ccc(-c2cccc([Si](c3ccccc3)(c3ccccc3)c3cc(-c4nc(-n5c6ccccc6c6ccccc65)cc(-n5c6ccccc6c6cc(-c7ccccc7)ccc65)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4nc(-n5c6ccccc6c6ccccc65)cc(-n5c6ccccc6c6cc(-c7ccccc7)ccc65)n4)cc([Si](c4ccccc4)(c4cccc(-c5ccccc5)c4)c4cccc(-c5ccccc5)c4)c3)c2)cc1]

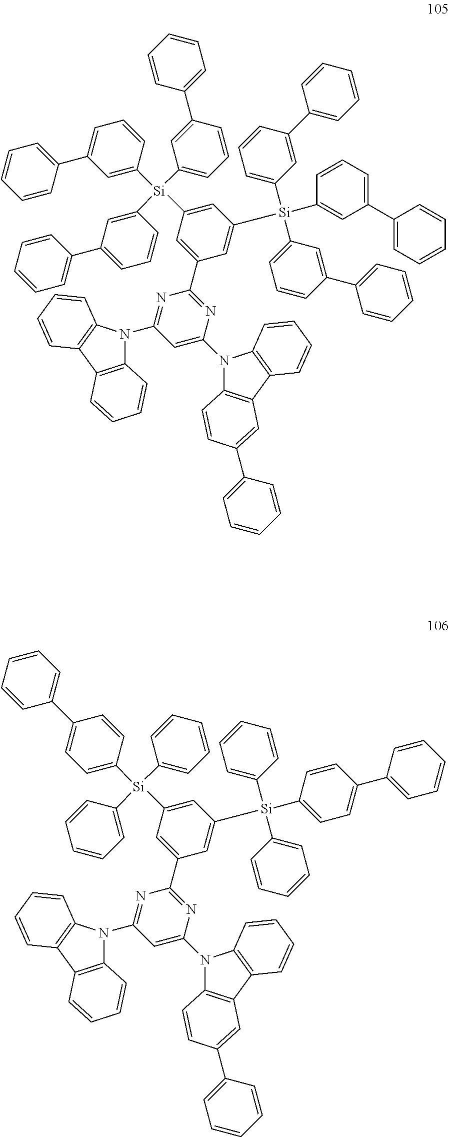 [SMILES: c1ccc(-c2cccc([Si](c3cccc(-c4ccccc4)c3)(c3cccc(-c4ccccc4)c3)c3cc(-c4nc(-n5c6ccccc6c6ccccc65)cc(-n5c6ccccc6c6cc(-c7ccccc7)ccc65)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4nc(-n5c6ccccc6c6ccccc65)cc(-n5c6ccccc6c6cc(-c7ccccc7)ccc65)n4)cc([Si](c4ccccc4)(c4ccccc4)c4ccc(-c5ccccc5)cc4)c3)cc2)cc1]

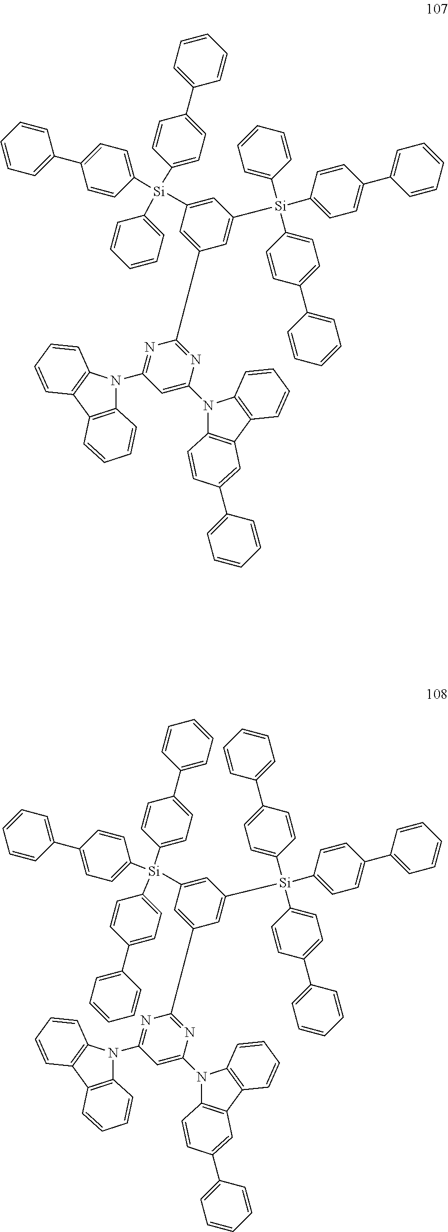 [SMILES: c1ccc(-c2ccc([Si](c3ccccc3)(c3ccc(-c4ccccc4)cc3)c3cc(-c4nc(-n5c6ccccc6c6ccccc65)cc(-n5c6ccccc6c6cc(-c7ccccc7)ccc65)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4nc(-n5c6ccccc6c6ccccc65)cc(-n5c6ccccc6c6cc(-c7ccccc7)ccc65)n4)cc([Si](c4ccc(-c5ccccc5)cc4)(c4ccc(-c5ccccc5)cc4)c4ccc(-c5ccccc5)cc4)c3)cc2)cc1]

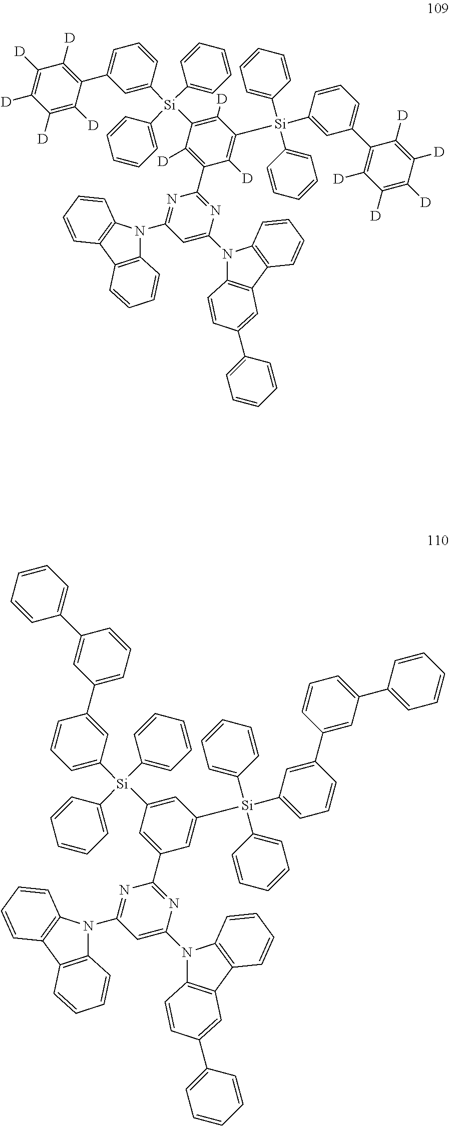 [SMILES: [2H]c1c([2H])c([2H])c(-c2cccc([Si](c3ccccc3)(c3ccccc3)c3c([2H])c(-c4nc(-n5c6ccccc6c6ccccc65)cc(-n5c6ccccc6c6cc(-c7ccccc7)ccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5nc(-n6c7ccccc7c7ccccc76)cc(-n6c7ccccc7c7cc(-c8ccccc8)ccc76)n5)cc([Si](c5ccccc5)(c5ccccc5)c5cccc(-c6cccc(-c7ccccc7)c6)c5)c4)c3)c2)cc1]

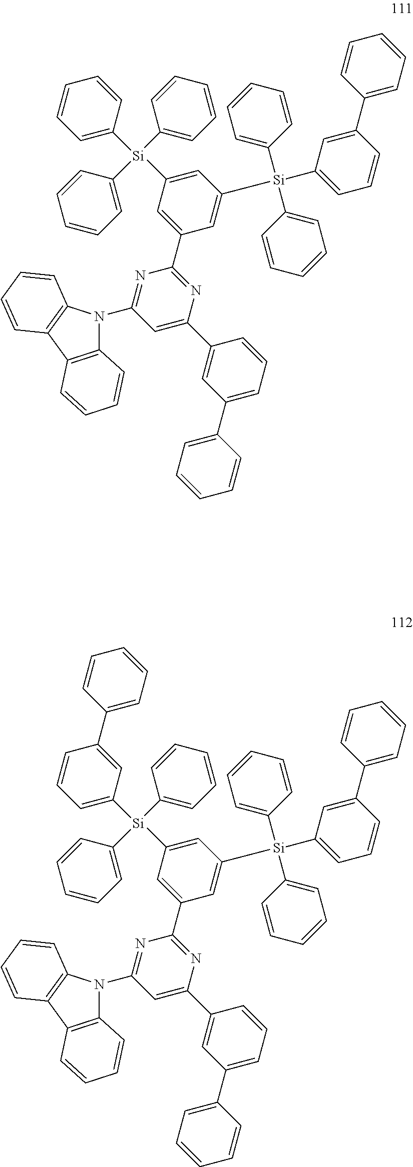 [SMILES: c1ccc(-c2cccc(-c3cc(-n4c5ccccc5c5ccccc54)nc(-c4cc([Si](c5ccccc5)(c5ccccc5)c5ccccc5)cc([Si](c5ccccc5)(c5ccccc5)c5cccc(-c6ccccc6)c5)c4)n3)c2)cc1 ; c1ccc(-c2cccc(-c3cc(-n4c5ccccc5c5ccccc54)nc(-c4cc([Si](c5ccccc5)(c5ccccc5)c5cccc(-c6ccccc6)c5)cc([Si](c5ccccc5)(c5ccccc5)c5cccc(-c6ccccc6)c5)c4)n3)c2)cc1]

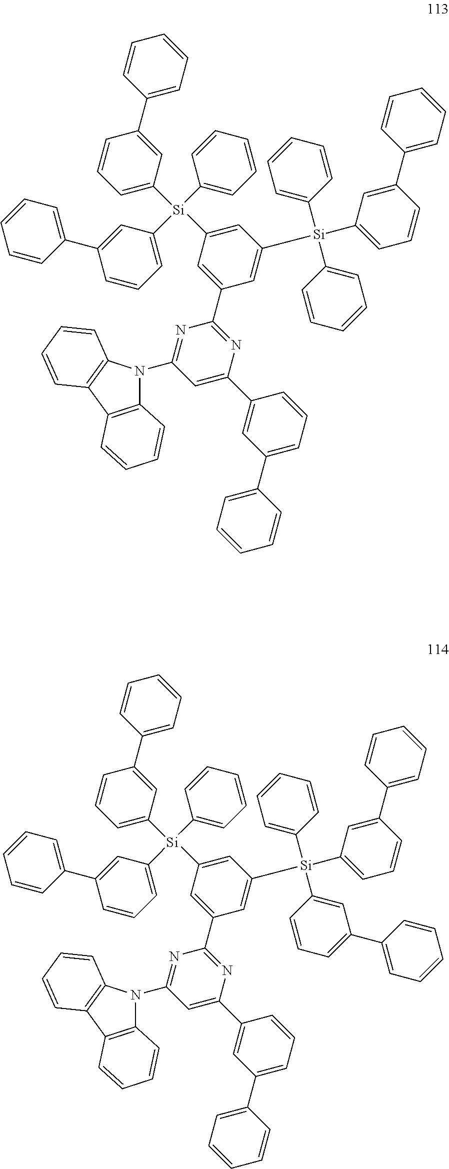 [SMILES: c1ccc(-c2cccc(-c3cc(-n4c5ccccc5c5ccccc54)nc(-c4cc([Si](c5ccccc5)(c5ccccc5)c5cccc(-c6ccccc6)c5)cc([Si](c5ccccc5)(c5cccc(-c6ccccc6)c5)c5cccc(-c6ccccc6)c5)c4)n3)c2)cc1 ; c1ccc(-c2cccc(-c3cc(-n4c5ccccc5c5ccccc54)nc(-c4cc([Si](c5ccccc5)(c5cccc(-c6ccccc6)c5)c5cccc(-c6ccccc6)c5)cc([Si](c5ccccc5)(c5cccc(-c6ccccc6)c5)c5cccc(-c6ccccc6)c5)c4)n3)c2)cc1]

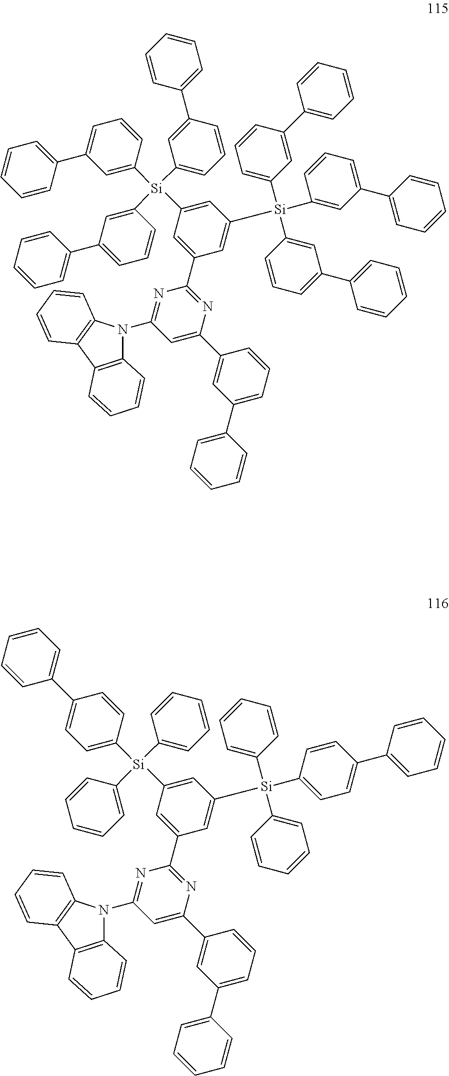 [SMILES: c1ccc(-c2cccc(-c3cc(-n4c5ccccc5c5ccccc54)nc(-c4cc([Si](c5cccc(-c6ccccc6)c5)(c5cccc(-c6ccccc6)c5)c5cccc(-c6ccccc6)c5)cc([Si](c5cccc(-c6ccccc6)c5)(c5cccc(-c6ccccc6)c5)c5cccc(-c6ccccc6)c5)c4)n3)c2)cc1 ; c1ccc(-c2ccc([Si](c3ccccc3)(c3ccccc3)c3cc(-c4nc(-c5cccc(-c6ccccc6)c5)cc(-n5c6ccccc6c6ccccc65)n4)cc([Si](c4ccccc4)(c4ccccc4)c4ccc(-c5ccccc5)cc4)c3)cc2)cc1]

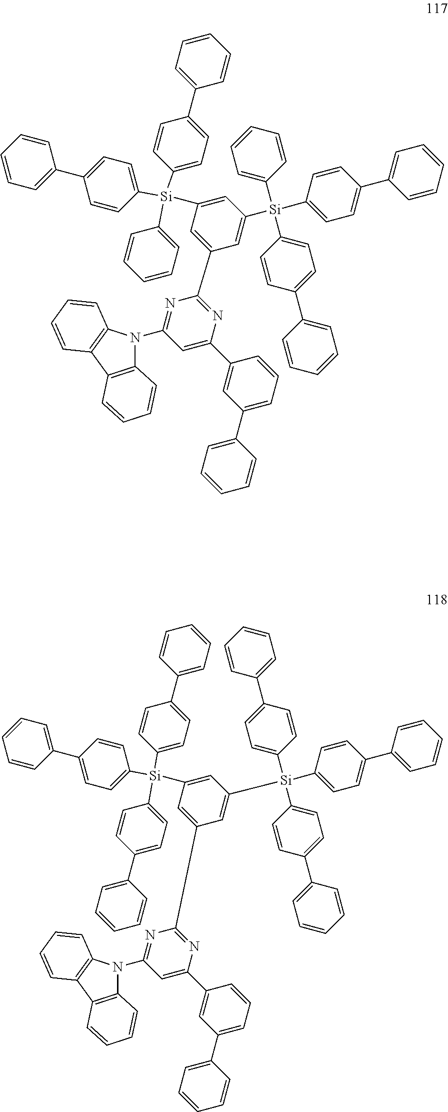 [SMILES: c1ccc(-c2ccc([Si](c3ccccc3)(c3ccc(-c4ccccc4)cc3)c3cc(-c4nc(-c5cccc(-c6ccccc6)c5)cc(-n5c6ccccc6c6ccccc65)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4nc(-c5cccc(-c6ccccc6)c5)cc(-n5c6ccccc6c6ccccc65)n4)cc([Si](c4ccc(-c5ccccc5)cc4)(c4ccc(-c5ccccc5)cc4)c4ccc(-c5ccccc5)cc4)c3)cc2)cc1]

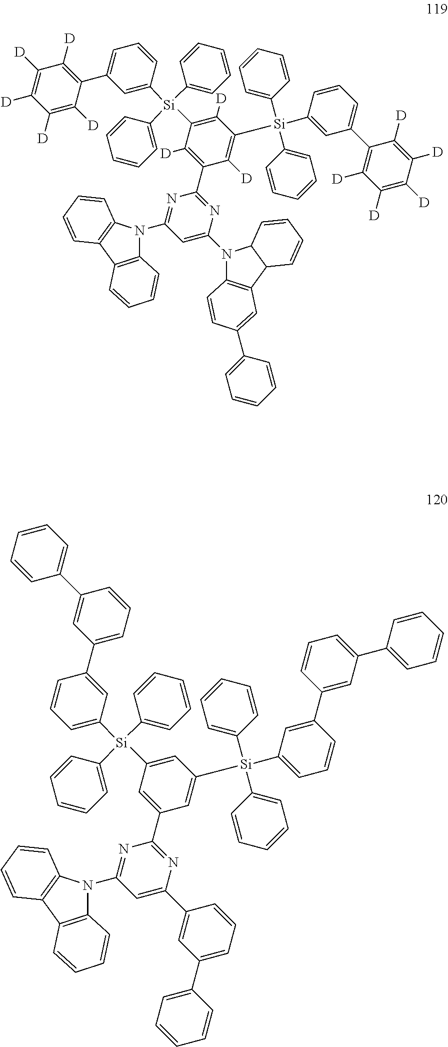 [SMILES: [2H]c1c([2H])c([2H])c(-c2cccc([Si](c3ccccc3)(c3ccccc3)c3c([2H])c(-c4nc(N5c6ccc(-c7ccccc7)cc6C6C=CC=CC65)cc(-n5c6ccccc6c6ccccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5nc(-c6cccc(-c7ccccc7)c6)cc(-n6c7ccccc7c7ccccc76)n5)cc([Si](c5ccccc5)(c5ccccc5)c5cccc(-c6cccc(-c7ccccc7)c6)c5)c4)c3)c2)cc1]

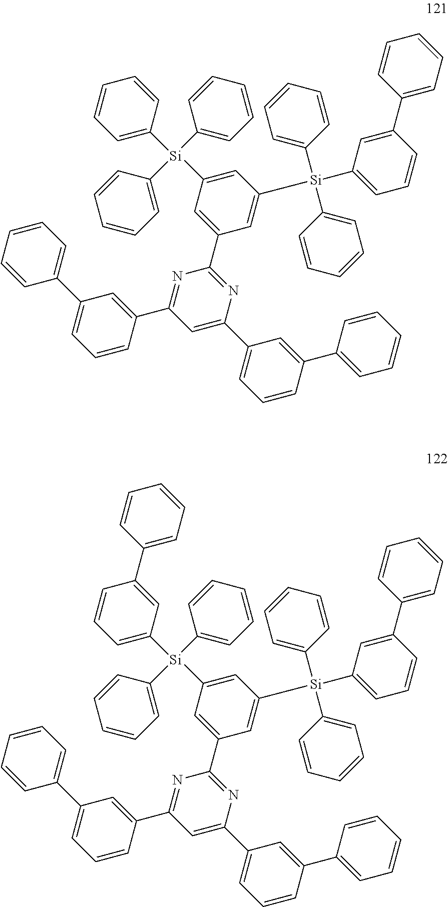 [SMILES: c1ccc(-c2cccc(-c3cc(-c4cccc(-c5ccccc5)c4)nc(-c4cc([Si](c5ccccc5)(c5ccccc5)c5ccccc5)cc([Si](c5ccccc5)(c5ccccc5)c5cccc(-c6ccccc6)c5)c4)n3)c2)cc1 ; c1ccc(-c2cccc(-c3cc(-c4cccc(-c5ccccc5)c4)nc(-c4cc([Si](c5ccccc5)(c5ccccc5)c5cccc(-c6ccccc6)c5)cc([Si](c5ccccc5)(c5ccccc5)c5cccc(-c6ccccc6)c5)c4)n3)c2)cc1]

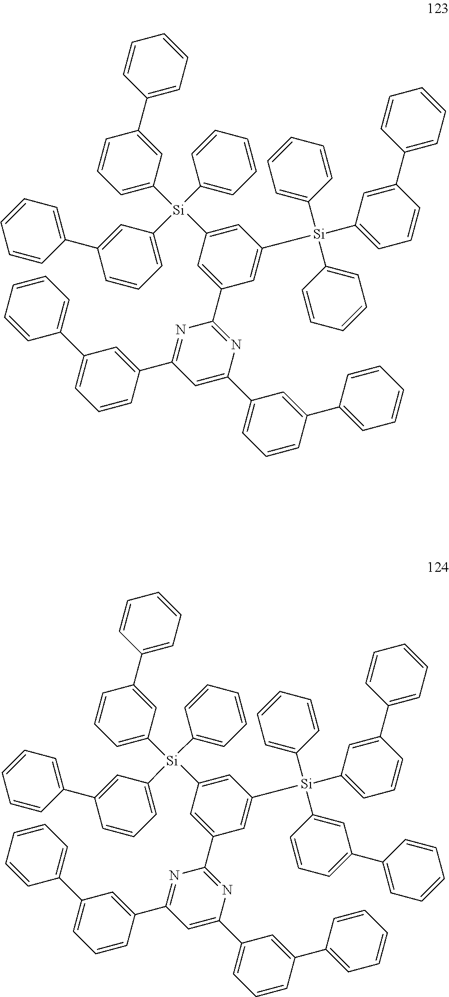 [SMILES: c1ccc(-c2cccc(-c3cc(-c4cccc(-c5ccccc5)c4)nc(-c4cc([Si](c5ccccc5)(c5ccccc5)c5cccc(-c6ccccc6)c5)cc([Si](c5ccccc5)(c5cccc(-c6ccccc6)c5)c5cccc(-c6ccccc6)c5)c4)n3)c2)cc1 ; c1ccc(-c2cccc(-c3cc(-c4cccc(-c5ccccc5)c4)nc(-c4cc([Si](c5ccccc5)(c5cccc(-c6ccccc6)c5)c5cccc(-c6ccccc6)c5)cc([Si](c5ccccc5)(c5cccc(-c6ccccc6)c5)c5cccc(-c6ccccc6)c5)c4)n3)c2)cc1]

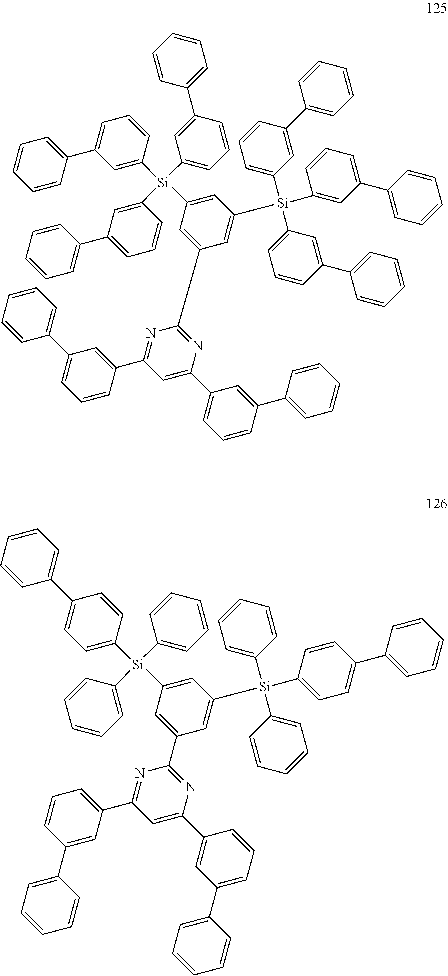 [SMILES: c1ccc(-c2cccc(-c3cc(-c4cccc(-c5ccccc5)c4)nc(-c4cc([Si](c5cccc(-c6ccccc6)c5)(c5cccc(-c6ccccc6)c5)c5cccc(-c6ccccc6)c5)cc([Si](c5cccc(-c6ccccc6)c5)(c5cccc(-c6ccccc6)c5)c5cccc(-c6ccccc6)c5)c4)n3)c2)cc1 ; c1ccc(-c2ccc([Si](c3ccccc3)(c3ccccc3)c3cc(-c4nc(-c5cccc(-c6ccccc6)c5)cc(-c5cccc(-c6ccccc6)c5)n4)cc([Si](c4ccccc4)(c4ccccc4)c4ccc(-c5ccccc5)cc4)c3)cc2)cc1]

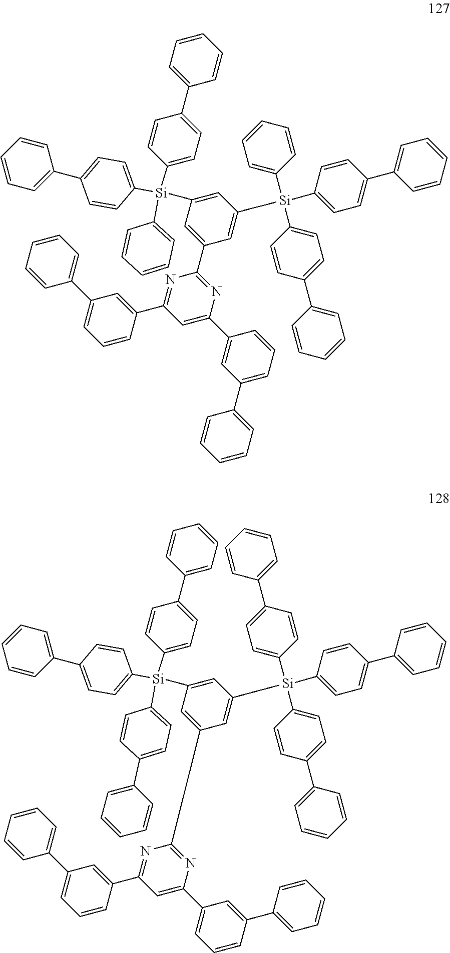 [SMILES: c1ccc(-c2ccc([Si](c3ccccc3)(c3ccc(-c4ccccc4)cc3)c3cc(-c4nc(-c5cccc(-c6ccccc6)c5)cc(-c5cccc(-c6ccccc6)c5)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4nc(-c5cccc(-c6ccccc6)c5)cc(-c5cccc(-c6ccccc6)c5)n4)cc([Si](c4ccc(-c5ccccc5)cc4)(c4ccc(-c5ccccc5)cc4)c4ccc(-c5ccccc5)cc4)c3)cc2)cc1]

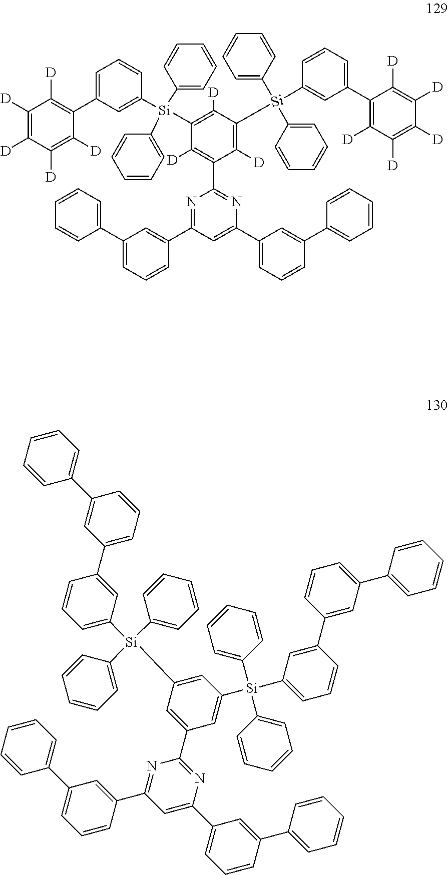 [SMILES: [2H]c1c([2H])c([2H])c(-c2cccc([Si](c3ccccc3)(c3ccccc3)c3c([2H])c(-c4nc(-c5cccc(-c6ccccc6)c5)cc(-c5cccc(-c6ccccc6)c5)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5nc(-c6cccc(-c7ccccc7)c6)cc(-c6cccc(-c7ccccc7)c6)n5)cc([Si](c5ccccc5)(c5ccccc5)c5cccc(-c6cccc(-c7ccccc7)c6)c5)c4)c3)c2)cc1]

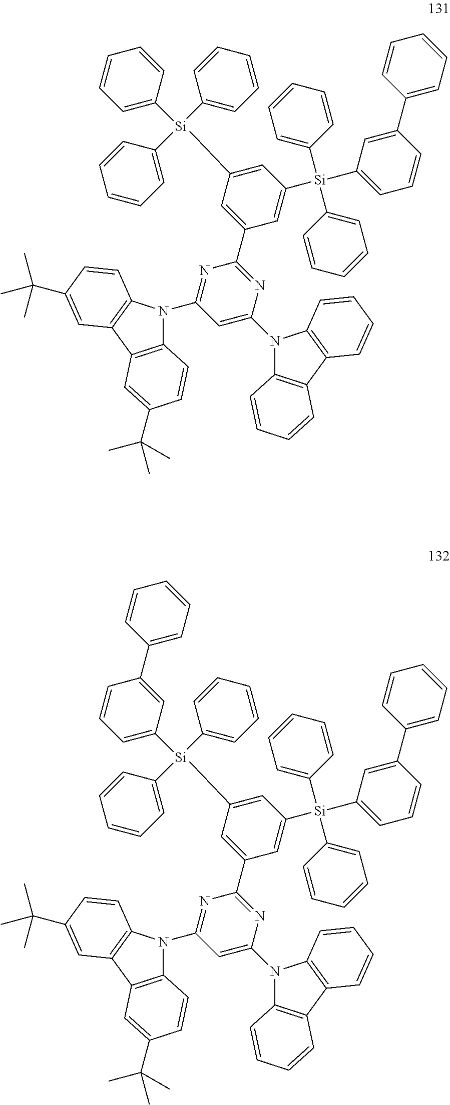 [SMILES: CC(C)(C)c1ccc2c(c1)c1cc(C(C)(C)C)ccc1n2-c1cc(-n2c3ccccc3c3ccccc32)nc(-c2cc([Si](c3ccccc3)(c3ccccc3)c3ccccc3)cc([Si](c3ccccc3)(c3ccccc3)c3cccc(-c4ccccc4)c3)c2)n1 ; CC(C)(C)c1ccc2c(c1)c1cc(C(C)(C)C)ccc1n2-c1cc(-n2c3ccccc3c3ccccc32)nc(-c2cc([Si](c3ccccc3)(c3ccccc3)c3cccc(-c4ccccc4)c3)cc([Si](c3ccccc3)(c3ccccc3)c3cccc(-c4ccccc4)c3)c2)n1]

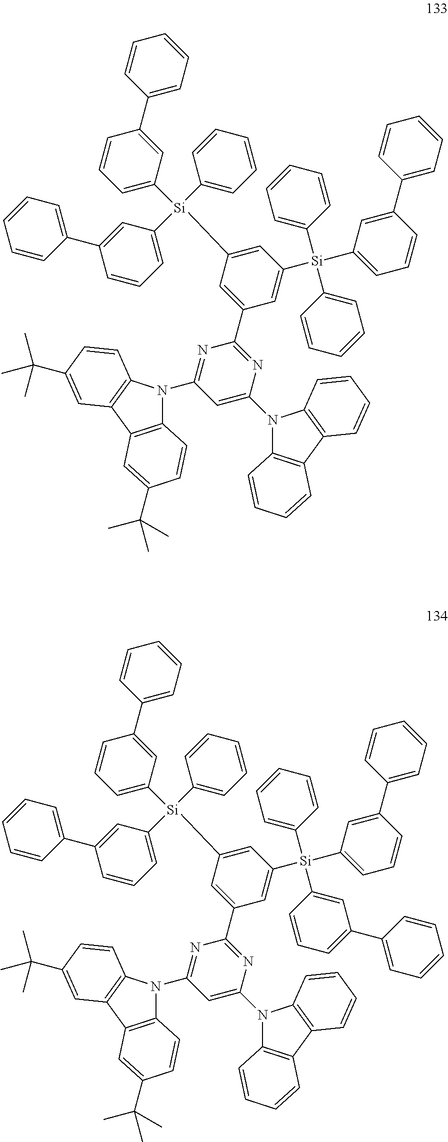 [SMILES: CC(C)(C)c1ccc2c(c1)c1cc(C(C)(C)C)ccc1n2-c1cc(-n2c3ccccc3c3ccccc32)nc(-c2cc([Si](c3ccccc3)(c3ccccc3)c3cccc(-c4ccccc4)c3)cc([Si](c3ccccc3)(c3cccc(-c4ccccc4)c3)c3cccc(-c4ccccc4)c3)c2)n1 ; CC(C)(C)c1ccc2c(c1)c1cc(C(C)(C)C)ccc1n2-c1cc(-n2c3ccccc3c3ccccc32)nc(-c2cc([Si](c3ccccc3)(c3cccc(-c4ccccc4)c3)c3cccc(-c4ccccc4)c3)cc([Si](c3ccccc3)(c3cccc(-c4ccccc4)c3)c3cccc(-c4ccccc4)c3)c2)n1]

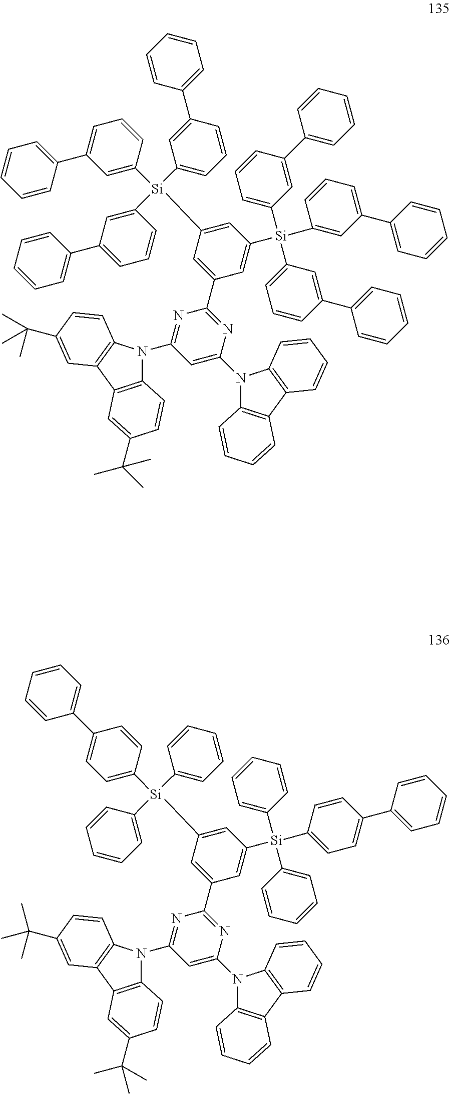 [SMILES: CC(C)(C)c1ccc2c(c1)c1cc(C(C)(C)C)ccc1n2-c1cc(-n2c3ccccc3c3ccccc32)nc(-c2cc([Si](c3cccc(-c4ccccc4)c3)(c3cccc(-c4ccccc4)c3)c3cccc(-c4ccccc4)c3)cc([Si](c3cccc(-c4ccccc4)c3)(c3cccc(-c4ccccc4)c3)c3cccc(-c4ccccc4)c3)c2)n1 ; CC(C)(C)c1ccc2c(c1)c1cc(C(C)(C)C)ccc1n2-c1cc(-n2c3ccccc3c3ccccc32)nc(-c2cc([Si](c3ccccc3)(c3ccccc3)c3ccc(-c4ccccc4)cc3)cc([Si](c3ccccc3)(c3ccccc3)c3ccc(-c4ccccc4)cc3)c2)n1]

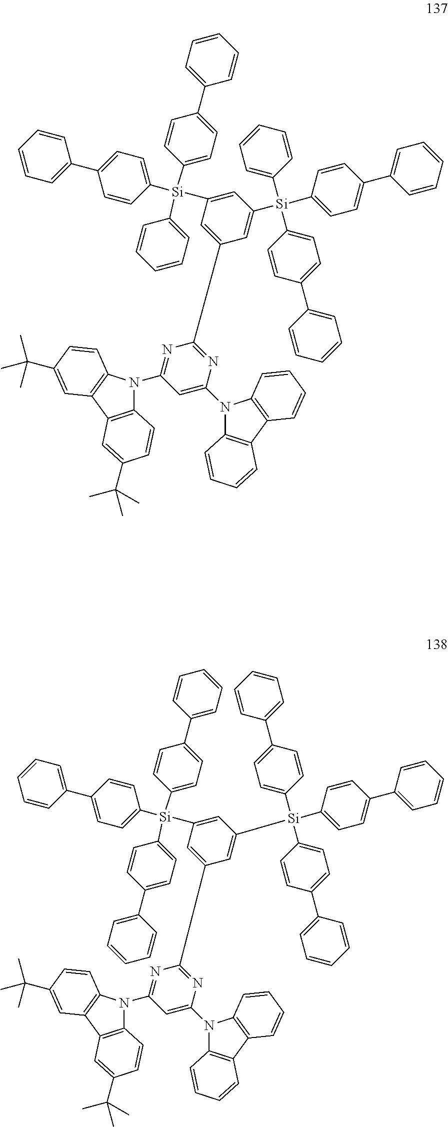 [SMILES: CC(C)(C)c1ccc2c(c1)c1cc(C(C)(C)C)ccc1n2-c1cc(-n2c3ccccc3c3ccccc32)nc(-c2cc([Si](c3ccccc3)(c3ccc(-c4ccccc4)cc3)c3ccc(-c4ccccc4)cc3)cc([Si](c3ccccc3)(c3ccc(-c4ccccc4)cc3)c3ccc(-c4ccccc4)cc3)c2)n1 ; CC(C)(C)c1ccc2c(c1)c1cc(C(C)(C)C)ccc1n2-c1cc(-n2c3ccccc3c3ccccc32)nc(-c2cc([Si](c3ccc(-c4ccccc4)cc3)(c3ccc(-c4ccccc4)cc3)c3ccc(-c4ccccc4)cc3)cc([Si](c3ccc(-c4ccccc4)cc3)(c3ccc(-c4ccccc4)cc3)c3ccc(-c4ccccc4)cc3)c2)n1]

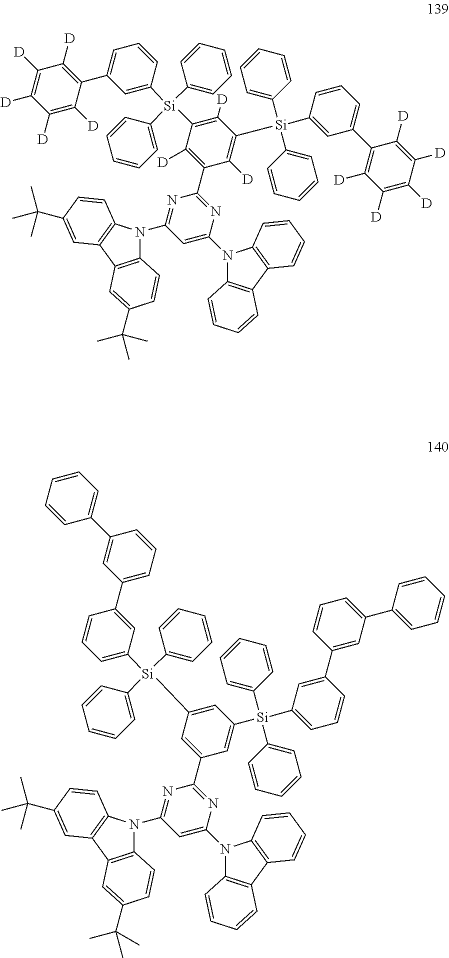 [SMILES: [2H]c1c([2H])c([2H])c(-c2cccc([Si](c3ccccc3)(c3ccccc3)c3c([2H])c(-c4nc(-n5c6ccccc6c6ccccc65)cc(-n5c6ccc(C(C)(C)C)cc6c6cc(C(C)(C)C)ccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; CC(C)(C)c1ccc2c(c1)c1cc(C(C)(C)C)ccc1n2-c1cc(-n2c3ccccc3c3ccccc32)nc(-c2cc([Si](c3ccccc3)(c3ccccc3)c3cccc(-c4cccc(-c5ccccc5)c4)c3)cc([Si](c3ccccc3)(c3ccccc3)c3cccc(-c4cccc(-c5ccccc5)c4)c3)c2)n1]

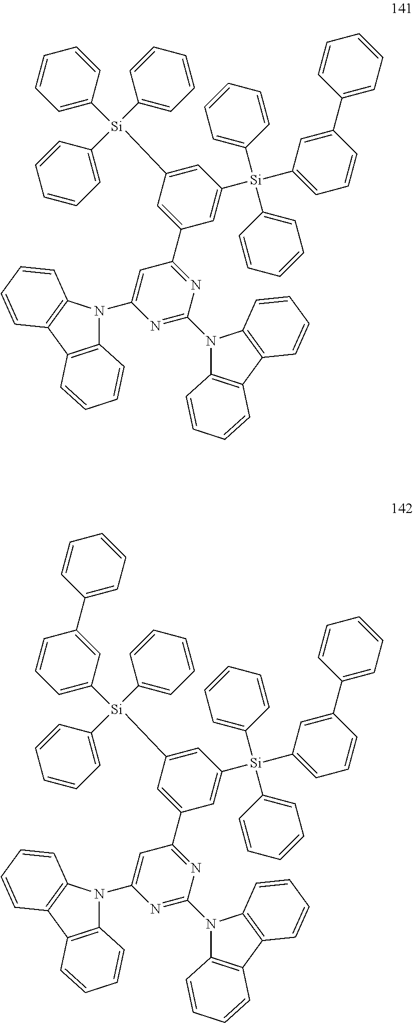 [SMILES: c1ccc(-c2cccc([Si](c3ccccc3)(c3ccccc3)c3cc(-c4cc(-n5c6ccccc6c6ccccc65)nc(-n5c6ccccc6c6ccccc65)n4)cc([Si](c4ccccc4)(c4ccccc4)c4ccccc4)c3)c2)cc1 ; c1ccc(-c2cccc([Si](c3ccccc3)(c3ccccc3)c3cc(-c4cc(-n5c6ccccc6c6ccccc65)nc(-n5c6ccccc6c6ccccc65)n4)cc([Si](c4ccccc4)(c4ccccc4)c4cccc(-c5ccccc5)c4)c3)c2)cc1]

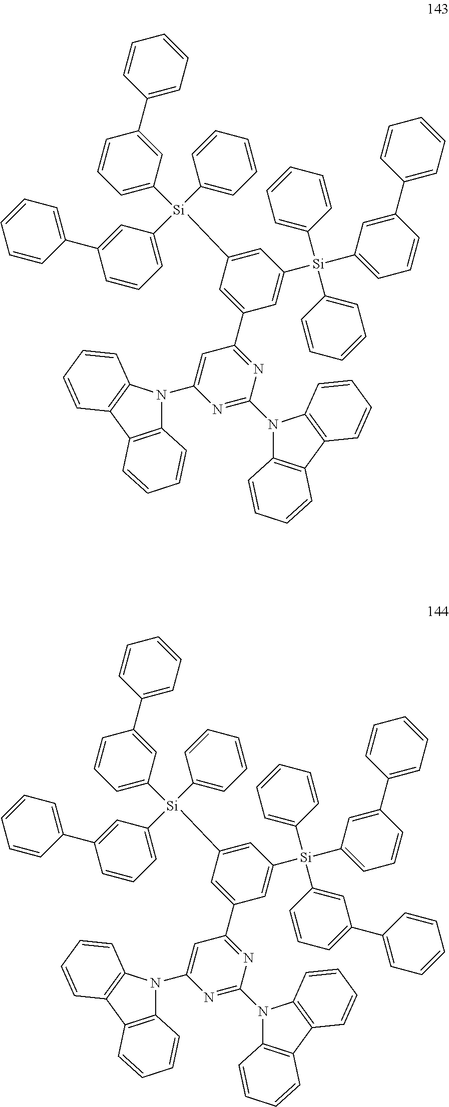 [SMILES: c1ccc(-c2cccc([Si](c3ccccc3)(c3ccccc3)c3cc(-c4cc(-n5c6ccccc6c6ccccc65)nc(-n5c6ccccc6c6ccccc65)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4cc(-n5c6ccccc6c6ccccc65)nc(-n5c6ccccc6c6ccccc65)n4)cc([Si](c4ccccc4)(c4cccc(-c5ccccc5)c4)c4cccc(-c5ccccc5)c4)c3)c2)cc1]

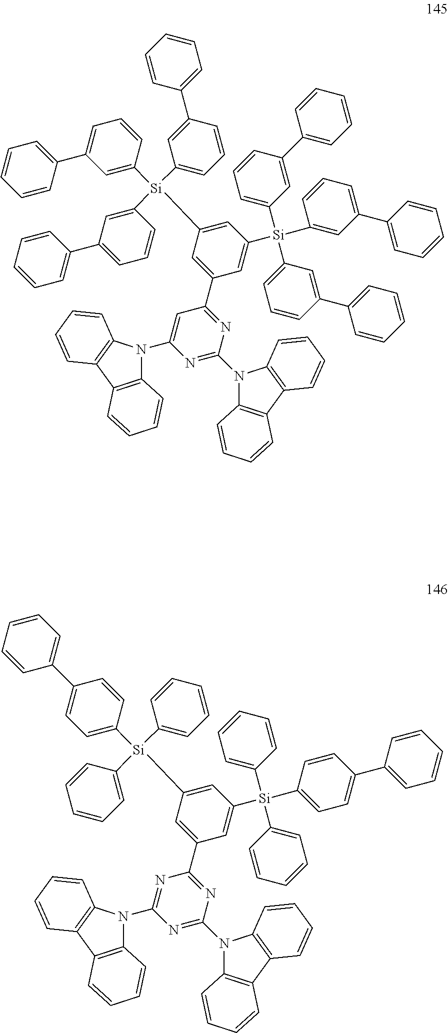 [SMILES: c1ccc(-c2cccc([Si](c3cccc(-c4ccccc4)c3)(c3cccc(-c4ccccc4)c3)c3cc(-c4cc(-n5c6ccccc6c6ccccc65)nc(-n5c6ccccc6c6ccccc65)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4nc(-n5c6ccccc6c6ccccc65)nc(-n5c6ccccc6c6ccccc65)n4)cc([Si](c4ccccc4)(c4ccccc4)c4ccc(-c5ccccc5)cc4)c3)cc2)cc1]

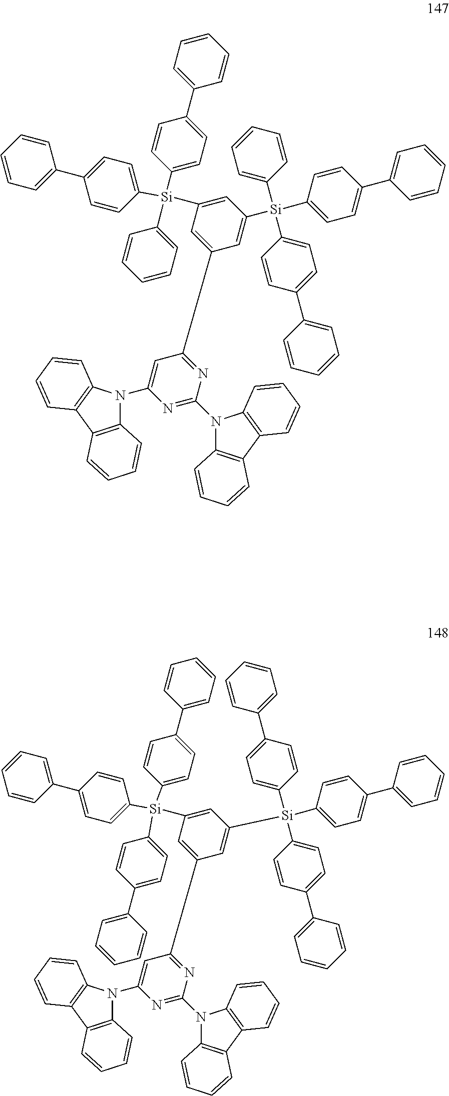 [SMILES: c1ccc(-c2ccc([Si](c3ccccc3)(c3ccc(-c4ccccc4)cc3)c3cc(-c4cc(-n5c6ccccc6c6ccccc65)nc(-n5c6ccccc6c6ccccc65)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4cc(-n5c6ccccc6c6ccccc65)nc(-n5c6ccccc6c6ccccc65)n4)cc([Si](c4ccc(-c5ccccc5)cc4)(c4ccc(-c5ccccc5)cc4)c4ccc(-c5ccccc5)cc4)c3)cc2)cc1]

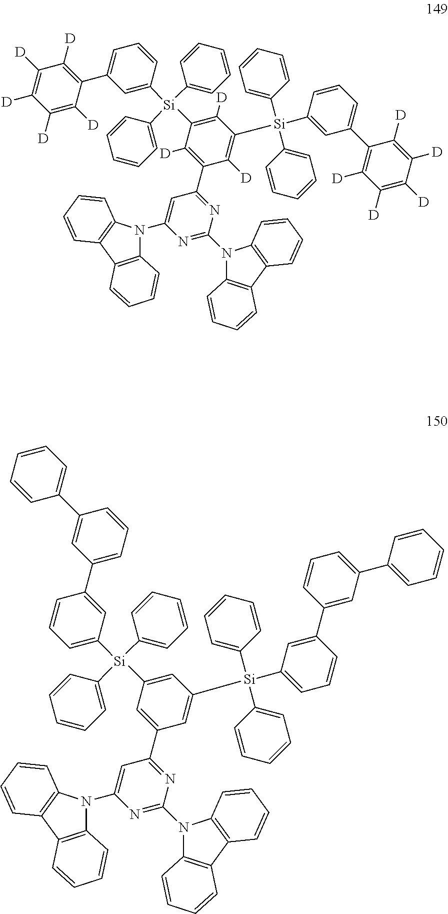 [SMILES: [2H]c1c([2H])c([2H])c(-c2cccc([Si](c3ccccc3)(c3ccccc3)c3c([2H])c(-c4cc(-n5c6ccccc6c6ccccc65)nc(-n5c6ccccc6c6ccccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5cc(-n6c7ccccc7c7ccccc76)nc(-n6c7ccccc7c7ccccc76)n5)cc([Si](c5ccccc5)(c5ccccc5)c5cccc(-c6cccc(-c7ccccc7)c6)c5)c4)c3)c2)cc1]

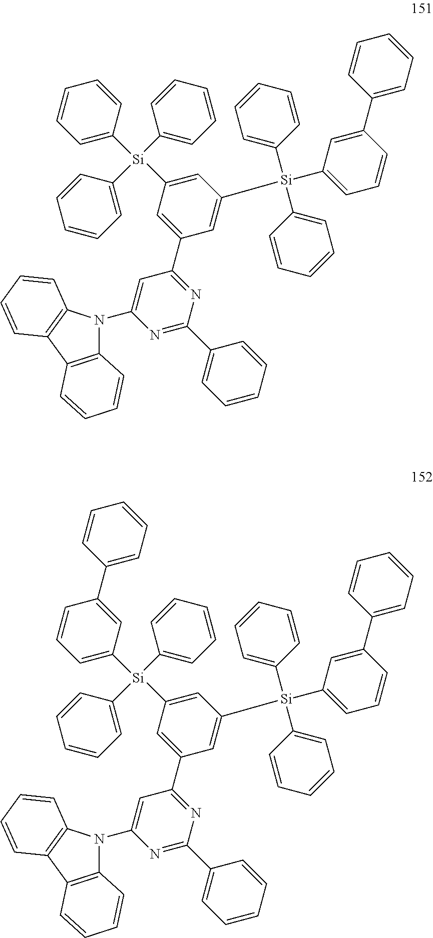 [SMILES: c1ccc(-c2cccc([Si](c3ccccc3)(c3ccccc3)c3cc(-c4cc(-n5c6ccccc6c6ccccc65)nc(-c5ccccc5)n4)cc([Si](c4ccccc4)(c4ccccc4)c4ccccc4)c3)c2)cc1 ; c1ccc(-c2cccc([Si](c3ccccc3)(c3ccccc3)c3cc(-c4cc(-n5c6ccccc6c6ccccc65)nc(-c5ccccc5)n4)cc([Si](c4ccccc4)(c4ccccc4)c4cccc(-c5ccccc5)c4)c3)c2)cc1]

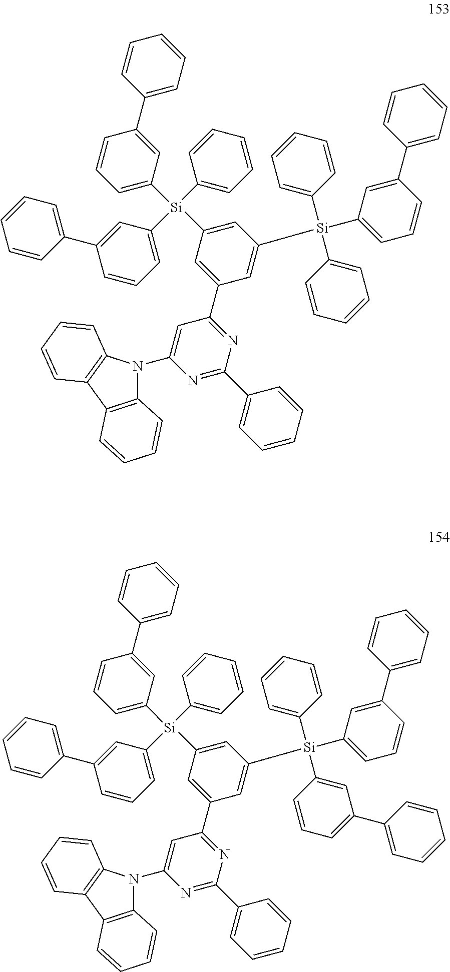 [SMILES: c1ccc(-c2cccc([Si](c3ccccc3)(c3ccccc3)c3cc(-c4cc(-n5c6ccccc6c6ccccc65)nc(-c5ccccc5)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4cc(-n5c6ccccc6c6ccccc65)nc(-c5ccccc5)n4)cc([Si](c4ccccc4)(c4cccc(-c5ccccc5)c4)c4cccc(-c5ccccc5)c4)c3)c2)cc1]

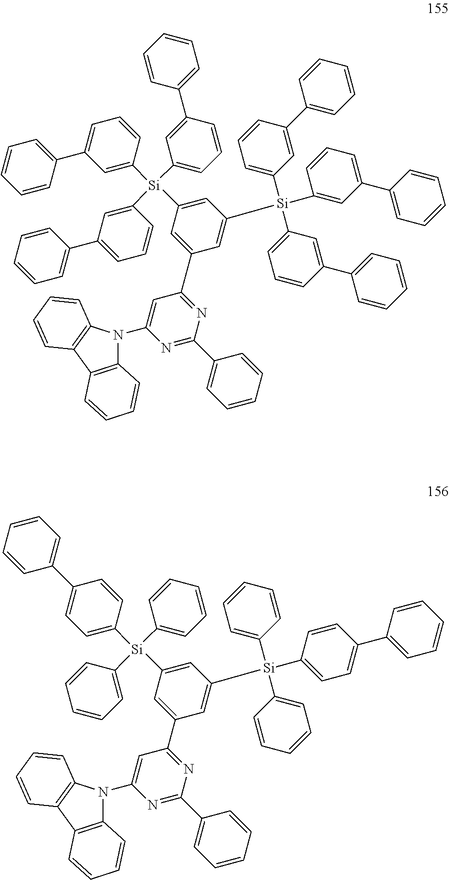 [SMILES: c1ccc(-c2cccc([Si](c3cccc(-c4ccccc4)c3)(c3cccc(-c4ccccc4)c3)c3cc(-c4cc(-n5c6ccccc6c6ccccc65)nc(-c5ccccc5)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4cc(-n5c6ccccc6c6ccccc65)nc(-c5ccccc5)n4)cc([Si](c4ccccc4)(c4ccccc4)c4ccc(-c5ccccc5)cc4)c3)cc2)cc1]

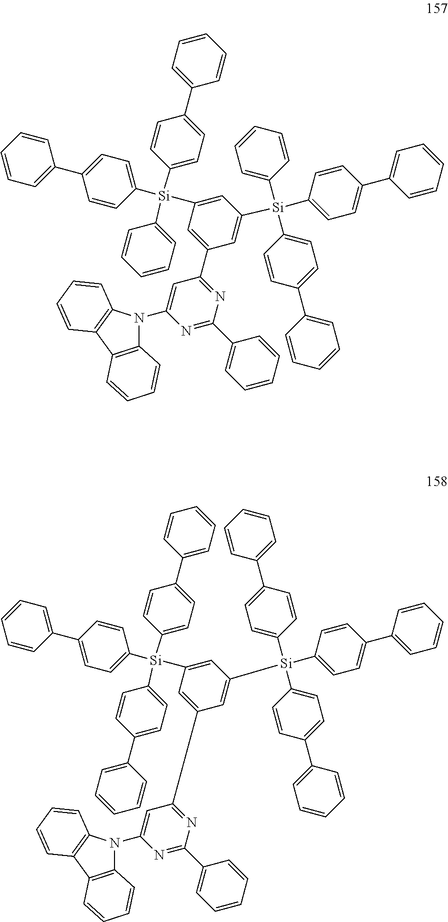 [SMILES: c1ccc(-c2ccc([Si](c3ccccc3)(c3ccc(-c4ccccc4)cc3)c3cc(-c4cc(-n5c6ccccc6c6ccccc65)nc(-c5ccccc5)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4cc(-n5c6ccccc6c6ccccc65)nc(-c5ccccc5)n4)cc([Si](c4ccc(-c5ccccc5)cc4)(c4ccc(-c5ccccc5)cc4)c4ccc(-c5ccccc5)cc4)c3)cc2)cc1]

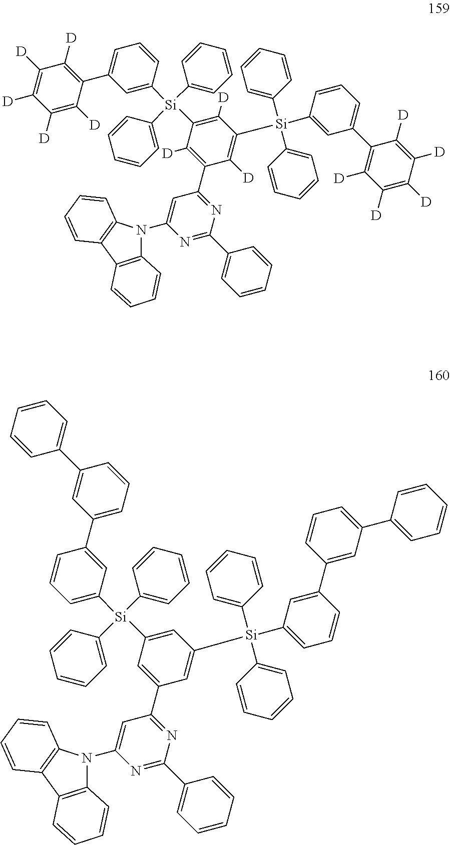 [SMILES: [2H]c1c([2H])c([2H])c(-c2cccc([Si](c3ccccc3)(c3ccccc3)c3c([2H])c(-c4cc(-n5c6ccccc6c6ccccc65)nc(-c5ccccc5)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5cc(-n6c7ccccc7c7ccccc76)nc(-c6ccccc6)n5)cc([Si](c5ccccc5)(c5ccccc5)c5cccc(-c6cccc(-c7ccccc7)c6)c5)c4)c3)c2)cc1]

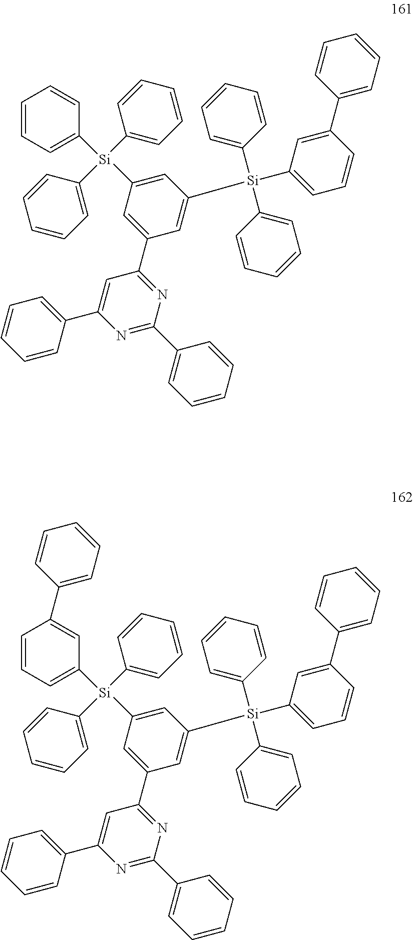 [SMILES: c1ccc(-c2cccc([Si](c3ccccc3)(c3ccccc3)c3cc(-c4cc(-c5ccccc5)nc(-c5ccccc5)n4)cc([Si](c4ccccc4)(c4ccccc4)c4ccccc4)c3)c2)cc1 ; c1ccc(-c2cccc([Si](c3ccccc3)(c3ccccc3)c3cc(-c4cc(-c5ccccc5)nc(-c5ccccc5)n4)cc([Si](c4ccccc4)(c4ccccc4)c4cccc(-c5ccccc5)c4)c3)c2)cc1]

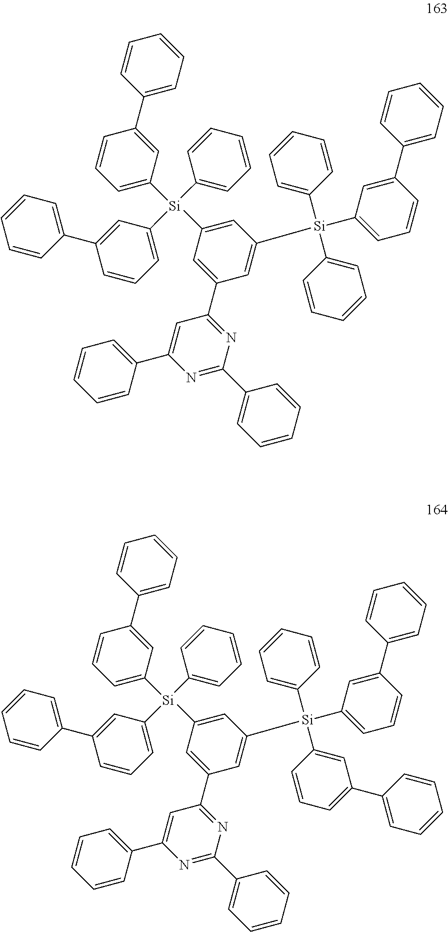 [SMILES: c1ccc(-c2cccc([Si](c3ccccc3)(c3ccccc3)c3cc(-c4cc(-c5ccccc5)nc(-c5ccccc5)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4cc(-c5ccccc5)nc(-c5ccccc5)n4)cc([Si](c4ccccc4)(c4cccc(-c5ccccc5)c4)c4cccc(-c5ccccc5)c4)c3)c2)cc1]

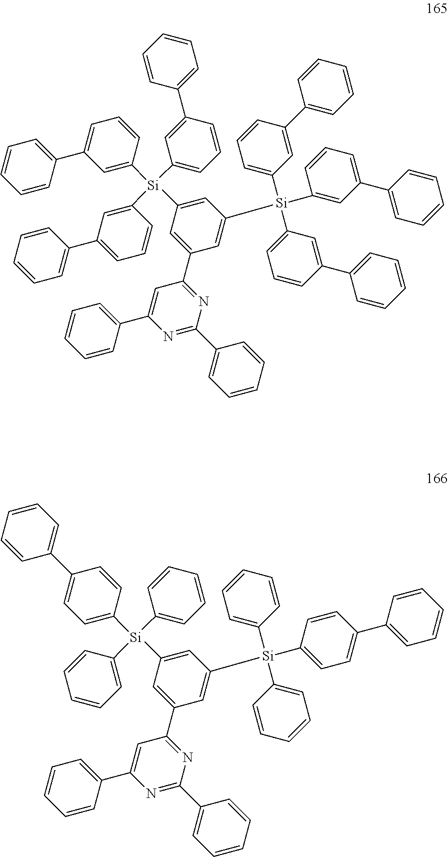 [SMILES: c1ccc(-c2cccc([Si](c3cccc(-c4ccccc4)c3)(c3cccc(-c4ccccc4)c3)c3cc(-c4cc(-c5ccccc5)nc(-c5ccccc5)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4cc(-c5ccccc5)nc(-c5ccccc5)n4)cc([Si](c4ccccc4)(c4ccccc4)c4ccc(-c5ccccc5)cc4)c3)cc2)cc1]

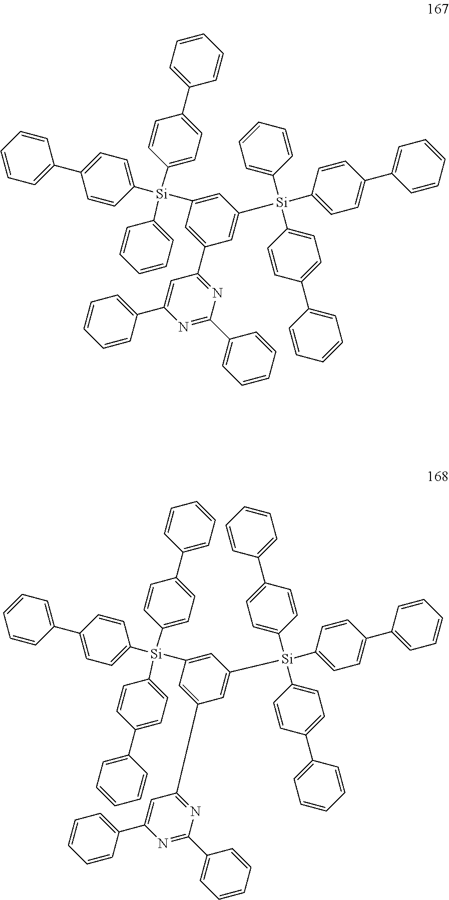 [SMILES: c1ccc(-c2ccc([Si](c3ccccc3)(c3ccc(-c4ccccc4)cc3)c3cc(-c4cc(-c5ccccc5)nc(-c5ccccc5)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4cc(-c5ccccc5)nc(-c5ccccc5)n4)cc([Si](c4ccc(-c5ccccc5)cc4)(c4ccc(-c5ccccc5)cc4)c4ccc(-c5ccccc5)cc4)c3)cc2)cc1]

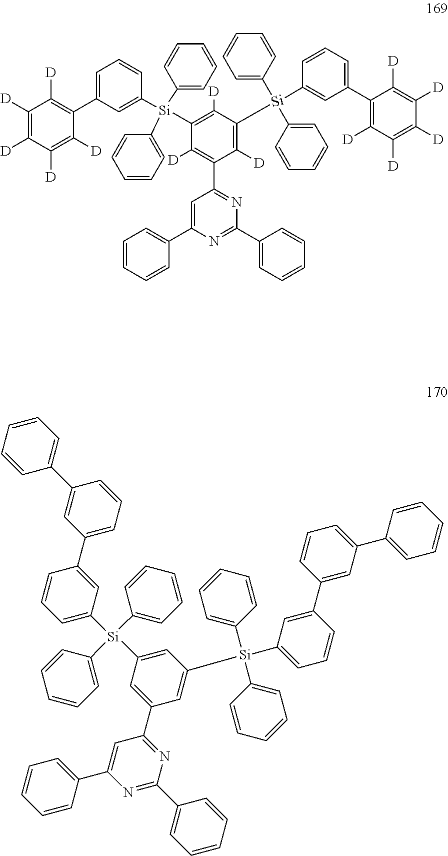 [SMILES: [2H]c1c([2H])c([2H])c(-c2cccc([Si](c3ccccc3)(c3ccccc3)c3c([2H])c(-c4cc(-c5ccccc5)nc(-c5ccccc5)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5cc(-c6ccccc6)nc(-c6ccccc6)n5)cc([Si](c5ccccc5)(c5ccccc5)c5cccc(-c6cccc(-c7ccccc7)c6)c5)c4)c3)c2)cc1]

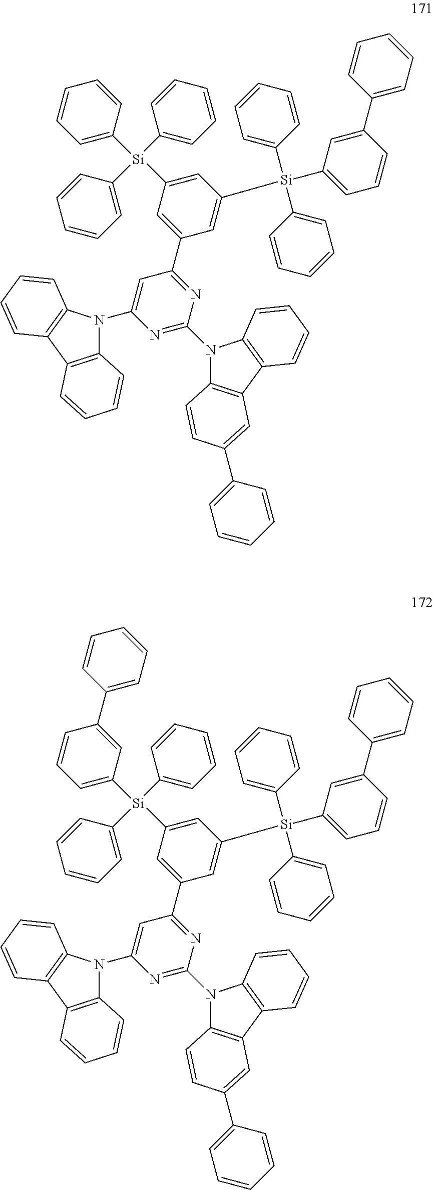 [SMILES: c1ccc(-c2cccc([Si](c3ccccc3)(c3ccccc3)c3cc(-c4cc(-n5c6ccccc6c6ccccc65)nc(-n5c6ccccc6c6cc(-c7ccccc7)ccc65)n4)cc([Si](c4ccccc4)(c4ccccc4)c4ccccc4)c3)c2)cc1 ; c1ccc(-c2cccc([Si](c3ccccc3)(c3ccccc3)c3cc(-c4cc(-n5c6ccccc6c6ccccc65)nc(-n5c6ccccc6c6cc(-c7ccccc7)ccc65)n4)cc([Si](c4ccccc4)(c4ccccc4)c4cccc(-c5ccccc5)c4)c3)c2)cc1]

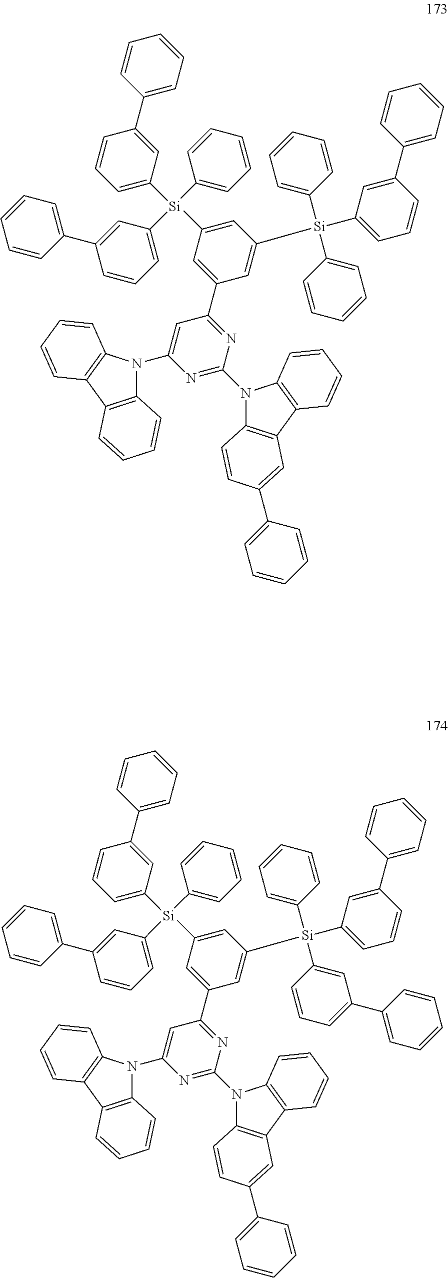 [SMILES: c1ccc(-c2cccc([Si](c3ccccc3)(c3ccccc3)c3cc(-c4cc(-n5c6ccccc6c6ccccc65)nc(-n5c6ccccc6c6cc(-c7ccccc7)ccc65)n4)cc([Si](c4ccccc4)(c4cccc(-c5ccccc5)c4)c4cccc(-c5ccccc5)c4)c3)c2)cc1 ; c1ccc(-c2cccc([Si](c3ccccc3)(c3cccc(-c4ccccc4)c3)c3cc(-c4cc(-n5c6ccccc6c6ccccc65)nc(-n5c6ccccc6c6cc(-c7ccccc7)ccc65)n4)cc([Si](c4ccccc4)(c4cccc(-c5ccccc5)c4)c4cccc(-c5ccccc5)c4)c3)c2)cc1]

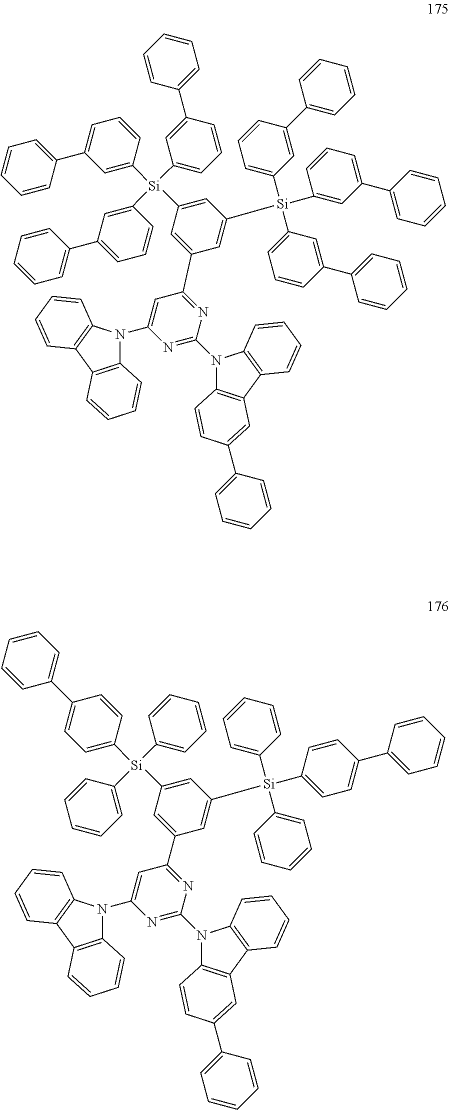 [SMILES: c1ccc(-c2cccc([Si](c3cccc(-c4ccccc4)c3)(c3cccc(-c4ccccc4)c3)c3cc(-c4cc(-n5c6ccccc6c6ccccc65)nc(-n5c6ccccc6c6cc(-c7ccccc7)ccc65)n4)cc([Si](c4cccc(-c5ccccc5)c4)(c4cccc(-c5ccccc5)c4)c4cccc(-c5ccccc5)c4)c3)c2)cc1 ; c1ccc(-c2ccc([Si](c3ccccc3)(c3ccccc3)c3cc(-c4cc(-n5c6ccccc6c6ccccc65)nc(-n5c6ccccc6c6cc(-c7ccccc7)ccc65)n4)cc([Si](c4ccccc4)(c4ccccc4)c4ccc(-c5ccccc5)cc4)c3)cc2)cc1]

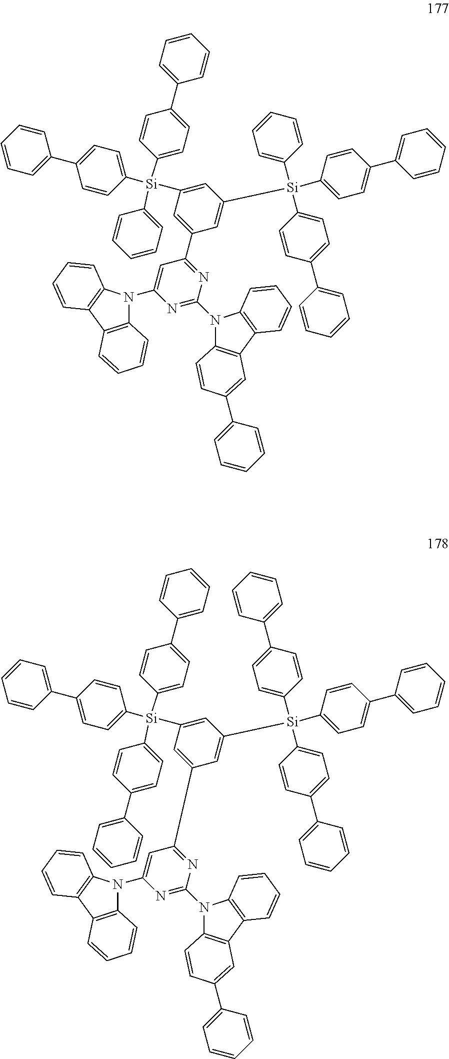 [SMILES: c1ccc(-c2ccc([Si](c3ccccc3)(c3ccc(-c4ccccc4)cc3)c3cc(-c4cc(-n5c6ccccc6c6ccccc65)nc(-n5c6ccccc6c6cc(-c7ccccc7)ccc65)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4cc(-n5c6ccccc6c6ccccc65)nc(-n5c6ccccc6c6cc(-c7ccccc7)ccc65)n4)cc([Si](c4ccc(-c5ccccc5)cc4)(c4ccc(-c5ccccc5)cc4)c4ccc(-c5ccccc5)cc4)c3)cc2)cc1]

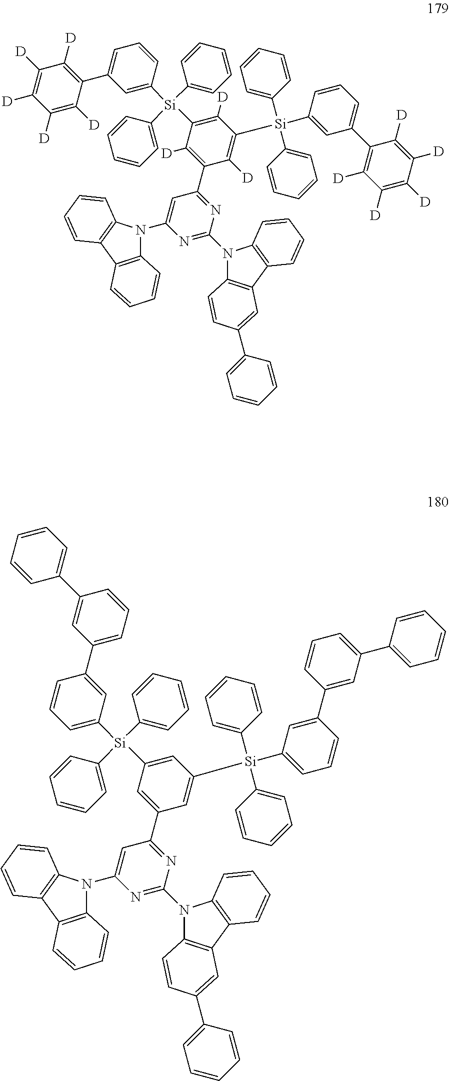 [SMILES: [2H]c1c([2H])c([2H])c(-c2cccc([Si](c3ccccc3)(c3ccccc3)c3c([2H])c(-c4cc(-n5c6ccccc6c6ccccc65)nc(-n5c6ccccc6c6cc(-c7ccccc7)ccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5cc(-n6c7ccccc7c7ccccc76)nc(-n6c7ccccc7c7cc(-c8ccccc8)ccc76)n5)cc([Si](c5ccccc5)(c5ccccc5)c5cccc(-c6cccc(-c7ccccc7)c6)c5)c4)c3)c2)cc1]

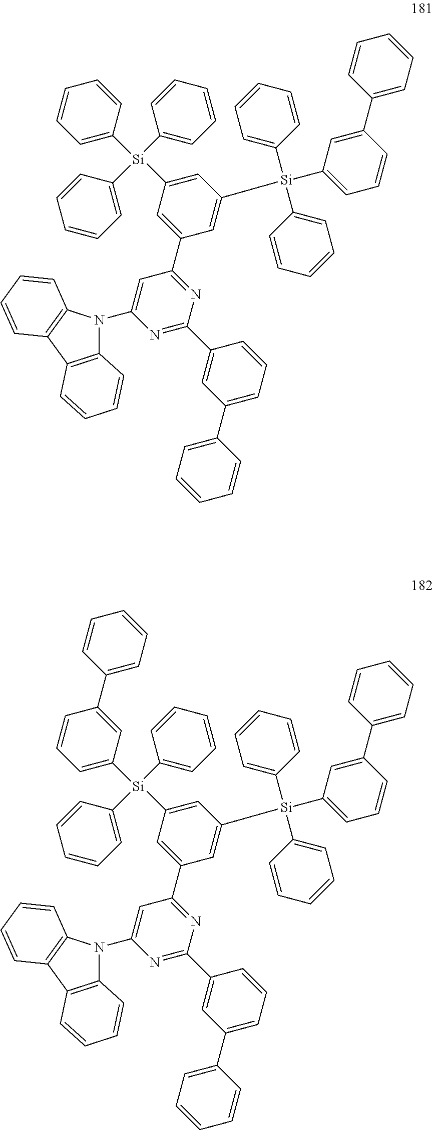 [SMILES: c1ccc(-c2cccc(-c3nc(-c4cc([Si](c5ccccc5)(c5ccccc5)c5ccccc5)cc([Si](c5ccccc5)(c5ccccc5)c5cccc(-c6ccccc6)c5)c4)cc(-n4c5ccccc5c5ccccc54)n3)c2)cc1 ; c1ccc(-c2cccc(-c3nc(-c4cc([Si](c5ccccc5)(c5ccccc5)c5cccc(-c6ccccc6)c5)cc([Si](c5ccccc5)(c5ccccc5)c5cccc(-c6ccccc6)c5)c4)cc(-n4c5ccccc5c5ccccc54)n3)c2)cc1]

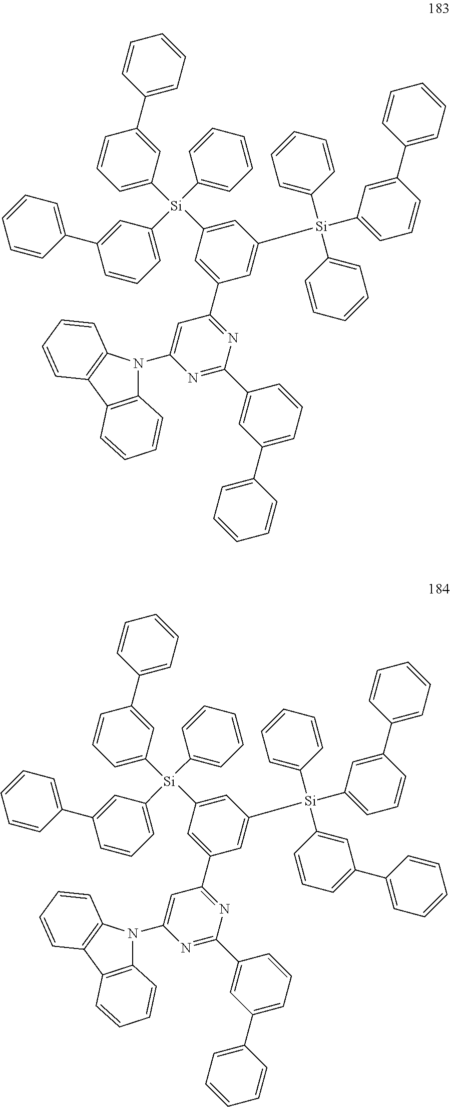 [SMILES: c1ccc(-c2cccc(-c3nc(-c4cc([Si](c5ccccc5)(c5ccccc5)c5cccc(-c6ccccc6)c5)cc([Si](c5ccccc5)(c5cccc(-c6ccccc6)c5)c5cccc(-c6ccccc6)c5)c4)cc(-n4c5ccccc5c5ccccc54)n3)c2)cc1 ; c1ccc(-c2cccc(-c3nc(-c4cc([Si](c5ccccc5)(c5cccc(-c6ccccc6)c5)c5cccc(-c6ccccc6)c5)cc([Si](c5ccccc5)(c5cccc(-c6ccccc6)c5)c5cccc(-c6ccccc6)c5)c4)cc(-n4c5ccccc5c5ccccc54)n3)c2)cc1]

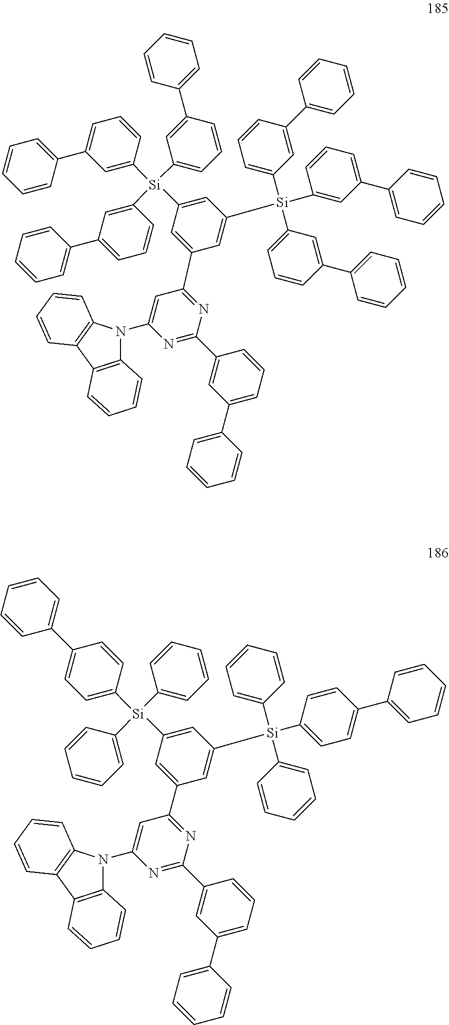 [SMILES: c1ccc(-c2cccc(-c3nc(-c4cc([Si](c5cccc(-c6ccccc6)c5)(c5cccc(-c6ccccc6)c5)c5cccc(-c6ccccc6)c5)cc([Si](c5cccc(-c6ccccc6)c5)(c5cccc(-c6ccccc6)c5)c5cccc(-c6ccccc6)c5)c4)cc(-n4c5ccccc5c5ccccc54)n3)c2)cc1 ; c1ccc(-c2ccc([Si](c3ccccc3)(c3ccccc3)c3cc(-c4cc(-n5c6ccccc6c6ccccc65)nc(-c5cccc(-c6ccccc6)c5)n4)cc([Si](c4ccccc4)(c4ccccc4)c4ccc(-c5ccccc5)cc4)c3)cc2)cc1]

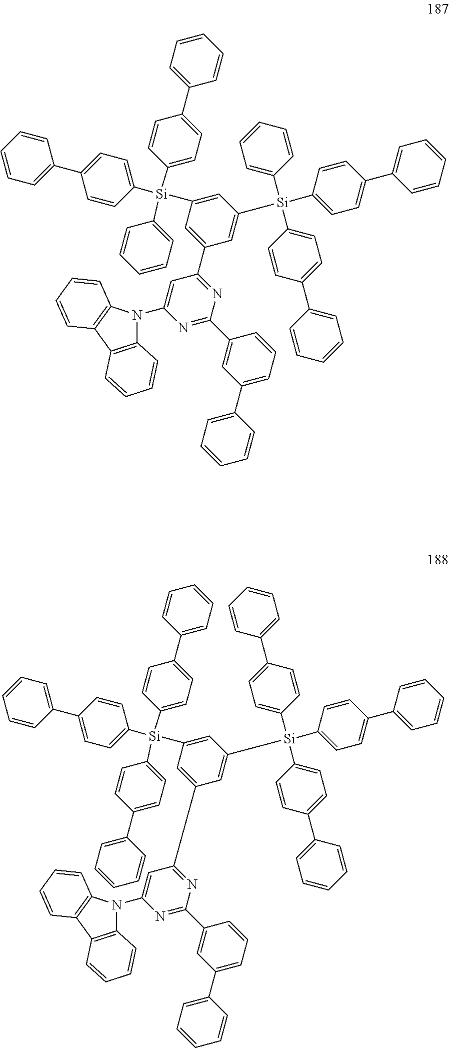 [SMILES: c1ccc(-c2ccc([Si](c3ccccc3)(c3ccc(-c4ccccc4)cc3)c3cc(-c4cc(-n5c6ccccc6c6ccccc65)nc(-c5cccc(-c6ccccc6)c5)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4cc(-n5c6ccccc6c6ccccc65)nc(-c5cccc(-c6ccccc6)c5)n4)cc([Si](c4ccc(-c5ccccc5)cc4)(c4ccc(-c5ccccc5)cc4)c4ccc(-c5ccccc5)cc4)c3)cc2)cc1]

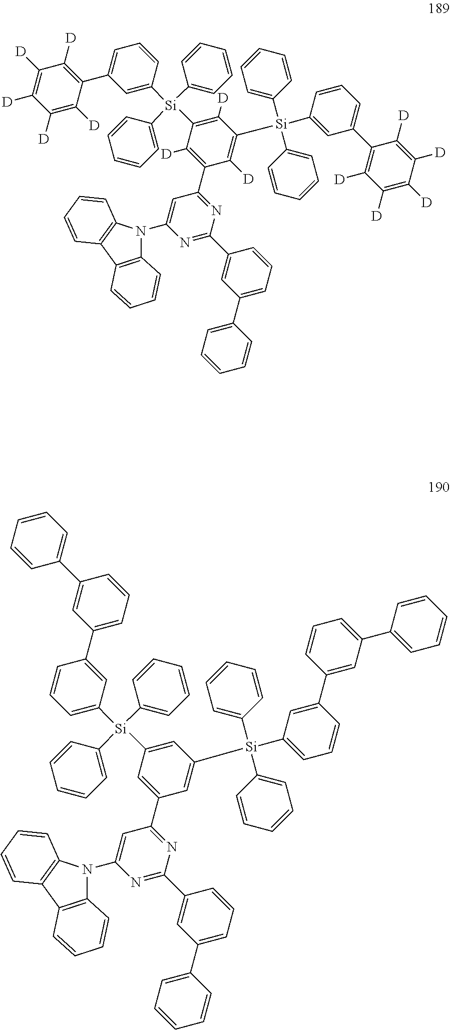 [SMILES: [2H]c1c([2H])c([2H])c(-c2cccc([Si](c3ccccc3)(c3ccccc3)c3c([2H])c(-c4cc(-n5c6ccccc6c6ccccc65)nc(-c5cccc(-c6ccccc6)c5)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5cc(-n6c7ccccc7c7ccccc76)nc(-c6cccc(-c7ccccc7)c6)n5)cc([Si](c5ccccc5)(c5ccccc5)c5cccc(-c6cccc(-c7ccccc7)c6)c5)c4)c3)c2)cc1]

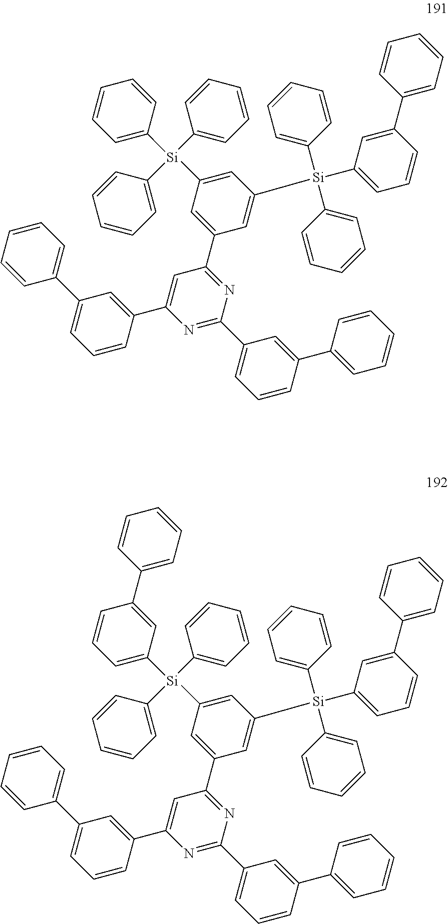 [SMILES: c1ccc(-c2cccc(-c3cc(-c4cc([Si](c5ccccc5)(c5ccccc5)c5ccccc5)cc([Si](c5ccccc5)(c5ccccc5)c5cccc(-c6ccccc6)c5)c4)nc(-c4cccc(-c5ccccc5)c4)n3)c2)cc1 ; c1ccc(-c2cccc(-c3cc(-c4cc([Si](c5ccccc5)(c5ccccc5)c5cccc(-c6ccccc6)c5)cc([Si](c5ccccc5)(c5ccccc5)c5cccc(-c6ccccc6)c5)c4)nc(-c4cccc(-c5ccccc5)c4)n3)c2)cc1]

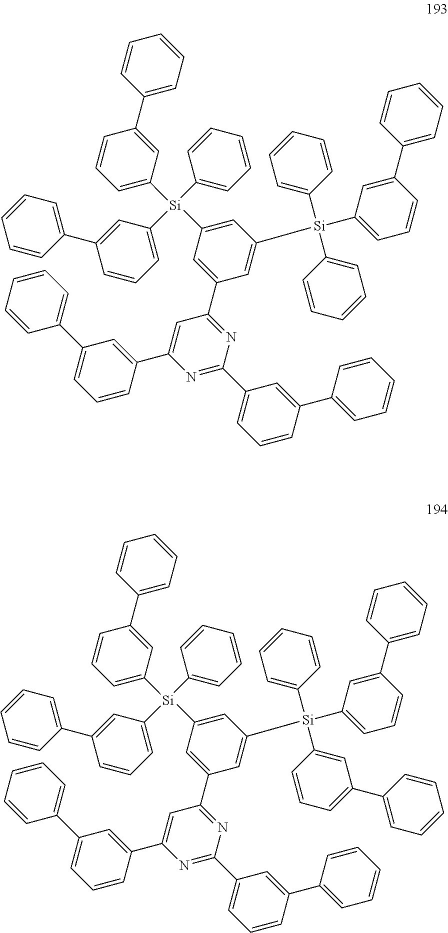 [SMILES: c1ccc(-c2cccc(-c3cc(-c4cc([Si](c5ccccc5)(c5ccccc5)c5cccc(-c6ccccc6)c5)cc([Si](c5ccccc5)(c5cccc(-c6ccccc6)c5)c5cccc(-c6ccccc6)c5)c4)nc(-c4cccc(-c5ccccc5)c4)n3)c2)cc1 ; c1ccc(-c2cccc(-c3cc(-c4cc([Si](c5ccccc5)(c5cccc(-c6ccccc6)c5)c5cccc(-c6ccccc6)c5)cc([Si](c5ccccc5)(c5cccc(-c6ccccc6)c5)c5cccc(-c6ccccc6)c5)c4)nc(-c4cccc(-c5ccccc5)c4)n3)c2)cc1]

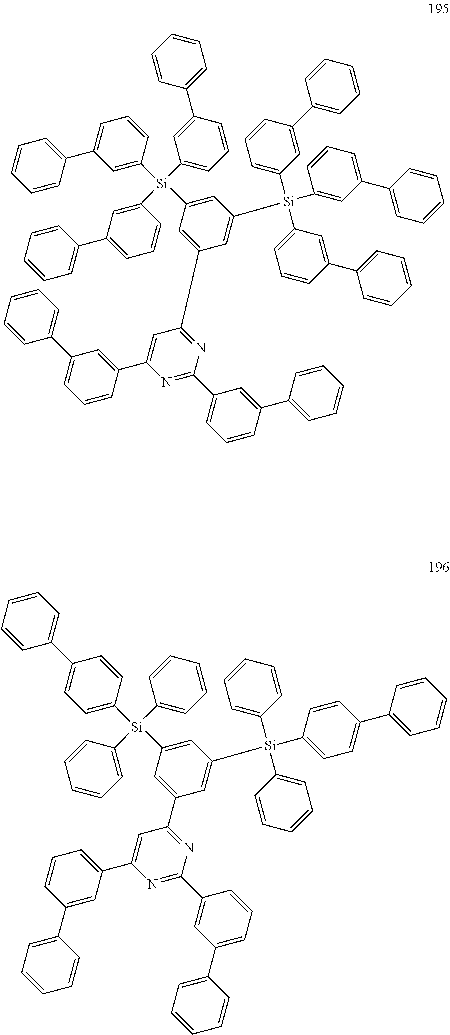 [SMILES: c1ccc(-c2cccc(-c3cc(-c4cc([Si](c5cccc(-c6ccccc6)c5)(c5cccc(-c6ccccc6)c5)c5cccc(-c6ccccc6)c5)cc([Si](c5cccc(-c6ccccc6)c5)(c5cccc(-c6ccccc6)c5)c5cccc(-c6ccccc6)c5)c4)nc(-c4cccc(-c5ccccc5)c4)n3)c2)cc1 ; c1ccc(-c2ccc([Si](c3ccccc3)(c3ccccc3)c3cc(-c4cc(-c5cccc(-c6ccccc6)c5)nc(-c5cccc(-c6ccccc6)c5)n4)cc([Si](c4ccccc4)(c4ccccc4)c4ccc(-c5ccccc5)cc4)c3)cc2)cc1]

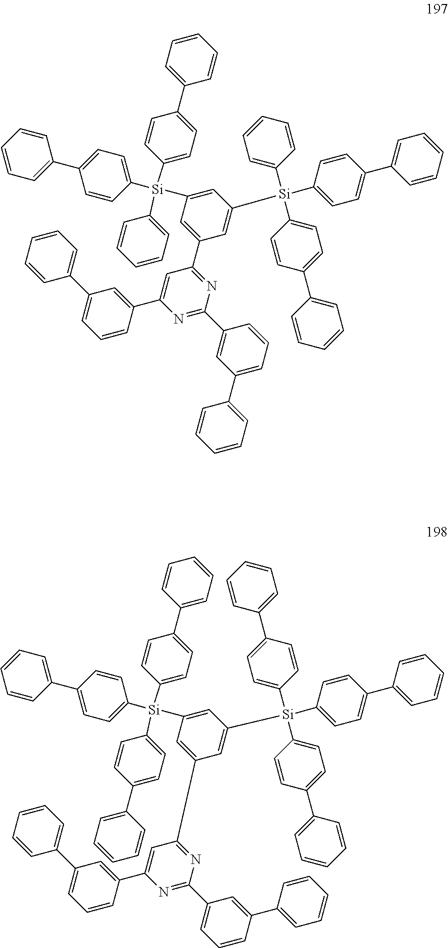 [SMILES: c1ccc(-c2ccc([Si](c3ccccc3)(c3ccc(-c4ccccc4)cc3)c3cc(-c4cc(-c5cccc(-c6ccccc6)c5)nc(-c5cccc(-c6ccccc6)c5)n4)cc([Si](c4ccccc4)(c4ccc(-c5ccccc5)cc4)c4ccc(-c5ccccc5)cc4)c3)cc2)cc1 ; c1ccc(-c2ccc([Si](c3ccc(-c4ccccc4)cc3)(c3ccc(-c4ccccc4)cc3)c3cc(-c4cc(-c5cccc(-c6ccccc6)c5)nc(-c5cccc(-c6ccccc6)c5)n4)cc([Si](c4ccc(-c5ccccc5)cc4)(c4ccc(-c5ccccc5)cc4)c4ccc(-c5ccccc5)cc4)c3)cc2)cc1]

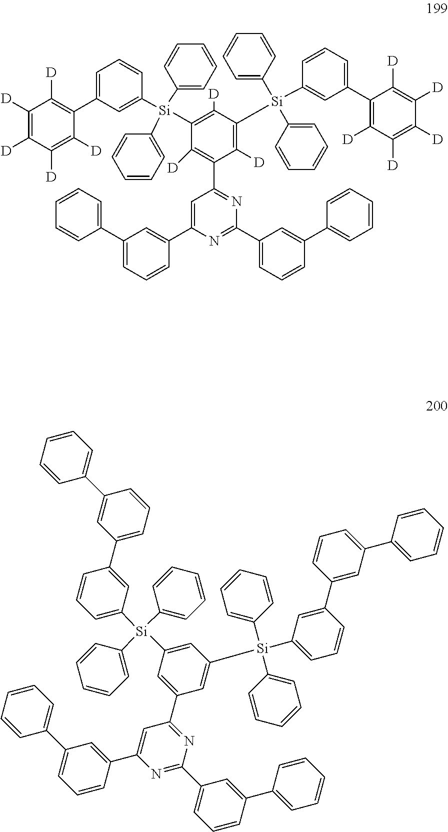 [SMILES: [2H]c1c([2H])c([2H])c(-c2cccc([Si](c3ccccc3)(c3ccccc3)c3c([2H])c(-c4cc(-c5cccc(-c6ccccc6)c5)nc(-c5cccc(-c6ccccc6)c5)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; c1ccc(-c2cccc(-c3cccc([Si](c4ccccc4)(c4ccccc4)c4cc(-c5cc(-c6cccc(-c7ccccc7)c6)nc(-c6cccc(-c7ccccc7)c6)n5)cc([Si](c5ccccc5)(c5ccccc5)c5cccc(-c6cccc(-c7ccccc7)c6)c5)c4)c3)c2)cc1]

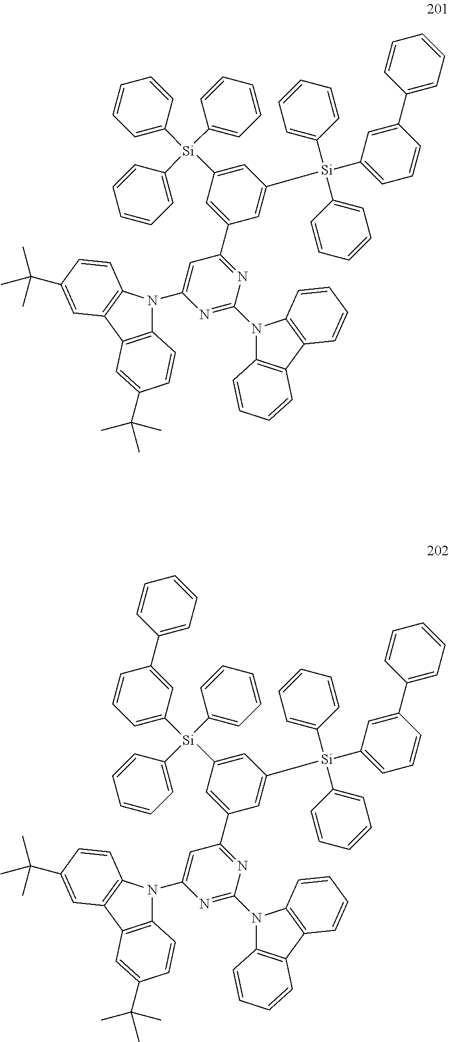 [SMILES: CC(C)(C)c1ccc2c(c1)c1cc(C(C)(C)C)ccc1n2-c1cc(-c2cc([Si](c3ccccc3)(c3ccccc3)c3ccccc3)cc([Si](c3ccccc3)(c3ccccc3)c3cccc(-c4ccccc4)c3)c2)nc(-n2c3ccccc3c3ccccc32)n1 ; CC(C)(C)c1ccc2c(c1)c1cc(C(C)(C)C)ccc1n2-c1cc(-c2cc([Si](c3ccccc3)(c3ccccc3)c3cccc(-c4ccccc4)c3)cc([Si](c3ccccc3)(c3ccccc3)c3cccc(-c4ccccc4)c3)c2)nc(-n2c3ccccc3c3ccccc32)n1]

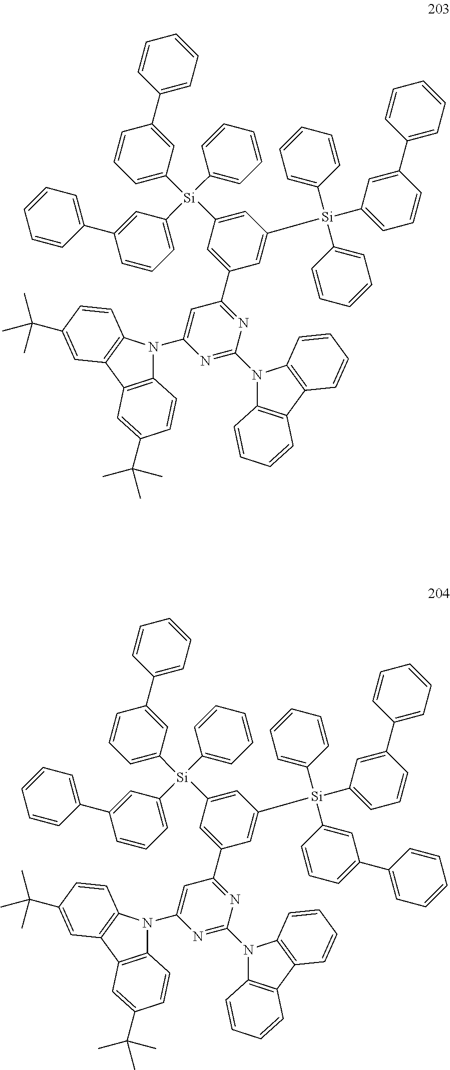 [SMILES: CC(C)(C)c1ccc2c(c1)c1cc(C(C)(C)C)ccc1n2-c1cc(-c2cc([Si](c3ccccc3)(c3ccccc3)c3cccc(-c4ccccc4)c3)cc([Si](c3ccccc3)(c3cccc(-c4ccccc4)c3)c3cccc(-c4ccccc4)c3)c2)nc(-n2c3ccccc3c3ccccc32)n1 ; CC(C)(C)c1ccc2c(c1)c1cc(C(C)(C)C)ccc1n2-c1cc(-c2cc([Si](c3ccccc3)(c3cccc(-c4ccccc4)c3)c3cccc(-c4ccccc4)c3)cc([Si](c3ccccc3)(c3cccc(-c4ccccc4)c3)c3cccc(-c4ccccc4)c3)c2)nc(-n2c3ccccc3c3ccccc32)n1]

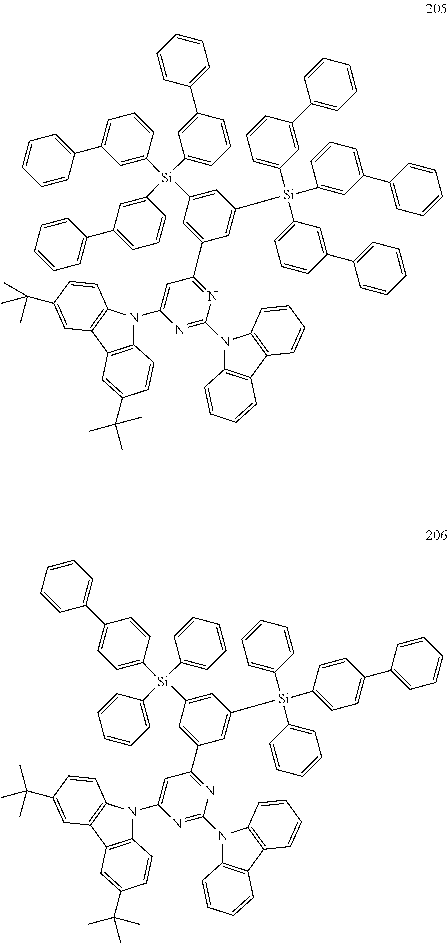 [SMILES: CC(C)(C)c1ccc2c(c1)c1cc(C(C)(C)C)ccc1n2-c1cc(-c2cc([Si](c3cccc(-c4ccccc4)c3)(c3cccc(-c4ccccc4)c3)c3cccc(-c4ccccc4)c3)cc([Si](c3cccc(-c4ccccc4)c3)(c3cccc(-c4ccccc4)c3)c3cccc(-c4ccccc4)c3)c2)nc(-n2c3ccccc3c3ccccc32)n1 ; CC(C)(C)c1ccc2c(c1)c1cc(C(C)(C)C)ccc1n2-c1cc(-c2cc([Si](c3ccccc3)(c3ccccc3)c3ccc(-c4ccccc4)cc3)cc([Si](c3ccccc3)(c3ccccc3)c3ccc(-c4ccccc4)cc3)c2)nc(-n2c3ccccc3c3ccccc32)n1]

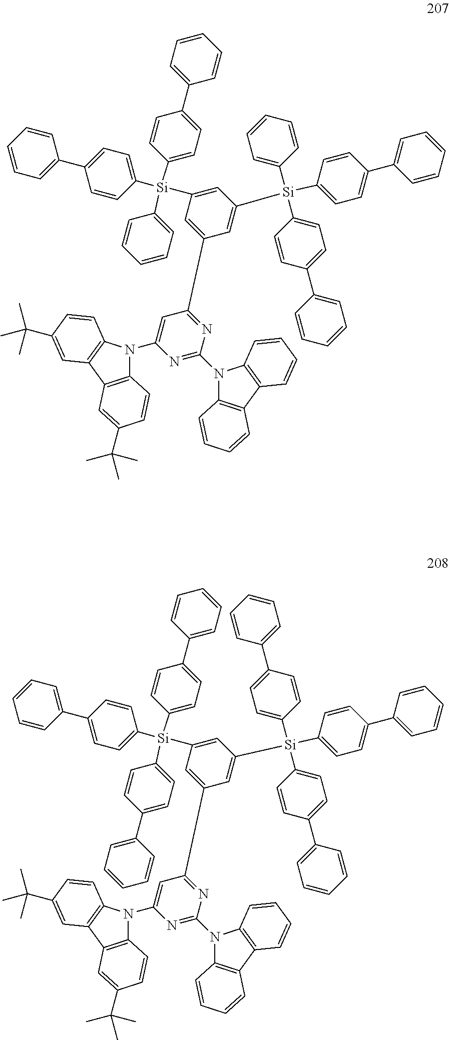 [SMILES: CC(C)(C)c1ccc2c(c1)c1cc(C(C)(C)C)ccc1n2-c1cc(-c2cc([Si](c3ccccc3)(c3ccc(-c4ccccc4)cc3)c3ccc(-c4ccccc4)cc3)cc([Si](c3ccccc3)(c3ccc(-c4ccccc4)cc3)c3ccc(-c4ccccc4)cc3)c2)nc(-n2c3ccccc3c3ccccc32)n1 ; CC(C)(C)c1ccc2c(c1)c1cc(C(C)(C)C)ccc1n2-c1cc(-c2cc([Si](c3ccc(-c4ccccc4)cc3)(c3ccc(-c4ccccc4)cc3)c3ccc(-c4ccccc4)cc3)cc([Si](c3ccc(-c4ccccc4)cc3)(c3ccc(-c4ccccc4)cc3)c3ccc(-c4ccccc4)cc3)c2)nc(-n2c3ccccc3c3ccccc32)n1]

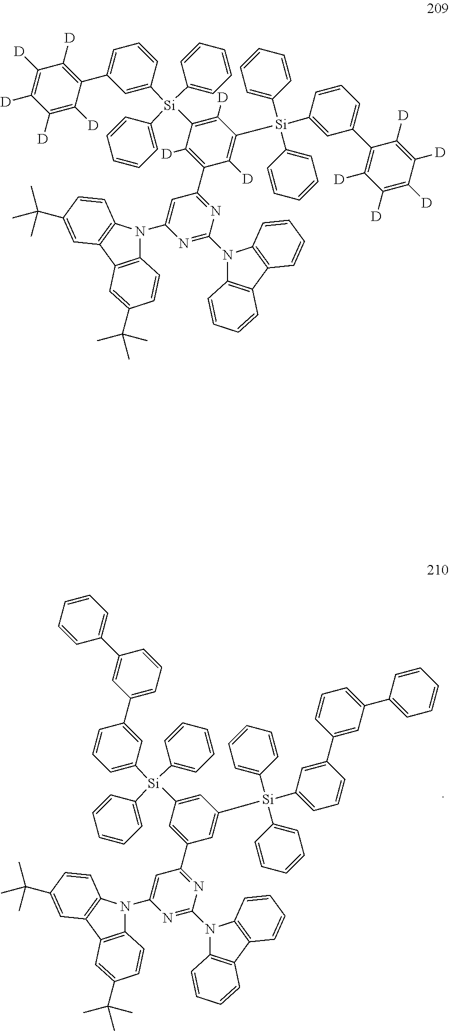 [SMILES: [2H]c1c([2H])c([2H])c(-c2cccc([Si](c3ccccc3)(c3ccccc3)c3c([2H])c(-c4cc(-n5c6ccc(C(C)(C)C)cc6c6cc(C(C)(C)C)ccc65)nc(-n5c6ccccc6c6ccccc65)n4)c([2H])c([Si](c4ccccc4)(c4ccccc4)c4cccc(-c5c([2H])c([2H])c([2H])c([2H])c5[2H])c4)c3[2H])c2)c([2H])c1[2H] ; CC(C)(C)c1ccc2c(c1)c1cc(C(C)(C)C)ccc1n2-c1cc(-c2cc([Si](c3ccccc3)(c3ccccc3)c3cccc(-c4cccc(-c5ccccc5)c4)c3)cc([Si](c3ccccc3)(c3ccccc3)c3cccc(-c4cccc(-c5ccccc5)c4)c3)c2)nc(-n2c3ccccc3c3ccccc32)n1]

The heterocyclic compound represented by Formula 1 has a molecular structure with large steric hindrance by including a group represented by Formula 1-1, and the formation of an exciplex between the heterocyclic compound represented by Formula 1 and the dopant may be limited. Also, the heterocyclic compound as described above may maintain an optimal or suitable intermolecular density by including at least one biphenyl group, and chemical decomposition of the heterocyclic compound according to the movement of electrons or holes may be further delayed.

Furthermore, substituents in Formula 1-1, Ar₂, and Ar₃ may be identical to or different from each other, and thus, the highest occupied molecular orbital (HOMO) energy level, the lowest unoccupied molecular orbital (LUMO) energy level, and/or the energy gap between HOMO-LUMO energy levels of the heterocyclic compound represented by Formula 1 may be finely adjusted.

As a result, hole mobility and electron mobility may be improved, energy transfer efficiency to a dopant may be improved, and an electronic device, for example, an organic light-emitting device, including the heterocyclic compound may have excellent or suitable color coordinates, low driving voltage, high efficiency, and/or long lifespan.

Methods of synthesizing the heterocyclic compound represented by Formula 1 may be easily understood by those of ordinary skill in the art by referring to Synthesis Examples and Examples described herein.

At least one heterocyclic compound represented by Formula 1 may be utilized in a light-emitting device (for example, an organic light-emitting device). Accordingly, a light-emitting device may include: a first electrode; a second electrode facing the first electrode; an interlayer located between the first electrode and the second electrode and including an emission layer; and a heterocyclic compound represented by Formula 1 as described herein.

In an embodiment,
the first electrode of the light-emitting device may be an anode,
the second electrode of the light-emitting device may be a cathode,
the interlayer may further include a hole transport region arranged between the first electrode and the emission layer and an electron transport region arranged between the emission layer and the second electrode,
the hole transport region may include a hole injection layer, a hole transport layer, an emission auxiliary layer, an electron blocking layer, or any combination thereof, and
the electron transport region may include a buffer layer, a hole blocking layer, an electron control layer, an electron transport layer, an electron injection layer, or any combination thereof.

In an embodiment, the heterocyclic compound may be included between the first electrode and the second electrode of the light-emitting device. Accordingly, the heterocyclic compound may be included in the interlayer of the light-emitting device, for example, in the emission layer of the interlayer.

In an embodiment, the emission layer of the interlayer of the light-emitting device may include a dopant and a host, and the heterocyclic compound may be included in the host. In other words, the heterocyclic compound may act (e.g., serve) as a host. The emission layer may be to emit red light, green light, blue light, and/or white light. In an embodiment, the emission layer may be to emit blue light. The blue light may have a maximum emission wavelength in a range of, for example, about 400 nm to about 490 nm.

In an embodiment, the emission layer of the interlayer of the light-emitting device may include a dopant and a host, and the heterocyclic compound may be included in the host, and the dopant may be to emit blue light. In an embodiment, the dopant may include a transition metal and m ligand(s), m may be an integer from 1 to 6, the m ligand(s) may be identical to or different from each other, at least one of the m ligand(s) may be bound to the transition metal via a carbon-transition metal bond, and the carbon-transition metal bond may be a coordinate bond. For example, at least one of the m ligand(s) may be a carbene ligand (for example, the dopant may include Ir(pmp)₃ and/or the like). The transition metal may be, for example, iridium, platinum, osmium, palladium, rhodium, or gold. The emission layer and the dopant may respectively be the same as described herein.

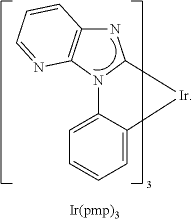

In an embodiment, the light-emitting device may include a capping layer located outside the first electrode or located outside the second electrode.

In an embodiment, the light-emitting device may further include at least one of a first capping layer located outside the first electrode or a second capping layer located outside the second electrode, and at least one of the first capping layer or the second capping layer may include the heterocyclic compound represented by Formula 1. The first capping layer and/or the second capping layer may respectively be the same as described herein.

In an embodiment, the light-emitting device may include:
a first capping layer located outside the first electrode (e.g., facing away from the second electrode) and including the heterocyclic compound represented by Formula 1;
a second capping layer located outside the second electrode (e.g., facing away from the first electrode) and including the heterocyclic compound represented by Formula 1; or
both the first capping layer and the second capping layer.

The expression “(interlayer and/or capping layer) includes at least one heterocyclic compound” as utilized herein may refer to that the (interlayer and/or capping layer) may include one kind of the heterocyclic compound represented by Formula 1 or two or more different kinds of heterocyclic compounds, each represented by Formula 1.

In an embodiment, the interlayer and/or capping layer may include only Compound 1 as the heterocyclic compound. In this regard, Compound 1 may be present in the emission layer of the light-emitting device. In an embodiment, the interlayer may include, as the heterocyclic compound, Compound 1 and Compound 2. In this regard, Compound 1 and Compound 2 may be present in substantially the same layer (for example, both Compound 1 and Compound 2 may be present in the emission layer), or may be present in different layers (for example, Compound 1 may be present in the emission layer, and Compound 2 may be present in the electron transport region).

The term “interlayer” as utilized herein refers to a single layer and/or all of a plurality of layers arranged between the first electrode and the second electrode of the light-emitting device.

According to one or more embodiments, an electronic apparatus includes the light-emitting device. The electronic apparatus may further include a thin-film transistor. In an embodiment, the electronic apparatus may further include a thin-film transistor including a source electrode and a drain electrode, and the first electrode of the light-emitting device may be electrically connected to the source electrode or the drain electrode. In an embodiment, the electronic apparatus may further include a color filter, a color-conversion layer, a touch screen layer, a polarizing layer, or any combination thereof. The electronic apparatus may be the same as described in the present specification.

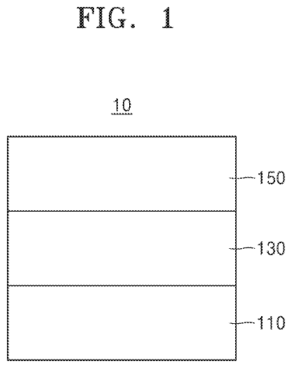

### Description of FIG. 1

FIG. 1 is a schematic cross-sectional view of a light-emitting device 10 according to an embodiment of the disclosure. The light-emitting device 10 includes a first electrode 110, an interlayer 130, and a second electrode 150.

Hereinafter, a structure of the light-emitting device 10 according to an embodiment and a method of manufacturing the light-emitting device 10 will be described in connection with FIG. 1.

### First Electrode 110

In FIG. 1, a substrate may be additionally located under the first electrode 110 or above the second electrode 150. In an embodiment, as the substrate, a glass substrate and/or a plastic substrate may be utilized. In an embodiment, the substrate may be a flexible substrate, and may include one or more plastics with excellent or suitable heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high work function material to facilitate injection of holes.

The first electrode 110 may be a reflective electrode, a semi-transmissive electrode, or a transmissive electrode. When the first electrode 110 is a transmissive electrode, the material for forming the first electrode 110 may include indium tin oxide (ITO), indium zinc oxide (IZO), tin oxide (SnO₂), zinc oxide (ZnO), or any combination thereof. In an embodiment, when the first electrode 110 is a semi-transmissive electrode or a reflective electrode, the material for forming the first electrode 110 may include magnesium (Mg), silver (Ag), aluminum (AI), aluminum-lithium (Al—Li), calcium (Ca), magnesium-indium (Mg—In), magnesium-silver (Mg—Ag), or any combination thereof.

The first electrode 110 may have a single-layered structure consisting of a single layer, or a multilayer structure including a plurality of layers. In an embodiment, the first electrode 110 may have a three-layered structure of ITO/Ag/ITO.

### Interlayer 130

The interlayer 130 is located on the first electrode 110. The interlayer 130 includes an emission layer.

The interlayer 130 may further include a hole transport region located between the first electrode 110 and the emission layer and an electron transport region located between the emission layer and the second electrode 150.

The interlayer 130 may further include a metal-containing compound such as an organometallic compound, an inorganic material such as a quantum dot, and/or the like, in addition to one or more suitable organic materials.

In an embodiment, the interlayer 130 may include, i) two or more emitting (e.g., light-emitting) units sequentially stacked between the first electrode 110 and the second electrode 150, and ii) a charge generation layer located between the two or more emitting units. When the interlayer 130 includes the two or more emitting units and the charge generation layer as described above, the light-emitting device 10 may be a tandem light-emitting device.

### Hole Transport Region in Interlayer 130

The hole transport region may have: i) a single-layered structure consisting of a single layer consisting of a single material; ii) a single-layered structure consisting of a single layer including (e.g., consisting of) a plurality of different materials; or iii) a multilayer structure including a plurality of layers including different materials.

The hole transport region may include a hole injection layer, a hole transport layer, an emission auxiliary layer, an electron blocking layer, or any combination thereof.

In an embodiment, the hole transport region may have a multilayer structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, with the constituting layers of each structure being stacked sequentially from the first electrode 110 in the respective stated order.

The hole transport region may include a compound represented by Formula 201, a compound represented by Formula 202, or any combination thereof:

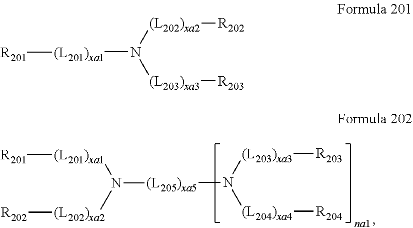

wherein, in Formulae 201 and 202,
L₂₀₁ to L₂₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
L₂₀₅ may be *—O—*′, *—S—*′, *—N(Q₂₀₁)-*′, a C₁-C₂₀ alkylene group that is unsubstituted or substituted with at least one R₁₀ₐ, a C₂-C₂₀ alkenylene group that is unsubstituted or substituted with at least one R₁₀ₐ, a C₃-C₆₀ carbocyclic group that is unsubstituted or substituted with at least one R₁₀ₐ, or a C₁-C₆₀ heterocyclic group that is unsubstituted or substituted with at least one R₁₀ₐ,
xa1 to xa4 may each independently be an integer from 0 to 5,
xa5 may be an integer from 1 to 10,
R₂₀₁ to R₂₀₄ and 0201 may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
R₂₀₁ and R₂₀₂ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group (for example, a carbazole group) that is unsubstituted or substituted with at least one R₁₀ₐ (for example, see Compound HT16),
R₂₀₃ and R₂₀₄ may optionally be linked to each other via a single bond, a C₁-C₅ alkylene group that is unsubstituted or substituted with at least one R₁₀ₐ, or a C₂-C₅ alkenylene group that is unsubstituted or substituted with at least one R₁₀ₐ to form a C₈-C₆₀ polycyclic group that is unsubstituted or substituted with at least one R₁₀ₐ, and
na1 may be an integer from 1 to 4.

In an embodiment, Formulae 201 and 202 may each include at least one of the groups represented by Formulae CY201 to CY217:

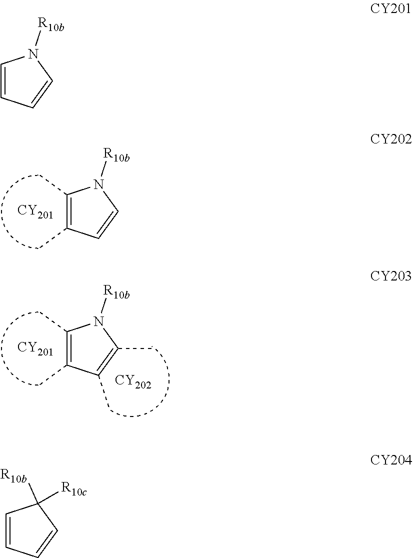

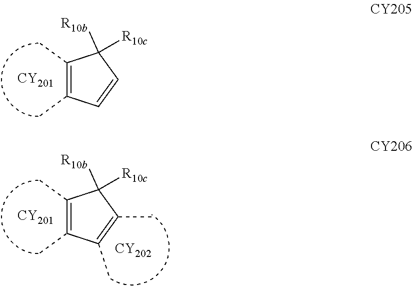

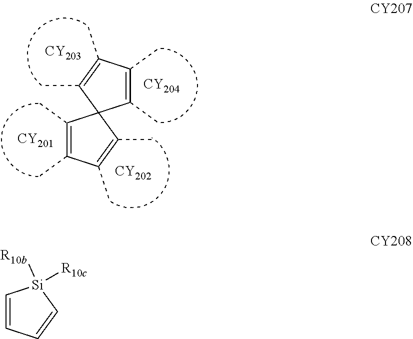

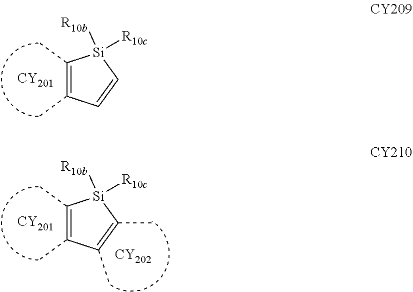

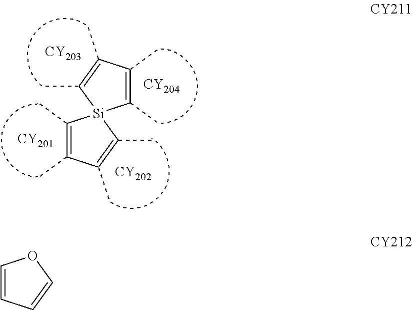

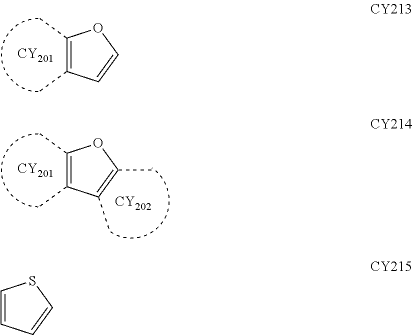

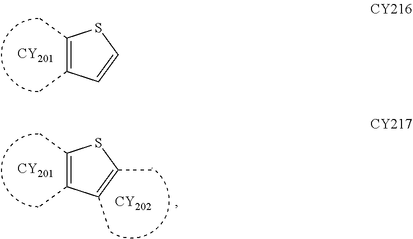

wherein, in Formulae CY201 to CY217, R_{10b} and R_{10c} may each independently be the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ.

In an embodiment, ring CY201 to ring CY204 in Formulae CY201 to CY217 may each independently be a benzene group, a naphthalene group, a phenanthrene group, or an anthracene group.

In an embodiment, Formulae 201 and 202 may each include at least one of the groups represented by Formulae CY201 to CY203.

In an embodiment, Formula 201 may include at least one of the groups represented by Formulae CY201 to CY203 and at least one of the groups represented by Formulae CY204 to CY217.

In an embodiment, xa1 in Formula 201 may be 1, R₂₀₁ may be a group represented by one of Formulae CY201 to CY203, xa2 may be 0, and R₂₀₂ may be a group represented by one of Formulae CY204 to CY207.

In an embodiment, each of Formulae 201 and 202 may not include (e.g., may exclude) any of the groups represented by Formulae CY201 to CY203.

In an embodiment, each of Formulae 201 and 202 may not include (e.g., may exclude) any of the groups represented by Formulae CY201 to CY203, and may include at least one of the groups represented by Formulae CY204 to CY217.

In an embodiment, each of Formulae 201 and 202 may not include (e.g., may exclude) any of the groups represented by Formulae CY201 to CY217.

In an embodiment, the hole transport region may include at least one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), or any combination thereof:

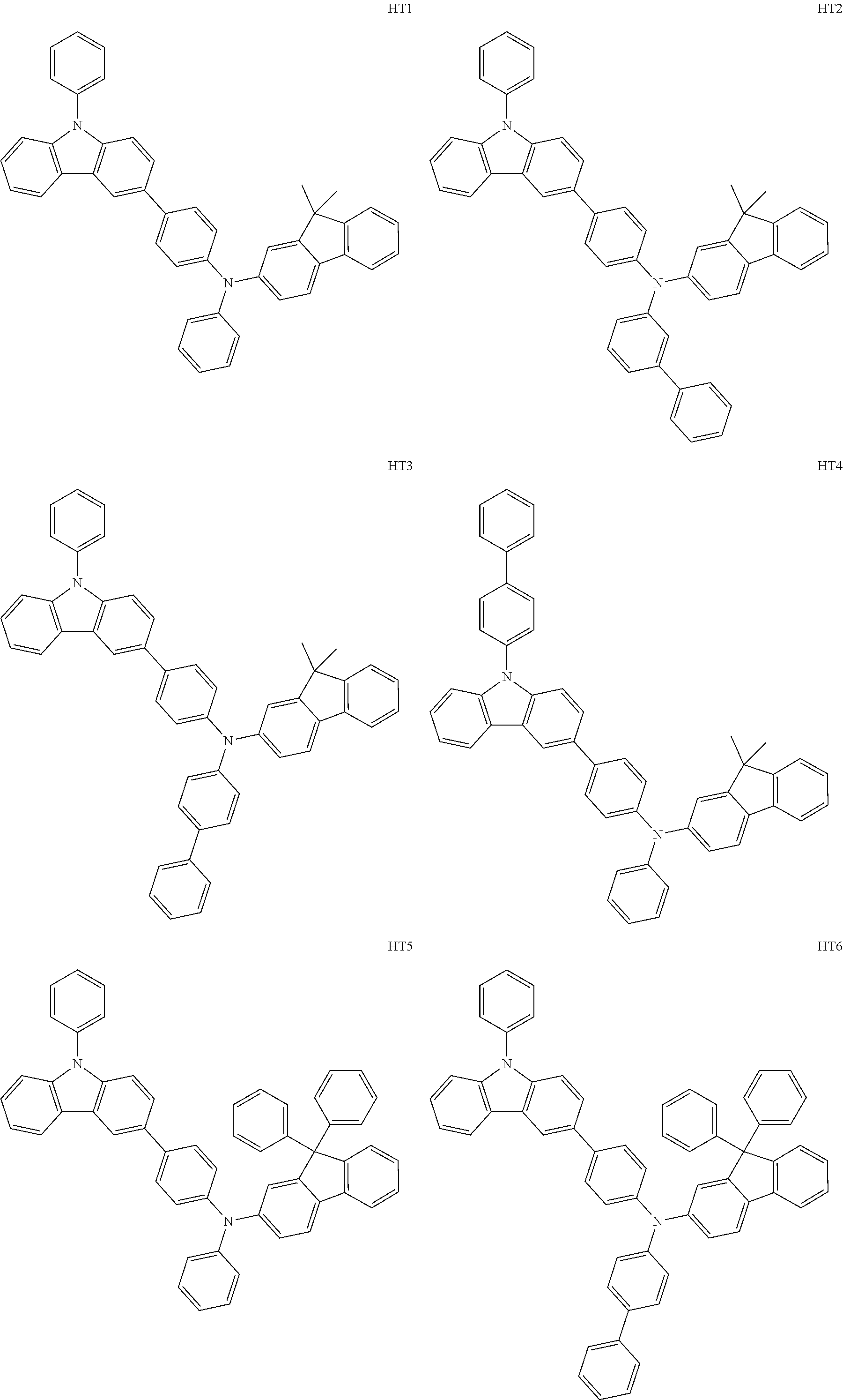

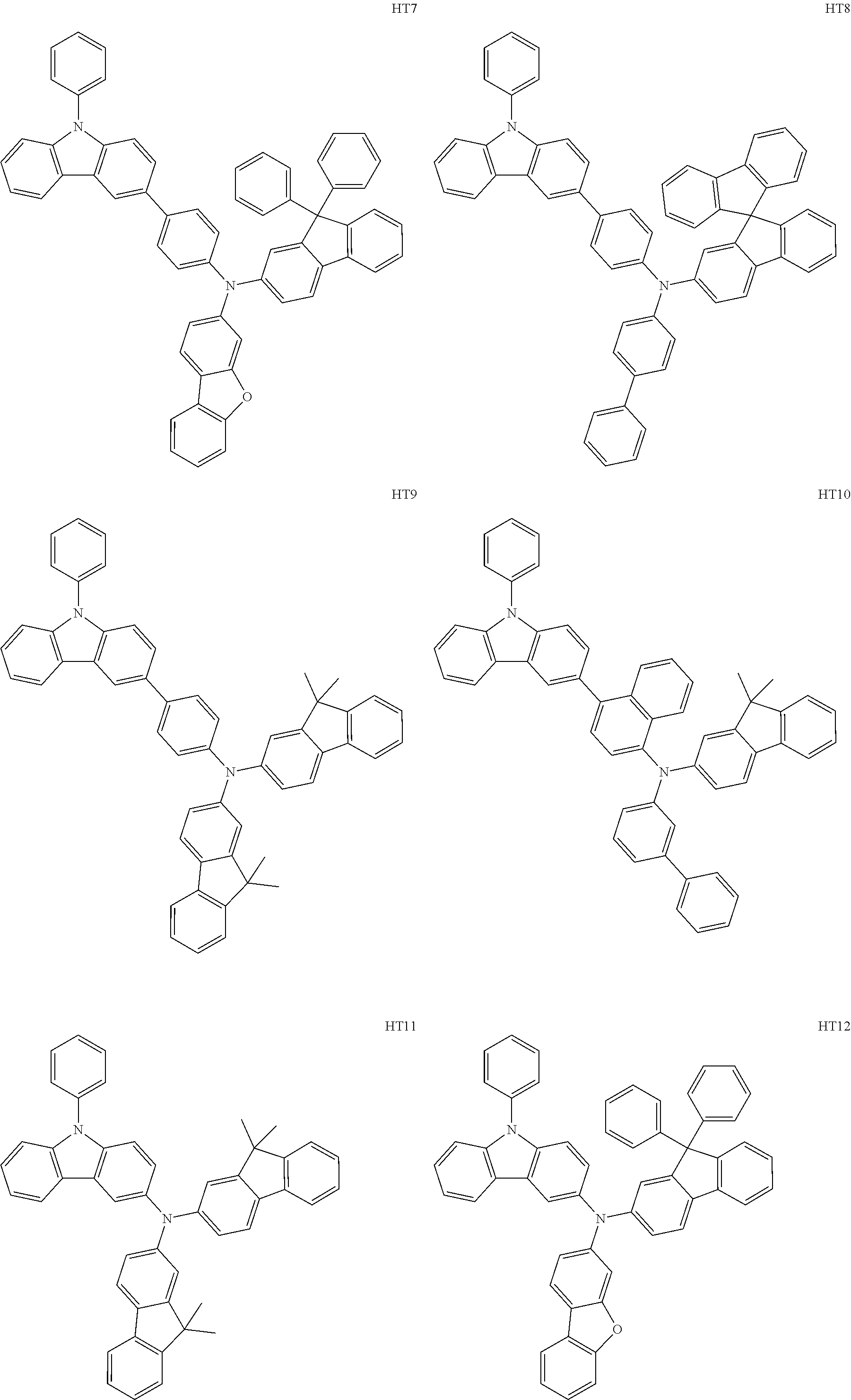

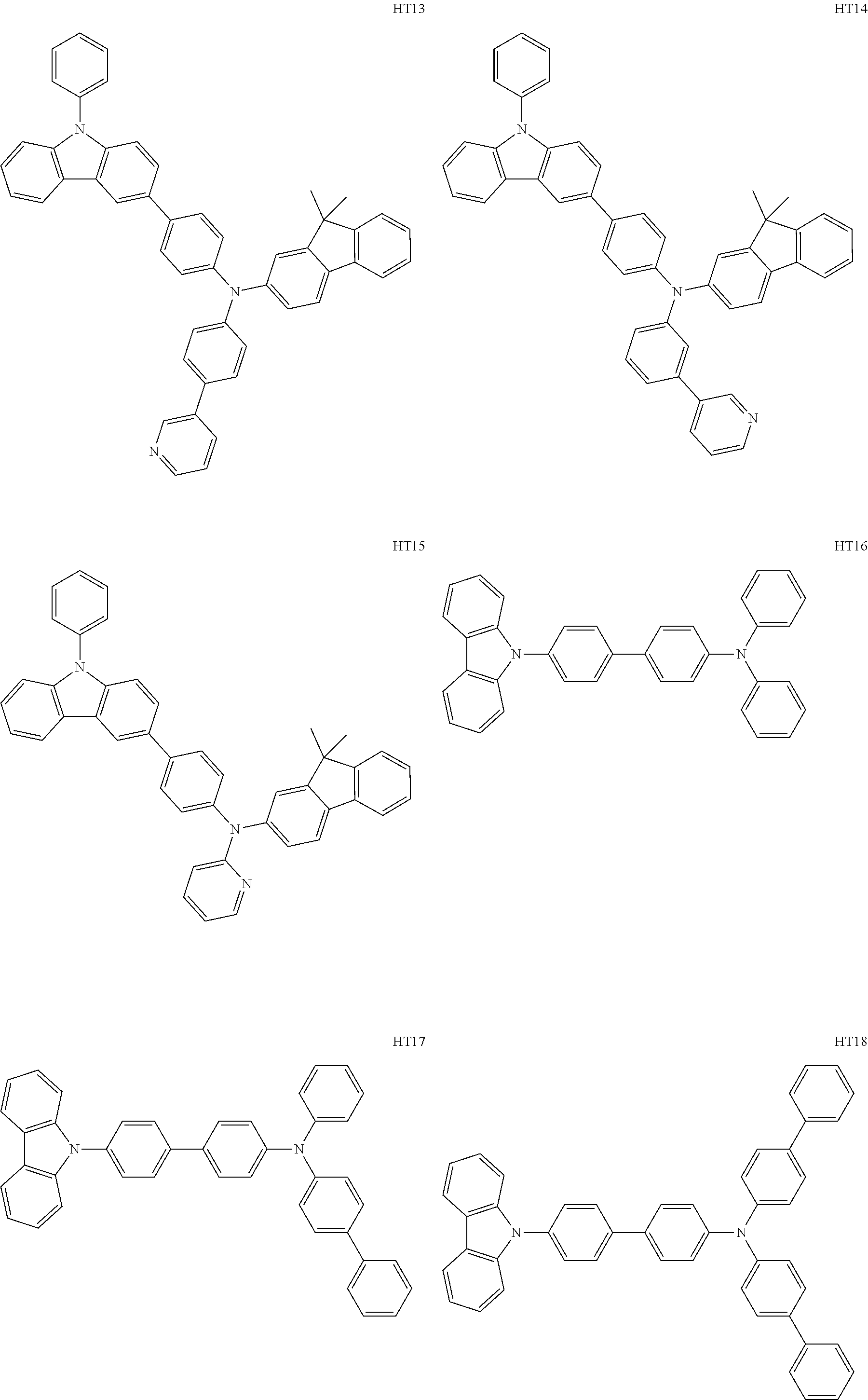

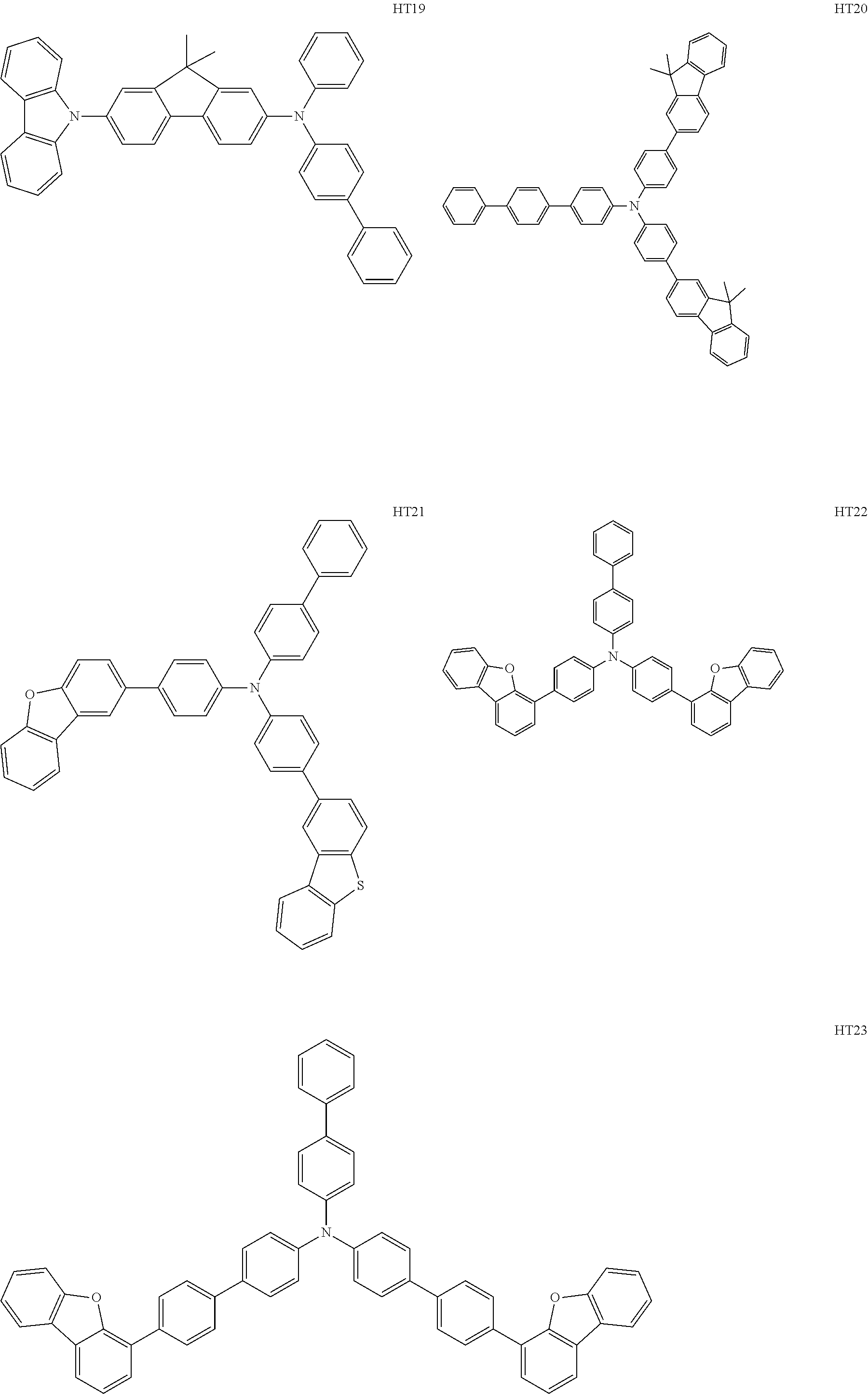 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

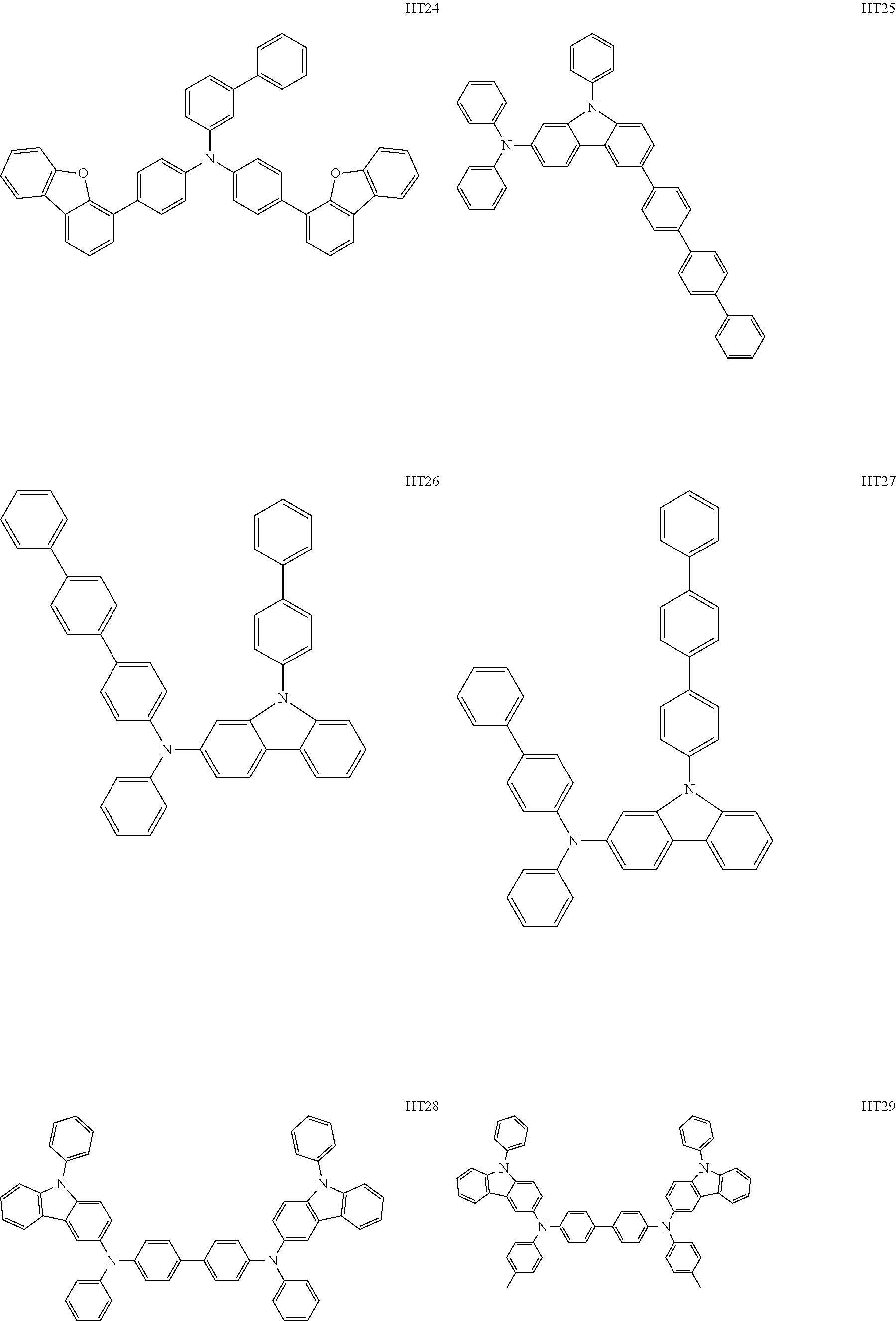

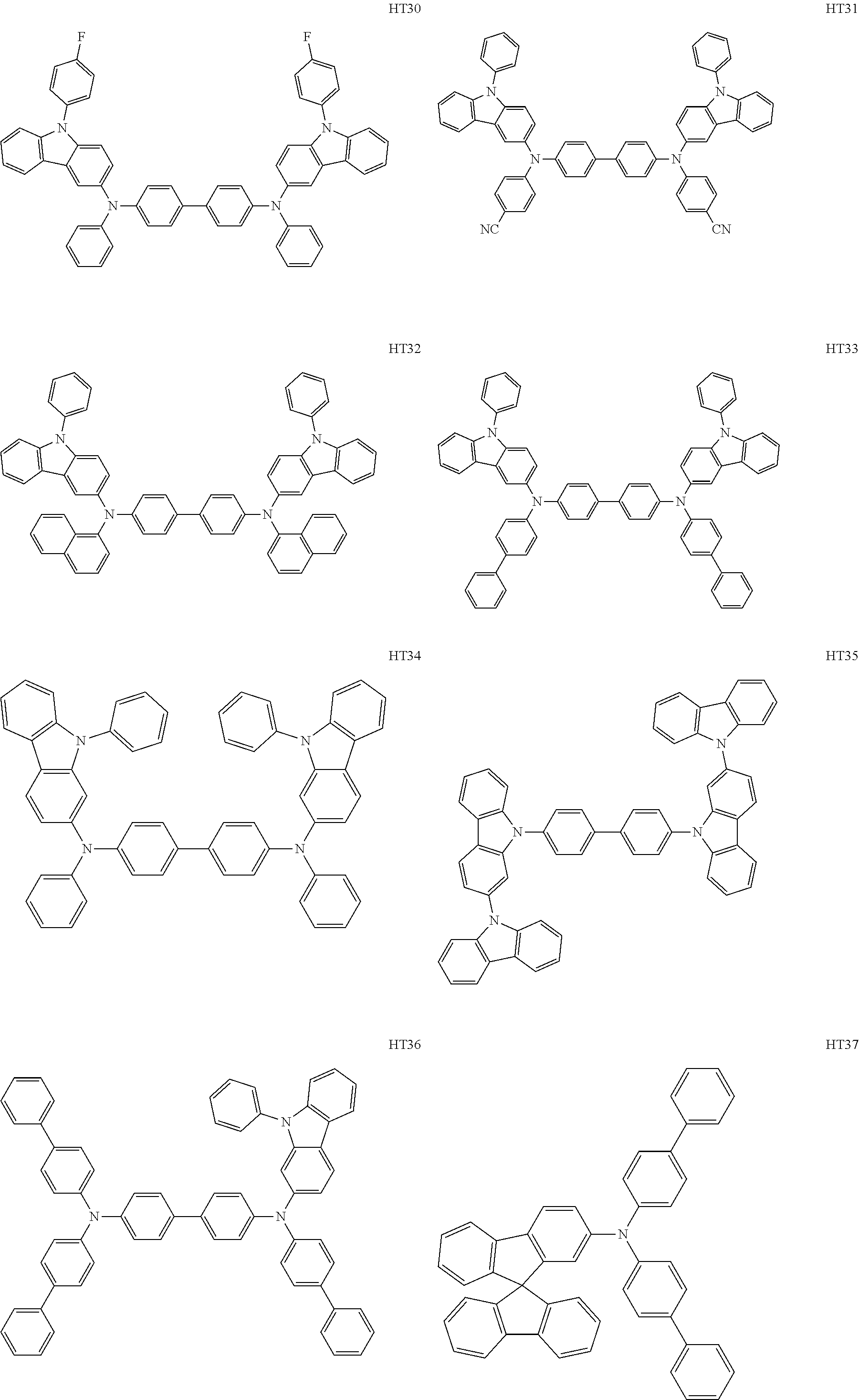

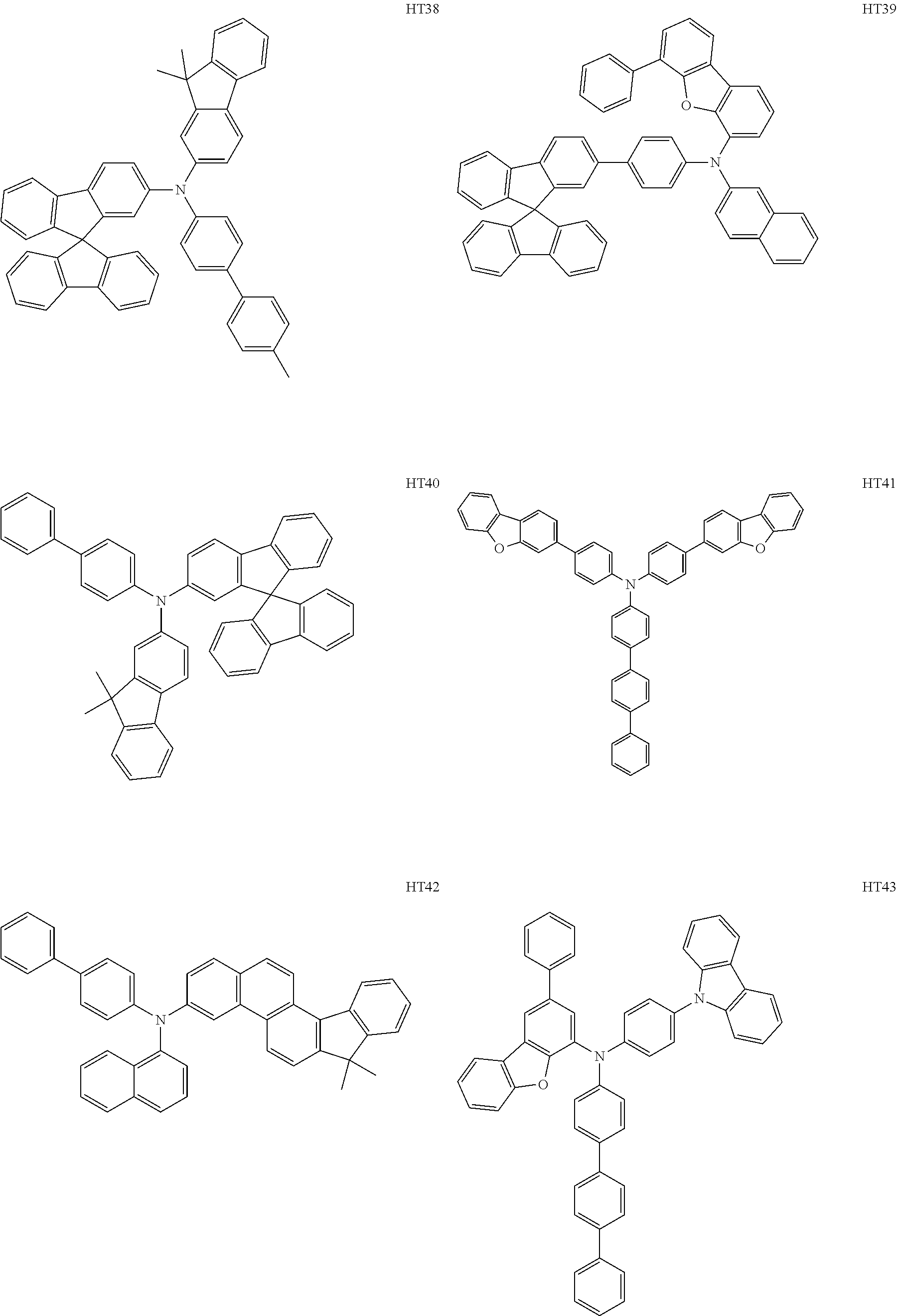

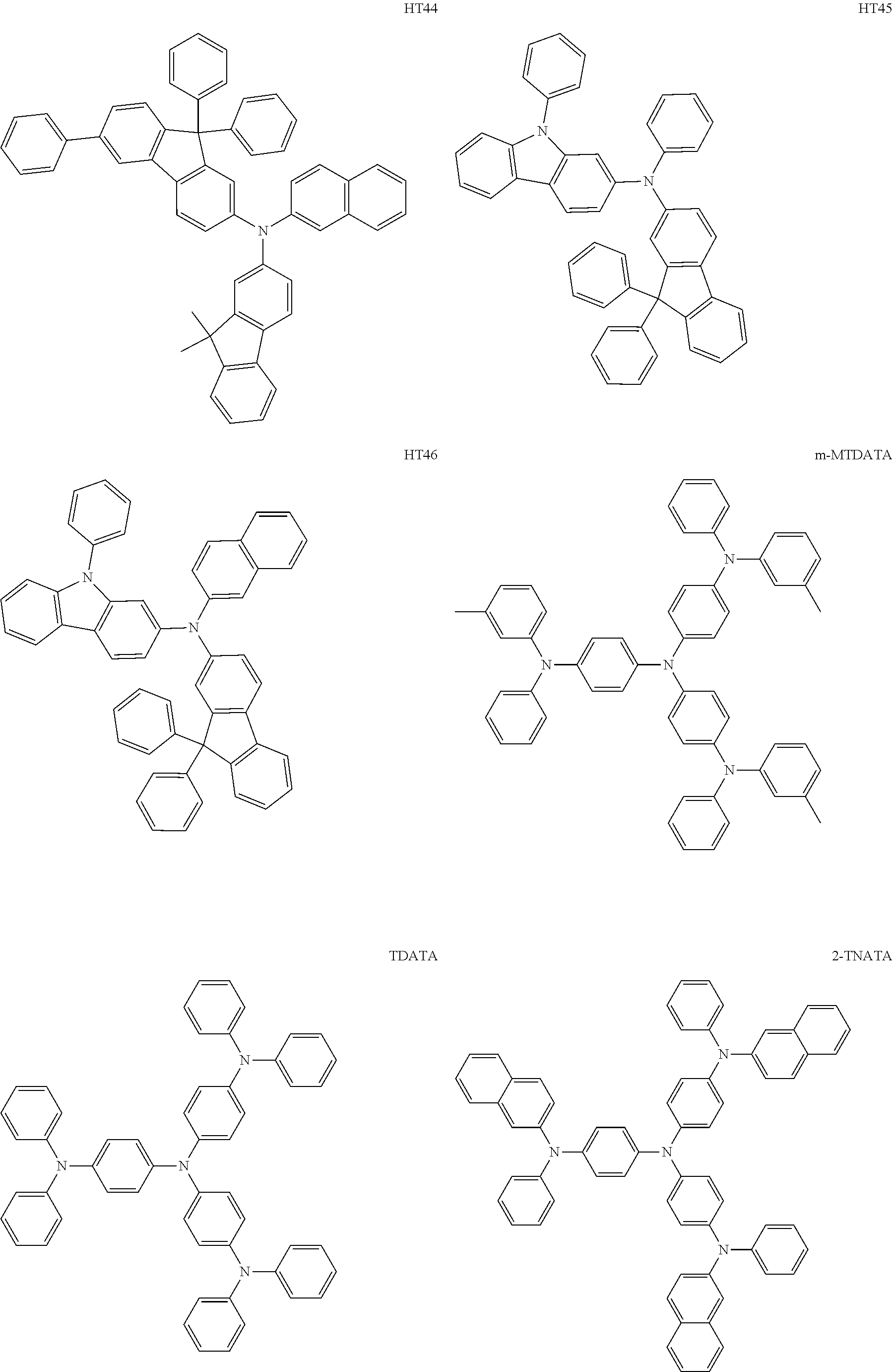

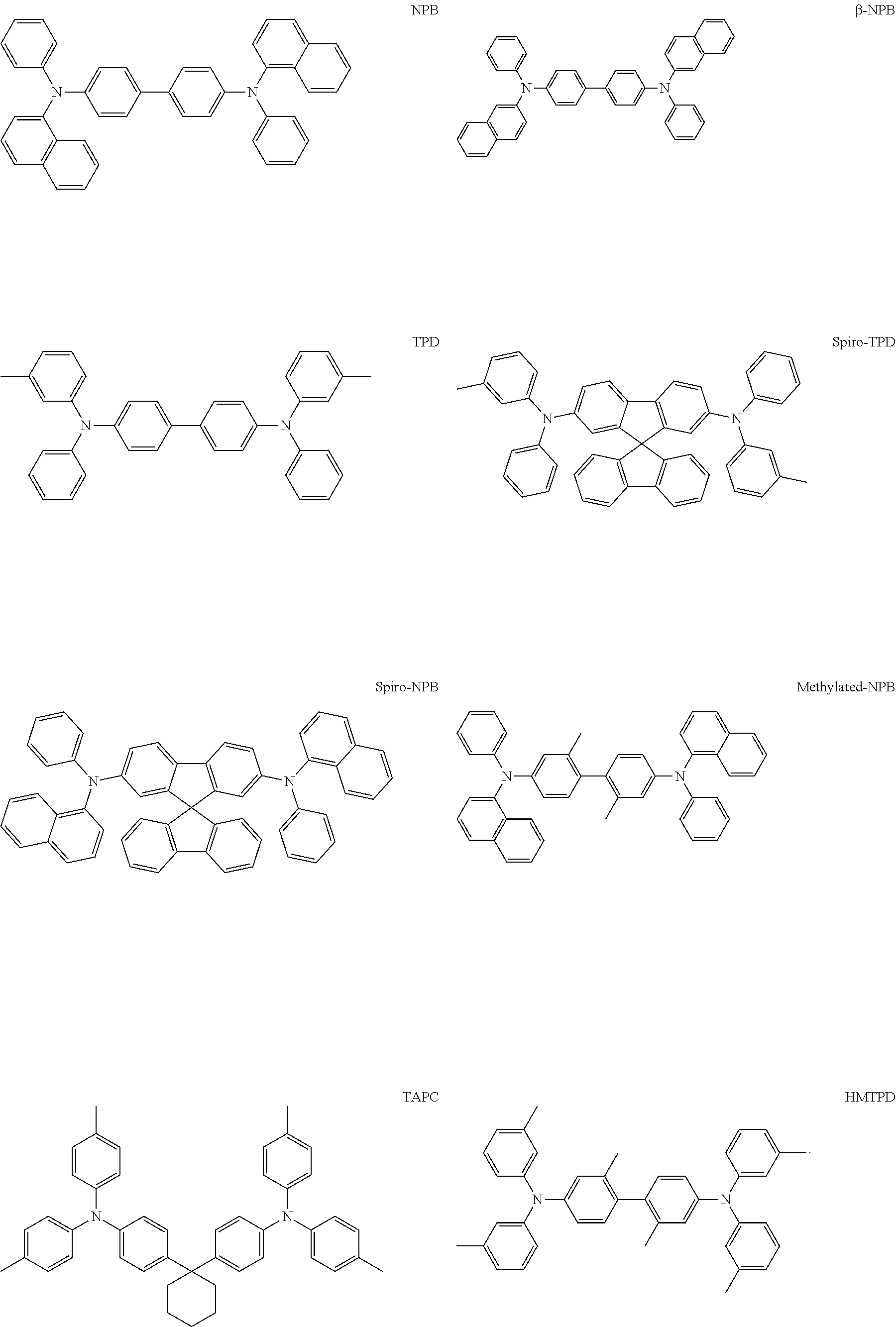

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, satisfactory hole-transporting characteristics may be obtained without a substantial increase in driving voltage.

The emission auxiliary layer may increase light-emission efficiency by compensating for an optical resonance distance according to the wavelength of light emitted by an emission layer, and the electron blocking layer may block or reduce the leakage of electrons from the emission layer to the hole transport region. Materials that may be included in the hole transport region may be included in the emission auxiliary layer and the electron blocking layer.

p-Dopant

The hole transport region may further include, in addition to these materials, a charge-generation material for the improvement of conductive properties. The charge-generation material may be uniformly or non-uniformly dispersed in the hole transport region (for example, in the form of a single layer consisting of the charge-generation material).

The charge-generation material may be, for example, a p-dopant.

In an embodiment, the LUMO energy level of the p-dopant may be about −3.5 eV or less.

In an embodiment, the p-dopant may include a quinone derivative, a cyano group-containing compound, a compound including an element EL1 and an element EL2 (to be described in more detail below), or any combination thereof.

Examples of the quinone derivative may include TCNQ, F4-TCNQ, and/or the like.

Examples of the cyano group-containing compound may include HAT-CN, a compound represented by Formula 221, and/or the like.

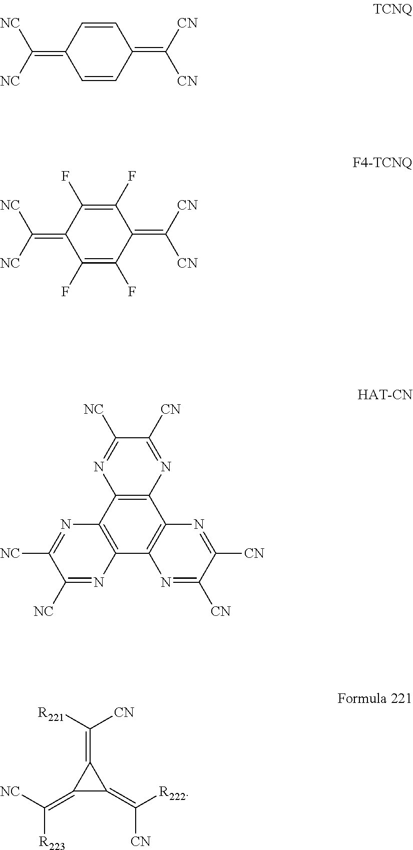

In Formula 221,

R₂₂₁ to R₂₂₃ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ, and

at least one of R₂₂₁ to R₂₂₃ may each independently be: a C₃-C₆₀ carbocyclic group or a C₁-C₆₀ heterocyclic group, each substituted with: a cyano group; —F; —Cl; —Br; —I; a C₁-C₂₀ alkyl group that is substituted with a cyano group, —F, —Cl, —Br, —I, or any combination thereof; or any combination thereof.

In the compound including the element EL1 and the element EL2, the element EL1 may be a metal, a metalloid, or any combination thereof, and the element EL2 may be a non-metal, a metalloid, or any combination thereof.

Examples of the metal may include an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid may include silicon (Si), antimony (Sb), and tellurium (Te).

Examples of the non-metal may include oxygen (O) and halogen (for example, F, Cl, Br, I, etc.).

In an embodiment, examples of the compound containing the element EL1 and the element EL2 may include a metal oxide, a metal halide (for example, a metal fluoride, a metal chloride, a metal bromide, or a metal iodide), a metalloid halide (for example, a metalloid fluoride, a metalloid chloride, a metalloid bromide, and/or a metalloid iodide), a metal telluride, or any combination thereof.

Examples of the metal oxide may include a tungsten oxide (for example, WO, W₂O₃, WO₂, WO₃, W₂O₅, etc.), a vanadium oxide (for example, VO, V₂O₃, VO₂, V₂O₅, etc.), a molybdenum oxide (MoO, Mo₂O₃, MoO₂, MoO₃, Mo₂O₅, etc.), and a rhenium oxide (for example, ReO₃, etc.).

Examples of the metal halide may include an alkali metal halide, an alkaline earth metal halide, a transition metal halide, a post-transition metal halide, and a lanthanide metal halide.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, and CsI.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and BaI₂.

Examples of the transition metal halide may include a titanium halide (for example, TiF₄, TiCl₄, TiBr₄, Til₄, etc.), a zirconium halide (for example, ZrF₄, ZrCl₄, ZrBr₄, ZrI₄, etc.), a hafnium halide (for example, HfF₄, HfCl₄, HfBr₄, Hfl₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, Rul₂, etc.), an osmium halide (for example, OsF₂, OsCl₂, OsBr₂, OsI₂, etc.), a cobalt halide (for example, CoF₂, CoCl₂, CoBr₂, CoI₂, etc.), a rhodium halide (for example, RhF₂, RhCl₂, RhBr₂, Rhl₂, etc.), an iridium halide (for example, IrF₂, IrCl₂, IrBr₂, IrI₂, etc.), a nickel halide (for example, NiF₂, NiCl₂, NiBr₂, Nil₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), and a gold halide (for example, AuF, AuCl, AuBr, AuI, etc.).

Examples of the post-transition metal halide may include a zinc halide (for example, ZnF₂, ZnCl₂, ZnBr₂, ZnI₂, etc.), an indium halide (for example, InI₃, etc.), and a tin halide (for example, SnI₂, etc.).

Examples of the lanthanide metal halide may include YbF, YbF2, YbF3, SmF₃, YbCl, YbCl₂, YbCl₃, SmC₁₃, YbBr, YbBr₂, YbBr₃, SmBr₃, YbI, YbI₂, YbI₃, and SmI₃.

Examples of the metalloid halide may include an antimony halide (for example, SbCl₅, etc.).

Examples of the metal telluride may include an alkali metal telluride (for example, Li₂Te, Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), and a lanthanide metal telluride (for example, LaTe, CeTe, PrTe, NdTe, PmTe, EuTe, GdTe, TbTe, DyTe, HoTe, ErTe, TmTe, YbTe, LuTe, etc.).

Emission layer in interlayer 130

When the light-emitting device 10 is a full-color light-emitting device, the emission layer may be patterned into a red emission layer, a green emission layer, and/or a blue emission layer, according to a sub-pixel. In an embodiment, the emission layer may have a stacked structure of two or more layers of a red emission layer, a green emission layer, and a blue emission layer, in which the two or more layers may contact each other or may be separated from each other. In an embodiment, the emission layer may include two or more materials of a red light-emitting material, a green light-emitting material, and a blue light-emitting material, in which the two or more materials may be mixed with each other in a single layer to emit white light.

The emission layer may include a host and a dopant. The dopant may include a phosphorescent dopant, a fluorescent dopant, or any combination thereof.

An amount of the dopant in the emission layer may be about 0.01 wt % to about 15 wt % based on 100 wt % of the host.

In an embodiment, the emission layer may include a quantum dot.

In an embodiment, the emission layer may include a delayed fluorescence material. The delayed fluorescence material may act (e.g., serve) as a host or as a dopant in the emission layer.

A thickness of the emission layer may be in a range of about 100 Å to about 1,000 Å, for example, about 200 Å to about 600 Å. When the thickness of the emission layer is within these ranges, excellent or suitable light-emission characteristics may be obtained without a substantial increase in driving voltage.

### Host

The host may include a compound represented by Formula 301:

[Ar₃₀₁]_{xb11}-[(L₃₀₁)_{xb1}-R₃₀₁]_{xb21} Formula 301
wherein, in Formula 301,
Ar₃₀₁ and L₃₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group that is unsubstituted or substituted with at least one R₁₀ₐ, a C₂-C₆₀ alkenyl group that is unsubstituted or substituted with at least one R₁₀ₐ, a C₂-C₆₀ alkynyl group that is unsubstituted or substituted with at least one R₁₀ₐ, a C₁-C₆₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)(Q₃₀₁), or —P(═O)(Q₃₀₁)(Q₃₀₂),
xb21 may be an integer from 1 to 5, and
Q₃₀₁ to Q₃₀₃ may each independently be the same as described in connection with Q₁.

In an embodiment, when xb11 in Formula 301 is 2 or more, two or more Ar₃₀₁(s) may be linked to each other via a single bond.

In an embodiment, the host may include a compound represented by Formula 301-1, a compound represented by Formula 301-2, or any combination thereof:

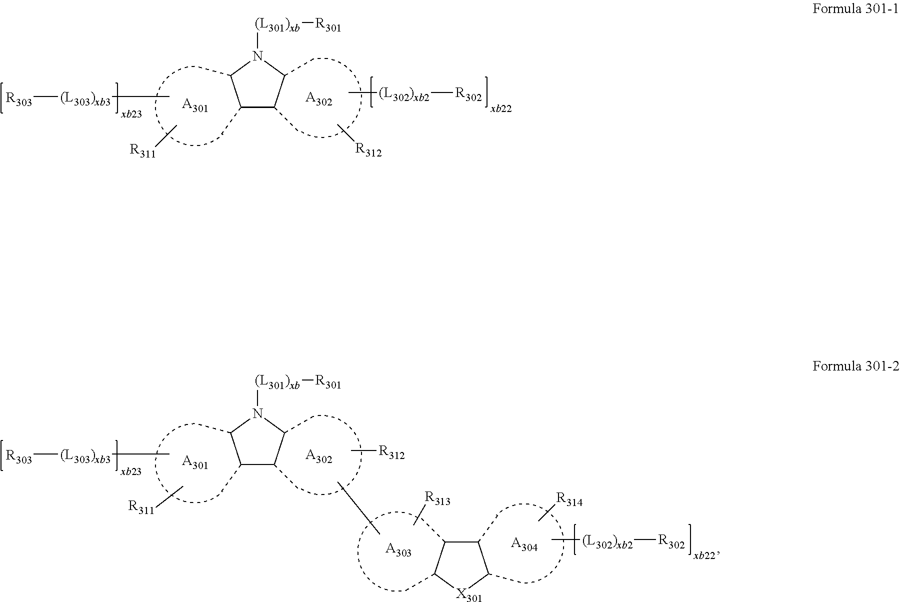

wherein, in Formulae 301-1 and 301-2,
ring A₃₀₁ to ring A₃₀₄ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each independently be the same as respectively described in the present specification,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, the host may include an alkaline earth metal complex, a post-transition metal complex, or any combination thereof. In an embodiment, the host may include a Be complex (for example, Compound H55), an Mg complex, a Zn complex, or any combination thereof.

In an embodiment, the host may include at least one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

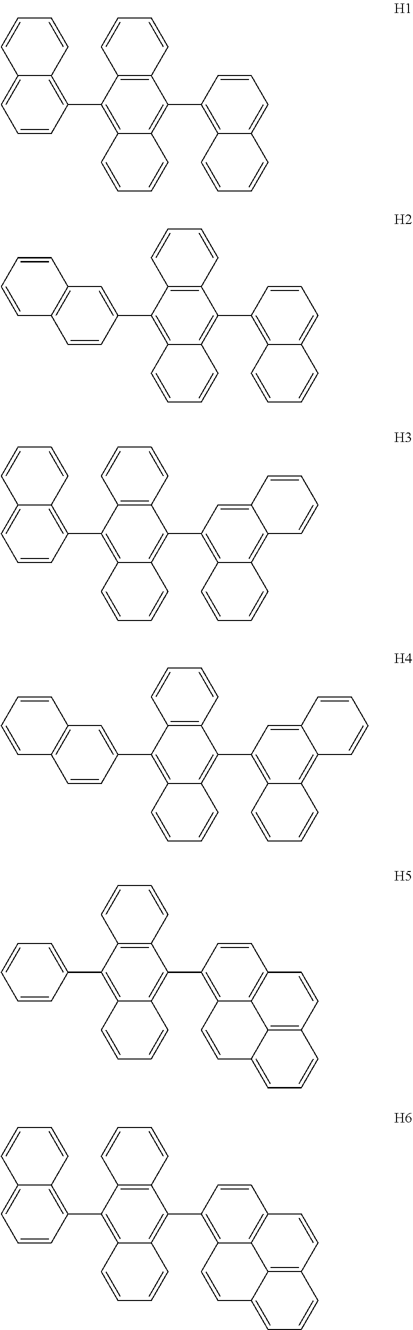

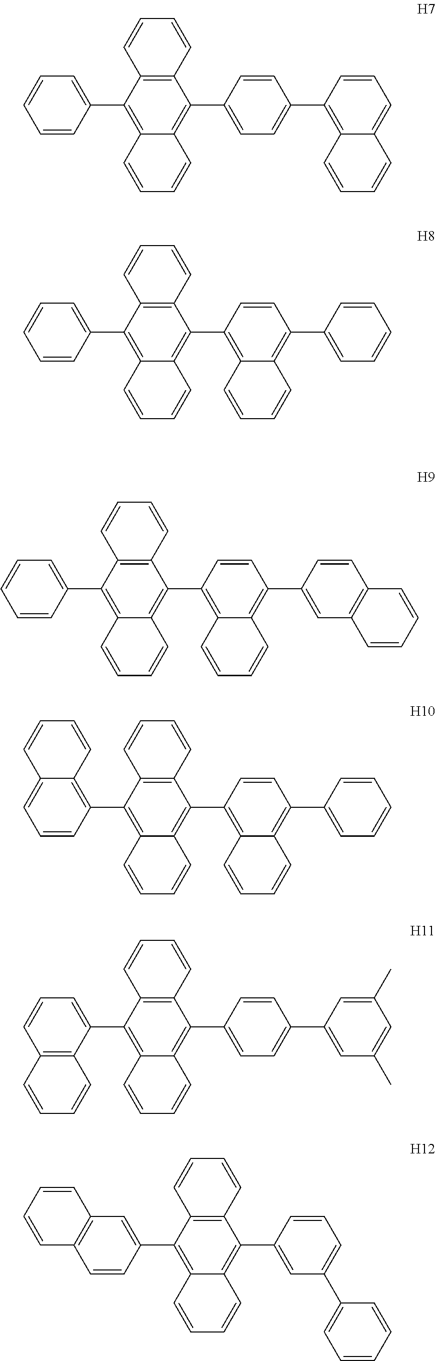

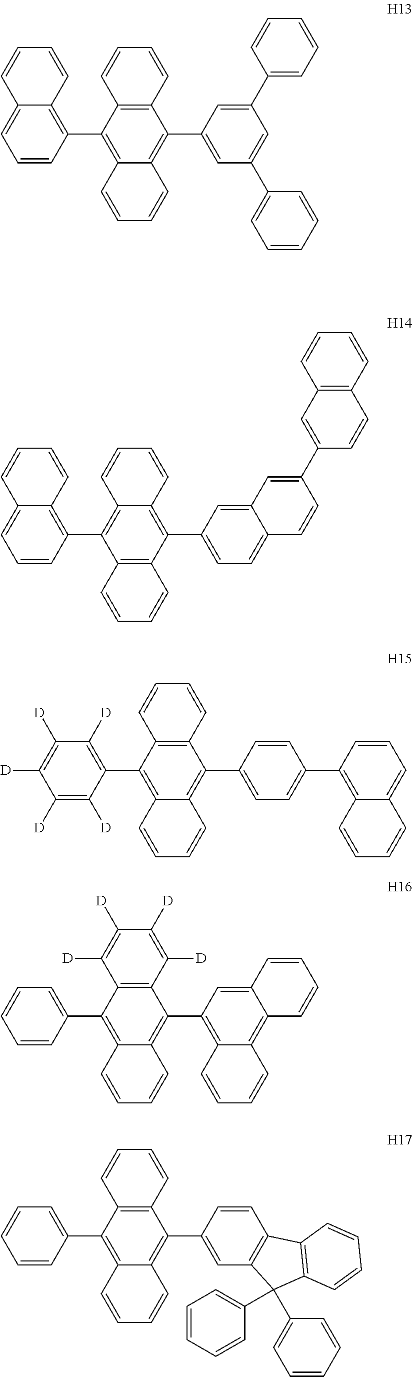

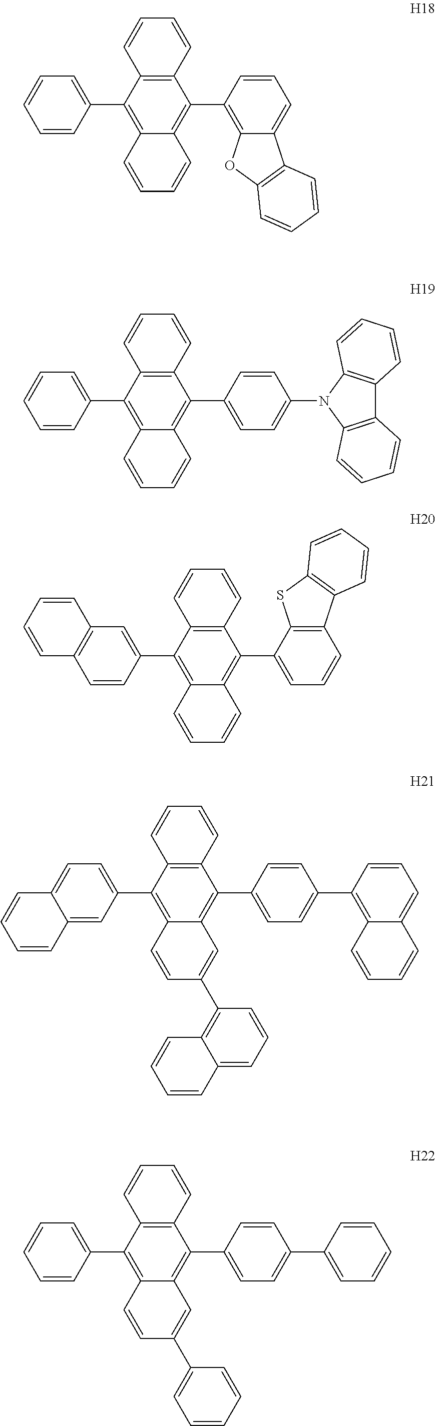

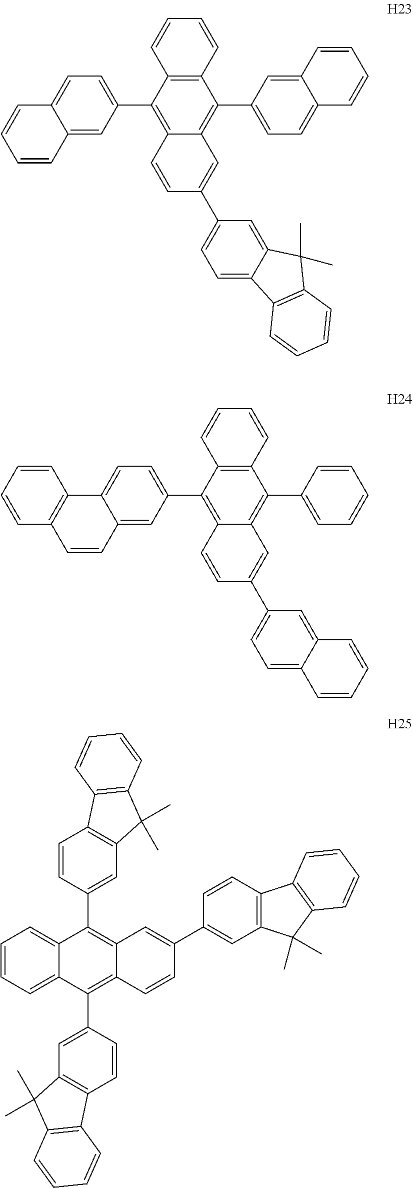

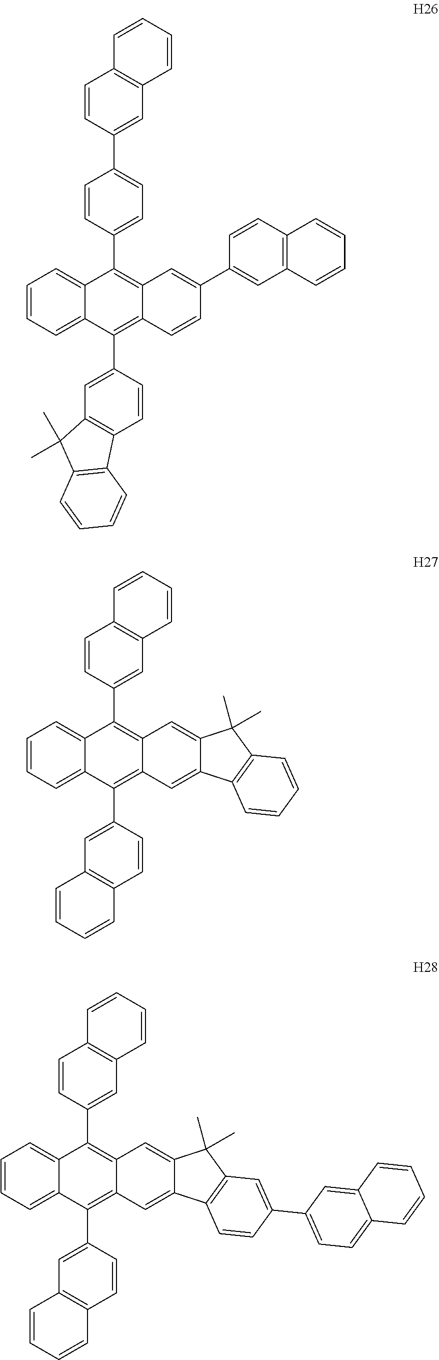

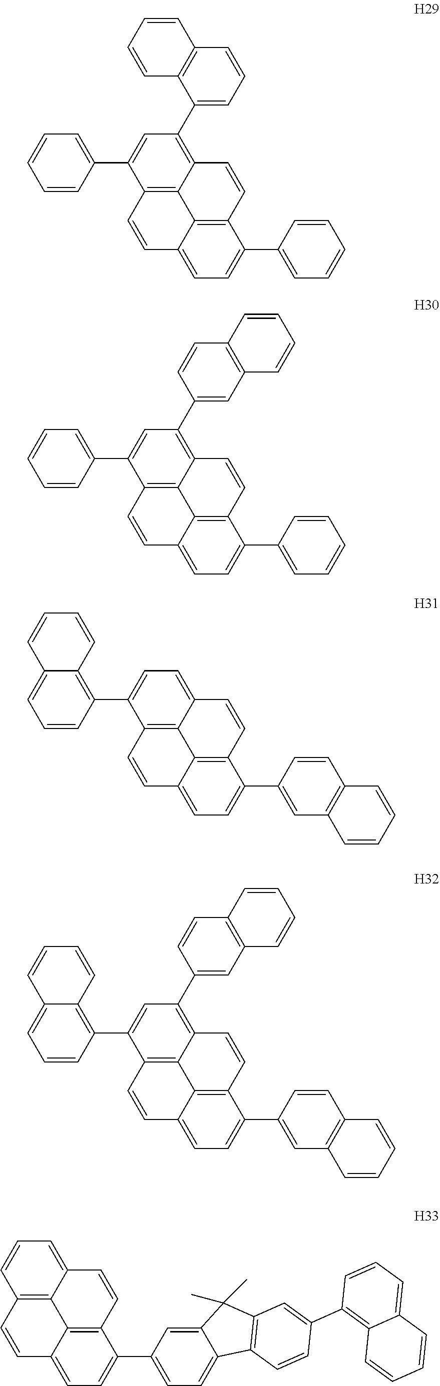

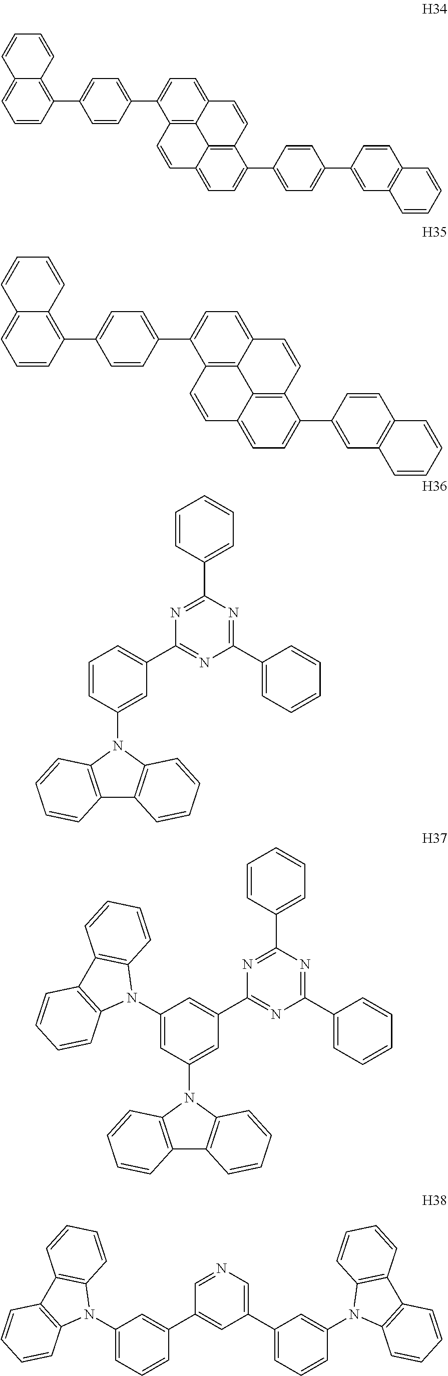

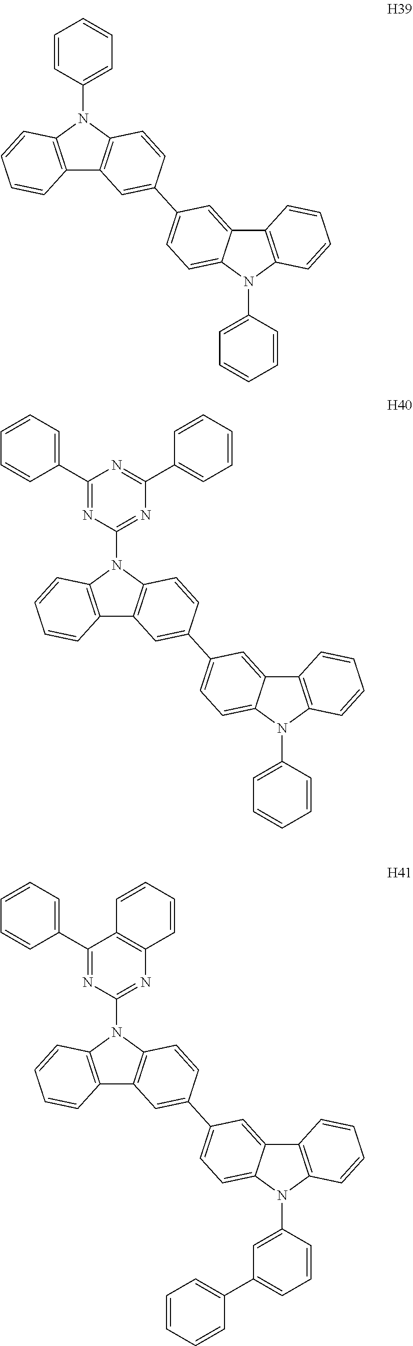 [SMILES: c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1]

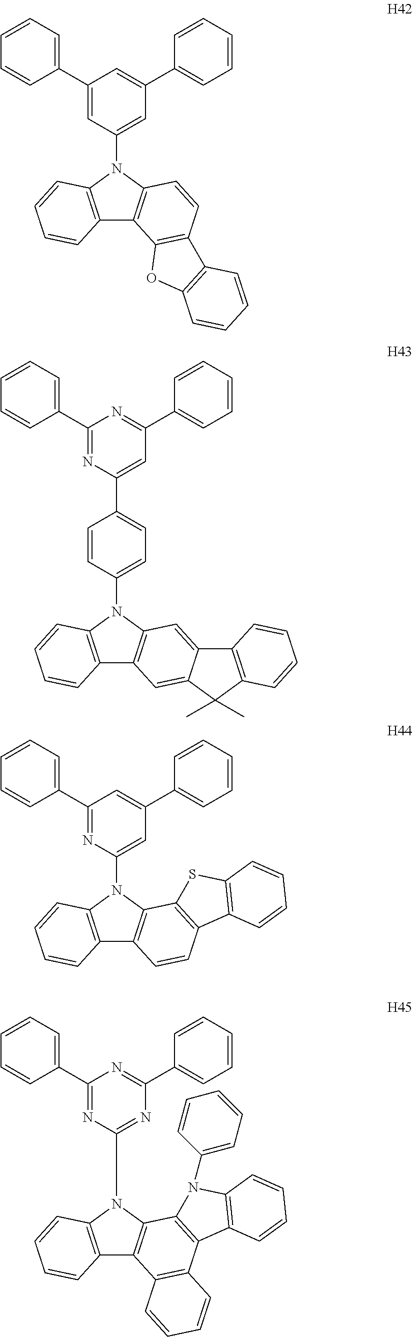

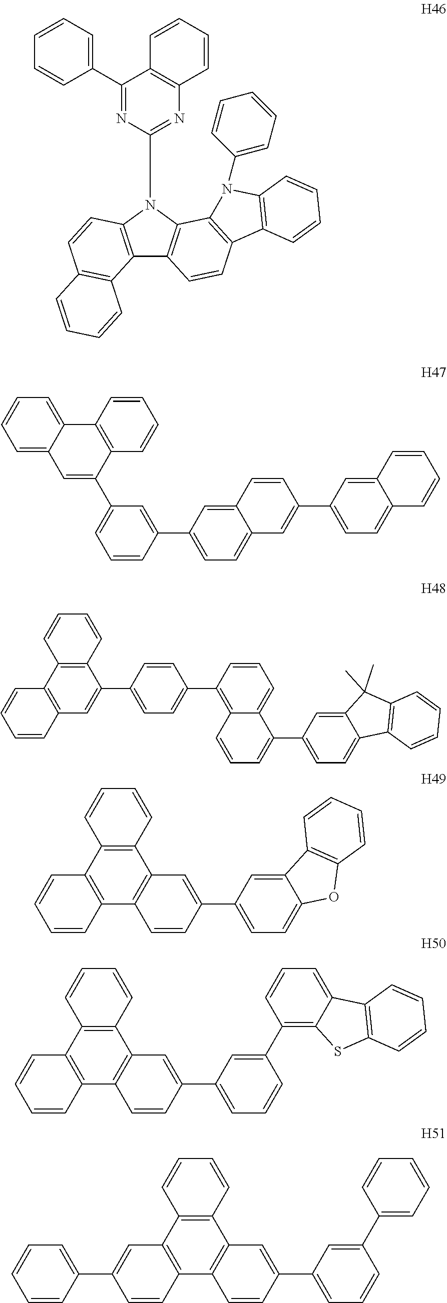

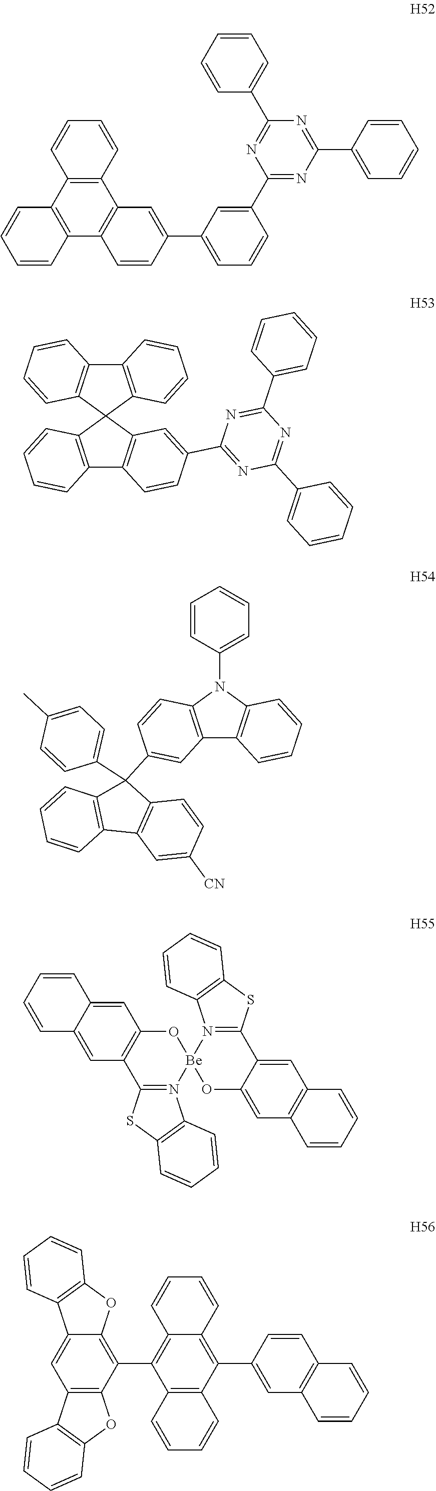

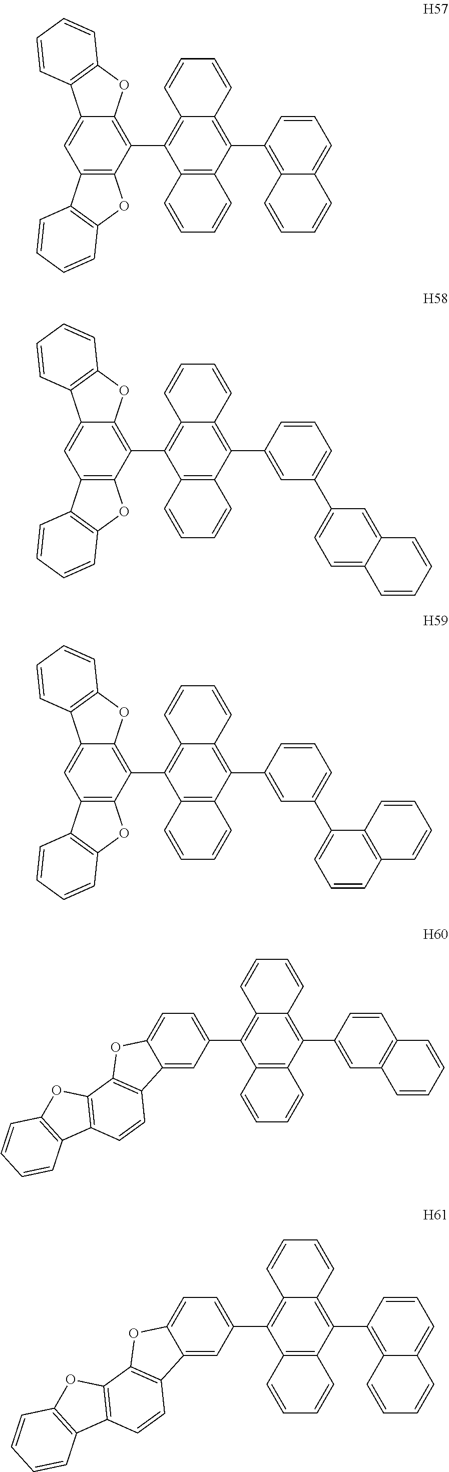 [SMILES: c1ccc2c(-c3c4ccccc4c(-c4c5oc6ccccc6c5cc5c4oc4ccccc45)c4ccccc34)cccc2c1 ; c1cc(-c2ccc3ccccc3c2)cc(-c2c3ccccc3c(-c3c4oc5ccccc5c4cc4c3oc3ccccc34)c3ccccc23)c1 ; c1cc(-c2cccc3ccccc23)cc(-c2c3ccccc3c(-c3c4oc5ccccc5c4cc4c3oc3ccccc34)c3ccccc23)c1 ; c1ccc2cc(-c3c4ccccc4c(-c4ccc5oc6c(ccc7c8ccccc8oc76)c5c4)c4ccccc34)ccc2c1 ; c1ccc2c(-c3c4ccccc4c(-c4ccc5oc6c(ccc7c8ccccc8oc76)c5c4)c4ccccc34)cccc2c1]

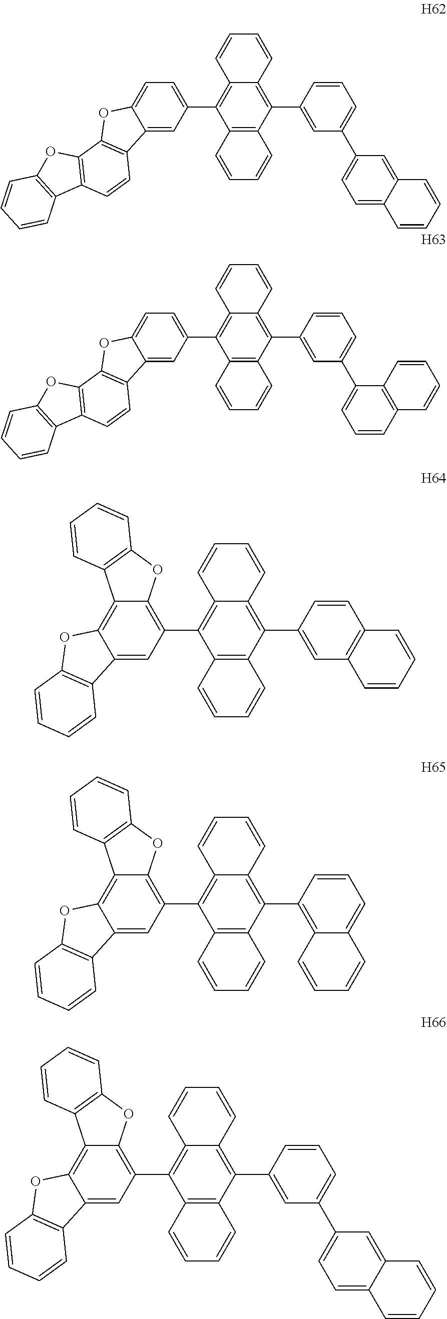

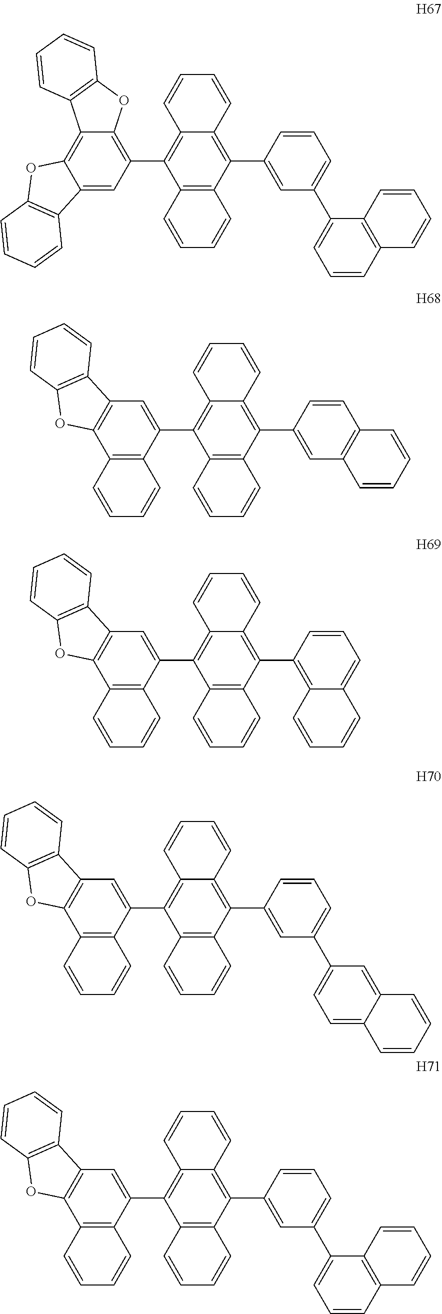 [SMILES: c1cc(-c2cccc3ccccc23)cc(-c2c3ccccc3c(-c3cc4c5ccccc5oc4c4c3oc3ccccc34)c3ccccc23)c1 ; c1ccc2cc(-c3c4ccccc4c(-c4cc5c6ccccc6oc5c5ccccc45)c4ccccc34)ccc2c1 ; c1ccc2c(-c3c4ccccc4c(-c4cc5c6ccccc6oc5c5ccccc45)c4ccccc34)cccc2c1 ; c1cc(-c2ccc3ccccc3c2)cc(-c2c3ccccc3c(-c3cc4c5ccccc5oc4c4ccccc34)c3ccccc23)c1 ; c1cc(-c2cccc3ccccc23)cc(-c2c3ccccc3c(-c3cc4c5ccccc5oc4c4ccccc34)c3ccccc23)c1]

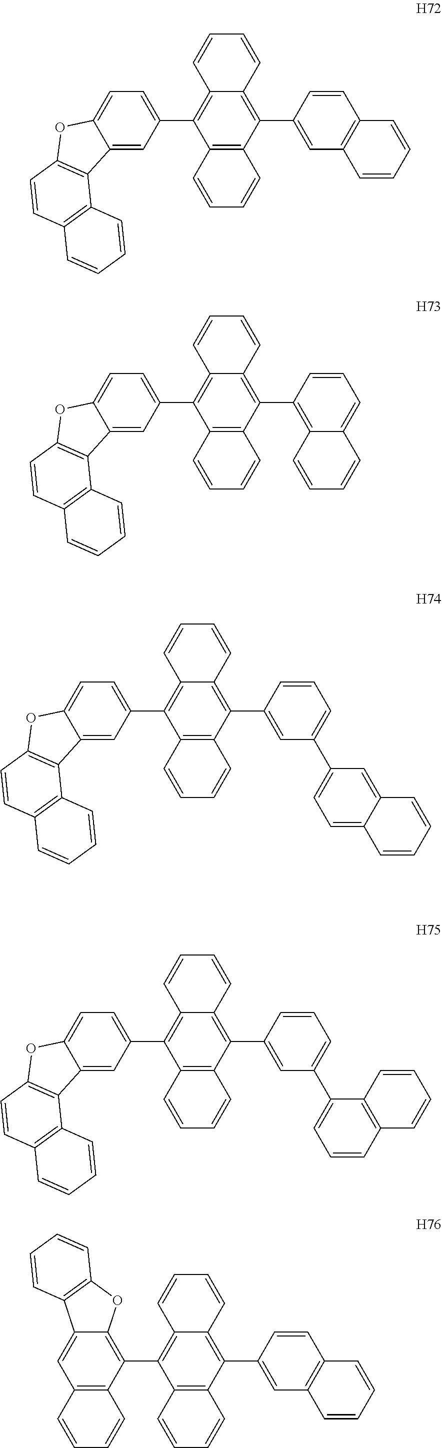

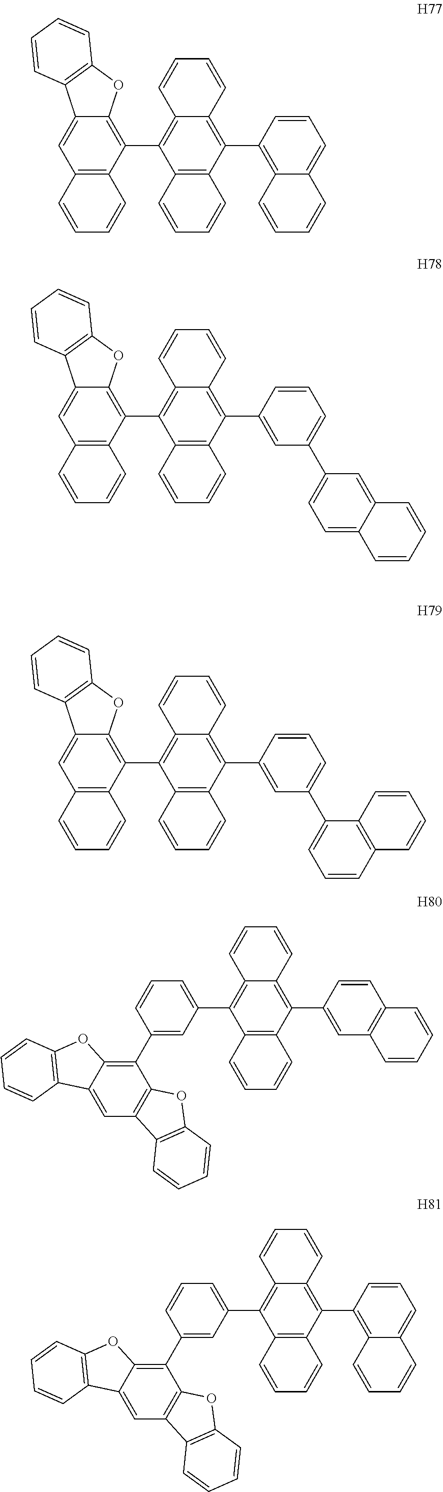 [SMILES: c1ccc2c(-c3c4ccccc4c(-c4c5ccccc5cc5c4oc4ccccc45)c4ccccc34)cccc2c1 ; c1cc(-c2ccc3ccccc3c2)cc(-c2c3ccccc3c(-c3c4ccccc4cc4c3oc3ccccc34)c3ccccc23)c1 ; c1cc(-c2cccc3ccccc23)cc(-c2c3ccccc3c(-c3c4ccccc4cc4c3oc3ccccc34)c3ccccc23)c1 ; c1cc(-c2c3ccccc3c(-c3ccc4ccccc4c3)c3ccccc23)cc(-c2c3oc4ccccc4c3cc3c2oc2ccccc23)c1 ; c1cc(-c2c3ccccc3c(-c3cccc4ccccc34)c3ccccc23)cc(-c2c3oc4ccccc4c3cc3c2oc2ccccc23)c1]

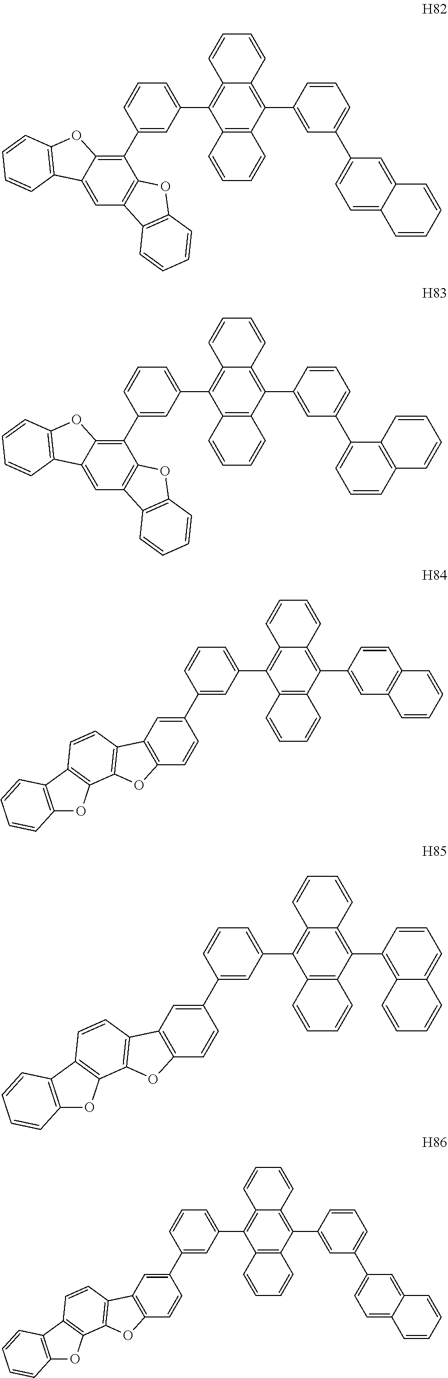 [SMILES: c1cc(-c2ccc3ccccc3c2)cc(-c2c3ccccc3c(-c3cccc(-c4c5oc6ccccc6c5cc5c4oc4ccccc45)c3)c3ccccc23)c1 ; c1cc(-c2cccc3ccccc23)cc(-c2c3ccccc3c(-c3cccc(-c4c5oc6ccccc6c5cc5c4oc4ccccc45)c3)c3ccccc23)c1 ; c1cc(-c2ccc3oc4c(ccc5c6ccccc6oc54)c3c2)cc(-c2c3ccccc3c(-c3ccc4ccccc4c3)c3ccccc23)c1 ; c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1]

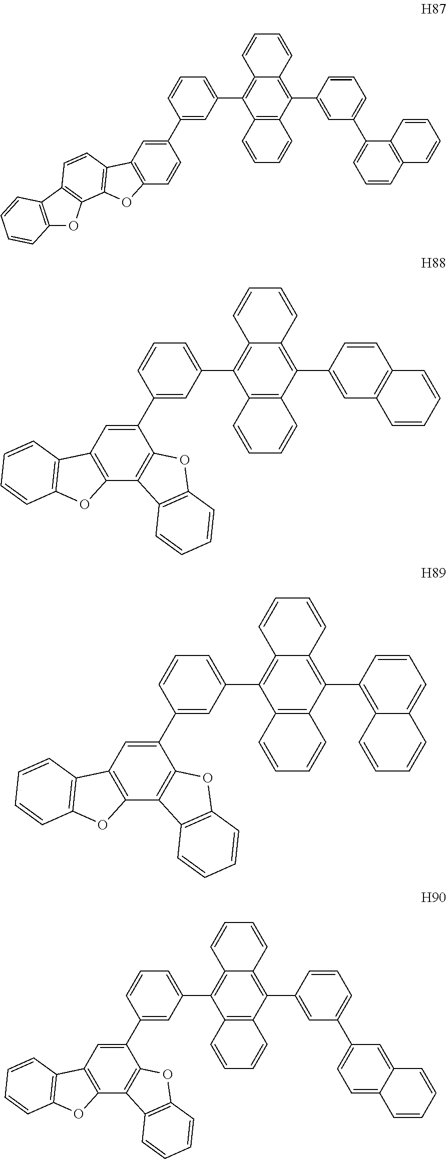 [SMILES: c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1 ; c1cc(-c2ccc3ccccc3c2)cc(-c2c3ccccc3c(-c3cccc(-c4cc5c6ccccc6oc5c5c4oc4ccccc45)c3)c3ccccc23)c1]

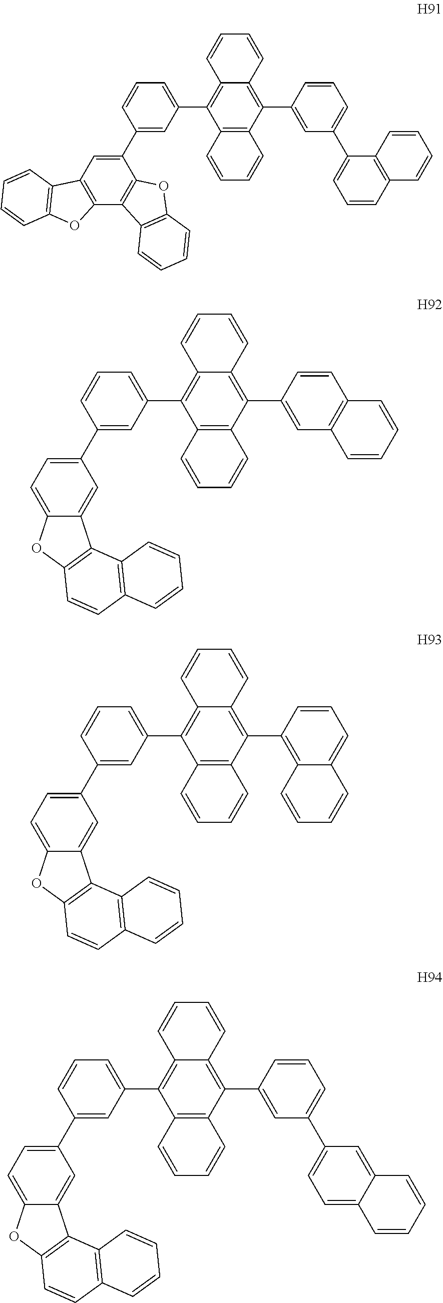 [SMILES: c1cc(-c2cccc3ccccc23)cc(-c2c3ccccc3c(-c3cccc(-c4cc5c6ccccc6oc5c5c4oc4ccccc45)c3)c3ccccc23)c1 ; c1cc(-c2ccc3oc4ccc5ccccc5c4c3c2)cc(-c2c3ccccc3c(-c3ccc4ccccc4c3)c3ccccc23)c1 ; c1cc(-c2ccc3oc4ccc5ccccc5c4c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6ccc7ccccc7c6c5c4)c3)c3ccccc23)c1]

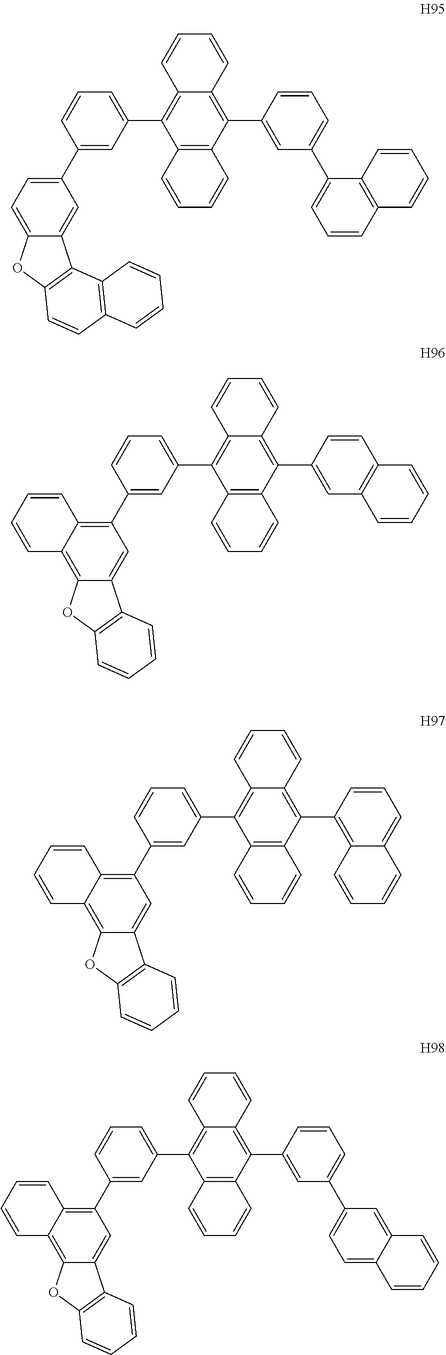 [SMILES: c1cc(-c2ccc3oc4ccc5ccccc5c4c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3ccccc23)c1 ; c1cc(-c2c3ccccc3c(-c3cccc4ccccc34)c3ccccc23)cc(-c2cc3c4ccccc4oc3c3ccccc23)c1 ; c1cc(-c2ccc3ccccc3c2)cc(-c2c3ccccc3c(-c3cccc(-c4cc5c6ccccc6oc5c5ccccc45)c3)c3ccccc23)c1]

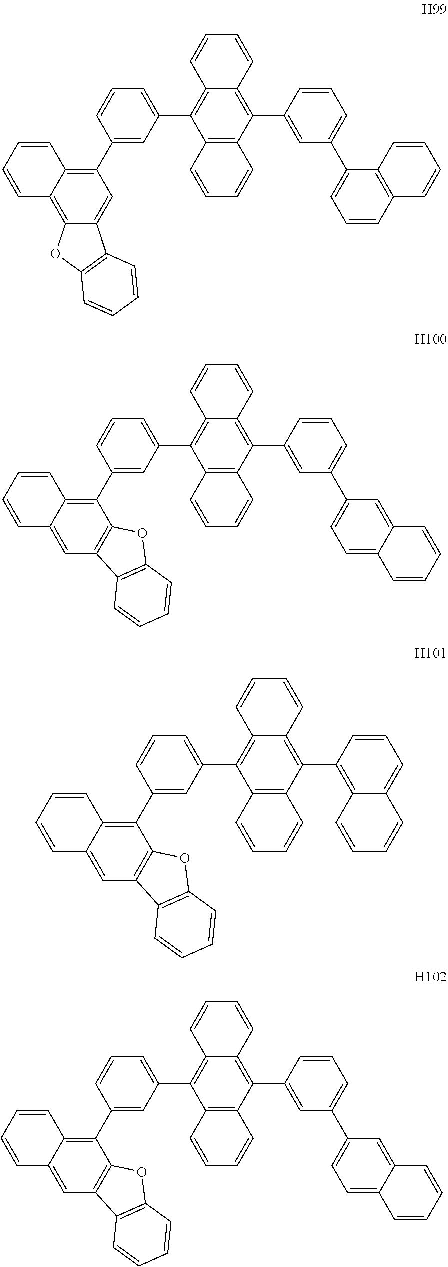 [SMILES: c1cc(-c2cccc3ccccc23)cc(-c2c3ccccc3c(-c3cccc(-c4cc5c6ccccc6oc5c5ccccc45)c3)c3ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1]

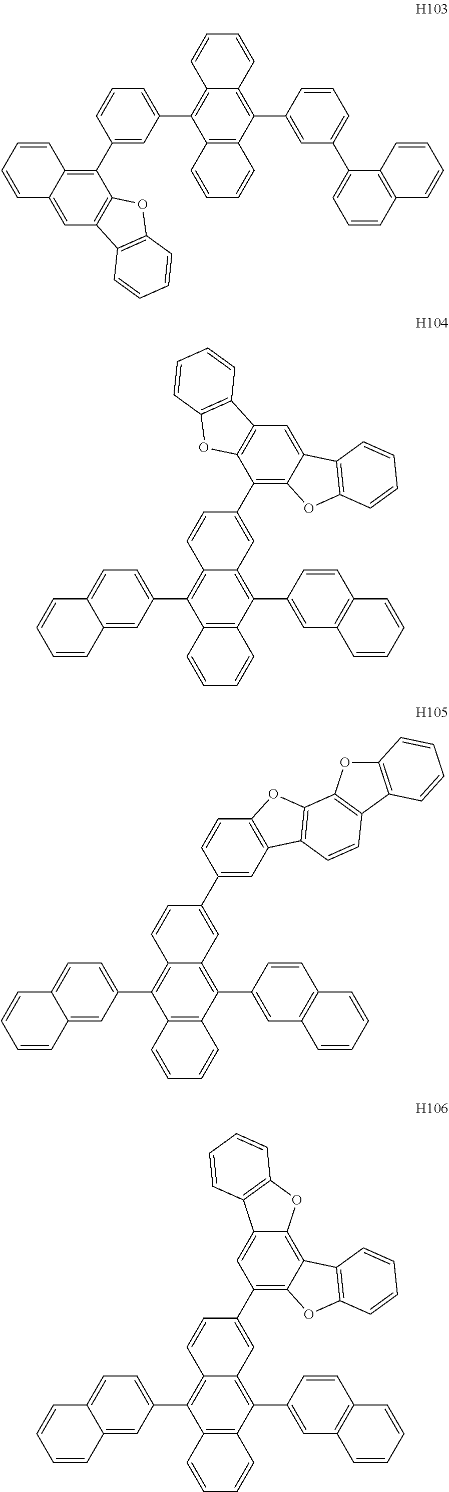 [SMILES: c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1 ; c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1]

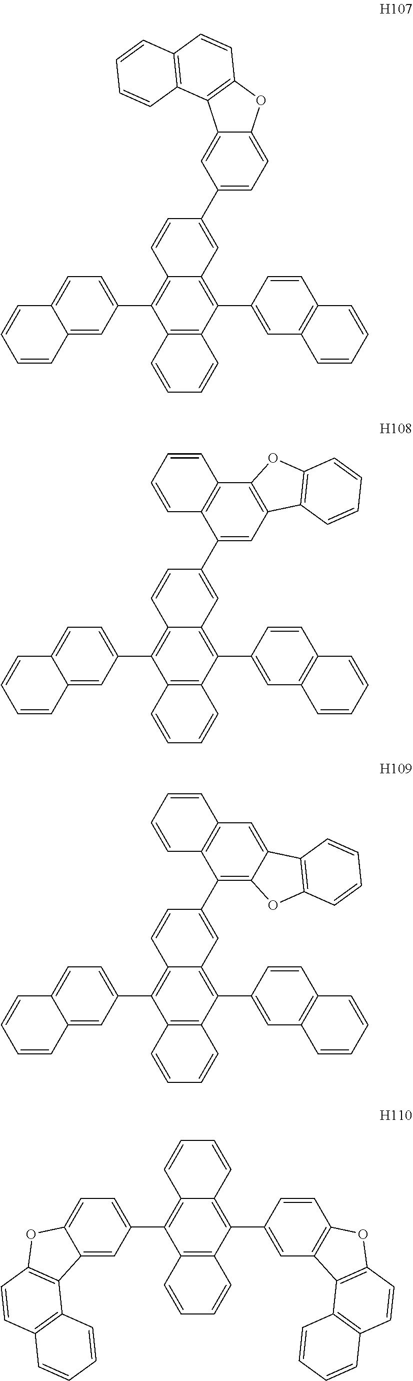 [SMILES: c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12]

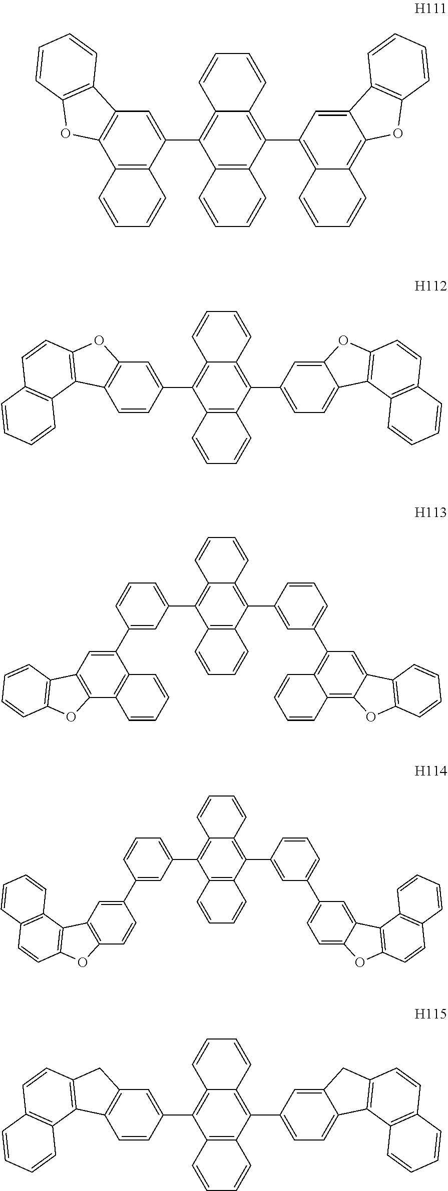

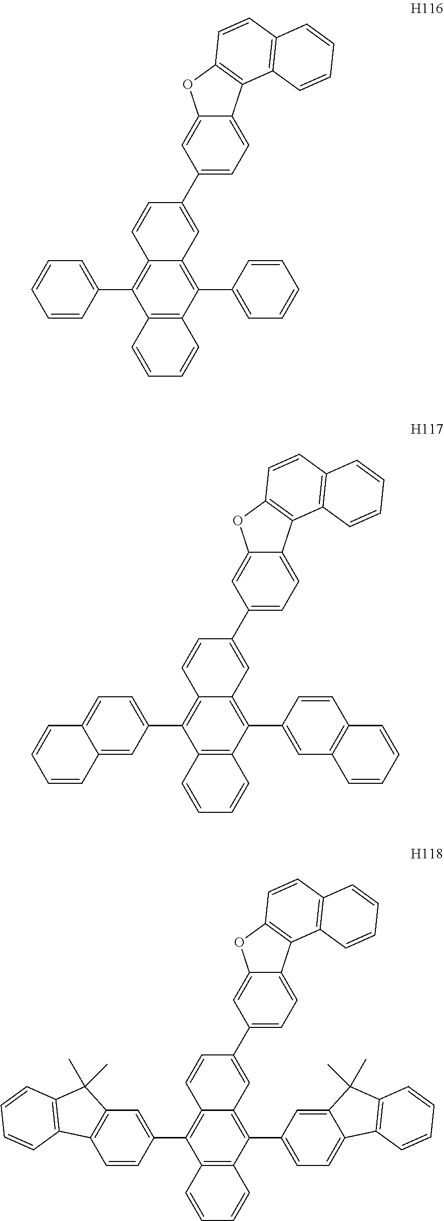 [SMILES: c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

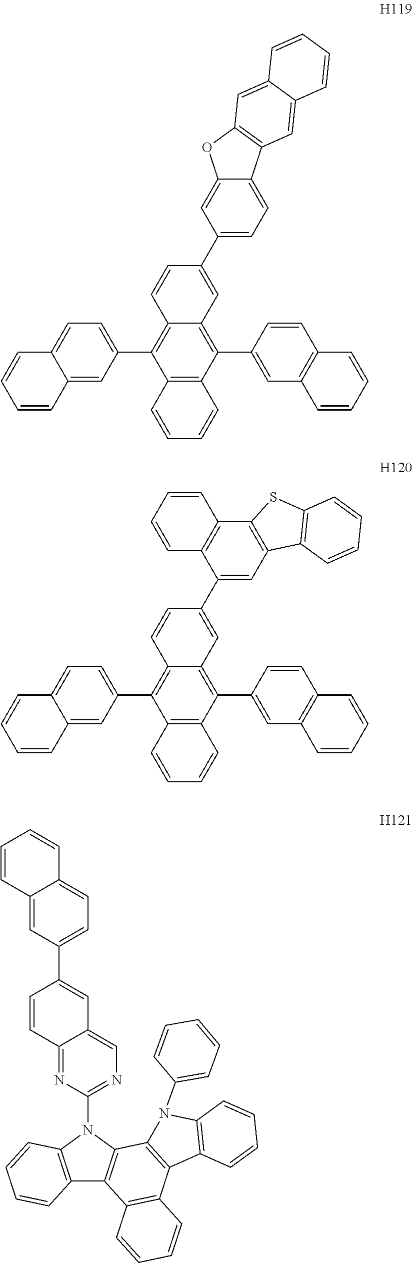 [SMILES: c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1 ; c1ccc(-n2c3ccccc3c3c4ccccc4c4c5ccccc5n(-c5ncc6cc(-c7ccc8ccccc8c7)ccc6n5)c4c32)cc1]

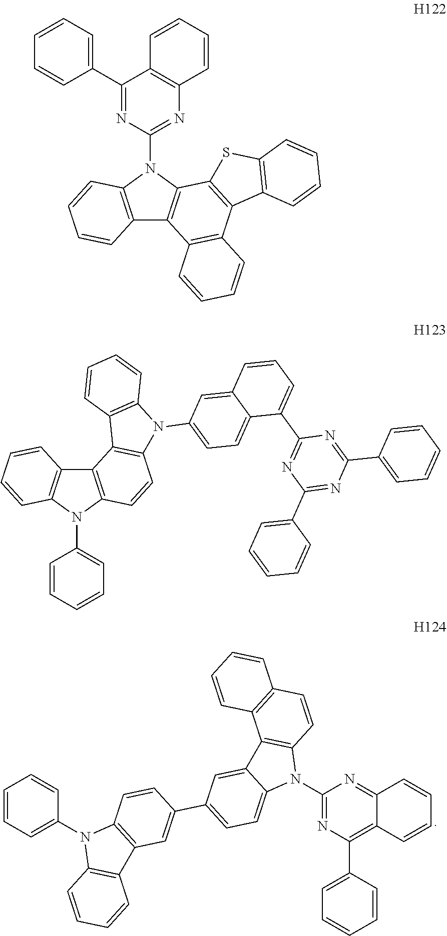 [SMILES: c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

### Phosphorescent Dopant

The phosphorescent dopant may include at least one transition metal as a central metal (e.g., a central metal atom).

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

M(L₄₀₁)_{xc1}(L₄₀₂)_{xc2} Formula 401

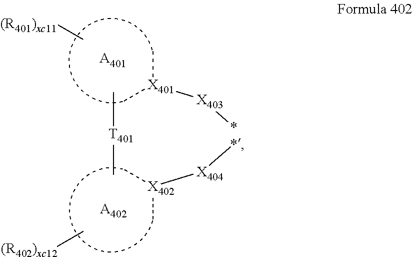

wherein, in Formulae 401 and 402,
M may be a transition metal (for example, iridium (Ir), palladium (Pd), osmium (Os), titanium (Ti), gold (Au), hafnium (Hf), europium (Eu), terbium (Tb), rhodium (Rh), rhenium (Re), or thulium (Tm)),
L₄₀₁ may be a ligand represented by Formula 402, and xc1 may be 1, 2, or 3, wherein, when xc1 is two or more, two or more L₄₀₁(s) may be identical to or different from each other,
L₄₀₂ may be an organic ligand, and xc2 may be 0, 1, 2, 3, or 4, wherein, when xc2 is 2 or more, two or more L₄₀₂(s) may be identical to or different from each other,
X₄₀₁ and X₄₀₂ may each independently be nitrogen or carbon,
ring A₄₀₁ and ring A₄₀₂ may each independently be a C₃-C₆₀ carbocyclic group or a C₁-C₆₀ heterocyclic group,
T₄₀₁ may be a single bond, *—O—*′, *—S—*′, *—C(═O)—*′, *—N(Q₄₁₁)-*′ *—C(Q₄₁₁)(Q₄₁₂)-*′, *—C(Q₄₁₁)=C(Q₄₁₂)-*′, *—C(Q₄₁₁)=*′, or *═C═*′,
X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(0414), or Si(Q₄₁₃)(Q₄₁₄),
Q₄₁₁ to Q₄₁₄ may each independently be the same as described in connection with Q₁,
R₄₀₁ and R₄₀₂ may each independently be hydrogen, deuterium, —F, —Cl, —Br, —I, a hydroxyl group, a cyano group, a nitro group, a C₁-C₂₀ alkyl group that is unsubstituted or substituted with at least one R₁₀ₐ, a C₁-C₂₀ alkoxy group that is unsubstituted or substituted with at least one R₁₀ₐ, a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₄₀₁)(0402)(0403), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
Q₄₀₁ to Q₄₀₃ may each independently be the same as described in connection with Q₁,
xc11 and xc12 may each independently be an integer from 0 to 10, and
* and *′ in Formula 402 may each indicate a binding site to M in Formula 401.

In an embodiment, in Formula 402, i) X₄₀₁ may be nitrogen, and X₄₀₂ may be carbon, or ii) each of X₄₀₁ and X₄₀₂ may be nitrogen.

In an embodiment, when xc1 in Formula 402 is 2 or more, two ring A₄₀₁ in two or more L₄₀₁(s) may be optionally linked to each other via T₄₀₂, which is a linking group, and/or two ring A₄₀₂ may optionally be linked to each other via T₄₀₃, which is a linking group. T₄₀₂ and T₄₀₃ may each independently be the same as described in connection with T₄₀₁.

L₄₀₂ in Formula 401 may be an organic ligand. In an embodiment, L₄₀₂ may include a halogen group, a diketone group (for example, an acetylacetonate group), a carboxylic acid group (for example, a picolinate group), —C(═O), an isonitrile group, —CN group, a phosphorus group (for example, a phosphine group, a phosphite group, etc.), or any combination thereof.

The phosphorescent dopant may include, for example, at least one of compounds PD1 to PD25 or any combination thereof:

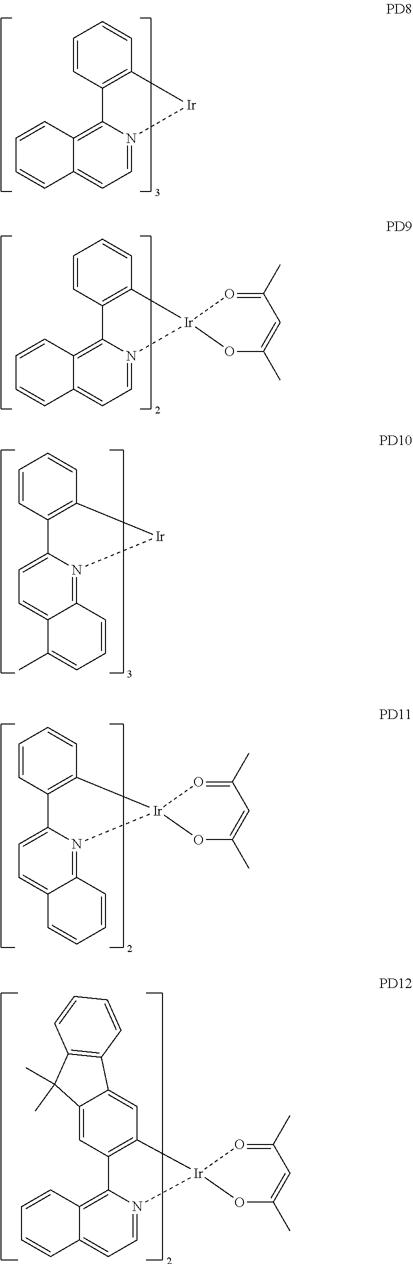

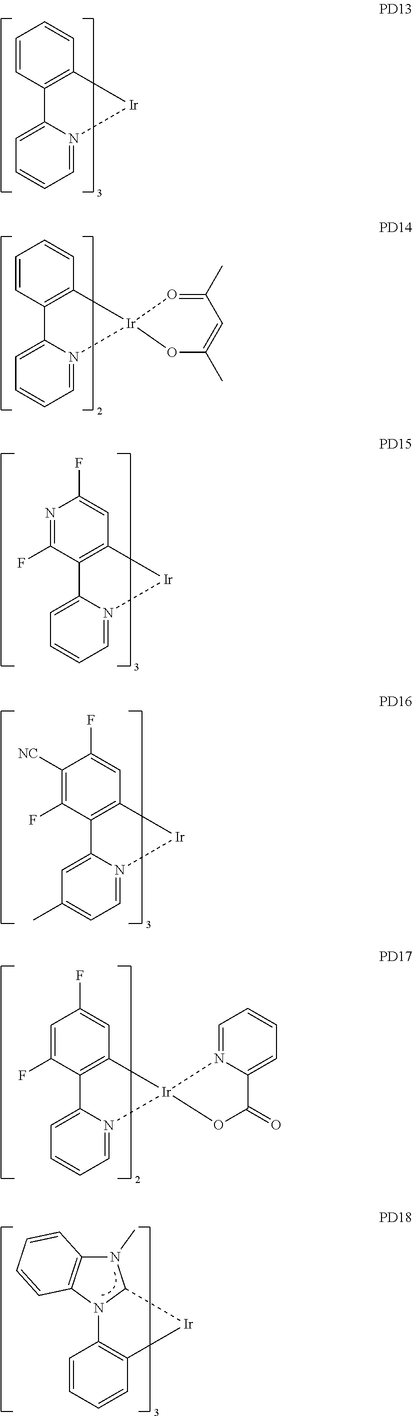

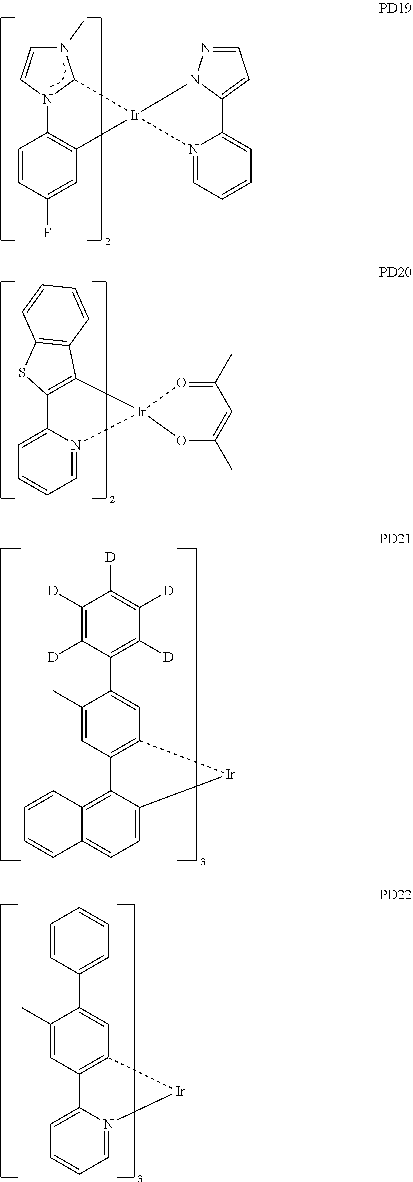

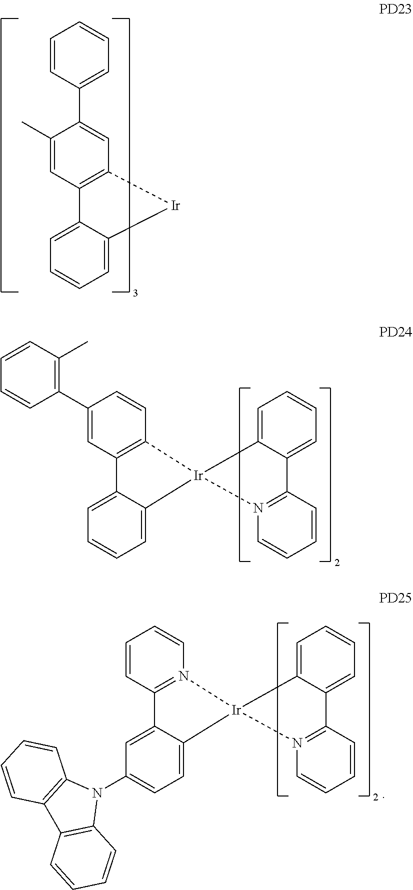

### Fluorescent Dopant

The fluorescent dopant may include an amine group-containing compound, a styryl group-containing compound, or any combination thereof.

In an embodiment, the fluorescent dopant may include a compound represented by Formula 501:

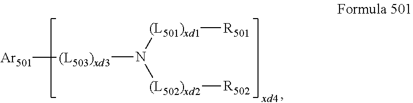

wherein, in Formula 501,
Ar₅₀₁, L₅₀₁ to L₅₀₃, R₅₀₁, and R₅₀₂ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,
xd1 to xd3 may each independently be 0, 1, 2, or 3, and
xd4 may be 1, 2, 3, 4, 5, or 6.

In an embodiment, Ar₅₀₁ in Formula 501 may be a condensed cyclic group (for example, an anthracene group, a chrysene group, or a pyrene group) in which three or more monocyclic groups are condensed together.

In an embodiment, xd4 in Formula 501 may be 2.

In an embodiment, the fluorescent dopant may include: at least one of Compounds FD1 to FD36; DPVBi; DPAVBi; or any combination thereof:

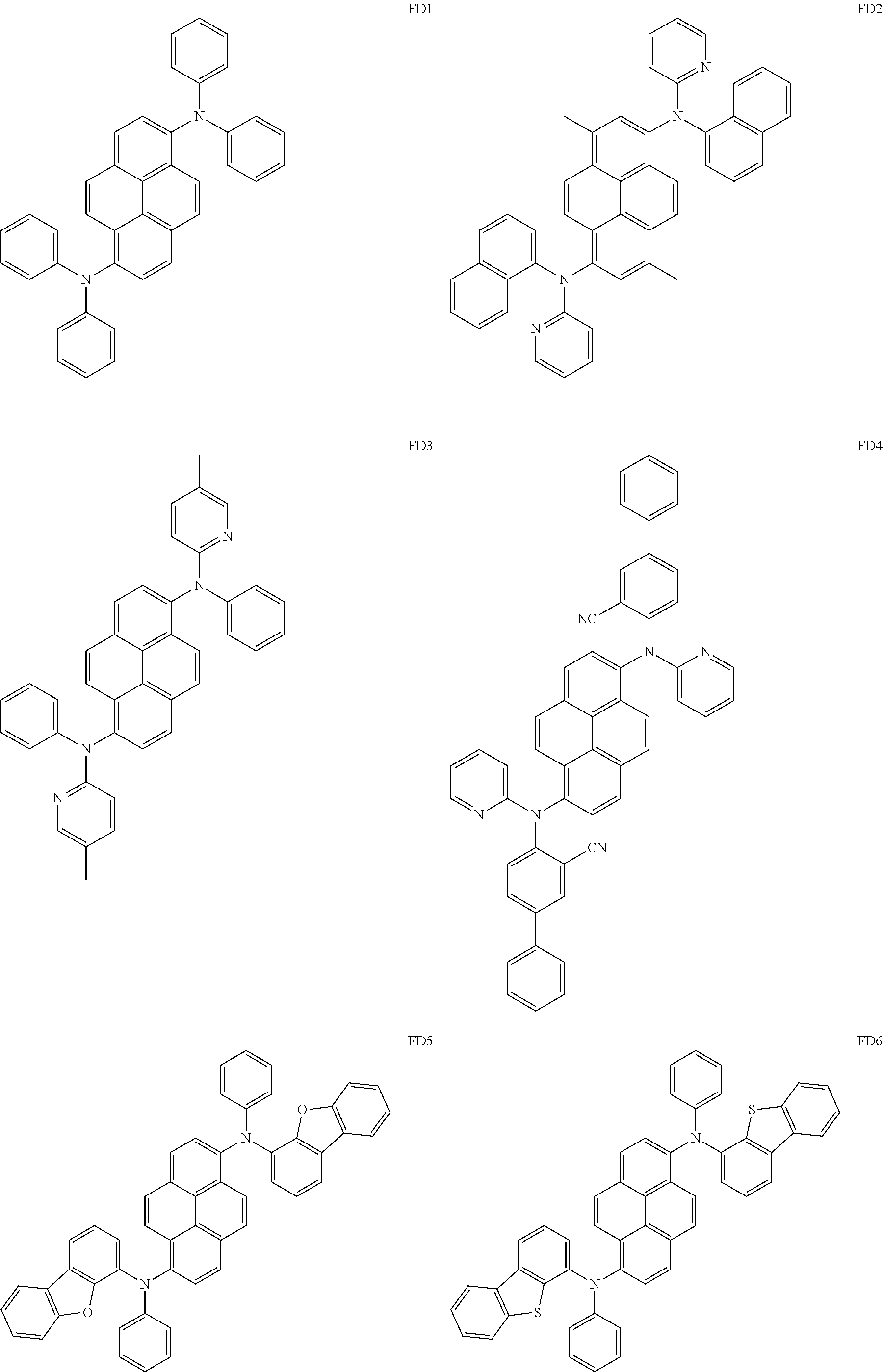

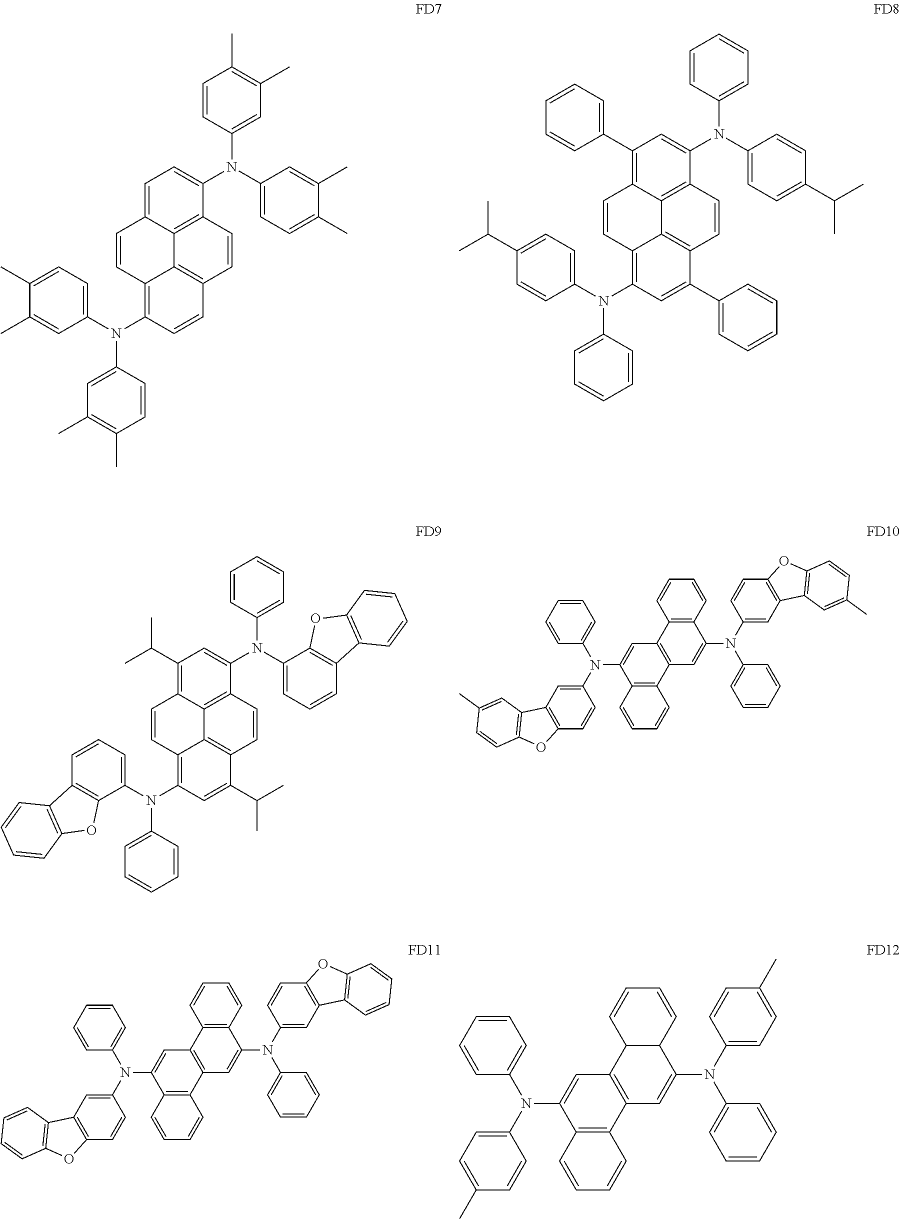

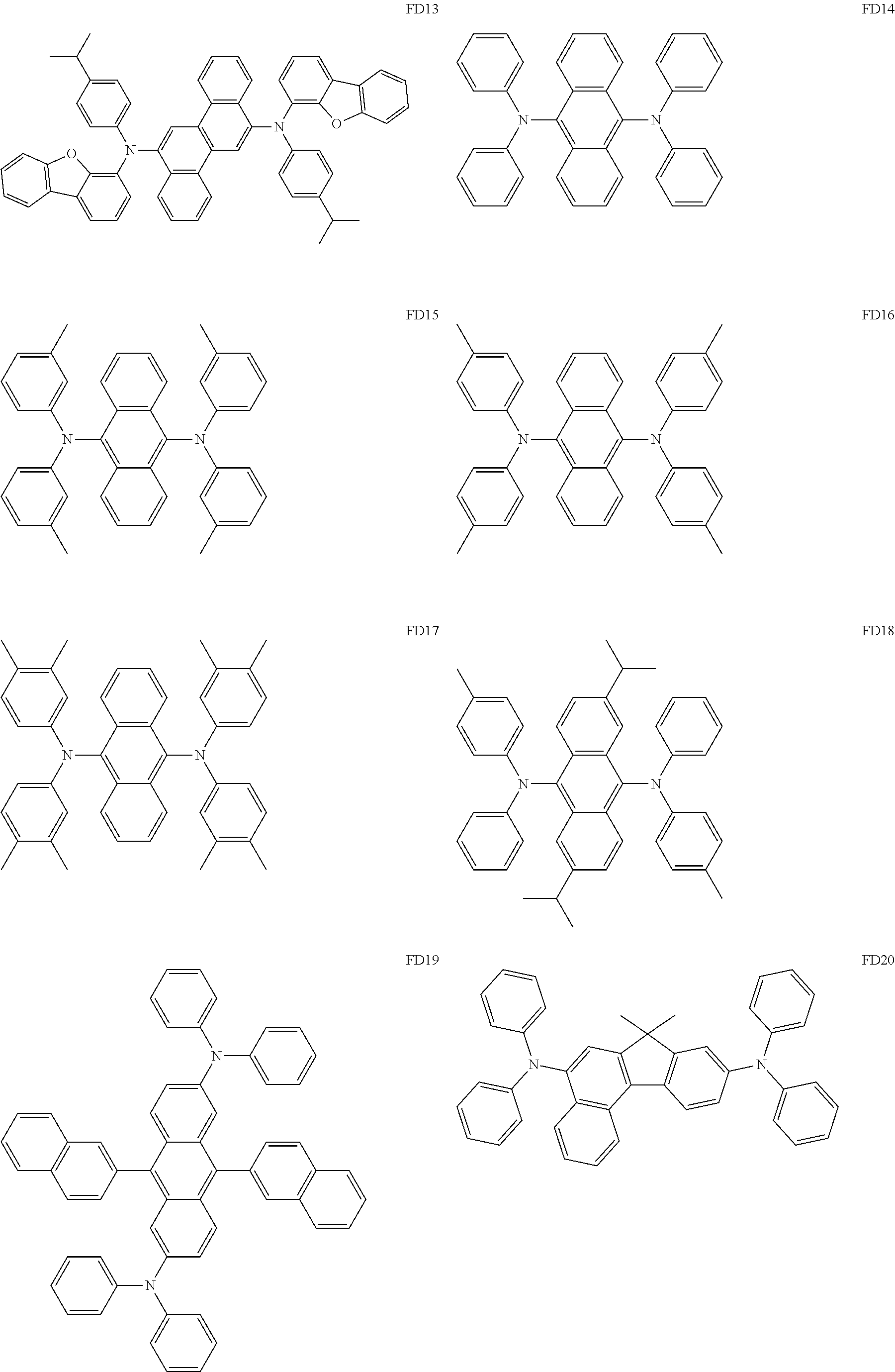

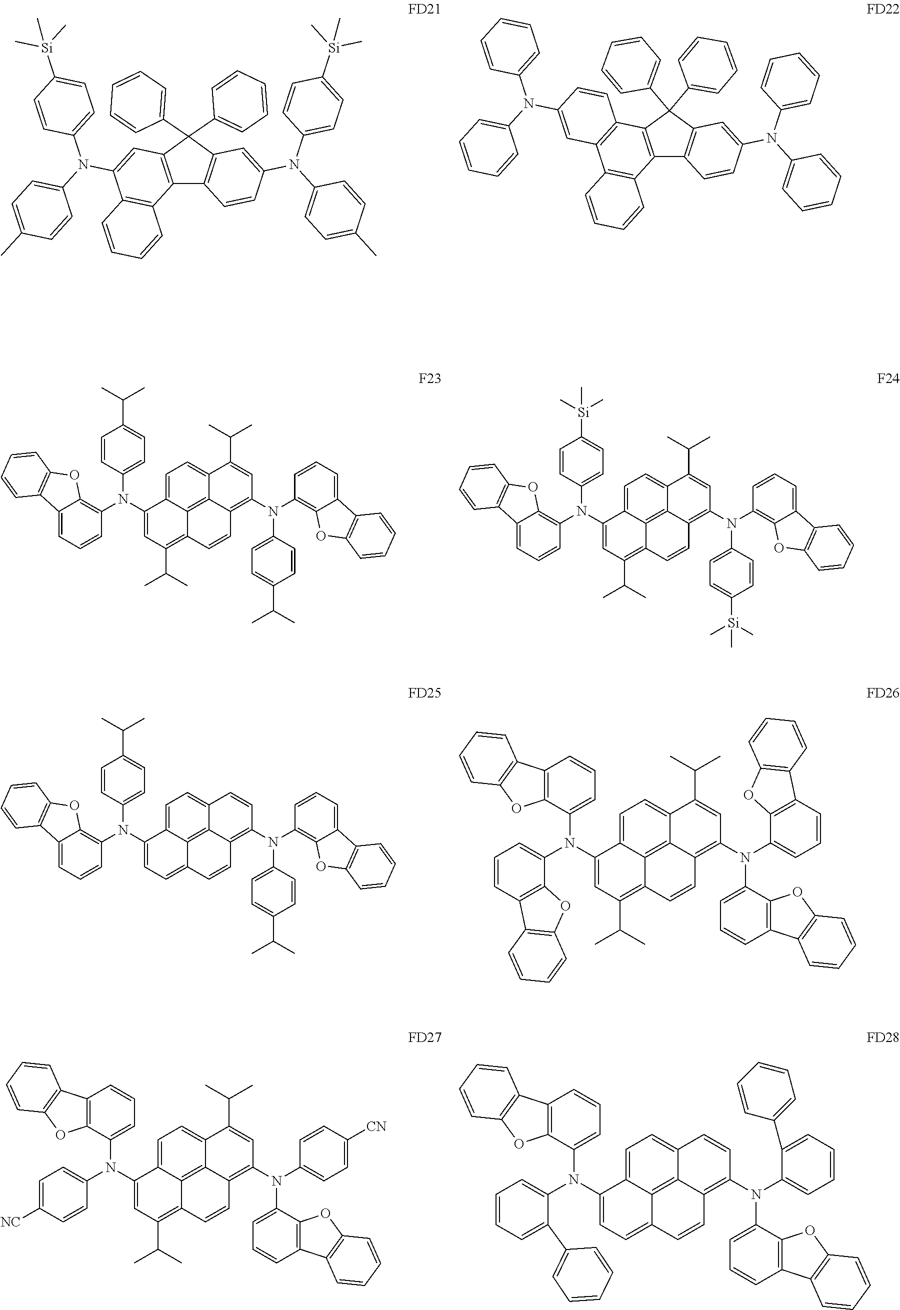

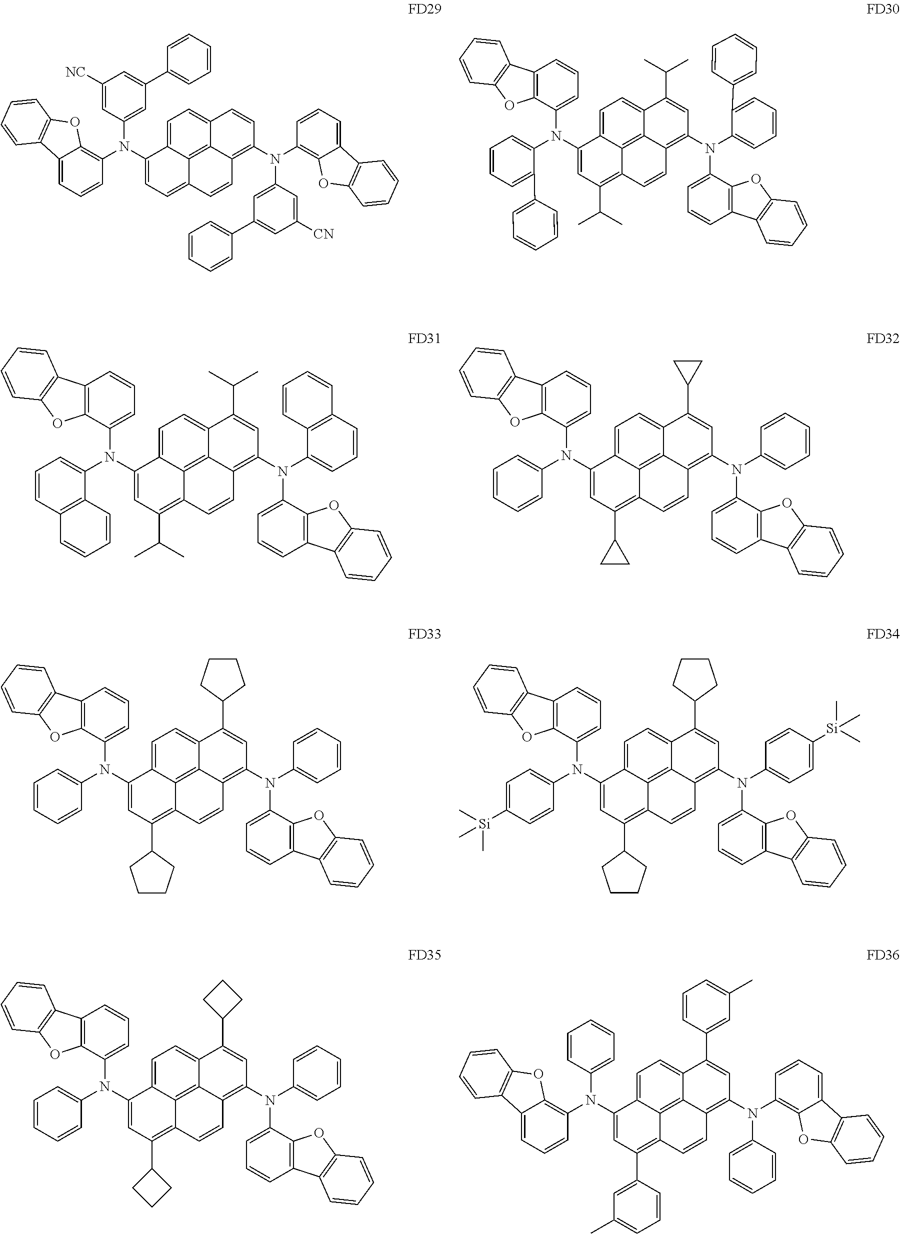

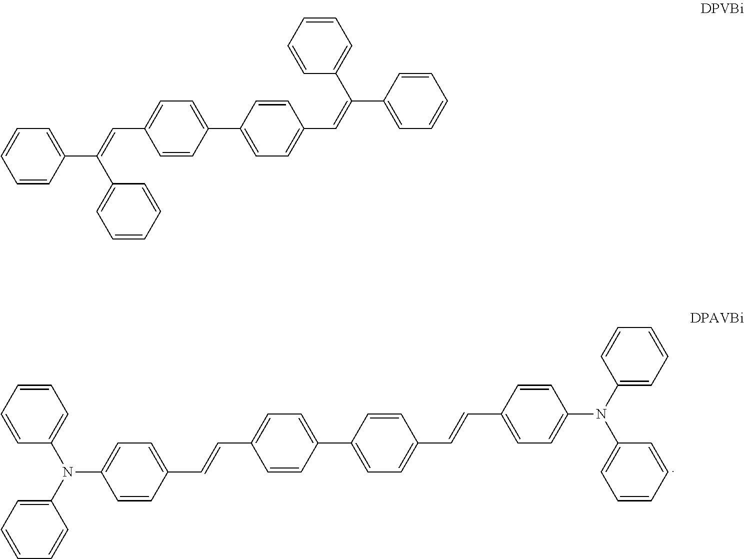

### Delayed Fluorescence Material

The emission layer may include a delayed fluorescence material.

In the present specification, the delayed fluorescence material may be selected from compounds capable of emitting delayed fluorescence based on a delayed fluorescence emission mechanism.

The delayed fluorescence material included in the emission layer may act (e.g., serve) as a host or a dopant depending on the type or kind of other materials included in the emission layer.

In an embodiment, the difference between the triplet energy level (eV) of the delayed fluorescence material and the singlet energy level (eV) of the delayed fluorescence material may be greater than or equal to about 0 eV and less than or equal to about 0.5 eV. When the difference between the triplet energy level (eV) of the delayed fluorescence material and the singlet energy level (eV) of the delayed fluorescence material satisfies the above-described range, up-conversion from the triplet state to the singlet state of the delayed fluorescence materials may occur effectively, and thus, the luminescence efficiency of the light-emitting device 10 may be improved.

In an embodiment, the delayed fluorescence material may include i) a material including at least one electron donor (for example, a π electron-rich C₃-C₆₀ cyclic group, such as a carbazole group) and at least one electron acceptor (for example, a sulfoxide group, a cyano group, and/or a π electron-deficient nitrogen-containing C₁-C₆₀ cyclic group), and/or ii) a material including a C₈-C₆₀ polycyclic group in which two or more cyclic groups are condensed (e.g., fused to each other) while sharing boron (B).

Examples of the delayed fluorescence material may include at least one of Compounds DF1 to DF9:

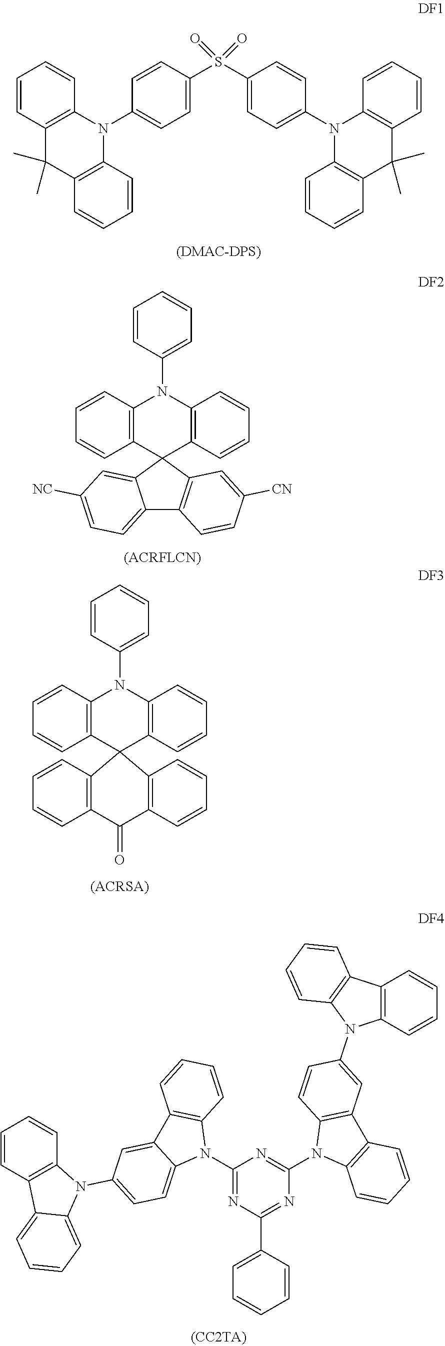

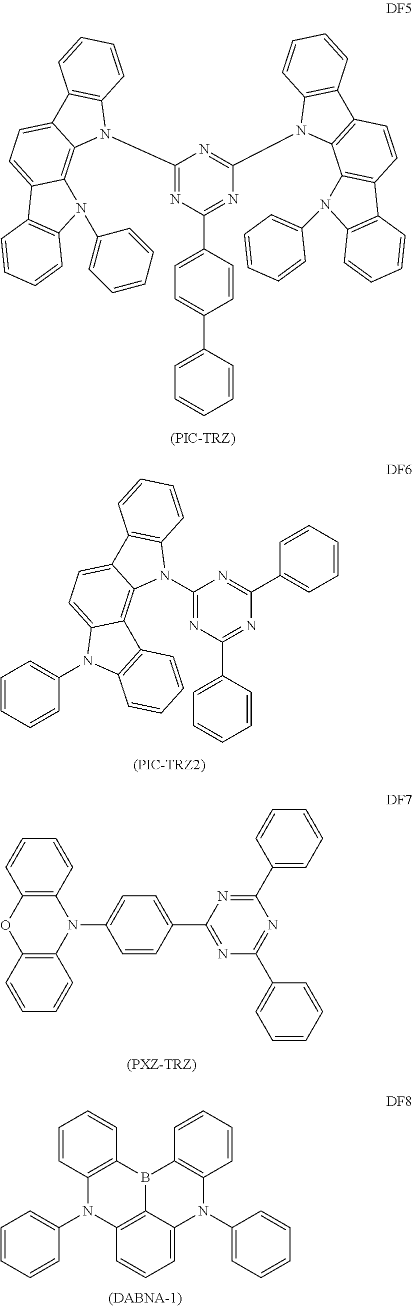

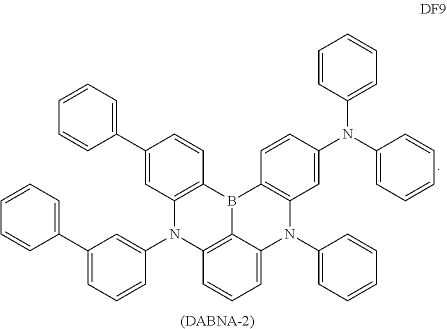

### Quantum Dot

The emission layer may include a quantum dot.

In the present specification, a quantum dot refers to a crystal of a semiconductor compound, and may include any suitable material capable of emitting light of various emission wavelengths according to the size of the crystal.

A diameter of the quantum dot may be, for example, in a range of about 1 nm to about 10 nm.

The quantum dot may be synthesized by a wet chemical process, a metal organic (e.g., organometallic) chemical vapor deposition process, a molecular beam epitaxy process, or any process similar thereto.

In the wet chemical process, a precursor material is mixed with an organic solvent to grow a quantum dot particle crystal. As the crystal grows, the organic solvent naturally acts (e.g., serves) as a dispersant coordinated on the surface of the quantum dot crystal and controls the growth of the crystal so that the growth of quantum dot particles may be controlled or selected through a process which is more easily performed than vapor deposition methods, such as metal organic chemical vapor deposition (MOCVD) and/or molecular beam epitaxy (MBE), and which has a lower cost.

The quantum dot may include: a Group II-VI semiconductor compound; a Group III-V semiconductor compound; a Group III-VI semiconductor compound; a Group I—III-VI semiconductor compound; a Group IV-VI semiconductor compound; a Group IV element or compound; or any combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, and/or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound, such as CdZnSeS, CdZnSeTe, CdZnSTe, CdHgSeS, CdHgSeTe, CdHgSTe, HgZnSeS, HgZnSeTe, and/or HgZnSTe; or any combination thereof.

Examples of the Group III-V semiconductor compound may include: a binary compound, such as GaN, GaP, GaAs, GaSb, AlN, AlP, AlAs, AlSb, InN, InP, InAs, and/or InSb; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound, such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; or any combination thereof. In an embodiment, the Group III-V semiconductor compound may further include Group II elements. Examples of the Group III-V semiconductor compound further including Group II elements may include InZnP, InGaZnP, InAlZnP, and/or the like.

Examples of the Group III-VI semiconductor compound may include: a binary compound, such as GaS, GaSe, Ga₂Se₃, GaTe, InS, InSe, In₂S₃, In₂Se₃, and/or InTe; a ternary compound, such as InGaS₃, and/or InGaSe₃; or any combination thereof.

Examples of the Group I—III-VI semiconductor compound may include: a ternary compound, such as AgInS, AgInS₂, CulnS, CulnS₂, CuGaO₂, AgGaO₂, AgAIO₂, or any combination thereof.

Examples of the Group IV-VI semiconductor compound may include: a binary compound, such as SnS, SnSe, SnTe, PbS, PbSe, PbTe, and/or the like; a ternary compound, such as SnSeS, SnSeTe, SnSTe, PbSeS, PbSeTe, PbSTe, SnPbS, SnPbSe, SnPbTe, and/or the like; a quaternary compound, such as SnPbSSe, SnPbSeTe, SnPbSTe, and/or the like; or any combination thereof.

The Group IV element or compound may include: a single element compound, such as Si and/or Ge; a binary compound, such as SiC and/or SiGe; or any combination thereof.

Each element included in a multi-element compound such as the binary compound, ternary compound and/or quaternary compound, may exist in a particle thereof with a substantially uniform concentration or non-uniform concentration.

In an embodiment, the quantum dot may have a single structure or a dual core-shell structure. In the case of the quantum dot having a single structure, the concentration of each element included in the corresponding quantum dot may be substantially uniform. In an embodiment, in a quantum dot with a core-shell structure, the material contained in the core and the material contained in the shell may be different from each other.

The shell of the quantum dot may act (e.g., serve) as a protective layer to prevent or reduce chemical degeneration of the core to maintain semiconductor characteristics and/or as a charging layer to impart electrophoretic characteristics to the quantum dot. The shell may be a single layer or a multi-layer. The element presented in the interface between the core and the shell of the quantum dot may have a concentration gradient with its concentration decreases toward the center of the quantum dot.

Examples of the material for forming the shell of the quantum dot may include an oxide of metal, metalloid, or non-metal, a semiconductor compound, or any combination thereof. Examples of the oxide of metal, metalloid, or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound, such as MgA₁₂O₄, CoFe₂O₄, NiFe₂O₄, and/or CoMn₂O₄; or any combination thereof. Examples of the semiconductor compound may include, as described herein, a Group II-VI semiconductor compound, a Group III-V semiconductor compound, a Group III-VI semiconductor compound, a Group I—III-VI semiconductor compound, a Group IV-VI semiconductor compound, or any combination thereof. In some embodiments, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of an emission wavelength spectrum of the quantum dot may be about 45 nm or less, for example, about 40 nm or less, or, about 30 nm or less, and within these ranges, color purity or color reproducibility may be increased. In some embodiments, because the light emitted through the quantum dot is emitted in all directions, the wide viewing angle may be improved.

In some embodiments, the quantum dot may be a spherical particle, a pyramidal particle, a multi-arm particle, a cubic nanoparticle, a nanotube particle, a nanowire particle, a nanofiber particle, or a nanoplate particle. Also, the diameter of the quantum dot may be, for example, a quantum dot particle size.

Because the energy band gap may be adjusted by controlling the size of the quantum dot, light having one or more suitable wavelength bands may be obtained from the quantum dot emission layer. Therefore, by utilizing quantum dots of different sizes, a light-emitting device that emits light of one or more suitable wavelengths may be implemented. In an embodiment, the size of the quantum dot may be selected to emit red, green and/or blue light. In some embodiments, the size of the quantum dot may be configured to emit white light by combining light of one or more suitable colors.

### Electron Transport Region in Interlayer 130

The electron transport region may have: i) a single-layered structure consisting of a single layer consisting of a single material, ii) a single-layered structure consisting of a single layer including (e.g., consisting of) a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

In an embodiment, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, with the constituting layers of each structure being sequentially stacked from an emission layer in the respective stated order.

In an embodiment, the electron transport region (for example, the buffer layer, the hole blocking layer, the electron control layer, and/or the electron transport layer in the electron transport region) may include a metal-free compound including at least one π electron-deficient nitrogen-containing C₁-C₆₀ cyclic group.

In an embodiment, the electron transport region may include a compound represented by Formula 601:

[Ar₆₀₁]ₓₑ₁₁-[(L₆₀₁)ₓₑ₁-R₆₀₁]ₓₑ₂₁ Formula 601

wherein, in Formula 601,

Ar₆₀₁ and L₆₀₁ may each independently be a C₃-C₆₀ carbocyclic group that is unsubstituted or substituted with at least one R₁₀ₐ or a C₁-C₆₀ heterocyclic group that is unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group that is unsubstituted or substituted with at least one R₁₀ₐ, a C₁-C₆₀ heterocyclic group that is unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each independently be the same as described in connection with Q₁,

xe21 may be 1, 2, 3, 4, or 5, and

at least one of Ar₆₀₁, L₆₀₁, or R₆₀₁ may each independently be a π electron-deficient nitrogen-containing C₁-C₆₀ cyclic group that is unsubstituted or substituted with at least one R₁₀ₐ.

In an embodiment, when xe11 in Formula 601 is 2 or more, two or more Ar₆₀₁ (s) may be linked to each other via a single bond.

In an embodiment, Ar₆₀₁ in Formula 601 may be a substituted or unsubstituted anthracene group.

In an embodiment, the electron transport region may include a compound represented by Formula 601-1:

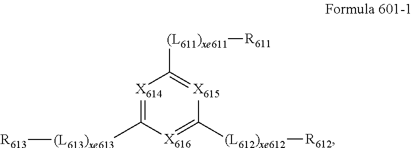

wherein, in Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may each independently be the same as described in connection with L₆₀₁,

xe611 to xe613 may each independently be the same as described in connection with xe1,

R₆₁₁ to R₆₁₃ may each independently be the same as described in connection with R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group that is unsubstituted or substituted with at least one R₁₀ₐ, or a C₁-C₆₀ heterocyclic group that is unsubstituted or substituted with at least one R₁₀ₐ.

In an embodiment, xe1 and xe611 to xe613 in Formulae 601 and 601-1 may each independently be 0, 1, or 2.

The electron transport region may include at least one of Compounds ET1 to ET45, 2,9-dimethyl-4,7-diphenyl-1,10-phenanthroline (BCP), 4,7-diphenyl-1,10-phenanthroline (Bphen), Alq₃, BAIq, TAZ, NTAZ, or any combination thereof:

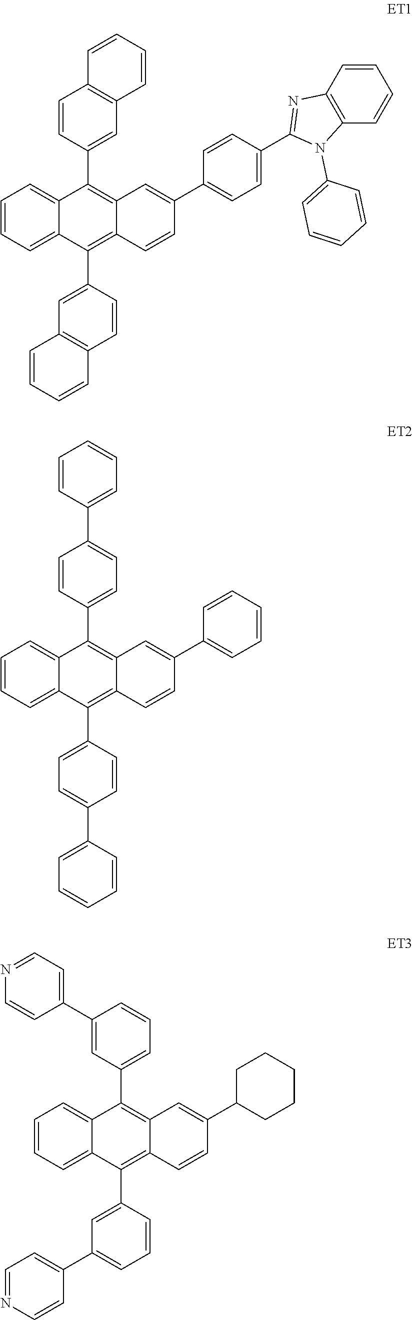

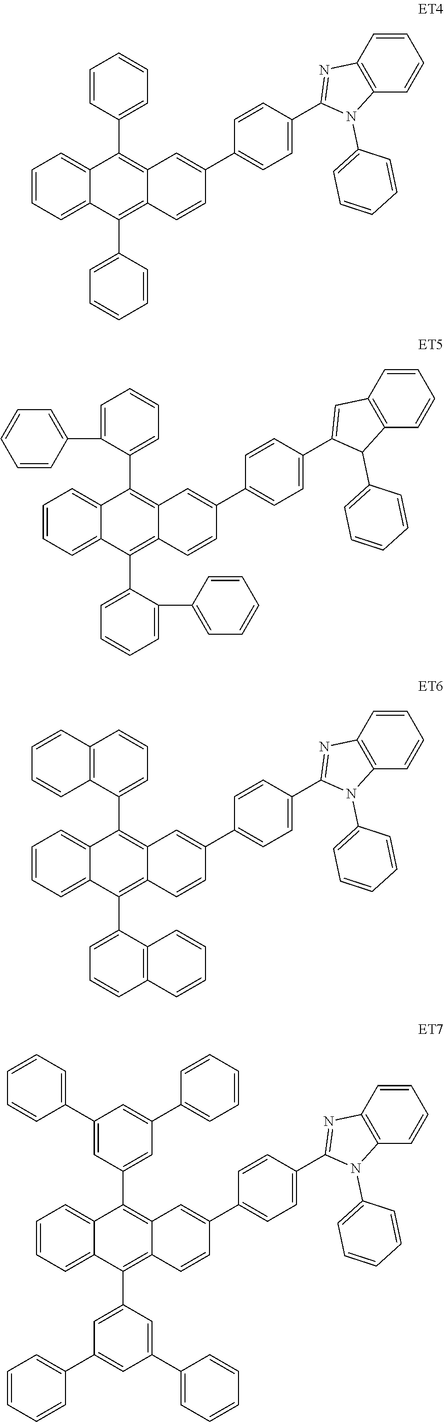

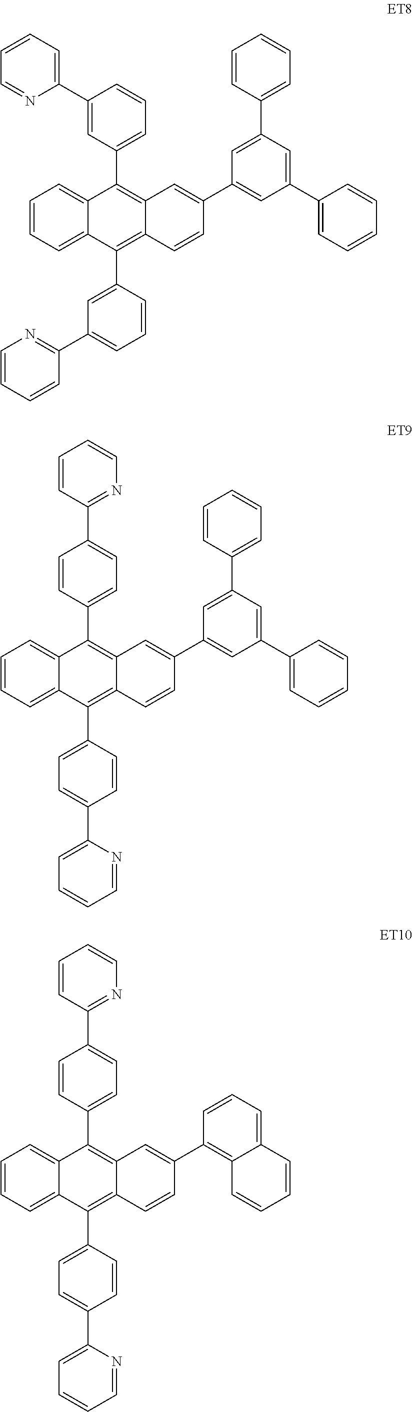

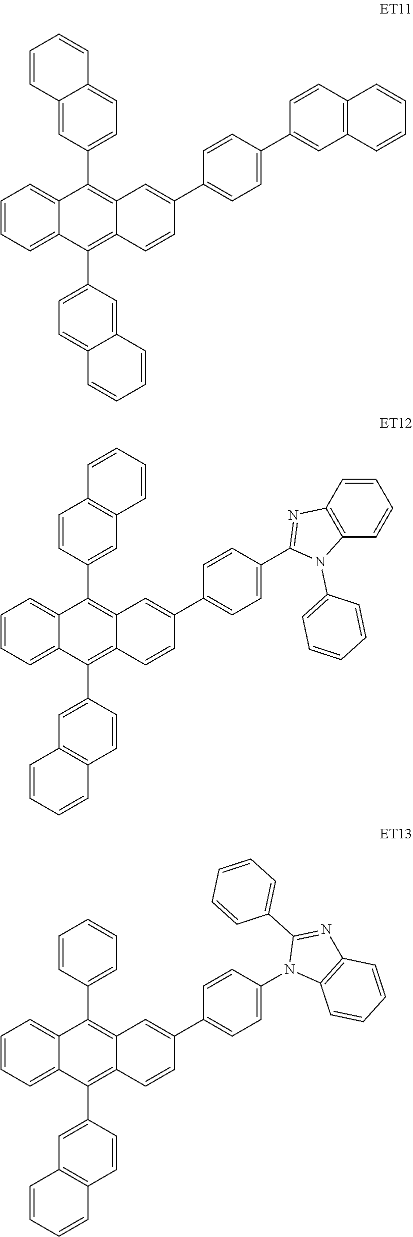

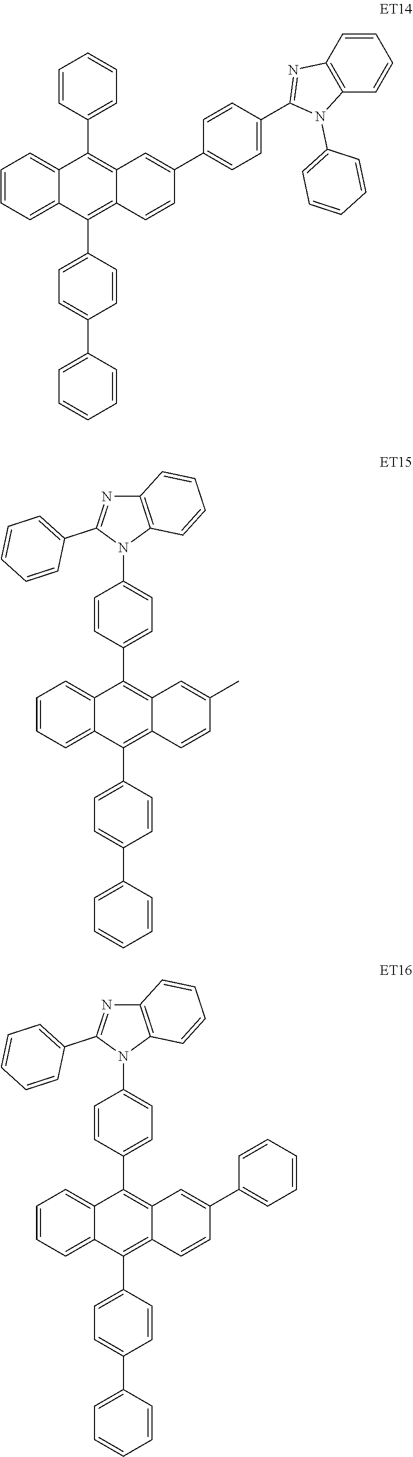 [SMILES: c1ccc(-c2ccc(-c3c4ccccc4c(-c4ccccc4)c4cc(-c5ccc(-c6nc7ccccc7n6-c6ccccc6)cc5)ccc34)cc2)cc1 ; Cc1ccc2c(-c3ccc(-c4ccccc4)cc3)c3ccccc3c(-c3ccc(-n4c(-c5ccccc5)nc5ccccc54)cc3)c2c1 ; c1ccc(-c2ccc(-c3c4ccccc4c(-c4ccc(-n5c(-c6ccccc6)nc6ccccc65)cc4)c4cc(-c5ccccc5)ccc34)cc2)cc1]

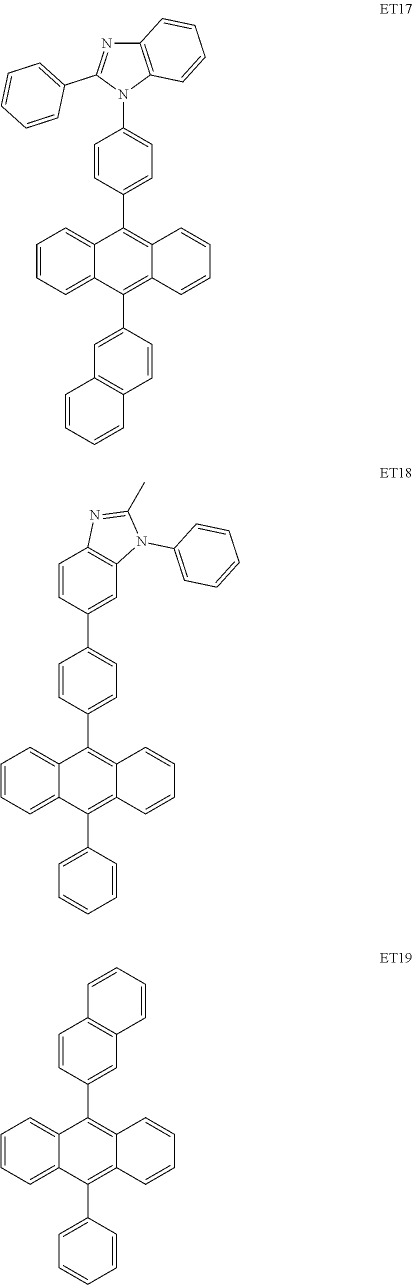

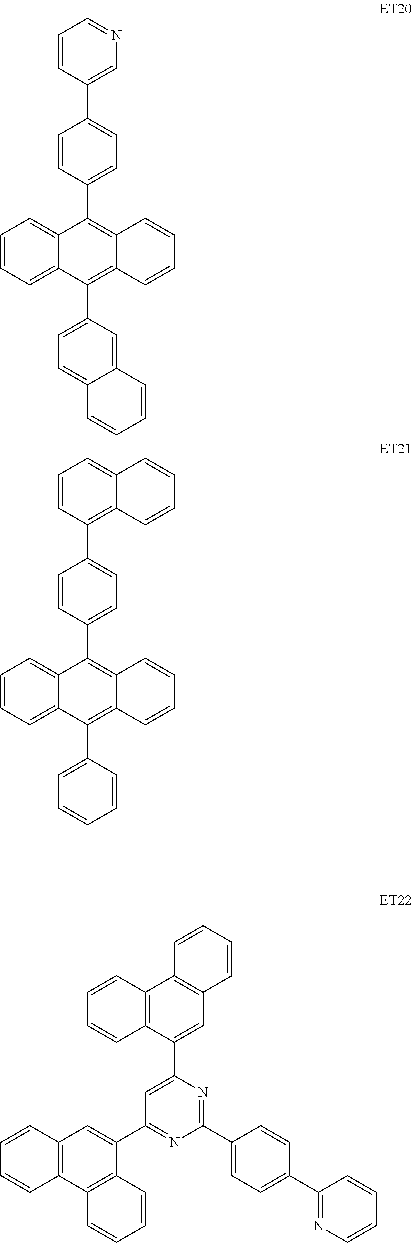

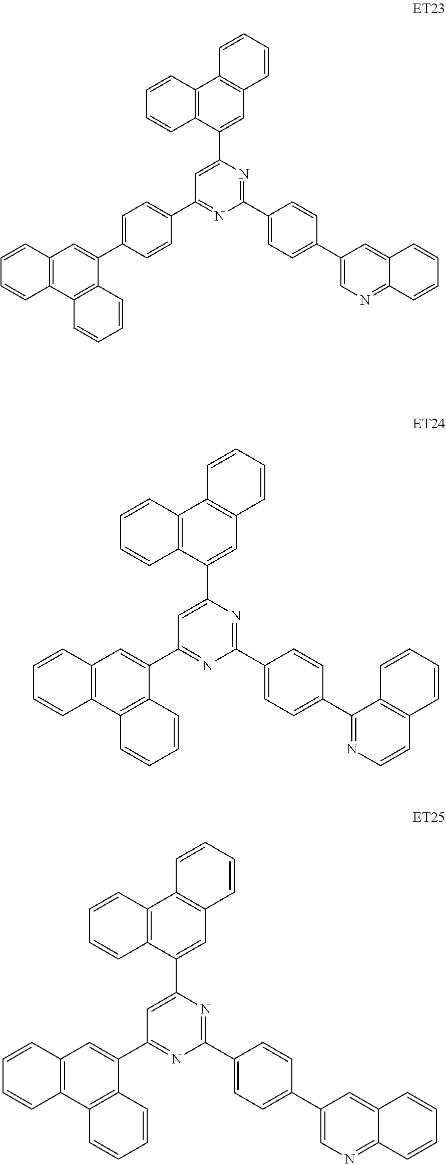 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)cc(-c5cc6ccccc6c6ccccc56)n4)cc3)cc2c1]

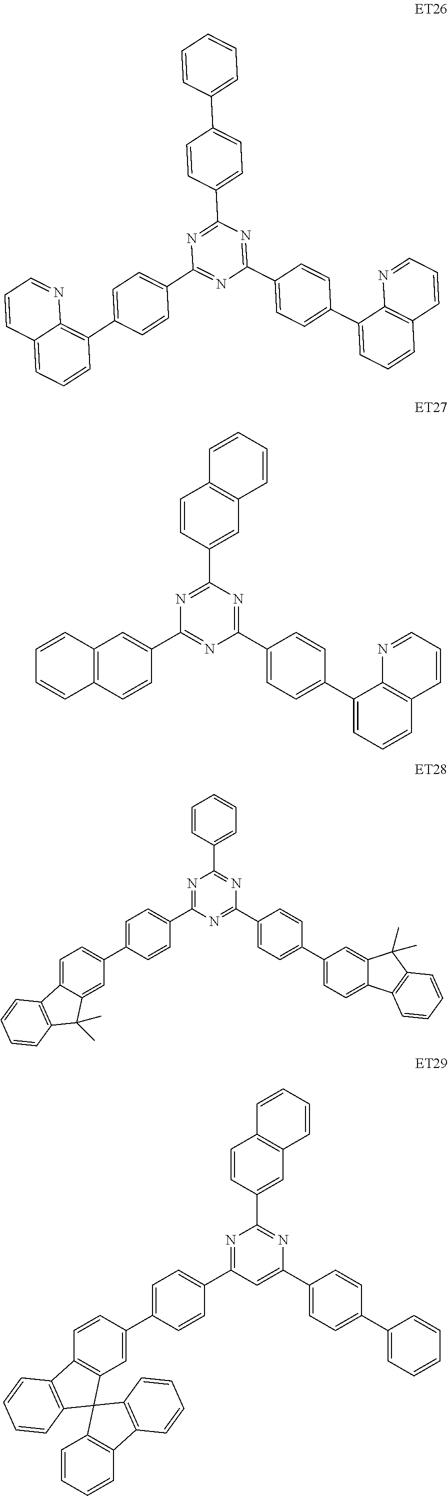 [SMILES: c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1]

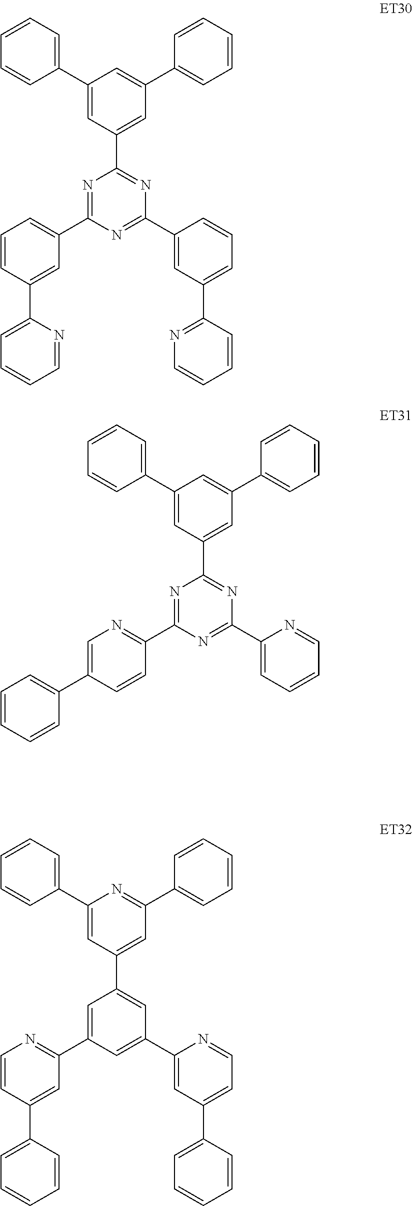 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3nc(-c4cc(-c5ccccc5)cc(-c5ccccc5)c4)nc(-c4ccccn4)n3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

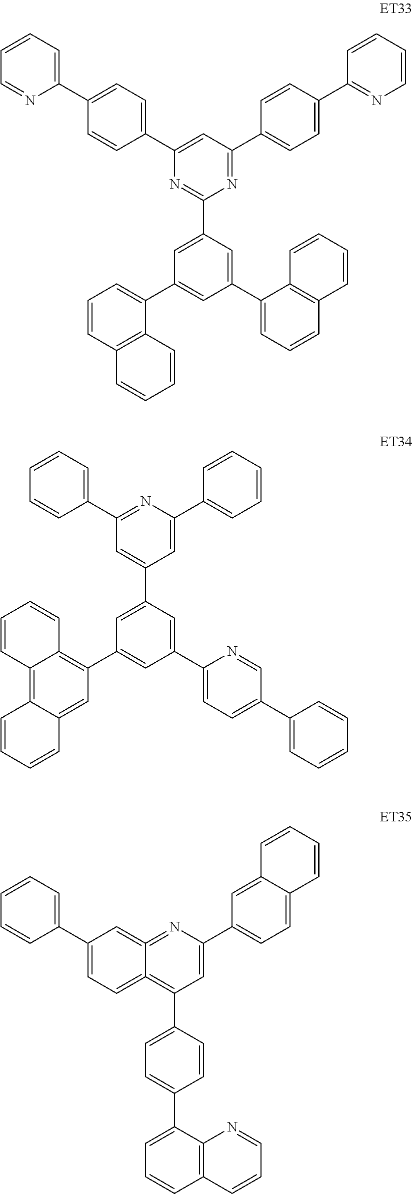

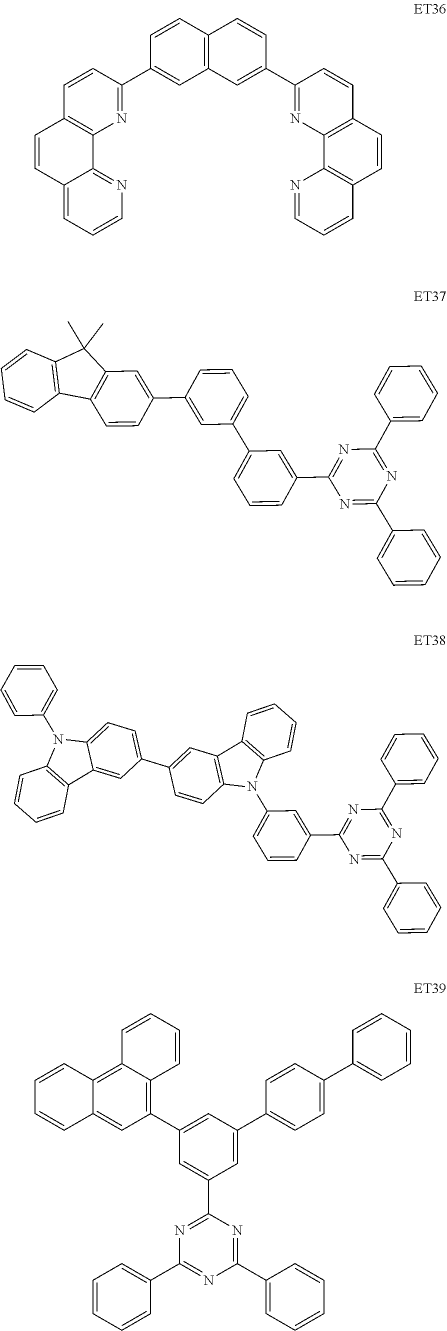 [SMILES: c1cnc2c(c1)ccc1ccc(-c3ccc4ccc(-c5ccc6ccc7cccnc7c6n5)cc4c3)nc12 ; CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1]

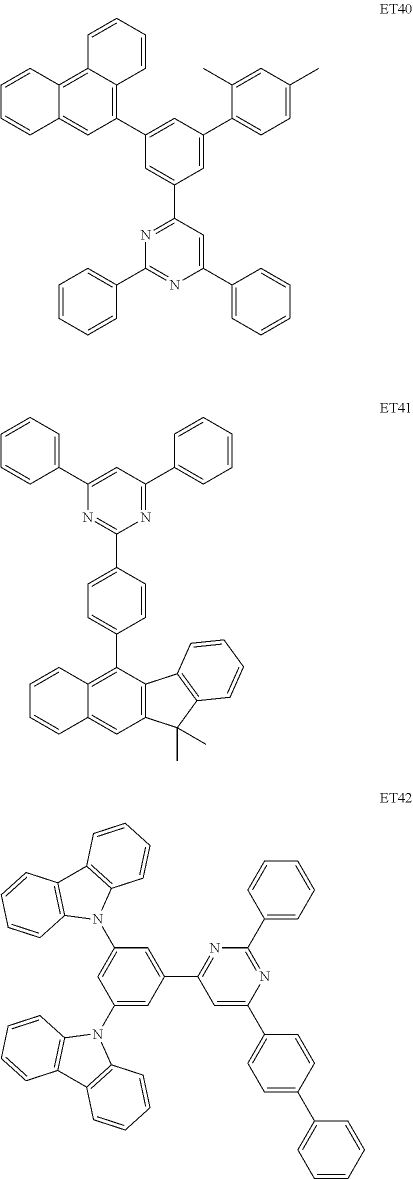 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

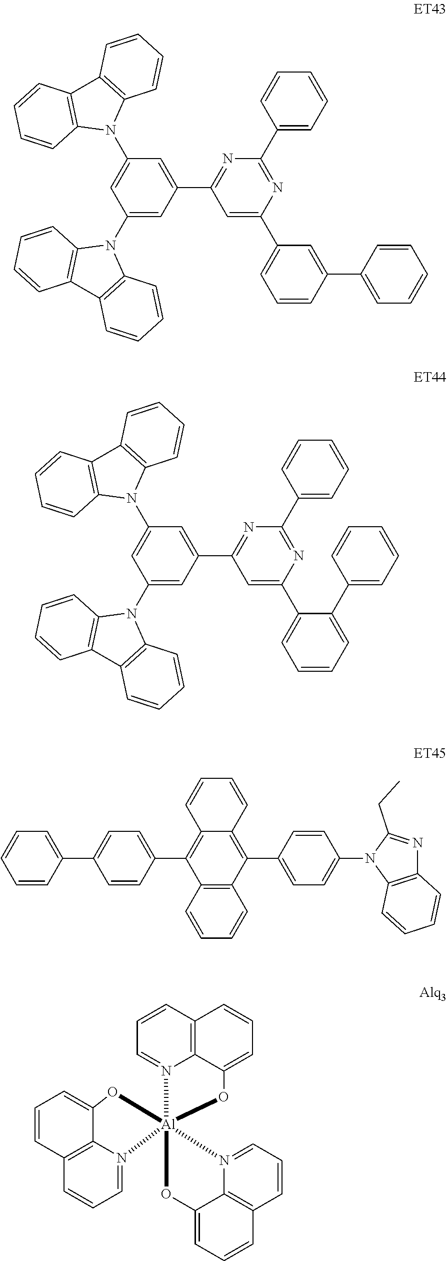

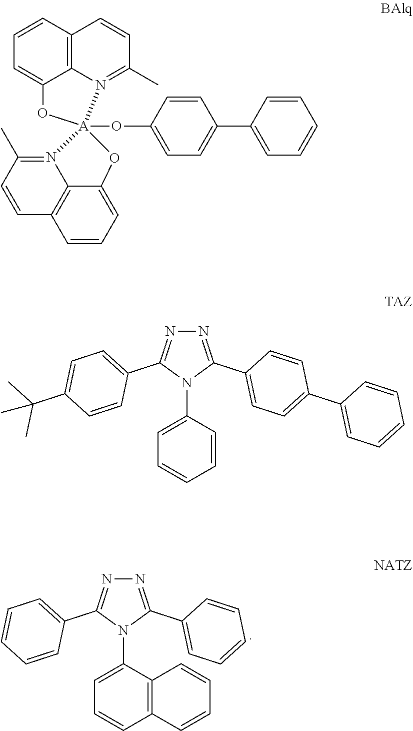

A thickness of the electron transport region may be about 100 Å to about 5,000 Å, for example, about 160 Å to about 4,000 Å. When the electron transport region includes a buffer layer, a hole blocking layer, an electron control layer, an electron transport layer, or any combination thereof, the thickness of the buffer layer, the hole blocking layer, or the electron control layer may each independently be from about 20 Å to about 1,000 Å, for example, about 30 Å to about 300 Å, and the thickness of the electron transport layer may be from about 100 Å to about 1,000 Å, for example, about 150 Å to about 500 Å. When the thicknesses of the buffer layer, the hole blocking layer, the electron control layer, the electron transport layer and/or the electron transport region are within these ranges, satisfactory electron-transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or ET-D2:

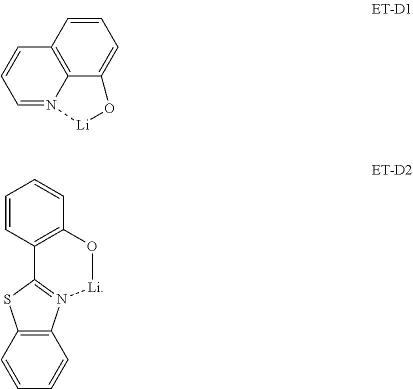

The electron transport region may include an electron injection layer to facilitate the injection of electrons from the second electrode 150. The electron injection layer may be in direct contact with the second electrode 150.

The electron injection layer may have: i) a single-layered structure consisting of a single layer consisting of a single material, ii) a single-layered structure consisting of a single layer including (e.g., consisting of) a plurality of different materials, or iii) a multilayer structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include L₁, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include one or more oxides, halides (for example, fluorides, chlorides, bromides, and/or iodides), and/or tellurides of the alkali metal, the alkaline earth metal, and/or the rare earth metal, or any combination thereof.

The alkali metal-containing compound may include one or more alkali metal oxides (such as Li₂O, Cs₂O, and/or K₂O), alkali metal halides (such as LiF, NaF, CsF, KF, LiI, NaI, CsI, and/or KI), or any combination thereof. The alkaline earth metal-containing compound may include an alkaline earth metal compound, such as BaO, SrO, CaO, BaxSri-xO (x is a real number satisfying the condition of 0<x<1), BaₓCa₁₋ₓO (x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth-metal complex, and the rare earth metal complex may include i) one of an ion of the alkali metal, the alkaline earth metal, and the rare earth metal and ii), as a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

In an embodiment, the electron injection layer may include (e.g., consist of) i) an alkali metal-containing compound (for example, an alkali metal halide), ii) a) an alkali metal-containing compound (for example, an alkali metal halide); and b) an alkali metal, an alkaline earth metal, a rare earth metal, or any combination thereof. For example, the electron injection layer may be a KI:Yb co-deposited layer, a RbI:Yb co-deposited layer, a LiF:Yb co-deposited layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or any combination thereof may be homogeneously or non-homogeneously dispersed in a matrix including the organic material.

A thickness of the electron injection layer may be in a range of about 1 Å to about 100 Å, and, for example, about 3 Å to about 90 Å. When the thickness of the electron injection layer is within the ranges described above, satisfactory electron injection characteristics may be obtained without a substantial increase in driving voltage.

### Second Electrode 150

The second electrode 150 may be located on the interlayer 130 having such a structure. The second electrode 150 may be a cathode, which is an electron injection electrode, and as the material for the second electrode 150, a metal, an alloy, an electrically conductive compound, or any combination thereof, each having a low work function, may be utilized.

In an embodiment, the second electrode 150 may include lithium (Li), silver (Ag), magnesium (Mg), aluminum (AI), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multilayer structure including two or more layers.

### Capping Layer

A first capping layer may be located outside the first electrode 110 (e.g., on the side of the first electrode 110 facing oppositely away from the second electrode 150), and/or a second capping layer may be located outside the second electrode 150 (e.g., on the side of the second electrode 150 facing oppositely away from the first electrode 110). In an embodiment, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in the emission layer of the interlayer 130 of the light-emitting device 10 may be extracted (e.g., emitted) toward the outside through the first electrode 110, which may be a semi-transmissive electrode or a transmissive electrode, and the first capping layer or light generated in the emission layer of the interlayer 130 of the light-emitting device 10 may be extracted (e.g., emitted) toward the outside through the second electrode 150, which may be a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 may be increased, so that the luminescence efficiency of the light-emitting device 10 may be improved.

Each of the first capping layer and second capping layer may include a material having a refractive index (at a wavelength of 589 nm) of 1.6 or more.

The first capping layer and the second capping layer may each independently be an organic capping layer including an organic material, an inorganic capping layer including an inorganic material, or an organic-inorganic composite capping layer including an organic material and an inorganic material.

At least one of the first capping layer or the second capping layer may each independently include one or more carbocyclic compounds, heterocyclic compounds, amine group-containing compounds, porphyrin derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may be optionally substituted with a substituent containing O, N, S, Se, Si, F, Cl, Br, I, or any combination thereof. In an embodiment, at least one of the first capping layer or the second capping layer may each independently include an amine group-containing compound.

In an embodiment, at least one of the first capping layer and the second capping layer may each independently include a compound represented by Formula 201, a compound represented by Formula 202, or any combination thereof.

In an embodiment, at least one of the first capping layer and the second capping layer may each independently include at least one of Compounds HT28 to HT33, at least one of Compounds CP1 to CP6, β-NPB, or any combination thereof:

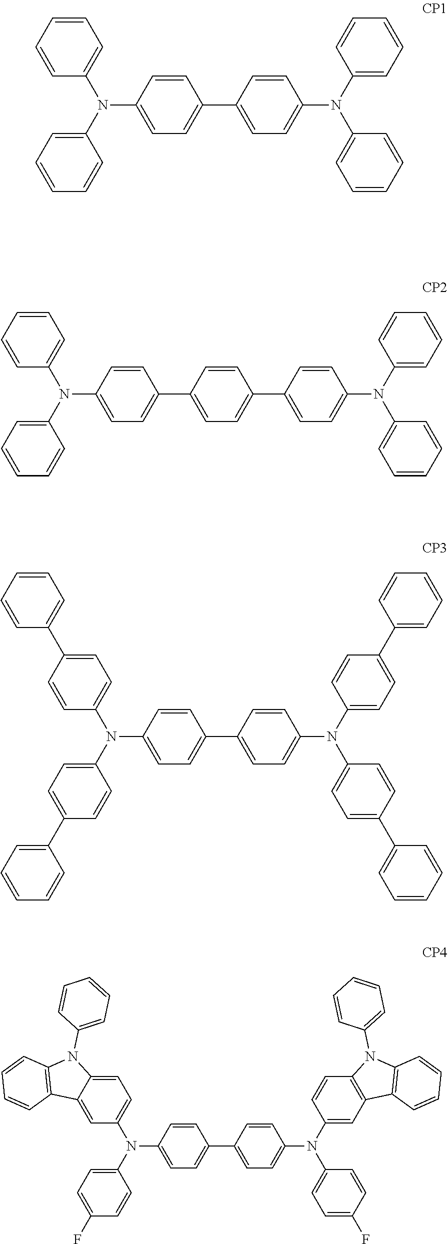 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

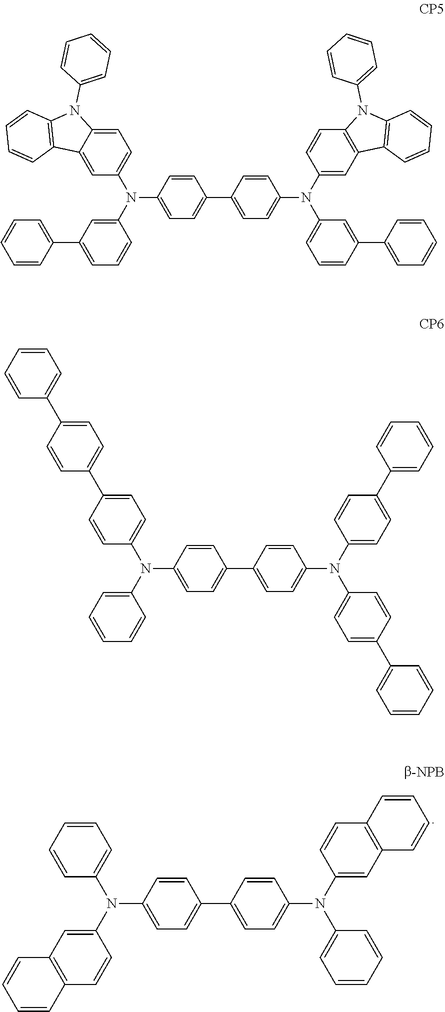 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Film

The heterocyclic compound represented by Formula 1 may be included in one or more suitable films. Accordingly, according to one or more embodiments, a film including the heterocyclic compound represented by Formula 1 may be provided. The film may be, for example, an optical member (or a light control member) (for example, a color filter, a color-conversion member, a capping layer, a light extraction efficiency enhancement layer, a selective light absorbing layer, a polarizing layer, a quantum dot-containing layer, and/or the like), a light-blocking member (for example, a light reflective layer, a light absorbing layer, and/or the like), and/or a protective member (for example, an insulating layer, a dielectric layer, and/or the like).

### Electronic Apparatus

The light-emitting device may be included in one or more suitable electronic apparatuses. In an embodiment, the electronic apparatus including the light-emitting device may be a light-emitting apparatus, an authentication apparatus, and/or the like.

The electronic apparatus (for example, a light-emitting apparatus) may further include, in addition to the light-emitting device, i) a color filter, ii) a color-conversion layer, or iii) a color filter and a color-conversion layer. The color filter and/or the color-conversion layer may be located in at least one traveling direction of light emitted from the light-emitting device. In an embodiment, the light emitted from the light-emitting device may be blue light or white light. The light-emitting device may be the same as described above. In an embodiment, the color-conversion layer may include quantum dots. The quantum dot may be, for example, a quantum dot as described herein.

The electronic apparatus may include a first substrate. The first substrate may include a plurality of subpixel areas, the color filter may include a plurality of color filter areas respectively corresponding to the plurality of subpixel areas, and the color-conversion layer may include a plurality of color-conversion areas respectively corresponding to the plurality of subpixel areas.

A pixel-defining layer may be located among the plurality of subpixel areas to define each of the subpixel areas.

The color filter may further include a plurality of color filter areas and light-shielding patterns located among the plurality of color filter areas, and the color-conversion layer may include a plurality of color-conversion areas and light-shielding patterns located among the plurality of color-conversion areas.

The plurality of color filter areas (or the plurality of color-conversion areas) may include a first area emitting a first color light, a second area emitting a second color light, and/or a third area emitting a third color light, and the first color light, the second color light, and/or the third color light may have different maximum emission wavelengths from one another. In an embodiment, the first color light may be red light, the second color light may be green light, and the third color light may be blue light. In an embodiment, the plurality of color filter areas (or the plurality of color-conversion areas) may include quantum dots. In an embodiment, the first area may include a red quantum dot, the second area may include a green quantum dot, and the third area may not include (e.g., may exclude) any quantum dot. The quantum dot may be the same as described in the present specification. The first area, the second area, and/or the third area may each further include a scatterer.

In an embodiment, the light-emitting device may be to emit a first light, the first area may be to absorb the first light to emit a first first-color light, the second area may be to absorb the first light to emit a second first-color light, and the third area may be to absorb the first light to emit a third first-color light. In this regard, the first first-color light, the second first-color light, and the third first-color light may each have different maximum emission wavelengths. In an embodiment, the first light may be blue light, the first first-color light may be red light, the second first-color light may be green light, and the third first-color light may be blue light.

The electronic apparatus may further include a thin-film transistor in addition to the light-emitting device as described above. The thin-film transistor may include a source electrode, a drain electrode, and an activation layer, wherein the source electrode or the drain electrode may be electrically connected to the first electrode or the second electrode of the light-emitting device.

The thin-film transistor may further include a gate electrode, a gate insulating film, etc.

The activation layer may include a crystalline silicon, an amorphous silicon, an organic semiconductor, an oxide semiconductor, and/or the like.

The electronic apparatus may further include a sealing portion for sealing the light-emitting device. The sealing portion may be located between the color filter and/or the color-conversion layer and the light-emitting device. The sealing portion allows light from the light-emitting device to be extracted to the outside, while concurrently (e.g., simultaneously) preventing or reducing penetration of ambient air and/or moisture into the light-emitting device. The sealing portion may be a sealing substrate including a transparent glass substrate and/or a plastic substrate. The sealing portion may be a thin-film encapsulation layer including at least one layer of an organic layer and/or an inorganic layer. When the sealing portion is a thin film encapsulation layer, the electronic apparatus may be flexible.

Various suitable functional layers may be additionally located on the sealing portion, in addition to the color filter and/or the color-conversion layer, according to the intended usage of the electronic apparatus. The functional layers may include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus that authenticates an individual by utilizing biometric information of a living body (for example, fingertips, pupils, etc.).

The authentication apparatus may further include, in addition to the light-emitting device, a biometric information collector.

The electronic apparatus may be applied to one or more suitable displays, light sources, lighting apparatuses, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, one or more suitable measuring instruments, meters (for example, meters for a vehicle, an aircraft, and/or a vessel), projectors, and/or the like.

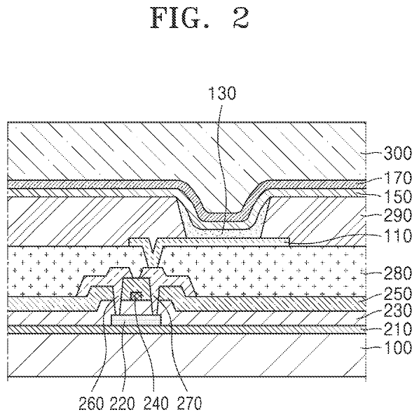

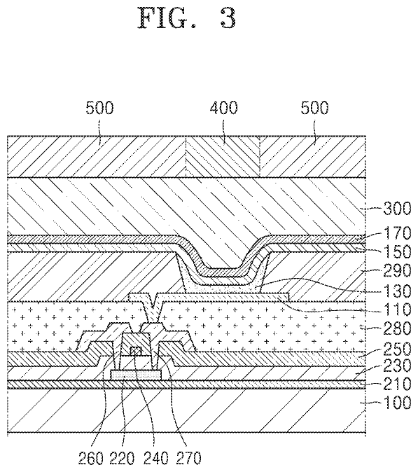

### Description of FIGS. 2 and 3

FIG. 2 is a cross-sectional view of a light-emitting apparatus according to an embodiment of the present disclosure.

The light-emitting apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, and/or a metal substrate. A buffer layer 210 may be formed on the substrate 100. The buffer layer 210 may prevent or reduce penetration of impurities through the substrate 100 and may provide a flat surface on the substrate 100.

A TFT may be located on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, and/or an oxide semiconductor, and may include a source region, a drain region and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240. The interlayer insulating film 250 may be placed between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be in contact with the exposed portions of the source region and the drain region of the activation layer 220.

The TFT is electrically connected to a light-emitting device to drive the light-emitting device, and is covered by a passivation layer 280. The passivation layer 280 may include an inorganic insulating film, an organic insulating film, or any combination thereof. A light-emitting device may be provided on the passivation layer 280. The light-emitting device may include a first electrode 110, an interlayer 130, and a second electrode 150.

The first electrode 110 may be formed on the passivation layer 280. The passivation layer 280 may not completely cover the drain electrode 270 and may expose a portion of the drain electrode 270, and the first electrode 110 may be connected to the exposed portion of the drain electrode 270.

A pixel-defining layer 290 containing an insulating material may be located on the first electrode 110. The pixel-defining layer 290 may expose a region of the first electrode 110, and an interlayer 130 may be formed in the exposed region of the first electrode 110. The pixel-defining layer 290 may be a polyimide or polyacrylic organic film. In one embodiment, one or more layers of the interlayer 130 may extend beyond the upper portion of the pixel-defining layer 290 in the form of a common layer.

The second electrode 150 may be located on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be located on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, and/or the like), an epoxy-based resin (for example, aliphatic glycidyl ether (AGE), and/or the like), or any combination thereof; or a combination of the inorganic film and the organic film.

FIG. 3 is a cross-sectional view of a light-emitting apparatus according to another embodiment of the present disclosure.

The light-emitting apparatus of FIG. 3 is the same as the light-emitting apparatus of FIG. 2, except that a light-shielding pattern 500 and a functional region 400 are additionally arranged on the encapsulation portion 300. The functional region 400 may be a combination of i) a color filter area, ii) a color-conversion area, or iii) a combination of the color filter area and the color-conversion area. In an embodiment, the light-emitting device included in the light-emitting apparatus of FIG. 3 may be a tandem light-emitting device.

### Manufacture Method

Respective layers included in the hole transport region, the emission layer, and respective layers included in the electron transport region may be formed in a certain region by utilizing one or more suitable methods selected from vacuum deposition, spin coating, casting, Langmuir-Blodgett (LB) deposition, ink-jet printing, laser-printing, and laser-induced thermal imaging.

When layers constituting the hole transport region, the emission layer, and layers constituting the electron transport region are formed by vacuum deposition, the vacuum deposition may be performed at a deposition temperature of about 100° C. to about 500° C., a vacuum degree of about 10-8 torr to about 10⁻³ torr, and a deposition speed of about 0.01 Å/sec to about 100 Å/sec, depending on a material to be included in a layer to be formed and the structure of a layer to be formed.

### Definition of Terms

The term “C₃-C₆₀ carbocyclic group” as utilized herein refers to a cyclic group consisting of only carbon atoms as ring-forming atoms and having three to sixty carbon atoms, and the term “C₁-C₆₀ heterocyclic group” as utilized herein refers to a cyclic group that has, in addition to one to sixty carbon atoms, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. In an embodiment, the C₁-C₆₀ heterocyclic group has 3 to 61 ring-forming atoms.

The term “cyclic group” as utilized herein may include the C₃-C₆₀ carbocyclic group and the C₁-C₆₀ heterocyclic group.

The term “π electron-rich C₃-C₆₀ cyclic group” as utilized herein refers to a cyclic group that has three to sixty carbon atoms and does not include *—N═*′ as a ring-forming moiety, and the term “π electron-deficient nitrogen-containing C₁-C₆₀ cyclic group” as utilized herein refers to a heterocyclic group that has one to sixty carbon atoms and includes *—N═*′ as a ring-forming moiety.

In an embodiment,
the C₃-C₆₀ carbocyclic group may be i) a group T₁ or ii) a condensed cyclic group in which two or more groups T₁ are condensed with each other (for example, the C₃-C₆₀ carbocyclic group may be a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) a group T2, ii) a condensed cyclic group in which two or more groups T₂ are condensed with each other, or iii) a condensed cyclic group in which at least one group T2 and at least one group T1 are condensed with each other (for example, the C₁-C₆₀ heterocyclic group may be a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the π electron-rich C₃-C₆₀ cyclic group may be i) a group T₁, ii) a condensed cyclic group in which two or more groups T₁ are condensed with each other, iii) a group T₃, iv) a condensed cyclic group in which two or more groups T₃ are condensed with each other, or v) a condensed cyclic group in which at least one group T₃ and at least one group T₁ are condensed with each other (for example, the π electron-rich C₃-C₆₀ cyclic group may be the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.), and
the π electron-deficient nitrogen-containing C₁-C₆₀ cyclic group may be i) a group T4, ii) a condensed cyclic group in which two or more group T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with one another (for example, the π electron-deficient nitrogen-containing C₁-C₆₀ cyclic group may be a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),
the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,
the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the group T3 may be a furan group, a thiophene group, a 1H-pyrrole group, a silole group, or a borole group, and
the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as utilized herein refers to a group condensed to any cyclic group, a monovalent group, or a polyvalent group (for example, a divalent group, a trivalent group, a tetravalent group, etc.), depending on the structure of a formula in connection with which the terms are utilized. In an embodiment, “a benzene group” may be a benzo group, a phenyl group, a phenylene group, and/or the like, which may be easily understood by one of ordinary skill in the art according to the structure of a formula including the “benzene group.”

In an embodiment, examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of a divalent C₃-C₆₀ carbocyclic group and a divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as utilized herein refers to a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as utilized herein refers to a divalent group having substantially the same structure as the C₁-C₆₀ alkyl group.

The term “C₂-C₆₀ alkenyl group” as utilized herein refers to a monovalent hydrocarbon group having at least one carbon-carbon double bond at a main chain (e.g., in the middle) and/or at a terminal end (e.g., the terminus) of the C₂-C₆₀ alkyl group, and examples thereof may include an ethenyl group, a propenyl group, and a butenyl group. The term “C₂-C₆₀ alkenylene group” as utilized herein refers to a divalent group having substantially the same structure as the C₂-C₆₀ alkenyl group.

The term “C₂-C₆₀ alkynyl group” as utilized herein refers to a monovalent hydrocarbon group having at least one carbon-carbon triple bond at a main chain (e.g., in the middle) and/or at a terminal end (e.g., the terminus) of the C₂-C₆₀ alkyl group, and examples thereof may include an ethynyl group and a propynyl group. The term “C₂-C₆₀ alkynylene group” as utilized herein refers to a divalent group having substantially the same structure as the C₂-C₆₀ alkynyl group.

The term “C₁-C₆₀ alkoxy group” as utilized herein refers to a monovalent group represented by —OA₁₀₁ (wherein A₁₁ is the C₁-C₆₀ alkyl group), and examples thereof may include a methoxy group, an ethoxy group, and an isopropyloxy group.

The term “C₃-C₁₀ cycloalkyl group” as utilized herein refers to a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as utilized herein refers to a divalent group having substantially the same structure as the C₃-C₁₀ cycloalkyl group.

The term “C₁-C₁₀ heterocycloalkyl group” as utilized herein refers to a monovalent saturated monocyclic group that further includes, in addition to 1 to 10 carbon atom(s), at least one heteroatom as a ring-forming atom, and examples thereof may include a 1,2,3,4-oxatriazolidinyl group, a tetrahydrofuranyl group, and a tetrahydrothiophenyl group. The term “C₁-C₁₀ heterocycloalkylene group” as utilized herein refers to a divalent group having substantially the same structure as the C₁-C₁₀ heterocycloalkyl group.

The term “C₃-C₁₀ cycloalkenyl group” utilized herein refers to a monovalent cyclic group that has three to ten carbon atoms and at least one carbon-carbon double bond in the ring thereof and no aromaticity, and examples thereof may include a cyclopentenyl group, a cyclohexenyl group, and a cycloheptenyl group. The term “C₃-C₁₀ cycloalkenylene group” as utilized herein refers to a divalent group having substantially the same structure as the C₃-C₁₀ cycloalkenyl group.

The term “C₁-C₁₀ heterocycloalkenyl group” as utilized herein refers to a monovalent cyclic group that has, in addition to 1 to 10 carbon atoms, at least one heteroatom as a ring-forming atom, and at least one carbon-carbon double bond in the cyclic structure thereof. Examples of the C₁-C₁₀ heterocycloalkenyl group may include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as utilized herein refers to a divalent group having substantially the same structure as the C₁-C₁₀ heterocycloalkenyl group.

The term “C₆-C₆₀ aryl group” as utilized herein refers to a monovalent group having a carbocyclic aromatic system having six to sixty carbon atoms, and the term “C₆-C₆ arylene group” as utilized herein refers to a divalent group having a carbocyclic aromatic system having six to sixty carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, a fluorenyl group, and an ovalenyl group. When the C₆-C₆₀ aryl group and the C₆-C₆₀ arylene group each include two or more rings, the two or more rings may be condensed with each other.

The term “C₁-C₆₀ heteroaryl group” as utilized herein refers to a monovalent group having a heterocyclic aromatic system that has, in addition to 1 to 60 carbon atoms, at least one heteroatom as a ring-forming atom. The term “C₁-C₆₀ heteroarylene group” as utilized herein refers to a divalent group having a heterocyclic aromatic system that has, in addition to 1 to 60 carbon atoms, at least one heteroatom as a ring-forming atom. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, a carbazolyl group, a dibenzofuranyl group, a dibenzothiofuranyl group, and a naphthyridinyl group. When the C₁-C₆₀ heteroaryl group and the C₁-C₆₀ heteroarylene group each include two or more rings, the two or more rings may be condensed with each other.

The term “monovalent non-aromatic condensed polycyclic group” as utilized herein refers to a monovalent group having two or more rings condensed to each other, only carbon atoms (for example, having 8 to 60 carbon atoms) as ring-forming atoms, and non-aromaticity in its molecular structure when considered as a whole. Examples of the monovalent non-aromatic condensed polycyclic group may include an indenyl group, a fluorenyl group, a spiro-bifluorenyl group, a benzofluorenyl group, an indenophenanthrenyl group, an adamantyl group, and an indeno anthracenyl group. The term “divalent non-aromatic condensed polycyclic group” as utilized herein refers to a divalent group having substantially the same structure as the monovalent non-aromatic condensed polycyclic group.

The term “monovalent non-aromatic condensed heteropolycyclic group” as utilized herein refers to a monovalent group having two or more rings condensed to each other, at least one heteroatom other than 1 to 60 carbon atoms as a ring-forming atom, and non-aromaticity in its molecular structure when considered as a whole. Examples of the monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, an azaadamantyl group, and a benzothienodibenzothiophenyl group. The term “divalent non-aromatic condensed heteropolycyclic group” as utilized herein refers to a divalent group having substantially the same structure as the monovalent non-aromatic condensed heteropolycyclic group.

The term “C₆-C₆₀ aryloxy group” as utilized herein refers to a monovalent group represented by —OA₁₀₂ (wherein A₁₀₂ is the C₆-C₆₀ aryl group), and the term “C₆-C₆₀ arylthio group” as utilized herein refers to a monovalent group represented by —SA₁₀₃ (wherein A₁₀₃ is the C₆-C₆₀ aryl group).

The term “C₇-C₆₀ aryl alkyl group” utilized herein refers to a monovalent group represented by -A₁₀₄A₁₀₅ (where A₁₀₄ may be a C₁-C₅₄ alkylene group, and A₁₀₅ may be a C₆-C₅₉ aryl group), and the term “C₂-C₆ heteroaryl alkyl group” utilized herein refers to a monovalent group represented by -A₁₀₆A₁₀₇ (where A₁₀₆ may be a C₁-C₅₉ alkylene group, and A₁₀₇ may be a C₁-C₅₉ heteroaryl group).
R₁₀ₐ may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₀₆ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ aryl alkyl group, or a C₂-C₆₀ heteroaryl alkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “hetero atom” as utilized herein refers to any atom other than a carbon atom. Examples of the heteroatom may include O, S, N, P, Si, B, Ge, Se, or any combination thereof.

The term “the third-row transition metal” as utilized herein includes hafnium (Hf), tantalum (Ta), tungsten (W), rhenium (Re), osmium (Os), iridium (Ir), platinum (Pt), gold (Au), and/or the like.

The term “Ph” as utilized herein refers to a phenyl group, the term “Me” as utilized herein refers to a methyl group, the term “Et” as utilized herein refers to an ethyl group, the term “tert-Bu” or “Bu^{t}” as utilized herein refers to a tert-butyl group, and the term “OMe” as utilized herein refers to a methoxy group.

The term “biphenyl group” as utilized herein refers to “a phenyl group substituted with a phenyl group.” In other words, the “biphenyl group” is a substituted phenyl group having a C₆-C₆₀ aryl group as a substituent.

The term “terphenyl group” as utilized herein refers to “a phenyl group substituted with a biphenyl group”. The “terphenyl group” is a substituted phenyl group having, as a substituent, a C₆-C₆₀ aryl group substituted with a C₆-C₆₀ aryl group.

* and *′ as utilized herein, unless defined otherwise, each refer to a binding site to a neighboring atom in a corresponding formula or moiety.

Hereinafter, a compound and light-emitting device according to an embodiment of the present disclosure will be described in more detail with reference to the following Synthesis example and Examples. The expression “B was utilized instead of A,” utilized in describing Synthesis Examples, indicates that an identical molar equivalent of B was utilized in place of A.

### EXAMPLES

### Synthesis Example 1: Synthesis of Compound 6

Compound 6 according to an embodiment may be synthesized according to, for example, Reaction Scheme 1.

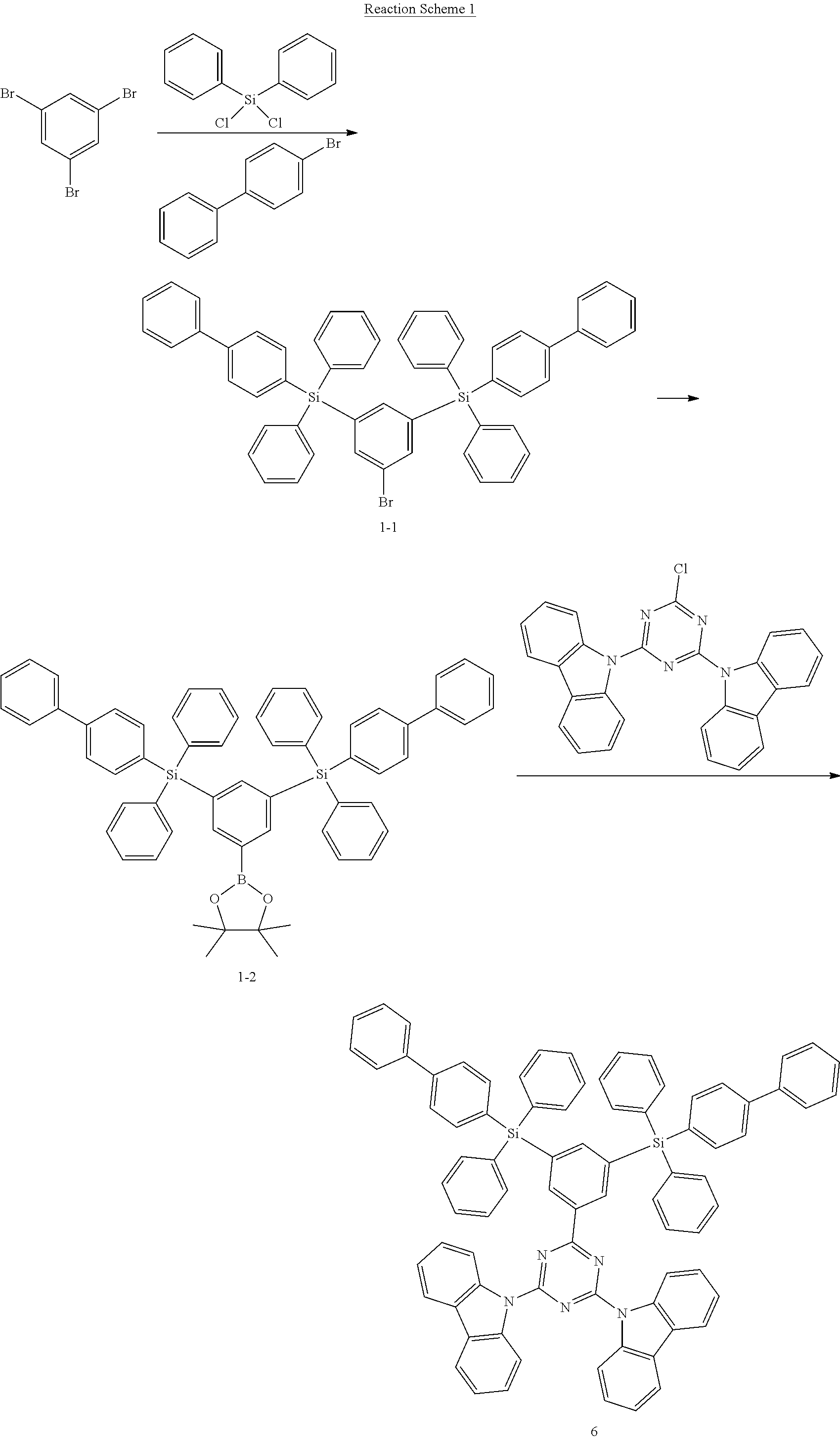

### 1) Synthesis of Intermediate 1-1

1,3,5-tribromobenzene (1 eq), 4-bromo-1,1′-biphenyl (2 eq), and dichlorodiphenylsilane (2 eq) were reacted in the presence of n-BuLi (4 eq) to obtain Intermediate 1-1. Intermediate 1-1 was confirmed by LC/MS.

C₅₄H41BrSi2 M+1: 825.27

### 2) Synthesis of Intermediate 1-2

Intermediate 1-1 (1 eq) and bispinacolatodiboron (1.5 eq) were reacted in the presence of Pd₂dba₃ (0.1 eq) to obtain Intermediate 1-2. Intermediate 1-2 was confirmed by LC/MS.

C₆₀H53BO2Si2 M+1: 874.15

### 3) Synthesis of Compound 6

2.15 g of Intermediate 1-2, 1 g of 9,9′-(6-chloro-1,3,5-triazine-2,4-diyl)bis(9H-carbazole), 0.62 g of potassium carbonate, and 0.11 g of tetrakis(triphenylphosphine)palladium(0) were added to RB and then dissolved in 24 mL of THF and 6 mL of DW, followed by refluxing for 12 hours. After the reaction is completed, the reaction solution was extracted by utilizing ethylacetate to collect an organic layer. The organic layer was dried by utilizing magnesium sulfate to obtain a residue. The residue was separated and purified by silica gel column chromatography to obtain 2.26 g (yield: 87%) of Compound 6. Compound 6 was confirmed by LC-MS and 1H-NMR.

C₈₁H57N5Si2 M+1: 1156.48

### Synthesis Example 2: Synthesis of Compound 9

Compound 9 according to an embodiment may be synthesized according to, for example, Reaction Scheme 2.

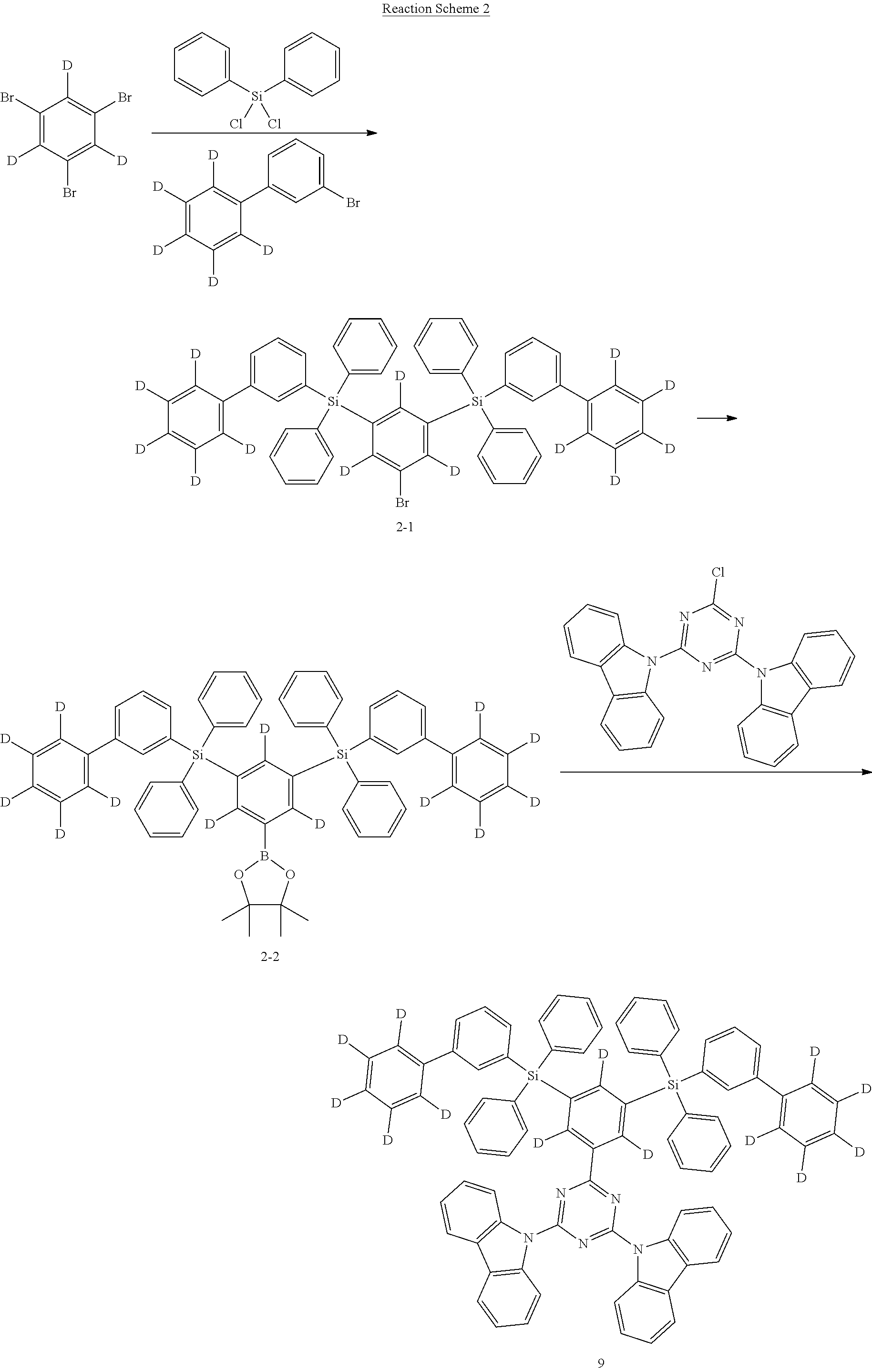

### 1) Synthesis of Intermediate 2-1

1,3,5-tribromobenzene-2,4,6-d₃ (1 eq), 3-bromo-1,1′-biphenyl-2′,3′,4′,5′,6′-d₅ (CAS No.: 51624-39-6) (2 eq), and dichlorodiphenylsilane (2 eq) were reacted in the presence of n-BuLi (4 eq) to obtain Intermediate 2-1. Intermediate 2-1 was identified by LC/MS.

C₅₄H28D13BrSi2 M+1: 838.51

### 2) Synthesis of Intermediate 2-2

Intermediate 2-1 (1 eq) and bispinacolatodiboron (1.5 eq) were reacted in the presence of Pd₂dba₃ (0.1 eq) to obtain Intermediate 2-2. Intermediate 2-2 was confirmed by LC/MS.

C₆₀H40D13BO2Si2 M+1: 886.63

### 3) Synthesis of Compound 9

2.19 g of Intermediate 2-2, 1 g of 9,9′-(6-chloro-1,3,5-triazine-2,4-diyl)bis(9H-carbazole), 0.62 g of potassium carbonate, and 0.11 g of tetrakis(triphenylphosphine)palladium(0) were added to RB and then dissolved in 24 mL of THF and 6 mL of DW, followed by refluxing for 12 hours. After the reaction is completed, the reaction solution was extracted by utilizing ethylacetate to collect an organic layer. The organic layer was dried by utilizing magnesium sulfate to obtain a residue. The residue was separated and purified by silica gel column chromatography to obtain 2.12 g (yield: 81%) of Compound 9. Compound 9 was confirmed by LC-MS and 1H-NMR.

C₈₁H44D13N5Si2 M+1: 1169.79

### Synthesis Example 3: Synthesis of Compound 22

Compound 22 according to an embodiment may be synthesized according to, for example, Reaction Scheme 3.

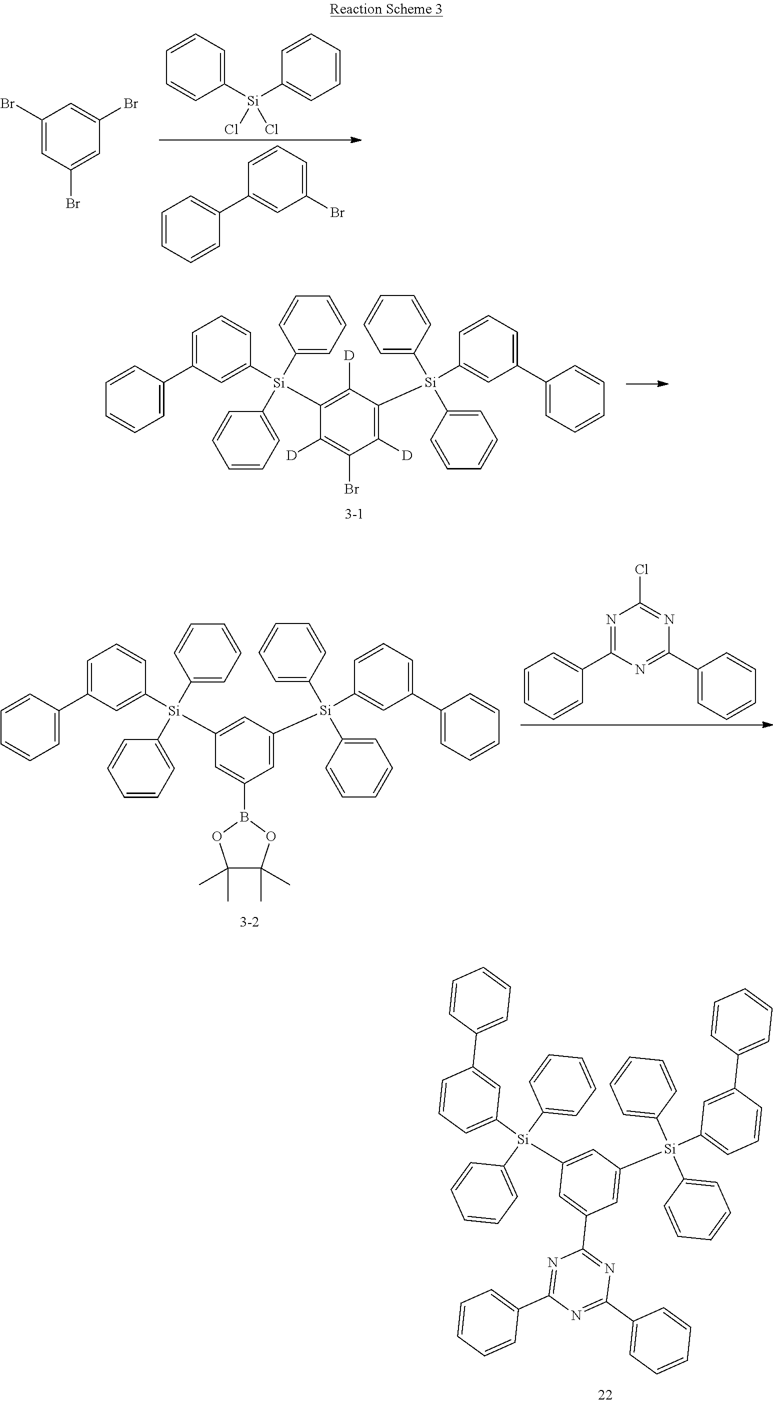

### 1) Synthesis of Intermediate 3-1

1,3,5-tribromobenzene-2,4,6-d₃ (1 eq), 3-bromo-1,1′-biphenyl (2 eq), and dichlorodiphenylsilane (2 eq) were reacted in the presence of n-BuLi (4 eq) to obtain Intermediate 3-1. Intermediate 3-1 was identified by LC/MS.

C₅₄H38D3BrSi2 M+1: 828.30

### 2) Synthesis of Intermediate 3-2

Intermediate 3-1 (1 eq) and bispinacolatodiboron (1.5 eq) were reacted in the presence of Pd₂dba₃ (0.1 eq) to obtain Intermediate 3-2. Intermediate 3-2 was confirmed by LC/MS.

C₆₀H53BO2Si2 M+1: 873.44

### 3) Synthesis of Compound 22

3.59 g of Intermediate 3-2, 1 g of 2-chloro-4,6-diphenyl-1,3,5-triazine, 1.03 g of potassium carbonate, and 0.19 g of tetrakis(triphenylphosphine)palladium(0) were added to RB and then dissolved in 40 mL of THF and 10 mL of DW, followed by refluxing for 12 hours. After the reaction is completed, the reaction solution was extracted by utilizing ethylacetate to collect an organic layer. The organic layer was dried by utilizing magnesium sulfate to obtain a residue. The residue was separated and purified by silica gel column chromatography to obtain 3.18 g (yield: 87%) of Compound 22. Compound 22 was confirmed by LC-MS and 1H-NMR.

C₆₉H51N3Si2 M+1: 978.59

### Synthesis Example 4: Synthesis of Compound 126

Compound 126 according to an embodiment may be synthesized according to, for example, Reaction Scheme 4.

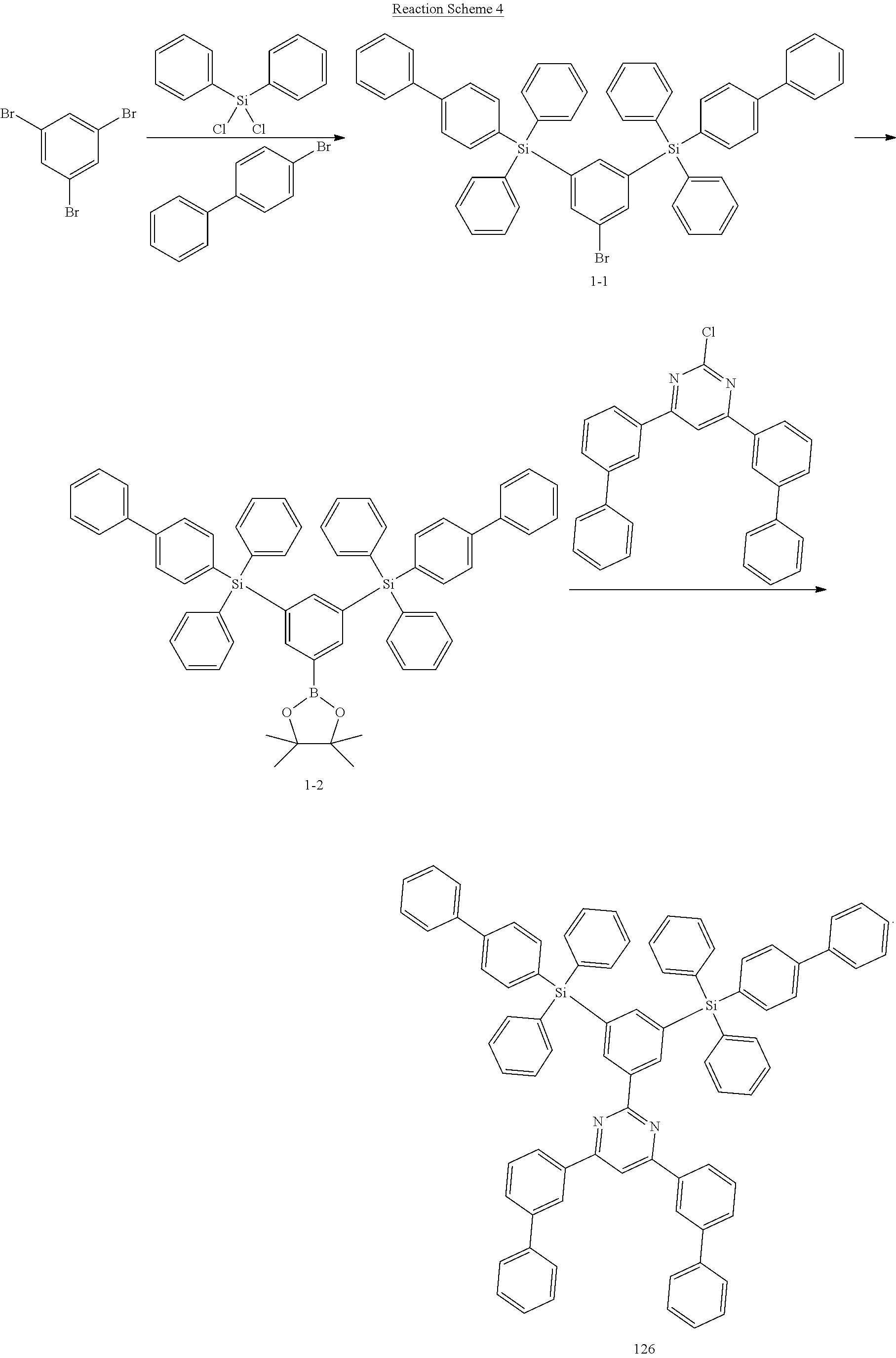

2.29 g of Intermediate 1-2, 1 g of 4,6-di([1,1′-biphenyl]-3-yl)-2-chloropyrimidine (CAS No.: 1384480-16-3), 0.66 g of potassium carbonate, and 0.12 g of tetrakis(triphenylphosphine)palladium(0) were added to RB and then dissolved in 24 mL of THF and 6 mL of DW, followed by refluxing for 12 hours. After the reaction is completed, the reaction solution was extracted by utilizing ethylacetate to collect an organic layer. The organic layer was dried by utilizing magnesium sulfate to obtain a residue. The residue was separated and purified by silica gel column chromatography to obtain 1.94 g (yield: 72%) of Compound 126. Compound 126 was confirmed by LC-MS and 1H-NMR.

C₈₂H60N2Si2 M+1: 1129.54

### Synthesis Example 5: Synthesis of Compound 129

Compound 129 according to an embodiment may be synthesized according to, for example, Reaction Scheme 5.

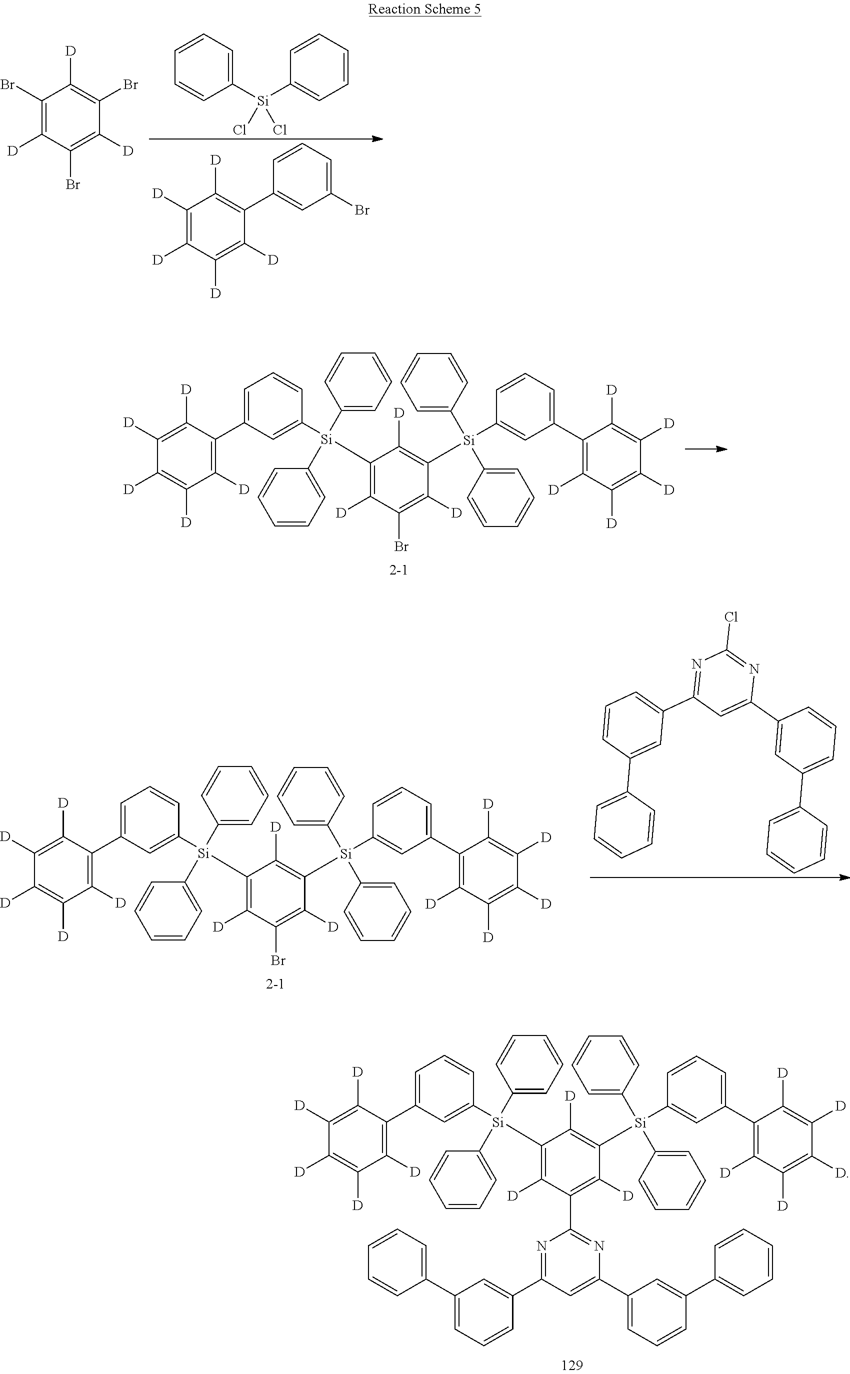

2.33 g of Intermediate 2-2, 1 g of 4,6-di([1,1′-biphenyl]-3-yl)-2-chloropyrimidine (CAS No.: 1384480-16-3), 0.66 g of potassium carbonate, and 0.12 g of tetrakis(triphenylphosphine)palladium(0) were added to RB and then dissolved in 24 mL of THF and 6 mL of DW, followed by refluxing for 12 hours. After the reaction is completed, the reaction solution was extracted by utilizing ethylacetate to collect an organic layer. The organic layer was dried by utilizing magnesium sulfate to obtain a residue. The residue was separated and purified by silica gel column chromatography to obtain 1.96 g (yield: 72%) of Compound 129. Compound 129 was confirmed by LC-MS and 1H-NMR.

C₈₂H47D13N2Si2 M+1: 1142.75

### Synthesis Example 6: Synthesis of Compound 156

Compound 156 according to an embodiment may be synthesized according to, for example, Reaction Scheme 6.

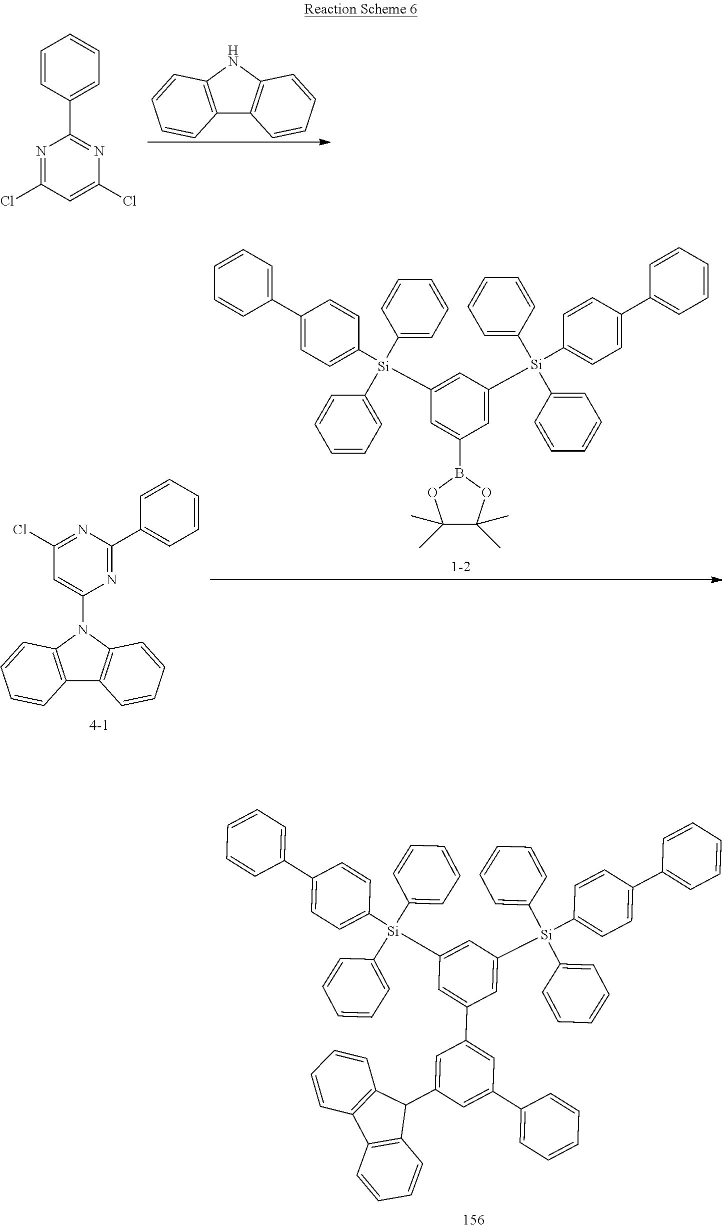 [SMILES: Clc1cc(Cl)nc(-c2ccccc2)n1 ; c1ccc2c(c1)[nH]c1ccccc12 ; Clc1cc(-n2c3ccccc3c3ccccc32)nc(-c2ccccc2)n1 ; CC1(C)OB(c2cc([Si](c3ccccc3)(c3ccccc3)c3ccc(-c4ccccc4)cc3)cc([Si](c3ccccc3)(c3ccccc3)c3ccc(-c4ccccc4)cc3)c2)OC1(C)C ; c1ccc(-c2ccc([Si](c3ccccc3)(c3ccccc3)c3cc(-c4cc(-c5ccccc5)cc(C5c6ccccc6-c6ccccc65)c4)cc([Si](c4ccccc4)(c4ccccc4)c4ccc(-c5ccccc5)cc4)c3)cc2)cc1]

### 1) Synthesis of Intermediate 4-1

4,6-dichloro-2-phenylpyrimidine (GAS No.: 3740-92-9) (1 eq) and 9H-carbazole (0.9 eq) were reacted in the presence of Pd₂dba₃ (0.1 eq) to obtain Intermediate 4-1. Intermediate 4-1 was confirmed by LC/MS.

C₂₂H14ClN3M+1: 356.90

### 2) Synthesis of Compound 156

1 g of Intermediate 4-1, 2.7 g of Intermediate 1-2, 0.78 g of potassium carbonate, and 0.14 g of tetrakis(triphenylphosphine)palladium(0) were added to RB and then dissolved in 28 mL of THF and 7 mL of DW, followed by refluxing for 12 hours. After the reaction is completed, the reaction solution was extracted by utilizing ethylacetate to collect an organic layer. The organic layer was dried by utilizing magnesium sulfate to obtain a residue. The residue was separated and purified by silica gel column chromatography to obtain 2.22 g (yield: 74%) of Compound 156. Compound 156 was confirmed by LC-MS and 1H-NMR.

C₇₆H55N3Si2 M+1: 1066.82

### Synthesis Example 7: Synthesis of Compound 189

Compound 189 according to an embodiment may be synthesized according to, for example, Reaction Scheme 7.

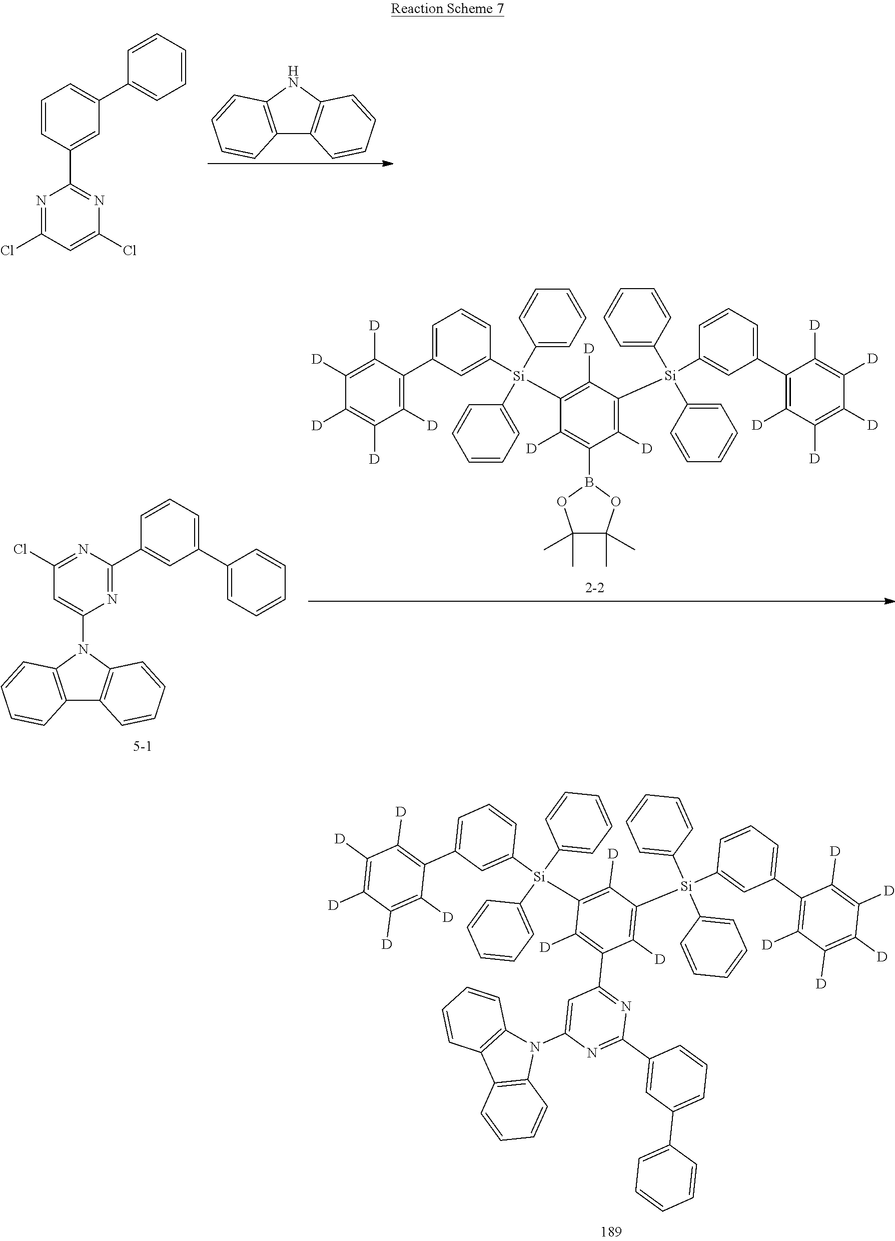

### 1) Synthesis of Intermediate 5-1

2-([1,1′-biphenyl]-3-yl)-4,6-dichloropyrimidine (CAS No.: 2414988-40-0) (1 eq) and 9H-carbazole (0.9 eq) were reacted in the presence of Pd₂dba₃ (0.1 eq) to obtain Intermediate 5-1. Intermediate 5-1 was confirmed by LC/MS.

C₂₈H18ClN3 M+1: 432.29

### 2) Synthesis of Compound 189

1 g of Intermediate 5-1, 2.26 g of Intermediate 2-1, 0.64 g of potassium carbonate, and 0.12 g of tetrakis(triphenylphosphine)palladium(0) were added to RB and then dissolved in 28 mL of THF and 7 mL of DW, followed by refluxing for 12 hours. After the reaction is completed, the reaction solution was extracted by utilizing ethylacetate to collect an organic layer. The organic layer was dried by utilizing magnesium sulfate to obtain a residue. The residue was separated and purified by silica gel column chromatography to obtain 2.01 g (yield: 75%) of Compound 189. Compound 189 was confirmed by LC-MS and 1H-NMR.

C₈₂H46D13N3Si2 M+1: 1155.63

1H-NMR and MS observation data of Compounds 6, 9, 22, 126, 129, 156, and 189 synthesized as described above are shown in Table 1.

TABLE 1

| Measured | | MS/FAB | |
|---|---|---|---|
| compound | H NMR (δ) | Calc. | Found |
| Compound | 8.55(d, 2H), 8.19(d, 2H), 7.94-7.35(m, | 1155.42 | 1156.48 |
| 6 | 49H), 7.20-7.16(t, 4H) | | |
| Compound | 8.55(d, 2H), 8.19(d, 2H), 7.94-7.88(m, | 1168.50 | 1169.79 |
| 9 | 4H), 7.64-7.35(m, 32H), 7.20-7.16(t, | | |
| | 4H) | | |
| Compound | 8.36(d, 4H), 7.98(s, 2H), 7.92(s, 1H), | 977.36 | 978.59 |
| 22 | 7.88(s, 2H), 7.75(d, 4H), 7.64-7.38(m, | | |
| | 38H) | | |
| Compound | 8.23(s, 1H), 7.94-7.38(m, 59H) | 1128.43 | 1129.54 |
| 126 | | | |
| Compound | 8.23(s, 1H), 7.94-7.88(m, 6H), 7.75- | 1141.51 | 1142.75 |
| 129 | 7.38(m, 40H) | | |
| Compound | 8.55(d, 1H), 8.19(d, 3H), 7.98-7.16(m, | 1065.39 | 1066.82 |
| 156 | 51H) | | |
| Compound | 8.55(d, 1H), 8.38(d, 1H), 8.19(d, 1H), | 1154.51 | 1155.63 |
| 189 | 7.94-7.16(m, 43H) | | |

### Example 1

As an anode, ITO-deposited substrate was cut to a size of 50 mm×50 mm×0.7 mm, sonicated by utilizing isopropyl alcohol and pure water for 5 minutes each, and then washed by irradiation of ultraviolet rays and exposure of ozone thereto for 30 minutes, and the substrate was loaded onto a vacuum deposition apparatus.

N,N′-di(1-naphthyl)-N,N′-diphenylbenzidine (NPB) was vacuum-deposited on the ITO substrate to form a hole injection layer having a thickness of 300 Å, and 1,3-di-9-carbazolylbenzene (mCP) was vacuum-deposited on the hole injection layer to form a hole transport layer having a thickness of 200 Å.

Compound 6 and Ir(pmp)₃, which is a suitable compound as a blue phosphorescent dopant, were co-deposited on the hole transport layer at a weight ratio of 92:8 to form an emission layer having a thickness of 250 Å.

3-(4-biphenylyl)-4-phenyl-5-tert-butylphenyl-1,2,4-triazole (TAZ) was deposited on the emission layer to form an electron transport layer having a thickness of 200 Å, and LiF, which is a halogenated alkaline metal, was deposited on the electron transport layer to a thickness of 10 Å, and Al was vacuum-deposited thereon to a thickness of 100 Å, to thereby form a LiF/AI cathode electrode, thereby completing manufacture of a light-emitting device.

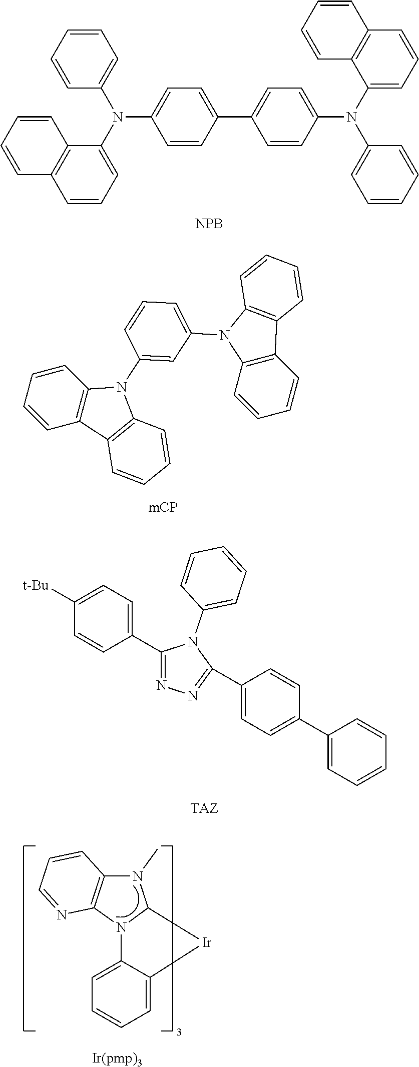

### Examples 2 to 7

Light-emitting devices were manufactured in substantially the same manner as in Example 1, except that the host of the emission layer was changed as shown in Table 4.

### Comparative Examples 1 to 2

Light-emitting devices were manufactured in substantially the same manner as in Example 1, except that the host of the emission layer was changed as shown in Table 4.

### Evaluation Example 1

Each of light-emitting devices manufactured according to Examples 1 to 7 and Comparative Examples 1 and 2 had a voltage supplied to have a current density of 10 mA/cm². Driving voltage (V), luminance (cd/m²), luminescence efficiency (cd/A), maximum quantum efficiency (%), T₁ (eV), and emission color were measured. The driving voltage and current density were measured by utilizing a source meter (Keithley Instrument, 2400 series), and the maximum quantum efficiency was measured by utilizing an external quantum efficiency measurement apparatus 09920-2-12 of Hamamatsu Photonics Inc. In evaluating the maximum quantum efficiency, the luminance/current density was measured utilizing a luminance meter that was calibrated for wavelength sensitivity, and the maximum quantum efficiency was converted by assuming an angular luminance distribution (Lambertian) which introduced a perfect reflecting diffuser. The results are shown in Table 2.

TABLE 2

| | | | | | Maximum | | |
|---|---|---|---|---|---|---|---|
| | | | Driving | | quantum | | |
| | | Host of | voltage | Efficiency | efficiency | | Emission |
| | | emission layer | (V) | (cd/A) | (%) | T₁ (eV) | color |
| Example | 1 | Compound 6 | 4.8 | 19.2 | 28.0 | 3.04 | Blue |
| | 2 | Compound 9 | 4.6 | 20.1 | 29.3 | 3.03 | Blue |
| | 3 | Compound 22 | 4.3 | 18.9 | 28.4 | 3.00 | Blue |
| | 4 | Compound 126 | 4.5 | 18.5 | 28.1 | 3.02 | Blue |
| | 5 | Compound | 4.4 | 19.6 | 29.2 | 3.01 | Blue |
| | | 129 | | | | | |
| | 6 | Compound | 4.2 | 18.8 | 28.8 | 3.03 | Blue |
| | | 156 | | | | | |
| | 7 | Compound | 4.4 | 19.3 | 29.2 | 3.01 | Blue |
| | | 189 | | | | | |
| Comparative | 1 | Comparative | 5.8 | 15.2 | 26.2 | 2.82 | Blue |
| Example | | Compound 1 | | | | | |
| | 2 | Comparative | 5.4 | 18.0 | 27.9 | 3.01 | Blue |
| | | Compound 2 | | | | | |

### 1) Structure Formula of Comparative Compound 1

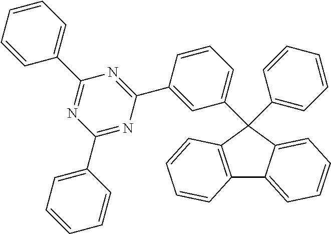 [SMILES: c1ccc(-c2nc(-c3ccccc3)nc(-c3cccc(C4(c5ccccc5)c5ccccc5-c5ccccc54)c3)n2)cc1]

### 2) Structure Formula of Comparative Compound 2

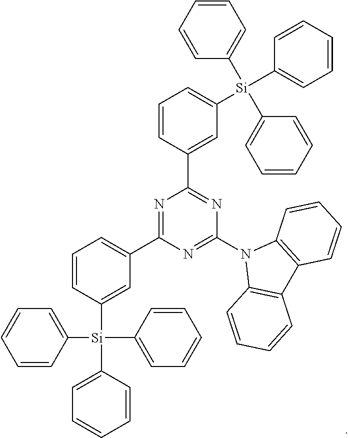 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1]

From Table 4, it may be confirmed that the light-emitting device according to each Example had excellent or suitable characteristics in terms of driving voltage (V), efficiency (cd/A), and maximum quantum efficiency (%), as compared to the light-emitting devices of Comparative Examples 1 and 2.

By utilizing the heterocyclic compound, a light-emitting device having high efficiency and long lifespan and a high-quality electronic apparatus including the same may be manufactured.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus, the display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A light-emitting device comprising:
a first electrode;
a second electrode facing the first electrode; and
an interlayer between the first electrode and the second electrode and comprising an emission layer,
wherein the light-emitting device comprises a heterocyclic compound represented by Formula 1: 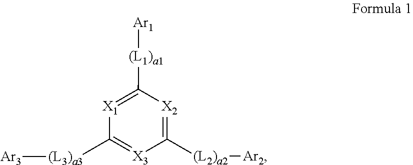
wherein, in Formula 1,
X₁ is C(R₁₀ₐₐ) or N,
X₂ is C(R_{10ab}) or N,
X₃ is C(R_{10ac}) or N,
at least one of X₁ to X₃ is N,
L₁ to L₃ are each independently a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a1 to a3 are each independently an integer from 0 to 3,
wherein, when a1 is 0, *-(L₁)ₐ₁-*′ is a single bond,
when a2 is 0, *-(L₂)ₐ₂-*′ is a single bond, and
when a3 is 0, *-(L₃)ₐ₃-*′ is a single bond,
Ar₁ is a group represented by Formula 1-1, and
Ar₂ to Ar₃ are each independently a C₃-C₃₀ carbocyclic group that is unsubstituted or substituted with R₁₀ₐ or a π electron-rich C₃-C₆₀ cyclic group that is unsubstituted or substituted with R₁₀ₐ, 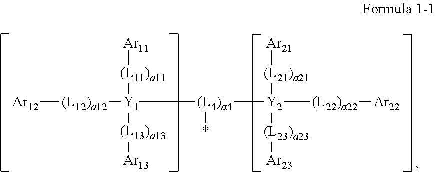
wherein, in Formula 1-1,
Y₁ and Y₂ are each independently C, Si, or Ge,
Ar₁₁, Ar₁₂, Ar₁₃, Ar₂₁, Ar₂₂, Ar₂₃, L₁₁, L₁₂, L₁₃, L₂₁, L₂₂, L₂₃, and L₄ are each independently a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a11, a12, a13, a21, a22, and a23 are each independently an integer from 0 to 3,
wherein a sum of a11, a12, a13, a21, a22, and a23 is 1 or more,
when a11 is 0, *-(L₁₁)ₐ₁₁-*′ is a single bond,
when a12 is 0, *-(L₁₂)ₐ₁₂-*′ is a single bond,
when a13 is 0, *-(L₁₃)ₐ₁₃-*′ is a single bond,
when a21 is 0, *-(L₂₁)ₐ₂₁-*′ is a single bond,
when a22 is 0, *-(L₂₂)ₐ₂₂-*′ is a single bond, and
when a23 is 0, *-(L₂₃)ₐ₂₃-*′ is a single bond,
a4 is an integer from 1 to 3,
* and *′ each indicates a binding site to a neighboring atom,
R₁₀ₐ, R₁₀ₐₐ, R_{10ab}, and R_{10ac} are each independently:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₂, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

2. The light-emitting device of claim 1, wherein the interlayer comprises the heterocyclic compound represented by Formula 1.

3. The light-emitting device of claim 1, wherein
the emission layer comprises the heterocyclic compound represented by Formula 1, and
the emission layer further comprises a fluorescent dopant or a phosphorescent dopant.

4. The light-emitting device of claim 1, wherein
the first electrode is an anode,
the second electrode is a cathode,
the interlayer further comprises a hole transport region between the first electrode and the emission layer and an electron transport region between the emission layer and the second electrode,
the hole transport region comprises a hole injection layer, a hole transport layer, an emission auxiliary layer, an electron blocking layer, or any combination thereof, and
the electron transport region comprises a hole blocking layer, an electron transport layer, an electron injection layer, or any combination thereof.

5. The light-emitting device of claim 3, wherein the emission layer is to emit blue light.

6. The light-emitting device of claim 4, further comprising at least one of a first capping layer or a second capping layer,
wherein the first capping layer is on one surface of the first electrode, and/or
the second capping layer is on one surface of the second electrode.

7. The light-emitting device of claim 6, wherein the at least one of the first capping layer or the second capping layer comprises the heterocyclic compound represented by Formula 1.

8. An electronic apparatus comprising the light-emitting device according to claim 1.

9. The electronic apparatus of claim 8, further comprising a thin-film transistor,
wherein the thin-film transistor comprises a source electrode and a drain electrode, and
the first electrode of the light-emitting device is electrically connected to the source electrode or the drain electrode of the thin-film transistor.

10. The light-emitting device of claim 8, further comprising a color filter, a color-conversion layer, a touch screen layer, a polarizing layer, or any combination thereof.

11. A heterocyclic compound represented by Formula 1: 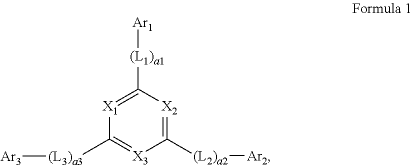
wherein, in Formula 1,
X₁ is C(R₁₀ₐₐ) or N,
X₂ is C(R_{10ab}) or N,
X₃ is C(R_{10ac}) or N,
at least one of X₁ to X₃ is N,
L₁ to L₃ are each independently a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a1 to a3 are each independently an integer from 0 to 3,
wherein, when a1 is 0, *-(L₁)ₐ₁-*′ is a single bond,
when a2 is 0, *-(L₂)ₐ₂-*′ is a single bond, and
when a3 is 0, *-(L₃)ₐ₃-*′ is a single bond,
Ar₁ is a group represented by Formula 1-1, and
Ar₂ to Ar₃ are each independently a C₃-C₃₀ carbocyclic group that is unsubstituted or substituted with R₁₀ₐ or a π electron-rich C₃-C₆₀ cyclic group that is unsubstituted or substituted with R₁₀ₐ, 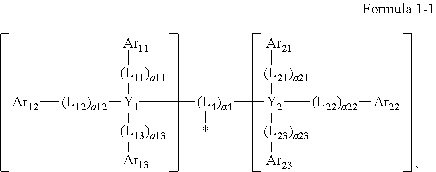
wherein, in Formula 1-1,
Y₁ and Y₂ are each independently C, Si, or Ge,
Ar₁₁, Ar₁₂, Ar₁₃, Ar₂₁, Ar₂₂, Ar₂₃, L₁₁, L₁₂, L₁₃, L₂₁, L₂₂, L₂₃, and L₄ are each independently a C₃-C₃₀ carbocyclic group that is unsubstituted or substituted with at least one R₁₀ₐ or a C₁-C₃₀ heterocyclic group that is unsubstituted or substituted with at least one R₁₀ₐ,
a11, a12, a13, a21, a22, and a23 are each independently an integer from 0 to 3,
wherein a sum of a11, a12, a13, a21, a22, and a23 is 1 or more,
when a11 is 0, *-(L₁₁)ₐ₁₁-*′ is a single bond,
when a12 is 0, *-(L₁₂)ₐ₁₂-*′ is a single bond,
when a13 is 0, *-(L₁₃)ₐ₁₃-*′ is a single bond,
when a21 is 0, *-(L₂₁)ₐ₂₁-*′ is a single bond,
when a22 is 0, *-(L₂₂)ₐ₂₂-*′ is a single bond, and
when a23 is 0, *-(L₂₃)ₐ₂₃-*′ is a single bond,
a4 is an integer from 1 to 3,
* and *′ each indicates a binding site to a neighboring atom,
R₁₀ₐ, R₁₀ₐₐ, R_{10ab}, and R_{10ac} are each independently:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₂, Q₁₁ to Q₁₃, Q₂₁ to Q₂₃, and Q₃₁ to Q₃₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

12. The heterocyclic compound of claim 11, wherein
i) each of X₁ to X₃ is N;
ii) X₁ is C(R₁₀ₐₐ), X₂ is N, and X₃ is N;
iii) X₁ is N, X₂ is C(R_{10ab}), and X₃ is N;
iv) X₁ is N, X₂ is N, and X₃ is C(R_{10ac});
v) X₁ is C(R₁₀ₐₐ), X₂ is C(R_{10ab}), and X₃ is N;
vi) X₁ is C(R₁₀ₐₐ), X₂ is N, and X₃ is C(R_{10ac}); or
vii) X₁ is N, X₂ is C(R_{10ab}), and X₃ is C(R_{10ac}).

13. The heterocyclic compound of claim 11, wherein L₁ to L₃ are each independently a group represented by one of Formulae 1-5-1 to Formula 1-5-3: 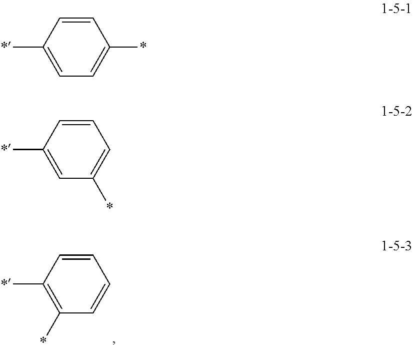
wherein, in Formulae 1-5-1 to 1-5-3,
* and *′ each indicate a binding site to a neighboring atom.

14. The heterocyclic compound of claim 11, wherein L₄ is a group represented by one of Formulae 1-5-4 to 1-5-6: 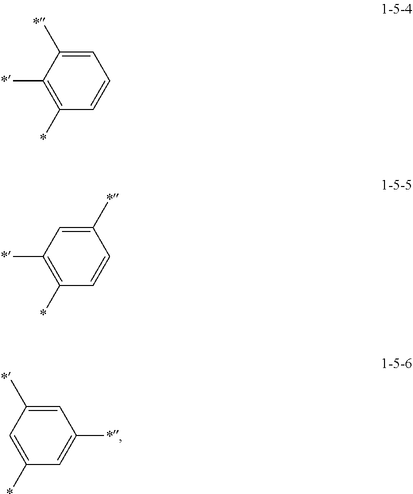
wherein, in Formulae 1-5-4 to 1-5-6,
*, *′, and *″ each indicate a binding site to a neighboring atom.

15. The heterocyclic compound of claim 11, wherein
i) each of a1 to a3 is 1;
ii) a1 is 0, and each of a2 and a3 is 1;
iii) a2 is 0, and each of a1 and a3 is 1;
iv) a3 is 0, and each of a1 and a2 is 1;
v) each of a1 and a2 is 0, and a3 is 1;
vi) each of a1 and a3 is 0, and a2 is 1; or
vii) each of a2 and a3 is 0, and a1 is 1.

16. The heterocyclic compound of claim 11, wherein, in Formula 1-1, a moiety represented by 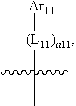
a moiety represented by 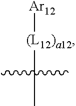
a moiety represented by 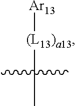
a moiety represented by 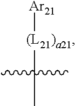
a moiety represented by 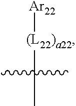
and a moiety represented by 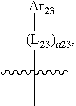
are each independently a benzene group represented by one of Formulae 1-1-1 to 1-1-19: 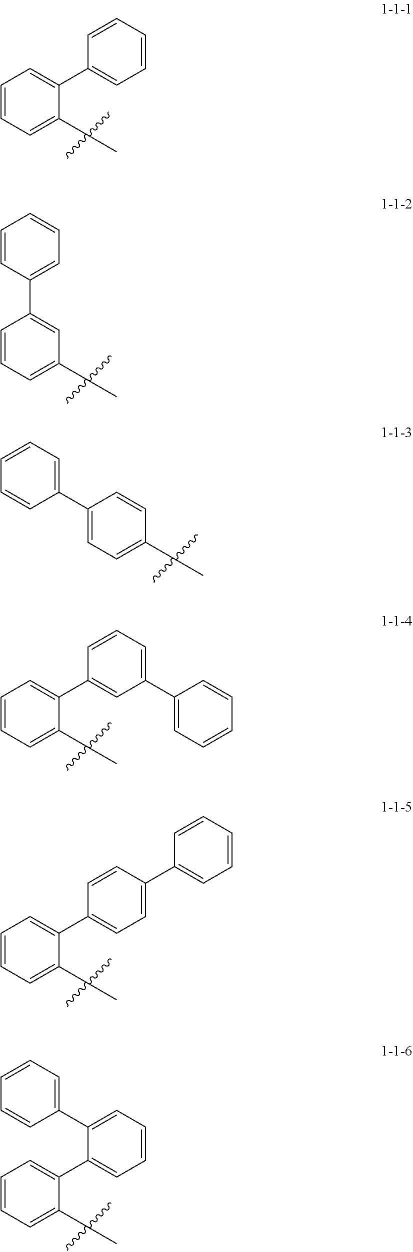 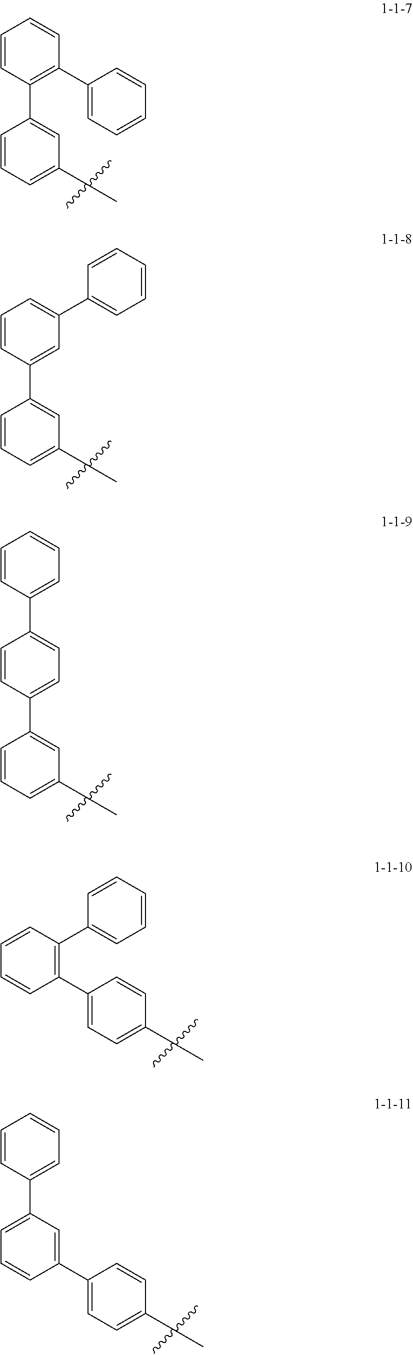 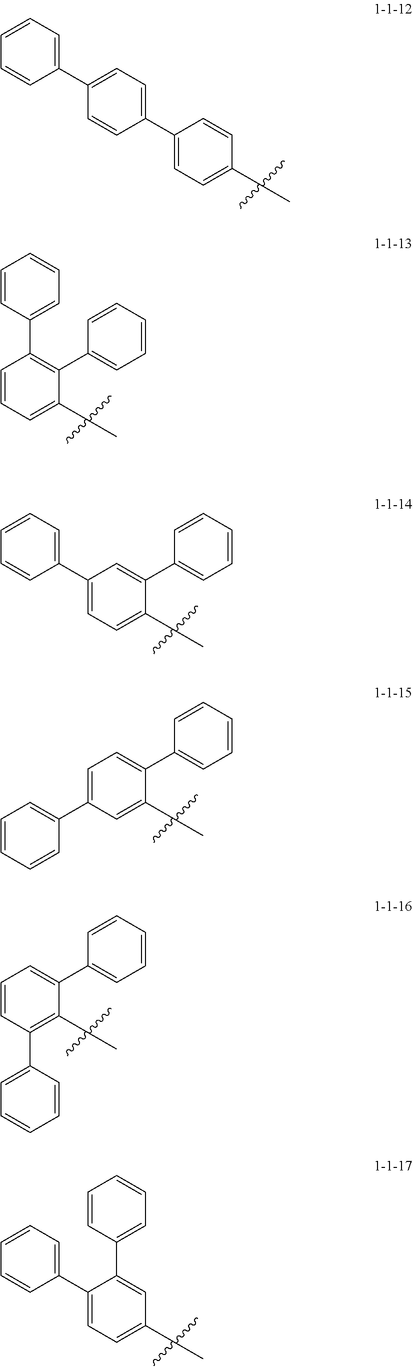 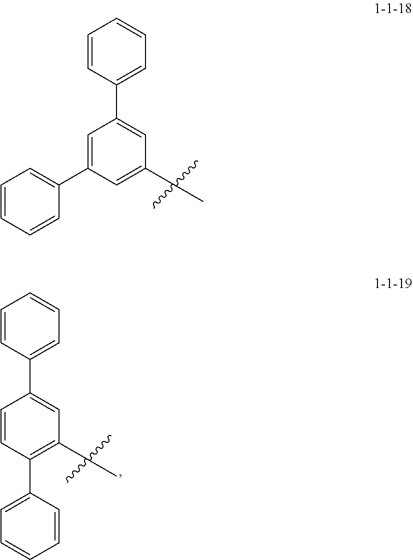
wherein, in Formulae 1-1-1 to 1-1-19, [symbol]
indicates a binding site to a neighboring atom.

17. The heterocyclic compound of claim 11, wherein Ar₂ or Ar₃ is a carbazole group that is unsubstituted or substituted with at least one R₁₀ₐ.

18. The heterocyclic compound of claim 17, wherein the other one of Ar₂ and Ar₃ that is not the carbazole group is a benzene group or a group represented by one of Formulae 1-6-1 to 1-6-3: 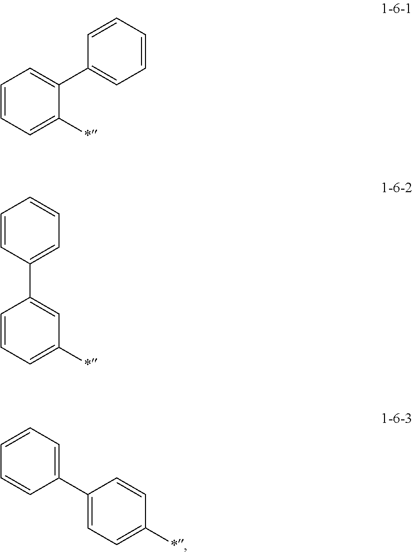
wherein, in Formulae 1-6-1 to 1-6-3,
*″, indicates a binding site to a neighboring atom.

19. The heterocyclic compound of claim 11, wherein Ar₂ and Ar₃ are each independently a carbazole group that is unsubstituted or substituted with at least one R₁₀ₐ.

20. The heterocyclic compound of claim 11, wherein a degree of deuteration of the heterocyclic compound is 1% or more.
